(19) United States
(12) Patent Application Publication
(10) Pub. No.: US 2012/0199825 A1
(43) Pub. Date: Aug. 9, 2012

(54) ORGANIC ELECTROLUMINESCENT DEVICE

(75) Inventors: Masayuki Soga, Kita-ku (JP); Yusuke Ishii, Tsukuba-shi (JP)

(73) Assignee: SUMITOMO CHEMICAL COMPANY, LIMITED, Chuo-ku, Tokyo (JP)

(21) Appl. No.: 13/502,933

(22) PCT Filed: Oct. 21, 2010
(86) PCT No.: PCT/JP2010/069122

§ 371 Date: Apr. 19, 2012

(30) Foreign Application Priority Data
Oct. 22, 2009 (JP) 2009-243349
Oct. 22, 2009 (JP) 2009-243351
Jun. 24, 2010 (JP) 2010-143554
Jun. 24, 2010 (JP) 2010-143555

(51) Int. Cl. H01L 51/54

(52) U.S. Cl. 257/40; 257/E51.026

(57) ABSTRACT

An organic electroluminescent device comprising an anode, a cathode, a light emitting layer that is disposed between the anode and the cathode and contains a first light emitting layer material containing a phosphorescent compound and a second light emitting layer material containing a charge transporting polymer compound (that is, a light emitting layer containing a first light emitting layer material and a second light emitting layer material), and a hole transporting layer that is disposed between the anode and the light emitting layer so as to be adjacent to the light emitting layer and is composed of a hole transporting polymer compound, wherein the lowest excitation triplet energy T1ₑ (eV) of the first light emitting layer material, the lowest excitation triplet energy T1ₕ (eV) of the second light emitting layer material and the lowest excitation triplet energy T1ₜ (eV) of the hole transporting polymer compound satisfy the following formulae (A) and (B):

T1ₑ≦T1ₕ (A)

T1ₜ−T1ₑ≦0.10 (B).

An organic electroluminescent device comprising an anode and a cathode, and a hole transporting layer and a light emitting layer disposed between the anode and the cathode, wherein the hole transporting layer contains 1) a mixture of 2,2′-bipyridine and/or 2,2′-bipyridine derivative and a non-2,2′-bipyridinediyl group-containing hole transporting polymer compound, 2) a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group, or a combination thereof.

### TECHNICAL FIELD

The present invention relates to an organic electroluminescent device.

### BACKGROUND ART

It is known that an organic electroluminescent device of high light emission efficiency having an anode and a cathode, a light emitting layer disposed between the electrodes, and a hole transporting layer disposed adjacent to the light emitting layer is obtained, by using a composition prepared by doping a polymer compound-containing host material with a phosphorescent compound as a dopant for fabrication of the light emitting layer and by using a hole transporting polymer compound having lowest excitation triplet energy larger than that of the phosphorescent compound for fabrication of the hole transporting layer (Patent document 1).

### [Patent Document 1]

JP-A No. 2008-179617

Recently, an organic electroluminescent device equipped with a hole transporting layer composed of a polymer compound has been developed. As this organic electroluminescent device, an organic electroluminescent device equipped with a hole transporting layer composed of a polymer compound having a substituted triphenylamine residue as a repeating unit and an organic electroluminescent device equipped with a hole transporting layer composed of a polymer compound having a fluorenediyl group as a repeating unit are known (Patent documents 2 and 3).

### [Patent Document 2]

JP-A No. 10-92582

### [Patent Document 3]

International Publication WO 2005/49548 pamphlet

### DISCLOSURE OF THE INVENTION

The organic electroluminescent device disclosed in the above-described patent document 1, however, has an insufficient luminance life.

The organic electroluminescent devices disclosed in the above-described patent documents 2 and 3 show an increase in driving voltage at the half life of luminance when driven at a constant current value.

First, the first group of inventions will be illustrated.

The present invention has an object of providing an organic electroluminescent device having a long luminance life.

The present invention provides the following organic electroluminescent devices.

[1] An organic electroluminescent device comprising

an anode,

a cathode,

a light emitting layer that is disposed between the anode and the cathode and contains a first light emitting layer material containing a phosphorescent compound and a second light emitting layer material containing a charge transporting polymer compound, and

a hole transporting layer that is disposed between the anode and the light emitting layer so as to be adjacent to the light emitting layer and is composed of a hole transporting polymer compound,

wherein the lowest excitation triplet energy T1ₑ (eV) of the first light emitting layer material, the lowest excitation triplet energy T1ₕ (eV) of the second light emitting layer material and the lowest excitation triplet energy T1ₜ (eV) of the hole transporting polymer compound satisfy the following formulae (A) and (B):

T1ₑ≦T1ₕ (A)

T1ₜ−T1ₑ≦0.10 (B).

[2] The organic electroluminescent device according to [1], wherein, T1ₜ and T1ₑ further satisfy the following formula (B′):

T1ₜ−T1ₑ≧−0.30 (B′).

[3] The organic electroluminescent device according to [1] or [2], wherein the minimum value IPₑₕ (eV) of the ionization potential of the above-described first light emitting layer material and the ionization potential of the above-described second light emitting layer material, and the ionization potential IPₜ (eV) of the above-described hole transporting polymer compound satisfy the following formula (C):

IPₑₕ−IPₜ≧−0.20 (C).

[4] The organic electroluminescent device according to any one of [1] to [3], wherein the above-described hole transporting polymer compound is a polymer compound containing a constitutional unit represented by the following formula (4):

Ar¹ (4)

in the formula (4), Ar¹ represents an arylene group, a divalent aromatic heterocyclic group, or a divalent group composed of two or more directly linked identical or different groups selected from the group consisting of the arylene group and the divalent aromatic heterocyclic group, wherein the group represented by Ar¹ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent; and a constitutional unit represented by the following formula (5):

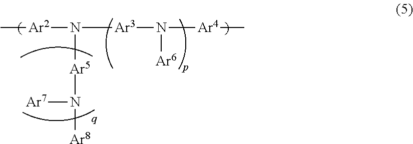

in the formula (5), Ar², Ar³, Ar⁴ and Ar⁵ each independently represent an arylene group, a divalent aromatic heterocyclic group, or a divalent group composed of two or more directly linked identical or different groups selected from the group consisting of the arylene group and the divalent aromatic heterocyclic group; Ar⁶, Ar⁷ and Ar⁸ each independently represent an aryl group or a monovalent aromatic heterocyclic group; p and q each independently represent 0 or 1, wherein the groups represented by Ar², Ar³, Ar⁴, Ar⁵, Ar⁶, Ar⁷ and Ar⁸ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent, and the groups represented by Ar⁵, Ar⁶, Ar⁷ and Ar⁸ may each be linked directly or via —O—, —S—, —C(═O)—, —C(═O)—O—, —N(R^{A})—, —C(═O)—N(R^{A})— or —C(R^{A})₂— to the group represented by Ar², Ar³, Ar⁴, Ar⁵, Ar⁶, Ar⁷ or Ar⁸ linked to the nitrogen atom to which the groups are attached, thereby forming a 5 to 7-membered ring; R^{A} represents an alkyl group, an aryl group, a monovalent aromatic heterocyclic group or an aralkyl group.

[5] The organic electroluminescent device according to any one of [1] to [4], wherein the above-described hole transporting polymer compound is a crosslinkable hole transporting polymer compound.

[6] The organic electroluminescent device according to any one of [1] to [5], wherein the above-described charge transporting polymer compound is a polymer compound containing at least one constitutional unit selected from the group consisting of constitutional units represented by the following formula (4):

Ar¹ (4)

in the formula (4), Ar¹ represents an arylene group, a divalent aromatic heterocyclic group, or a divalent group composed of two or more directly linked identical or different groups selected from the group consisting of the arylene group and the divalent aromatic heterocyclic group, wherein the group represented by Ar¹ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent; and constitutional units represented by the following formula (5):

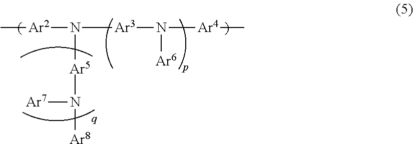

in the formula (5), Ar², Ar³, Ar⁴ and Ar⁵ each independently represent an arylene group, a divalent aromatic heterocyclic group, or a divalent group composed of two or more directly linked identical or different groups selected from the group consisting of the arylene group and the divalent aromatic heterocyclic group; Ar⁶, Ar⁷ and Ar⁸ each independently represent an aryl group or a monovalent aromatic heterocyclic group; p and q each independently represent 0 or 1, wherein the groups represented by Ar², Ar³, Ar⁴, Ar⁵, Ar⁶, Ar⁷ and Ar⁸ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent, and the groups represented by Ar⁵, Ar⁶, Ar⁷ and Ar⁸ may each be linked directly or via —O—, —S—, —C(═O)—, —C(═O)—O—, —N(R^{A})—, —C(═O)—N(R^{A})— or —C(R^{A})₂— to the group represented by Ar², Ar³, Ar⁴, Ar⁵, Ar⁶, Ar⁷ or Ar⁸ linked to the nitrogen atom to which the groups are attached, thereby forming a 5 to 7-membered ring; R^{A} represents an alkyl group, an aryl group, a monovalent aromatic heterocyclic group or an aralkyl group.

[7] The organic electroluminescent device according to any one of [4] to [6], containing a constitutional unit represented by the following formula (6) and/or a constitutional unit represented by the following formula (7), as the constitutional unit represented by the above-described formula (4):

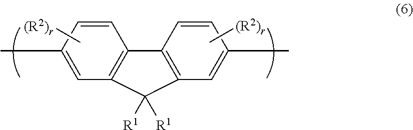

in the formula (6), each R¹ represents an alkyl group, an aryl group, a monovalent aromatic heterocyclic group or an aralkyl group; each R² represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group; each r represents an integer of 0 to 3, wherein two R¹ moieties may be the same or different, and two R¹ moieties may be linked to form a ring; when a plurality of R² moieties are present, these may be the same or different; two characters of r may be the same or different.

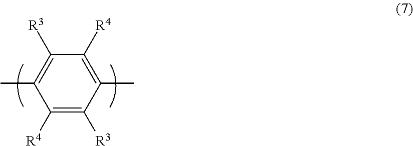

in the formula (7), each R³ represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group or a cyano group; each R⁴ represents a hydrogen atom, an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group, wherein two R³ moieties may be the same or different, and two R⁴ moieties may be the same or different.

[8] The organic electroluminescent device according to [7], wherein the constitutional unit represented by the above-described formula (4) is a constitutional unit represented by the above-described formula (6).

[9] The organic electroluminescent device according to [7], wherein the constitutional unit represented by the above-described formula (4) is a constitutional unit represented by the above-described formula (7).

[10] The organic electroluminescent device according to any one of [4] to [9], wherein at least one of p and q is 1 in the above-described formula (5).

[11] The organic electroluminescent device according to any one of [1] to [10], wherein the above-described phosphorescent compound is an iridium complex.

[12] The organic electroluminescent device according to any one of [1] to [11], having a hole injection layer between the above-described anode and the above-described hole transporting layer.

Next, the second group of inventions will be illustrated.

The present invention has an object of providing an organic electroluminescent device showing suppression of an increase in driving voltage at the half life of luminance when driven at a constant current value.

The present invention provides the following organic electroluminescent devices.

[13] An organic electroluminescent device comprising an anode, a cathode, and a hole transporting layer and a light emitting layer disposed between the anode and the cathode,

wherein the hole transporting layer contains

1) a mixture of 2,2′-bipyridine and/or 2,2′-bipyridine derivative and a non-2,2′-bipyridinediyl group-containing hole transporting polymer compound,

2) a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group,

or a combination thereof.

[14] The organic electroluminescent device according to [13], wherein the above-described non-2,2′-bipyridinediyl group-containing hole transporting polymer compound is a polymer compound represented by the following formula α-(2):

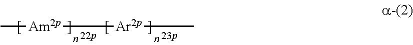

in the formula α-(2), Am^{2p} represents a divalent aromatic amine residue, and Ar^{2p} represents an unsubstituted or substituted arylene group; n^{22p} and n^{23p} each independently represent the number indicating the molar ratio of a divalent aromatic amine residue represented by Am^{2p} to an unsubstituted or substituted arylene group represented by Ar^{2p} in the polymer compound, satisfying n^{22p}+n^{23p}=1, 0.001≦n^{22p}≦1 and 0≦n^{23p}≦0.999; when a plurality of Am^{2p}s are present, these may be the same or different, and when a plurality of Ar^{2p}s are present, these may be the same or different.

[15] The organic electroluminescent device according to [14], wherein the arylene group represented by the above-described Ar^{2p} includes at least one member selected from the group consisting of an unsubstituted or substituted fluorenediyl group and an unsubstituted or substituted phenylene group.

[16] The organic electroluminescent device according to any one of [13] to [15], wherein the above-described 2,2′-bipyridine or 2,2′-bipyridine derivative is a compound represented by the following formula α-(3):

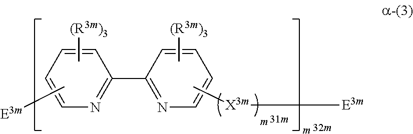

in the formula α-(3), each E^{3m} and each R^{3m} independently represent a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group; X^{3m} represents an unsubstituted or substituted arylene group, an unsubstituted or substituted alkanediyl group, an unsubstituted or substituted alkenediyl group or an unsubstituted or substituted alkynediyl group, wherein the plurality of E^{3m} moieties may be the same or different and the plurality of R^{3m} moieties may be the same or different; m^{31m} represents an integer of 0 to 3; m^{32m} represents an integer of 1 to 3; wherein when a plurality of m^{31m} moieties are present, these may be the same or different and when a plurality of X^{3m} moieties are present, these may be the same or different.

[17] The organic electroluminescent device according to [16], wherein E^{3m} represents a hydrogen atom, a hydroxyl group, an unsubstituted or substituted alkyl group, an unsubstituted or substituted alkoxy group or an unsubstituted or substituted aryl group in the above-described formula α-(3).

[18] The organic electroluminescent device according to [16] or [17], wherein R^{3m} represents a hydrogen atom in the above-described formula α-(3).

[19] The organic electroluminescent device according to any one of [16] to [18], wherein X^{3m} represents an unsubstituted or substituted arylene group or an unsubstituted or substituted alkanediyl group in the above-described formula α-(3).

[20] The organic electroluminescent device according to any one of [16] to [19], wherein the compound represented by the above-described formula α-(3) is a compound represented by the following formula α-(4):

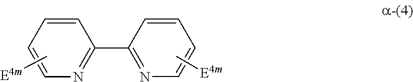

in the formula α-(4), each E^{4m} represents a hydrogen atom, a hydroxyl group, an unsubstituted or substituted alkyl group or an unsubstituted or substituted alkoxy group, wherein the plurality of E^{4m} moieties may be the same or different, and at least one of them represents a hydroxyl group, an unsubstituted or substituted alkyl group or an unsubstituted or substituted alkoxy group.

[21] The organic electroluminescent device according to any one of [16] to [19], wherein the compound represented by the above-described formula α-(3) is a compound represented by the following formula α-(5):

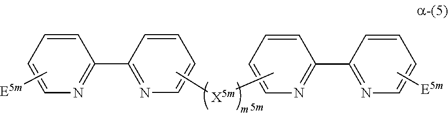

in the formula α-(5), each E^{5m} represents a hydrogen atom, a hydroxyl group, an unsubstituted or substituted alkyl group or an unsubstituted or substituted alkoxy group, wherein the plurality of E^{5m} moieties may be the same or different; X^{5m} represents an unsubstituted or substituted arylene group or an unsubstituted or substituted alkanediyl group; m^{5m} represents an integer of 1 to 3, wherein when a plurality of X^{5m}s are present, these may be the same or different.

[22] The organic electroluminescent device according to any one of [13] to [21], wherein the above-described hole transporting layer contains a mixture of 2,2′-bipyridine and/or 2,2′-bipyridine derivative and a non-2,2′-bipyridinediyl group-containing hole transporting polymer compound, and the proportion of the 2,2′-bipyridine and 2,2′-bipyridine derivative contained in the hole transporting layer is 0.01 to 50 wt %.

[23] The organic electroluminescent device according to any one of [13] to [22], wherein the above-described 2,2′-bipyridinediyl group-containing polymer compound is a polymer compound represented by the following formula α-(1):

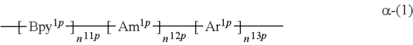

in the formula α-(1), Bpy^{1p} represents an unsubstituted or substituted 2,2′-bipyridinediyl group; Am^{1p} represents a divalent aromatic amine residue; Ar^{1p} represents an unsubstituted or substituted arylene group; n^{11p}, n^{12p} and n^{13p} each independently represent the number indicating the molar ratio of the unsubstituted or substituted 2,2′-bipyridinediyl group represented by Bpy^{1p}, the divalent aromatic amine residue represented by Am^{1p} and the unsubstituted or substituted arylene group represented by Ar^{1p} in the polymer compound, satisfying n^{11p}+n^{12p}+n^{13p}=1, 0.001≦n^{11p}≦0.999, 0.001≦n^{12p}≦0.999 and 0≦n^{13p}≦0.998; when a plurality of Bpy^{1p} moieties are present, these may be the same or different; when a plurality of Am^{1p} moieties are present, these may be the same or different; when a plurality of Ar^{1p} moieties are present, these may be the same or different.

[24] The organic electroluminescent device according to [23], wherein Bpy^{1p} in the above-described formula α-(1) is a divalent group represented by the following formula α-(1-2):

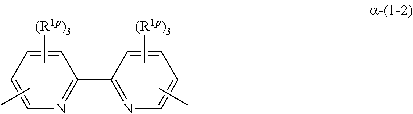

in the formula α-(1-2), each R^{1p} represents a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group, wherein a plurality of R^{1p} moieties may be the same or different.

[25] The organic electroluminescent device according to [24], wherein R^{1p} in the above-described formula α-(1-2) is a hydrogen atom.

[26] The organic electroluminescent device according to any one of [13] to [25], wherein the above-described hole transporting layer is fabricated by using

A) a first composition containing the above-described mixture of 2,2′-bipyridine and/or 2,2′-bipyridine derivative and a non-2,2′-bipyridinediyl group-containing hole transporting polymer compound; and an organic solvent,

B) a second composition containing the above-described 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group; and an organic solvent,

or a combination thereof.

[27] The organic electroluminescent device according to any one of [13] to [26], wherein the above-described hole transporting layer and the above-described light emitting layer are in contact with each other, and a hole injection layer is disposed between the above-described hole transporting layer and the above-described anode.

### MODES FOR CARRYING OUT THE INVENTION

First, the first group of inventions will be illustrated in detail.

The present invention will be illustrated below. In the present specification, Me represents a methyl group and Et represents an ethyl group.

In the present specification, “the hole transporting layer composed of a hole transporting polymer compound” includes a hole transporting layer containing a hole transporting polymer compound itself, a hole transporting layer containing a hole transporting polymer compound in cross-linked condition in its molecule and/or between molecules, and the like.

For the organic electroluminescent device of the present invention, the above-described formula (A) is T1ₑ≦T1ₕ, and if T1ₑ is larger than T1ₕ, there is a tendency of lowering of the light emission efficiency.

In the organic electroluminescent device of the present invention, the above-described formula (B) is T1ₜ−T1ₑ≦0.10, and if T1ₜ−T1ₑ is larger than 0.10, there is a tendency of shortening of the luminance life. T1ₜ−T1ₑ is preferably 0.05 or less, more preferably 0 or less, from the viewpoint of the luminance life.

Further, it is preferable that T1ₜ−T1ₑ satisfies the following formula (B′):

T1ₜ−T1ₑ≧−0.30 (B′),

and it is more preferably −0.20 or more, particularly preferably −0.10 or more, from the viewpoint of the light emission efficiency.

In the present invention, the lowest excitation triplet energy is determined by a scientific calculation method. In the scientific calculation method, a constitutional unit is optimized in its structure, by a density functional approach at B3LYP level, using a quantum chemistry calculation program Gaussian 03, with a base function of 3-21G*. Thereafter, the lowest excitation triplet energy is calculated, by a time-dependent density functional approach at B3LYP level, with a base function of 3-21G*. In the case of the presence of an atom to which 3-21G* cannot be applied as the base function, LANL2DZ is used as the base function for this atom.

In the present invention, when the above-described hole transporting polymer compound and the above-described charge transporting polymer compound are composed of one constitutional unit, the lowest excitation triplet energy is calculated for a dimer of this constitutional unit and the calculated value is used as the lowest excitation triplet energy of the polymer compound. When the above-described hole transporting polymer compound and the above-described charge transporting polymer compound are composed of two or more constitutional units, the lowest excitation triplet energies are calculated for all dimers which can be generated in polymerization from constitutional units contained in a molar ratio of 1% or more, and the minimum value among them is used as the lowest excitation triplet energy of the polymer compound.

In the organic electroluminescent device of the present invention, when the hole transporting layer is formed by using two or more of the above-described hole transporting polymer compound and when the light emitting layer is formed by using two or more of the above-described charge transporting polymer compound, the lowest excitation triplet energies are calculated for all the hole transporting polymer compounds and the charge transporting polymer compounds used in formation of the layers, and the minimum value among them is used as the lowest excitation triplet energy of the polymer compound.

In the organic electroluminescent device of the present invention, the minimum value IPₑₕ (eV) of the ionization potential of the above-described first light emitting layer material and the ionization potential of the above-described second light emitting layer material, and the ionization potential IPₜ (eV) of the above-described hole transporting polymer compound preferably satisfy the following formula (C):

IPₑₕ−IPₜ≧−0.20 (C)

and IPₑₕ−IPₜ is more preferably −0.10 or more, further preferably −0.05 or more, particularly preferably 0 or more, from the viewpoint of the hole injectability.

In the present invention, the ionization potential of the above-described first light emitting layer material, the above-described second light emitting layer material and the above-described hole transporting polymer compound can be directly measured by a photoelectron spectroscopic method, and specifically, can be measured by a low energy electron spectrometer.

In the organic electroluminescent device of the present invention, when light emitting layer contains two or more of the above-described first light emitting layer material and two or more of the above-described second light emitting layer material, the ionization potentials are measured for all the light emitting layer materials contained in a weight ratio of 5% or more in the layer, and the minimum value of them is used as the ionization potential of the material.

In the organic electroluminescent device of the present invention, when the hole transporting layer is formed by using two or more of the above-described hole transporting polymer compound, the ionization potentials are measured for all the compounds contained in a weight ratio of 5% or more, and the minimum value of them is used as the ionization potential of the hole transporting polymer compound.

### <Light Emitting Layer>

First Light Emitting Layer Material

The first light emitting layer material is usually composed only of a phosphorescent compound (that is, only a phosphorescent compound as an essential component), however, additionally, a fluorescent compound such as an anthracene derivative, a perylene derivative, a coumarin derivative, a rubrene derivative, a quinacridone derivative, a squarylium derivative, a porphyrin derivative, a styryl dye, a tetracene derivative, a pyrazolone derivative, decacyclene, phenoxazone and the like may also be contained. The components constituting the first light emitting layer material may each be composed of a single compound or two or more compounds. The first light emitting layer material is, in general, called a guest material in some cases.

The above-described phosphorescent compound includes phosphorescent metal complexes. This phosphorescent metal complex has a central metal and a ligand. The central metal is usually an atom having an atomic number of 50 or more and is a metal manifesting spin-orbit interaction in the compound and capable of causing intersystem crossing between the singlet state and the triplet state. This central metal includes preferably gold, platinum, iridium, osmium, rhenium, tungsten, europium, terbium, thulium, dysprosium, samarium, praseodymium, gadolinium and ytterbium, more preferably gold, platinum, iridium, osmium, rhenium and tungsten, further preferably gold, platinum, iridium, osmium and rhenium, particularly preferably platinum and iridium, and especially preferably iridium.

The ligand in the above-described phosphorescent metal complex is preferably an aromatic ring (single ring or condensed ring) containing a coordinating atom for the central metal, and more preferably an aromatic ring in which a part or all of hydrogen atoms in the aromatic ring are substituted by a monovalent group having no coordinating atom. This monovalent group is preferably an alkyl group, an aryl group or an aromatic heterocyclic group, more preferably an aryl group or an aromatic heterocyclic group, since the luminance life of the light emitting device becomes excellent.

Preferable as the above-described phosphorescent metal complex are iridium complexes such as Ir(ppy)₃ (described, for example, in Appl. Phys. Lett., (1999), 75(1), 4 and Jpn. J. Appl. Phys., 34, 1883 (1995)), Btp₂Ir(acac) (described, for example, in Appl. Phys. Lett., (2001), 78(11), 1622), ADS066GE commercially marketed from American Dye Source, Inc. (trade name) and the like containing iridium as the central metal, platinum complexes such as PtOEP and the like containing platinum as the central metal (described, for example, in Nature, (1998), 395, 151), and europium complexes such as Eu(TTA)₃-phen and the like containing europium as the central metal, and more preferable are iridium complexes.

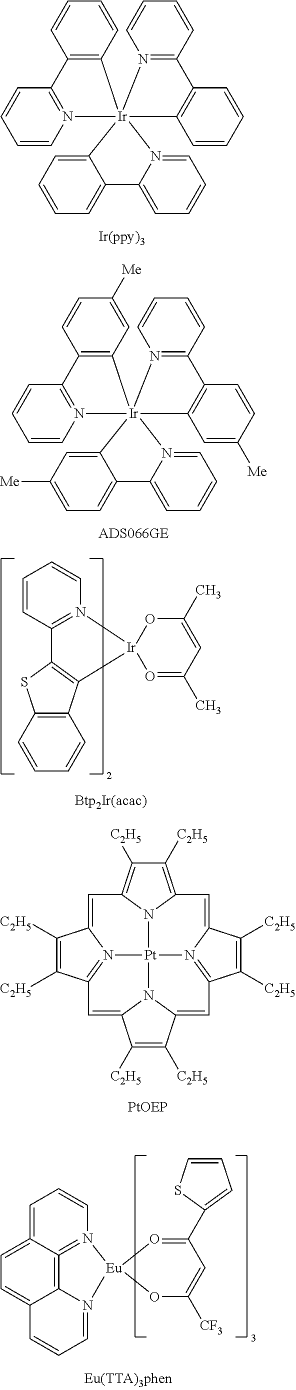

As the above-described phosphorescent metal complex, complexes such as FIrpic, light emitting materials A to S and the like described in Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 97(2), 113, Syn. Met., (1999), 99(2), 127, Adv. Mater., (1999), 11(10), 852, Inorg. Chem., (2003), 42, 8609, Inorg. Chem., (2004), 43, 6513, Inorg. Chem., 2007, 46, 11082, Journal of the SID 11/1, 161 (2003), WO2002/066552, WO2004/020504, WO2004/020448 and the like can also be used, in addition to the above-described complexes.

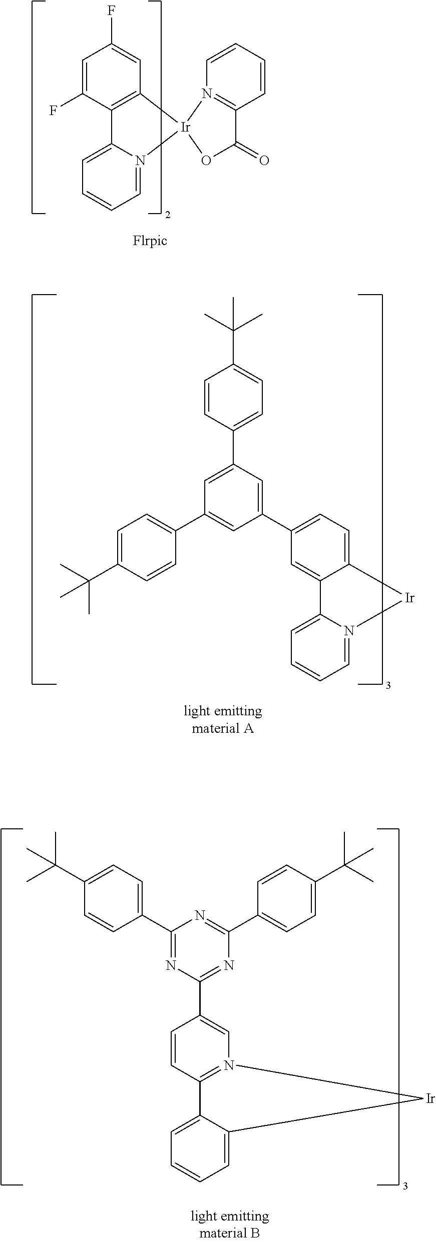

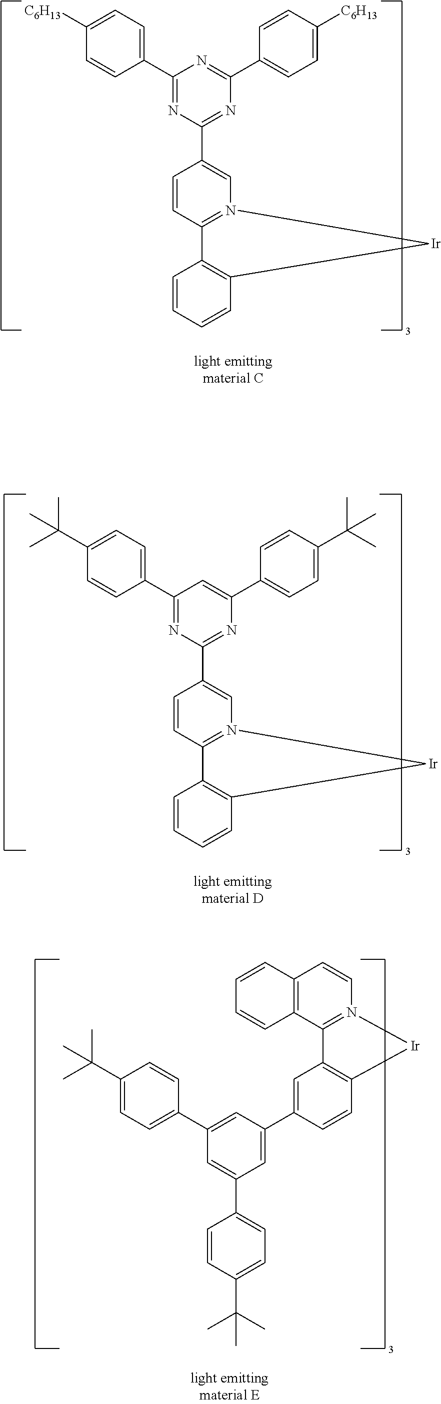

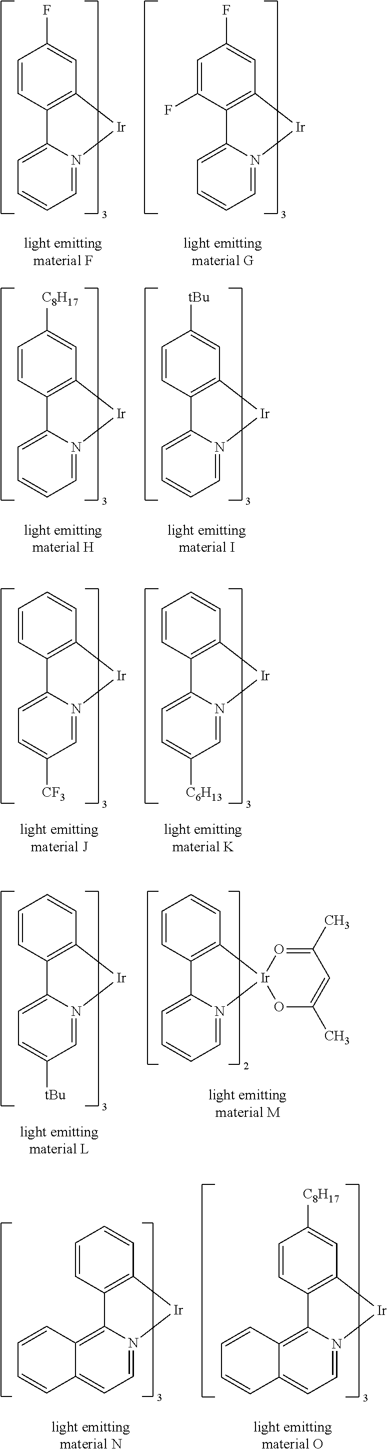

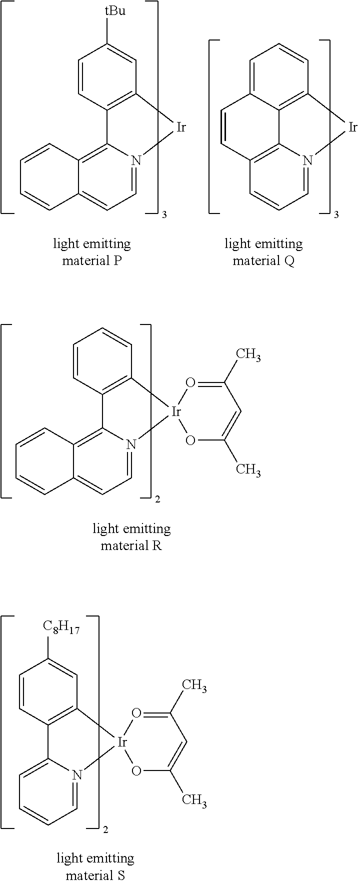

The weight proportion of the first light emitting layer material with respect to the weight of the second light emitting layer material described later is usually 0.01 to 1.0, and from the viewpoint of goodness of the luminance life of the light emitting device, it is preferably 0.02 to 0.8, more preferably 0.05 to 0.65.

Second Light Emitting Layer Material

The second light emitting layer material is usually composed only of a charge transporting polymer compound (that is, only a charge transporting polymer compound as an essential component), however, additionally, a charge transporting low molecular weight compound such as an aromatic amine, a carbazole derivative, a polyparaphenylene derivative, an oxadiazole derivative, anthraquinodimethane and its derivatives, benzoquinone and its derivatives, naphthoquinone and its derivatives, anthraquinone and its derivatives, tetracyanoanthraquinodimethane and its derivatives, diphenoquinone and its derivatives, triazine and its derivatives, a metal complex of 8-hydroxyquinoline and its derivatives, and the like may also be contained. The components constituting the second light emitting layer material may each be composed of a single compound or two or more compounds. The second light emitting layer material is, in general, called a host material in some cases.

The above-described charge transporting polymer compound is preferably a polymer compound containing at least one constitutional unit selected from the group consisting of constitutional units represented by the following formula (4):

Ar¹ (4)

in the formula (4), Ar¹ represents an arylene group, a divalent aromatic heterocyclic group, or a divalent group composed of two or more directly linked identical or different groups selected from the group consisting of the arylene group and the divalent aromatic heterocyclic group, wherein the group represented by Ar¹ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent.] and constitutional units represented by the following formula (5):

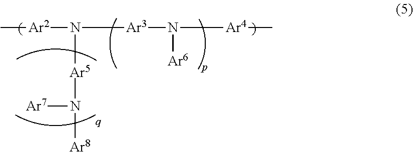

in the formula (5), Ar², Ar³, Ar⁴ and Ar⁵ each independently represent an arylene group, a divalent aromatic heterocyclic group, or a divalent group composed of two or more directly linked identical or different groups selected from the group consisting of the arylene group and the divalent aromatic heterocyclic group; Ar⁶, Ar⁷ and Ar⁸ each independently represent an aryl group or a monovalent aromatic heterocyclic group; p and q each independently represent 0 or 1, wherein the groups represented by Ar², Ar³, Ar⁴, Ar⁵, Ar⁶, Ar⁷ and Ar⁸ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent, and the groups represented by Ar⁵, Ar⁶, Ar⁷ and Ar⁸ may each be linked directly or via —O—, —S—, —C(═O)—, —C(═O)—O—, —N(R^{A})—, —C(═O)—N(R^{A})— or —C(R^{A})₂— to the group represented by Ar², Ar³, Ar⁴, Ar⁵, Ar⁶, Ar⁷ or Ar⁸ linked to the nitrogen atom to which the groups are attached, thereby forming a 5 to 7-membered ring; R^{A} represents an alkyl group, an aryl group, a monovalent aromatic heterocyclic group or an aralkyl group, from the viewpoint of the charge injectability and the charge transportability. Of them, the above-described polymer compound includes more preferably polymer compounds in which the molar ratio of a constitutional unit represented by the above-described formula (4) is 80% or more and the molar ratio of a constitutional unit represented by the above-described formula (5) is less than 20%, and particularly preferably polymer compounds in which the molar ratio of a constitutional unit represented by the above-described formula (4) is 90% or more and the molar ratio of a constitutional unit represented by the above-described formula (5) is less than 10%.

The constitutional unit represented by the above-described formula (4) is more preferably a constitutional unit represented by the following formula (6):

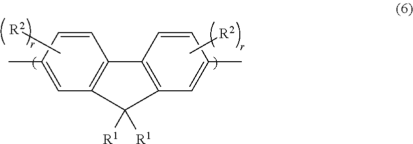

in the formula (6), each R¹ represents an alkyl group, an aryl group, a monovalent aromatic heterocyclic group or an aralkyl group; each R² represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group; each r represents an integer of 0 to 3, wherein two R′ moieties may be the same or different, and two R¹ moieties may be linked to form a ring; when a plurality of R² moieties are present, these may be the same or different; two characters of r may be the same or different,
or a constitutional unit represented by the following formula (7):

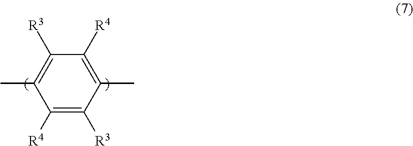

in the formula (7), each R³ represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group or a cyano group; each R⁴ represents a hydrogen atom, an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group, wherein two R³ moieties may be the same or different, and two R⁴ moieties may be the same or different,
from the viewpoint of the charge injectability and the charge transportability.

It is more preferable from the viewpoint of the driving voltage that a constitutional unit represented by the following formula (6) and/or a constitutional unit represented by the following formula (7) is contained as the constitutional unit represented by the above-described formula (4).

The arylene group represented by Ar¹ in the above-described formula (4) and the arylene groups represented by Ar² to Ar⁵ in the above-described formula (5) are an atomic group obtained by removing two hydrogen atoms from an aromatic hydrocarbon and include groups having a condensed ring, and groups having two or more independent benzene rings or condensed rings or both of them linked directly or via a conjugated connecting group such as a vinylene group and the like. The arylene group may have a substituent. The carbon atom number of a portion of the arylene group excluding the substituent is usually 6 to 60, and the total carbon atom number including the substituent is usually 6 to 100.

The substituent which the above-described arylene group may have includes preferably an alkyl group, an alkenyl group, an alkynyl group, an alkoxy group, an aryl group, an aryloxy group, a halogen atom and a cyano group from the viewpoint of the polymerizability and easiness of synthesis of a monomer, preferably an alkenyl group and an alkynyl group from the viewpoint of easiness of fabrication of an organic electroluminescent device, and preferably an alkyl group, an alkenyl group, an alkynyl group and an aryl group from the viewpoint of the light emission property when made into a device.

The above-described arylene group includes phenylene groups (the formulae Ar4 to Ar3), naphthalenediyl groups (the formulae Ar4 to Ar13), anthracenediyl groups (the formulae Ar14 to Ar19), biphenyldiyl groups (the formulae Ar20 to Ar25), terphenyldiyl groups (the formulae Ar26 to Ar28), condensed ring compound groups (the formulae Ar29 to Ar35), fluorenediyl groups (the formulae Ar36 to Ar68) and benzofluorenediyl groups (the formulae Ar69 to Ar88). Phenylene groups, biphenyldiyl groups, terphenyldiyl groups and fluorenediyl groups are preferable, phenylene groups and fluorenediyl groups are more preferable and fluorenediyl groups are particularly preferable, from the viewpoint of the light emission property when made into a device. These groups may have a substituent.

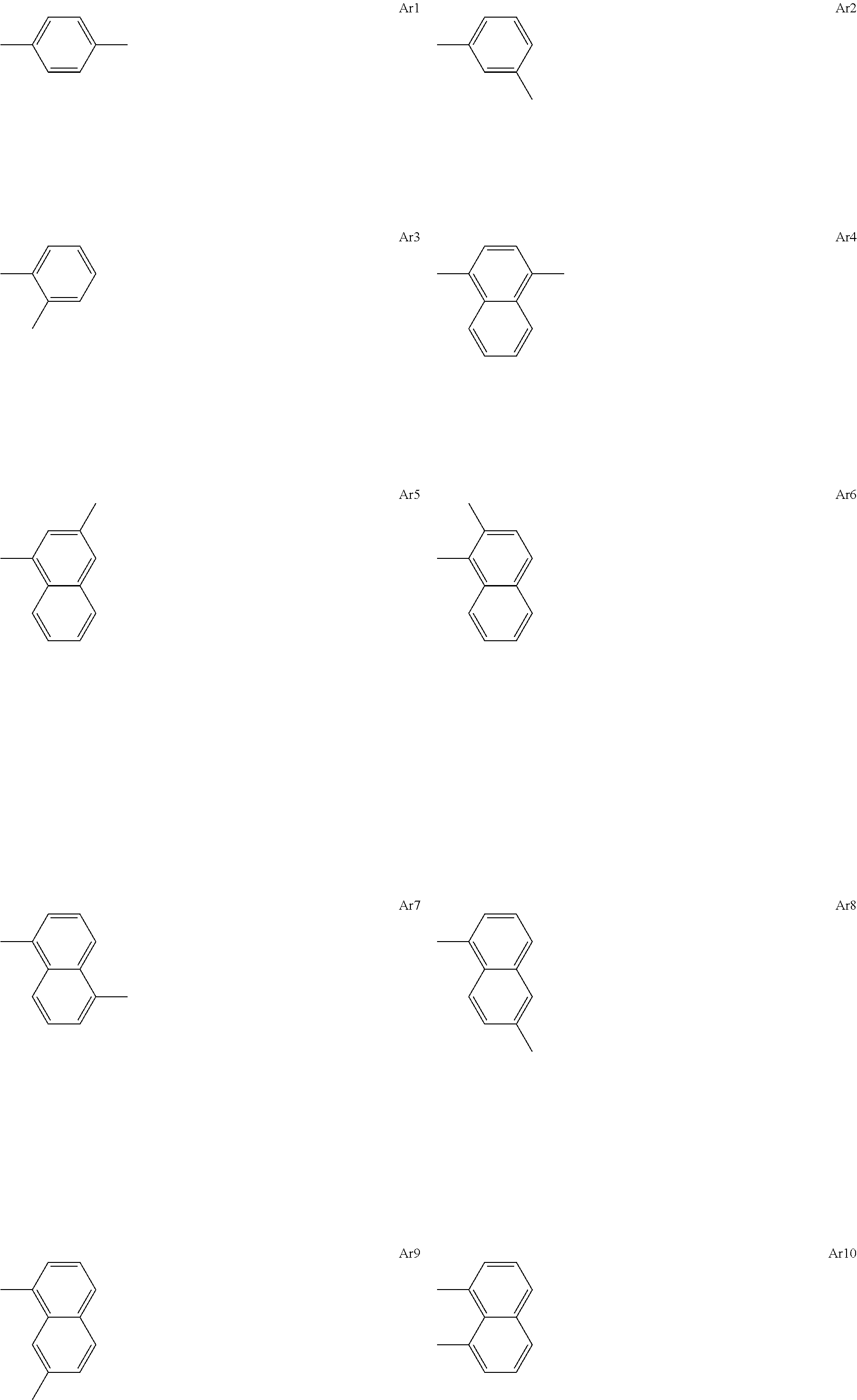

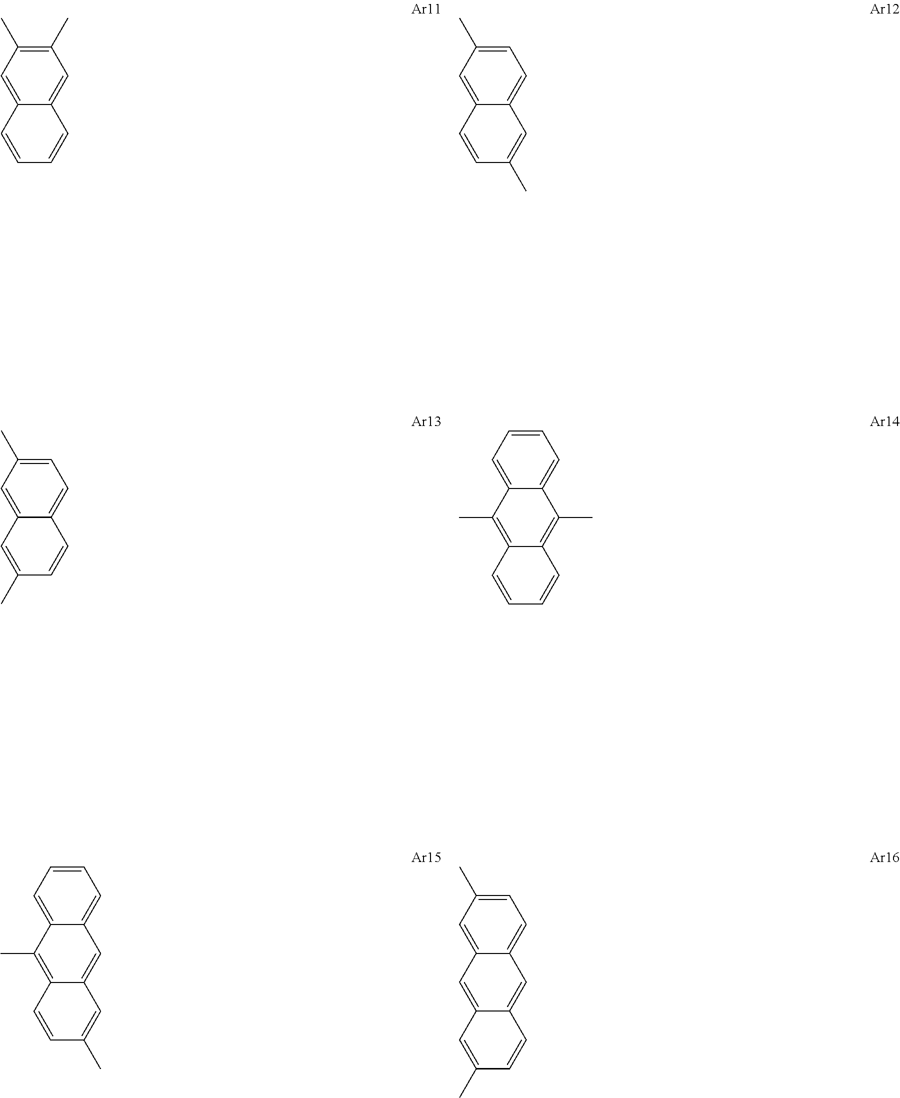

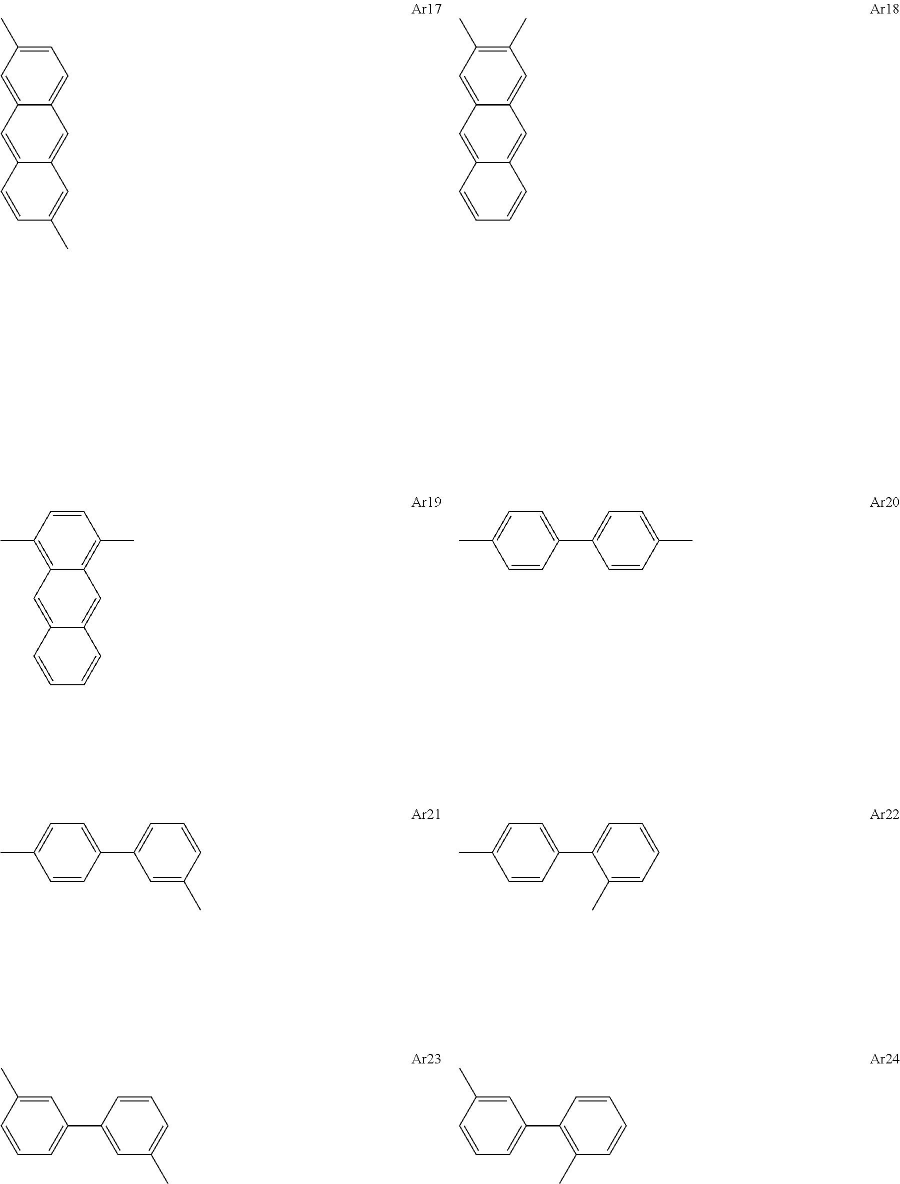

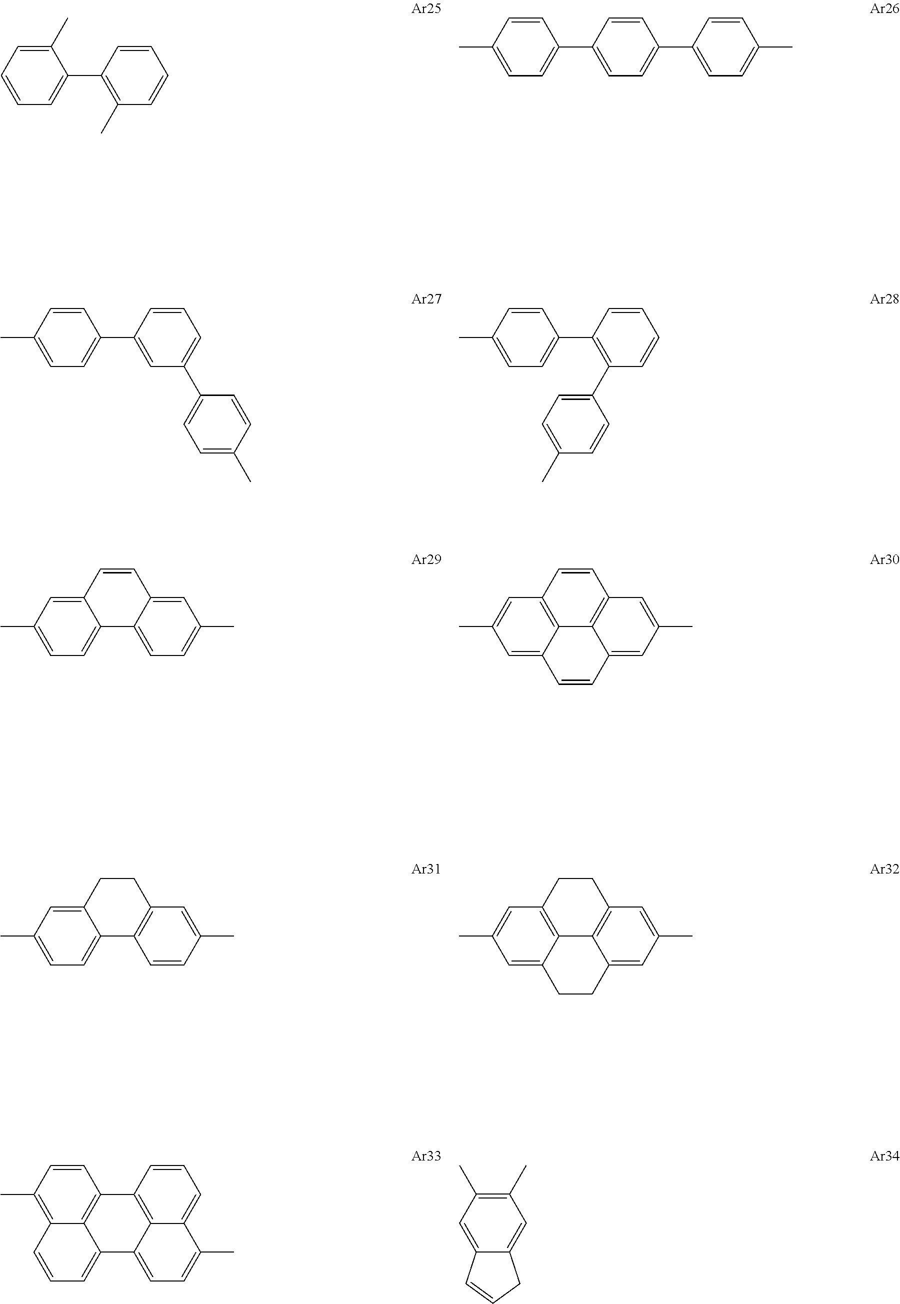

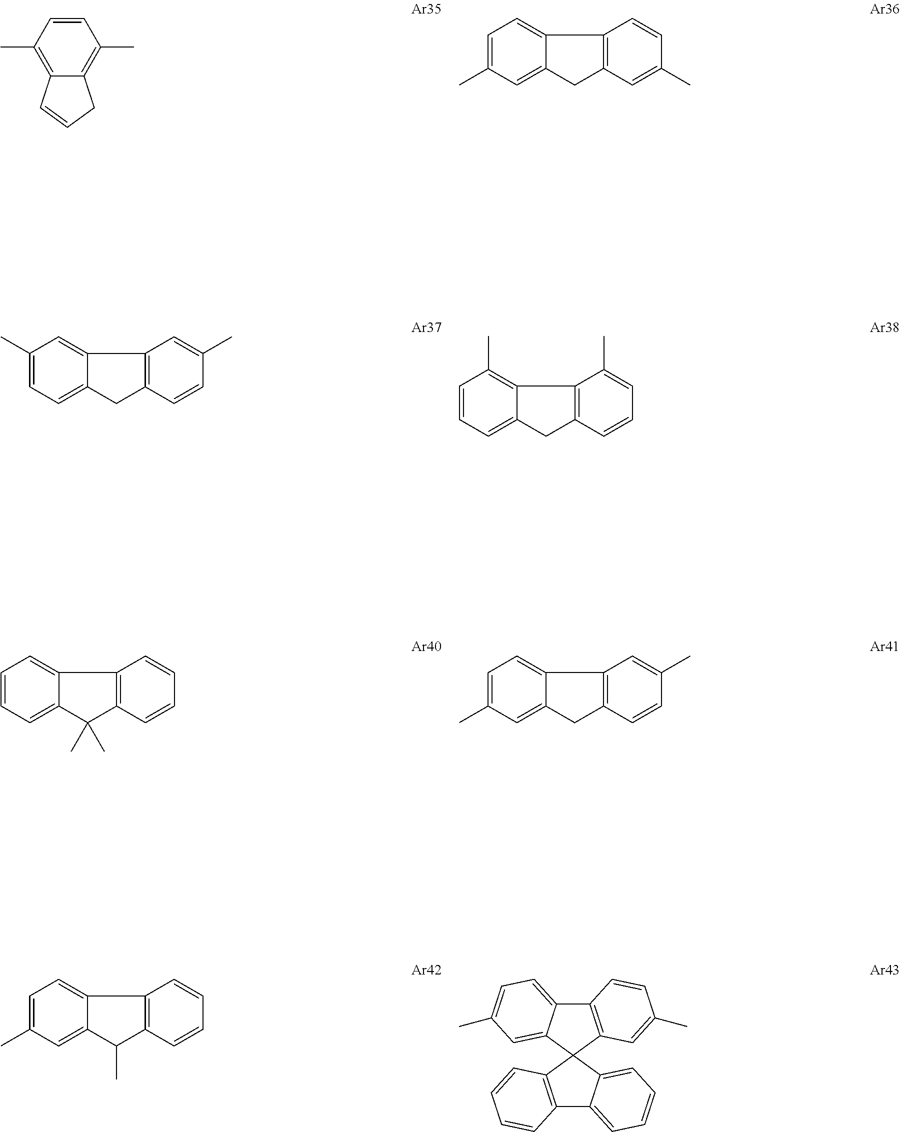

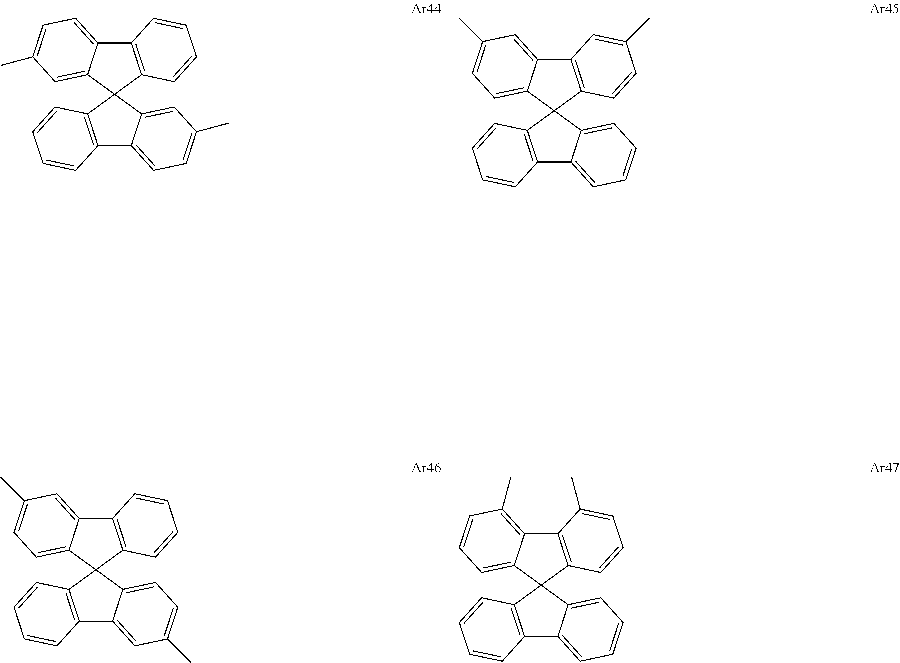

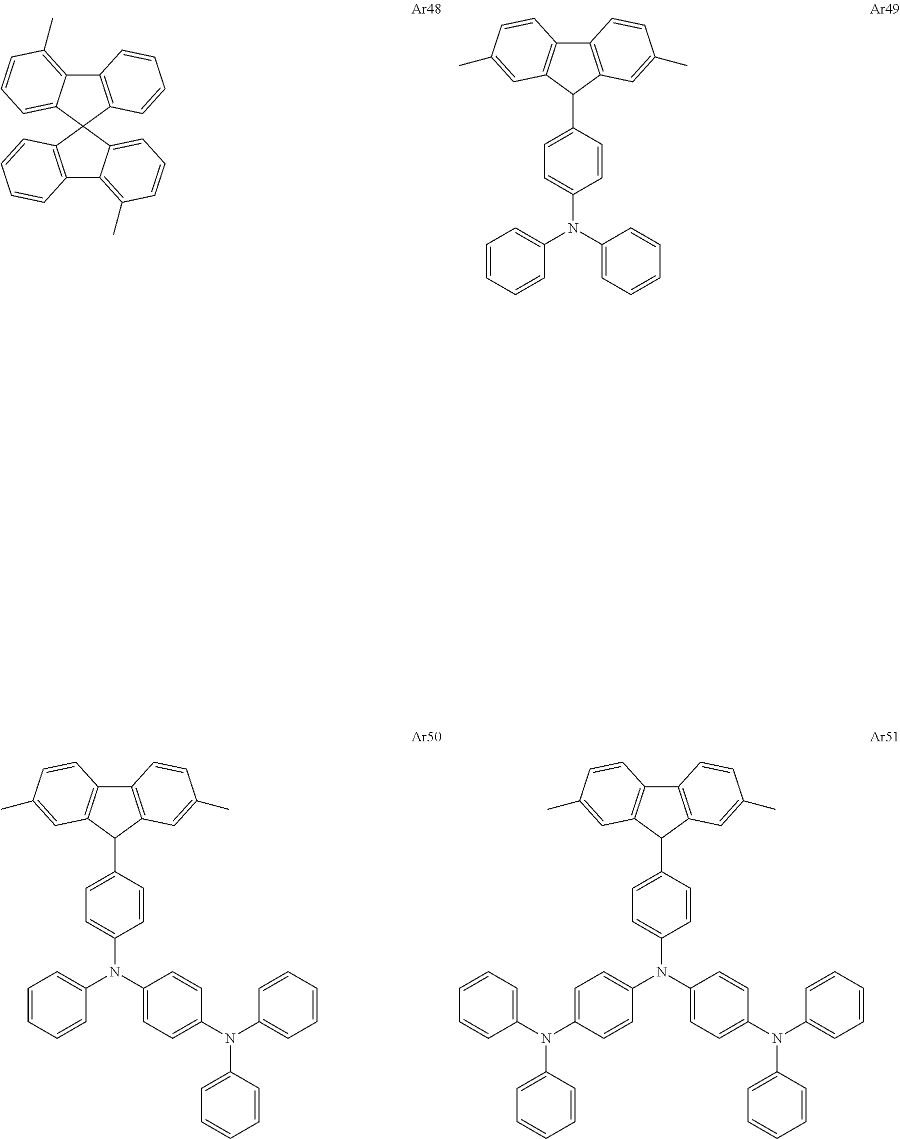

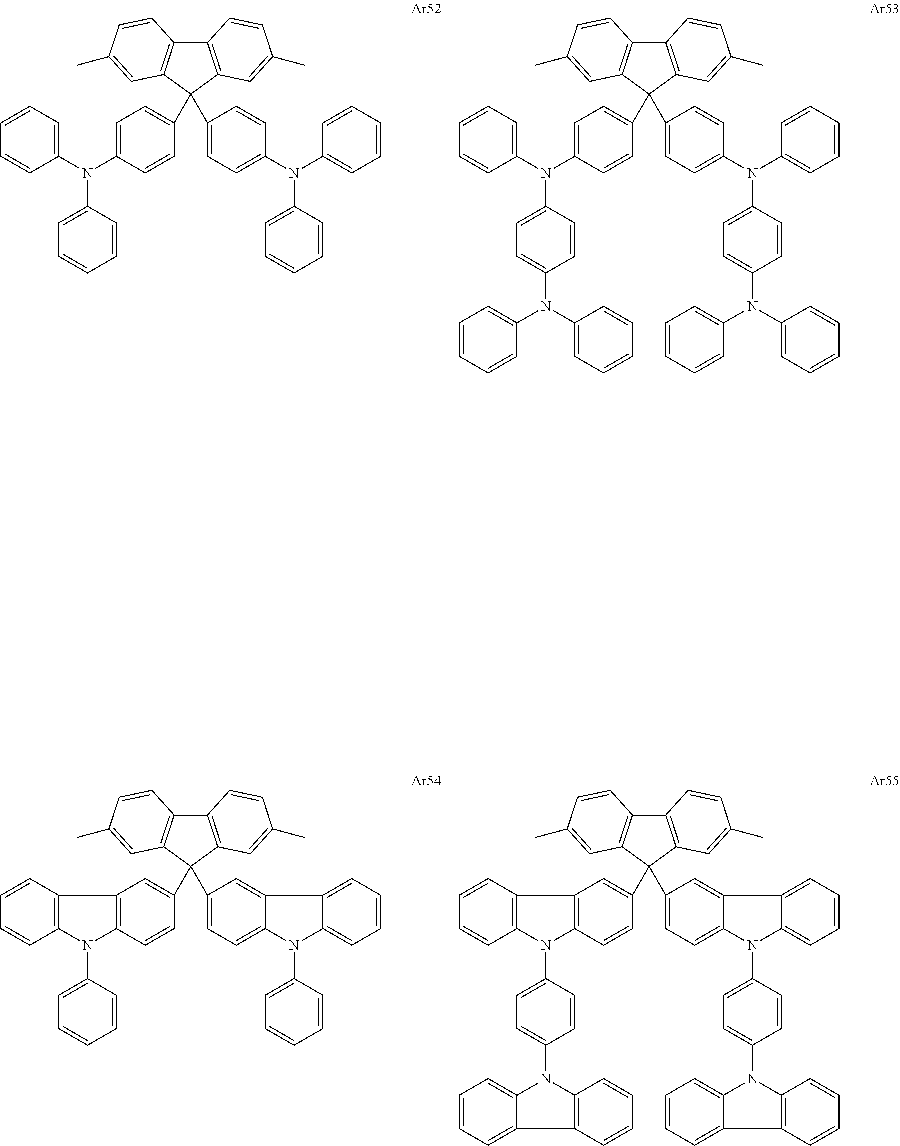

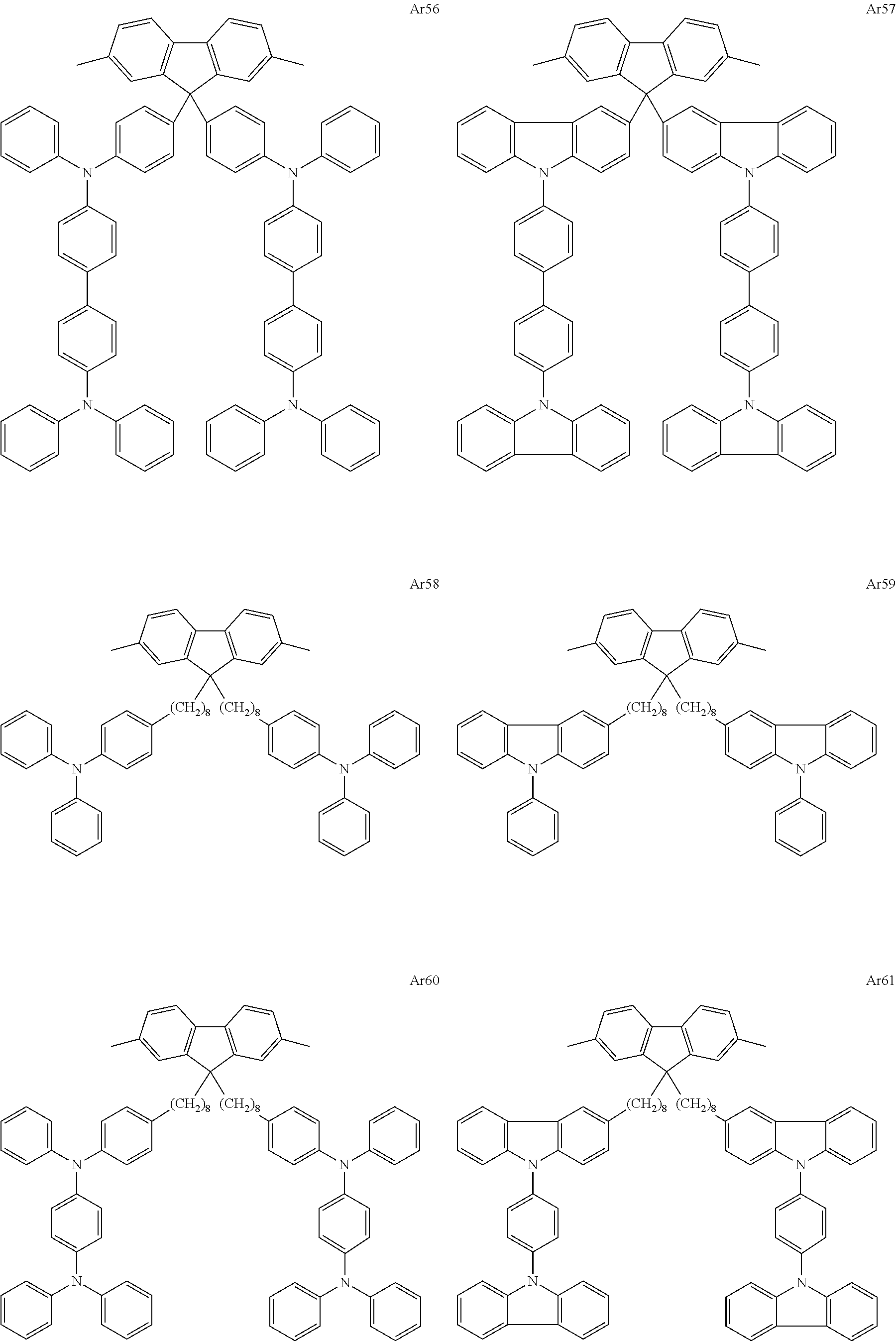

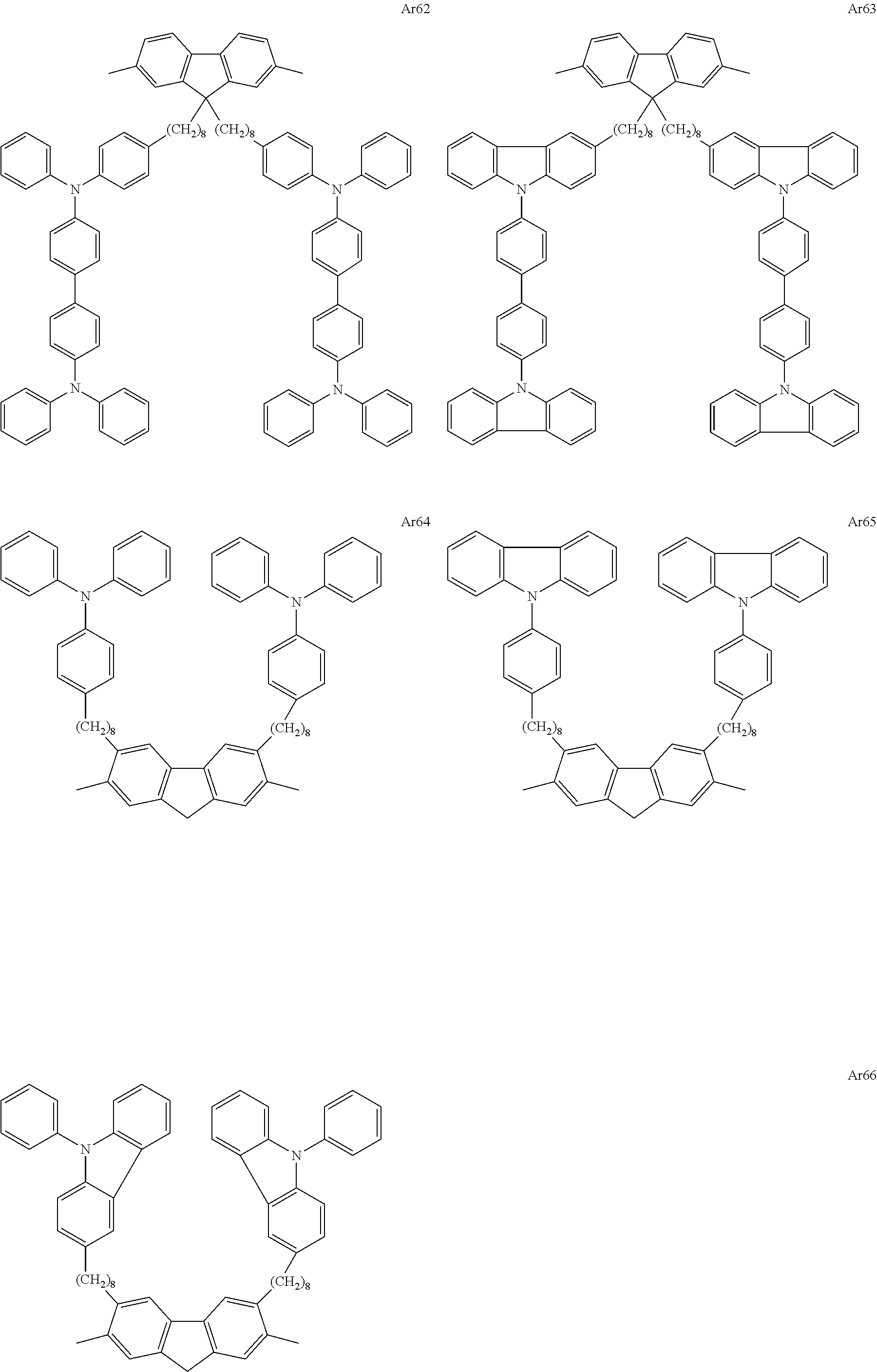

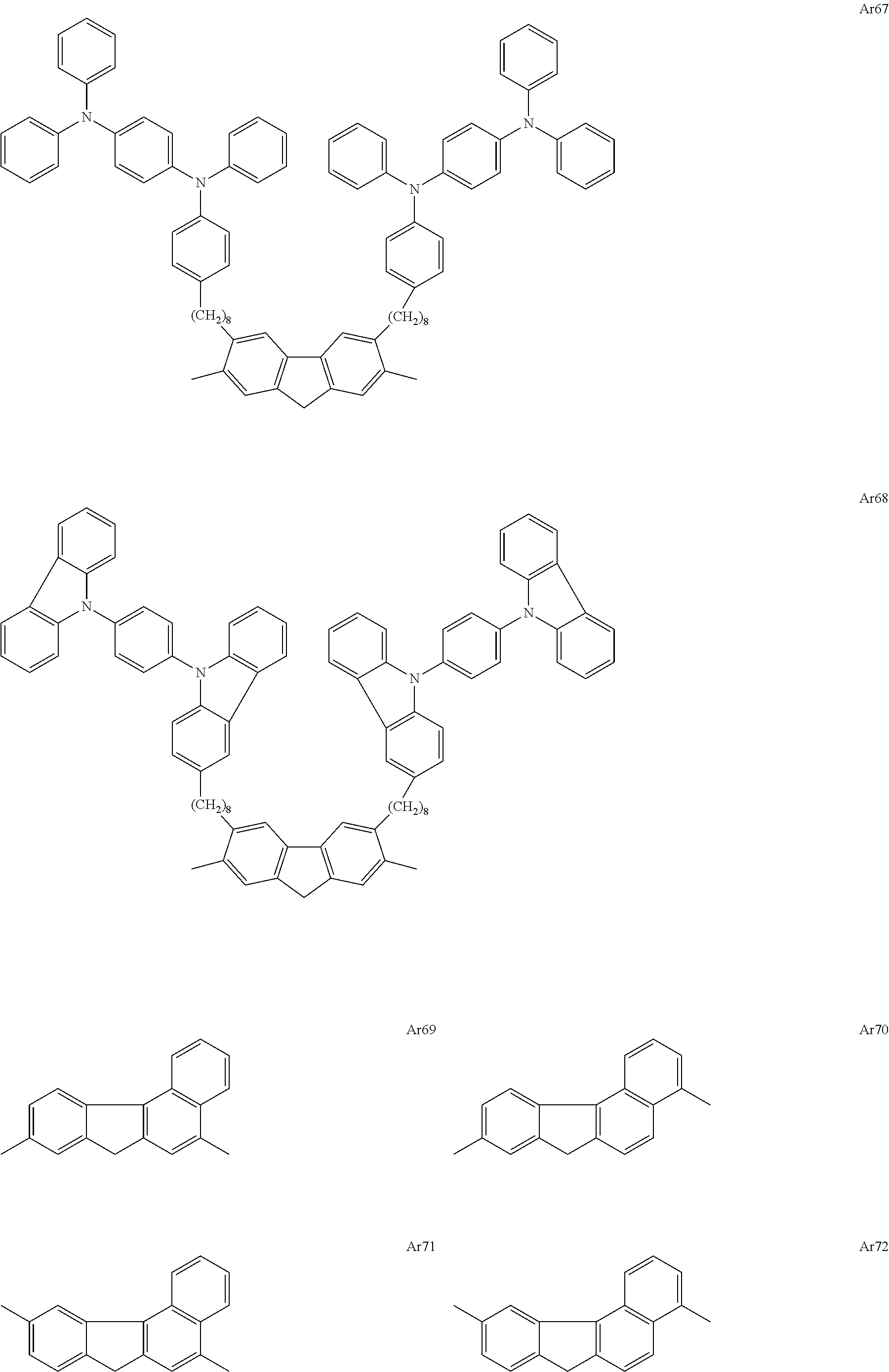

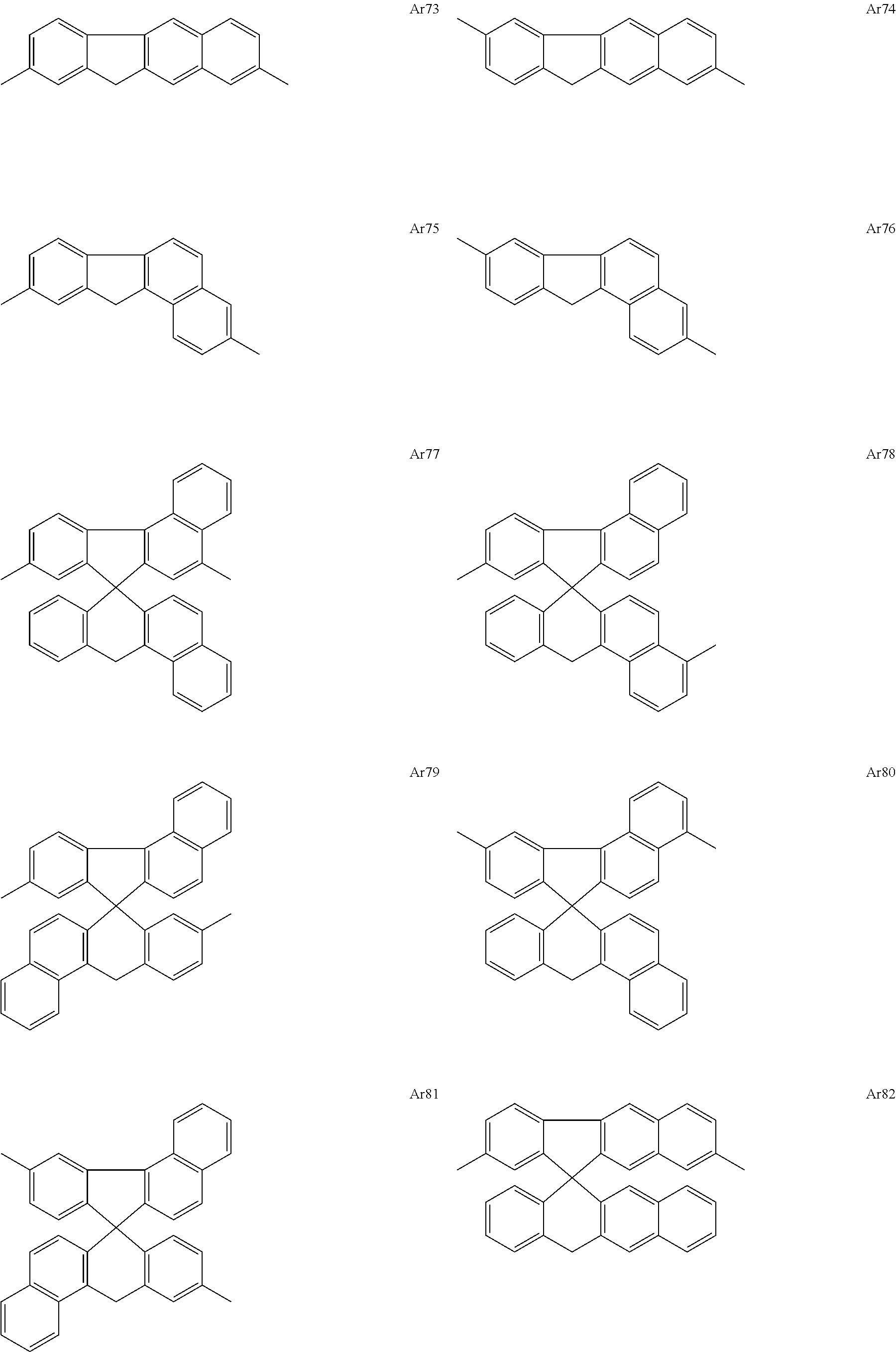

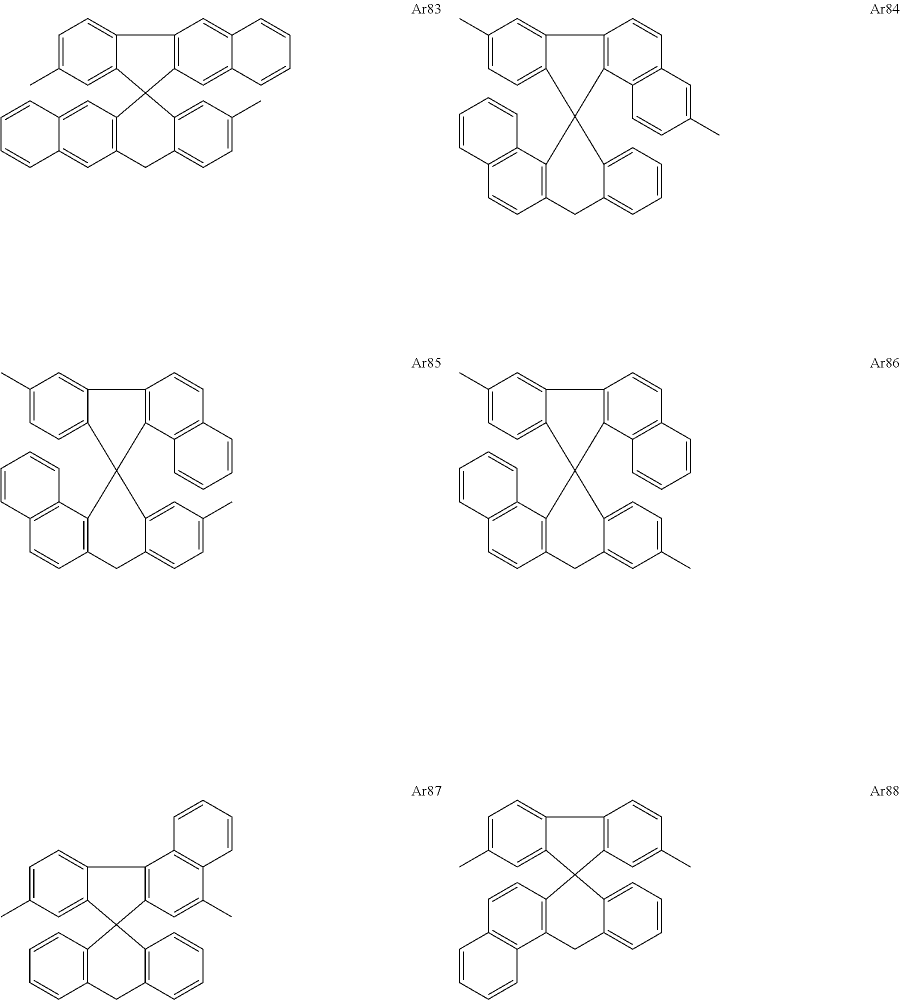

In the above-described formula (4), the divalent aromatic heterocyclic group represented by Ar¹ means an atomic group remaining after removal of two hydrogen atoms from an aromatic heterocyclic compound. The aromatic heterocyclic compound includes heterocyclic compounds containing a hetero atom wherein the hetero ring itself shows an aromatic property, such as oxadiazole, thiadiazole, thiazole, oxazole, thiophene, pyrrole, phosphole, furan, pyridine, pyrazine, pyrimidine, triazine, pyridazine, quinoline, isoquinoline, carbazole and dibenzophosphole, and compounds wherein even if the hetero ring itself containing a hetero atom shows no aromatic property, an aromatic ring is condensed to the hetero ring, such as phenoxazine, phenothiazine, dibenzoborole, dibenzosilole and benzopyran. Examples of the above-described divalent aromatic heterocyclic group include pyridinediyl groups (the formulae B1 to B3); diazaphenylene groups (the formulae B4 to B8); triazinediyl groups (the formula B9); quinoline-diyl groups (the formulae B10 to B12); quinoxaline-diyl groups (the formulae B13 to B15); acridinediyl groups (the formulae B16 and B17); phenanthrolinediyl groups (the formulae B18 and B19); groups having a structure in which a benzo ring is condensed to a cyclic structure containing a hetero atom (the formulae B20 to B26); phenoxazinediyl groups (the formulae B27 and B28); phenothiazinediyl groups (the formulae B29 and B30); nitrogen bond-containing polycyclic diyl groups (the formulae B31 to B35); 5-membered ring groups containing an oxygen atom, a sulfur atom, a nitrogen atom, a silicon atom and the like as a hetero atom (the formulae B36 to B39); and 5-membered ring condensed groups containing an oxygen atom, a sulfur atom, a nitrogen atom, a silicon atom and the like as a hetero atom (the formulae B40 to B47). A hydrogen atom in these divalent aromatic heterocyclic groups may be substituted by an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group.

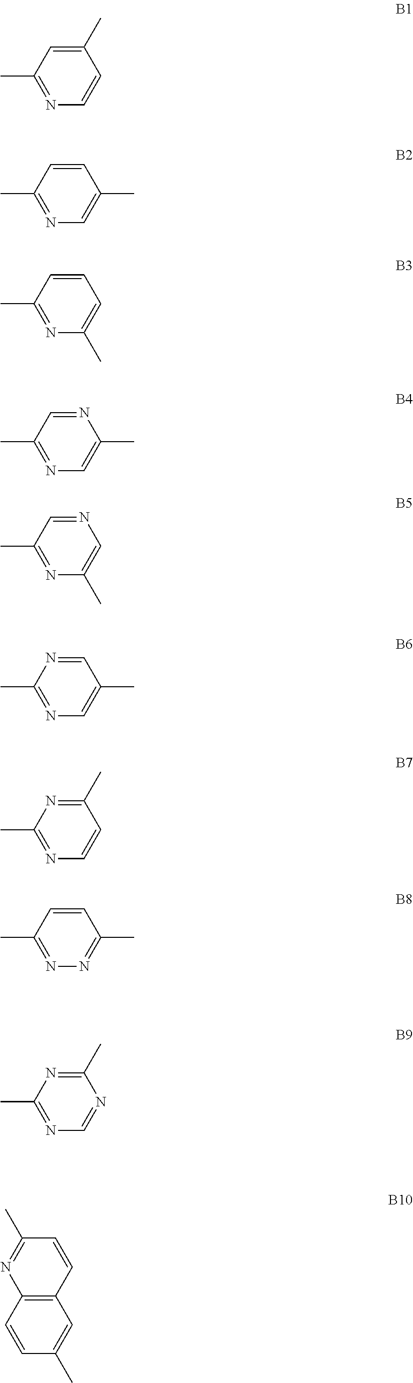

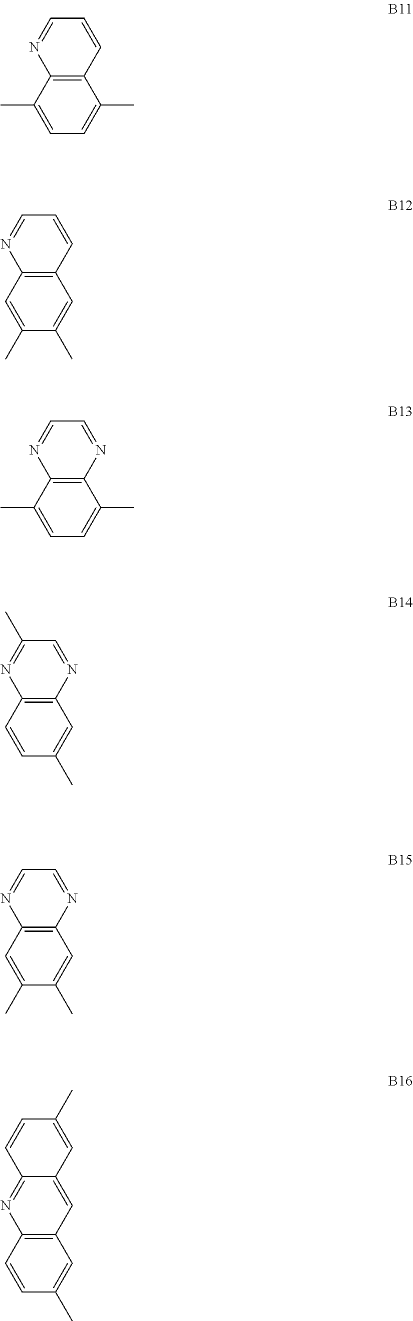

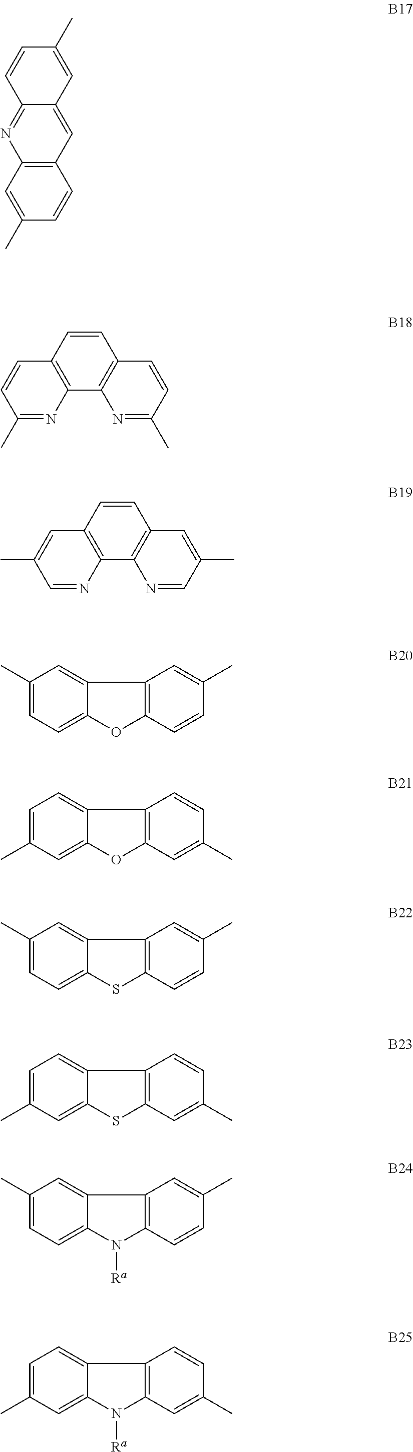

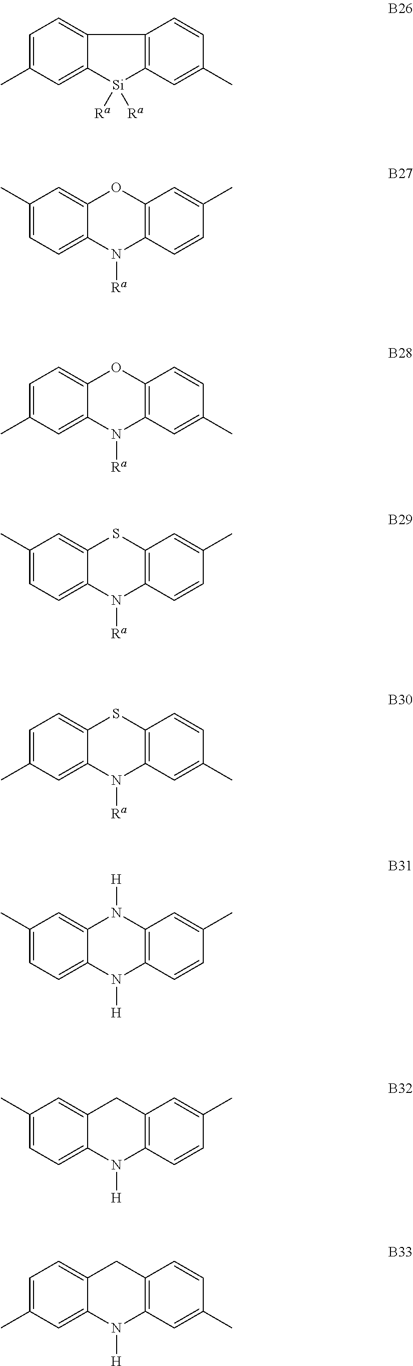

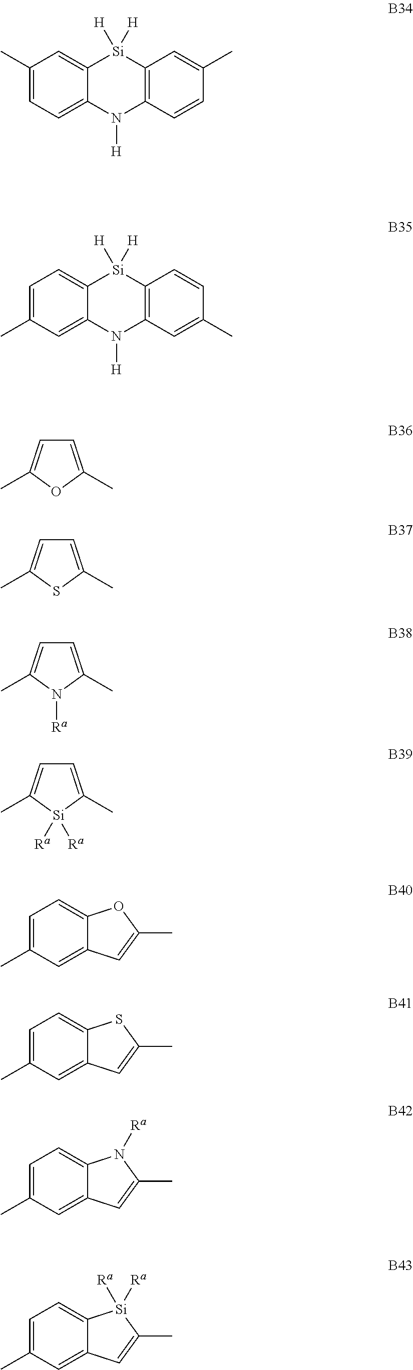

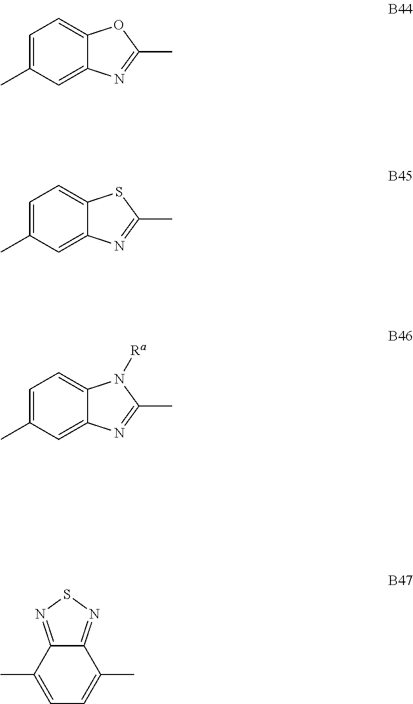

[wherein R^{a} represents a hydrogen atom, a hydroxyl group, an alkyl group, an aryl group, a monovalent aromatic heterocyclic group, an alkoxy group, an aryloxy group, an aralkyl group or an arylalkoxy group.]

The constitutional unit represented by the above-described formula (4) includes constitutional units represented by the following formulae Ka-1 to Ka-52.

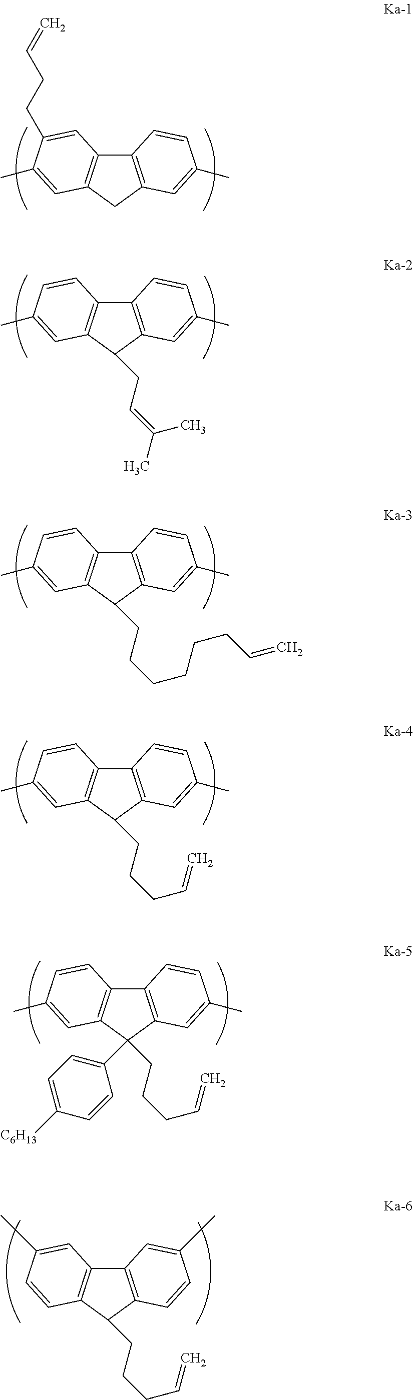

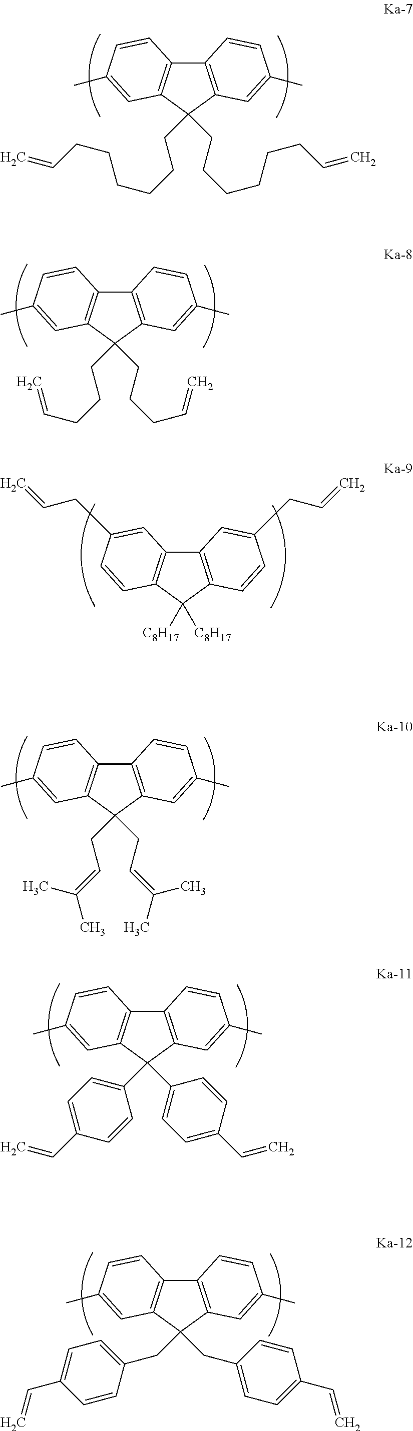

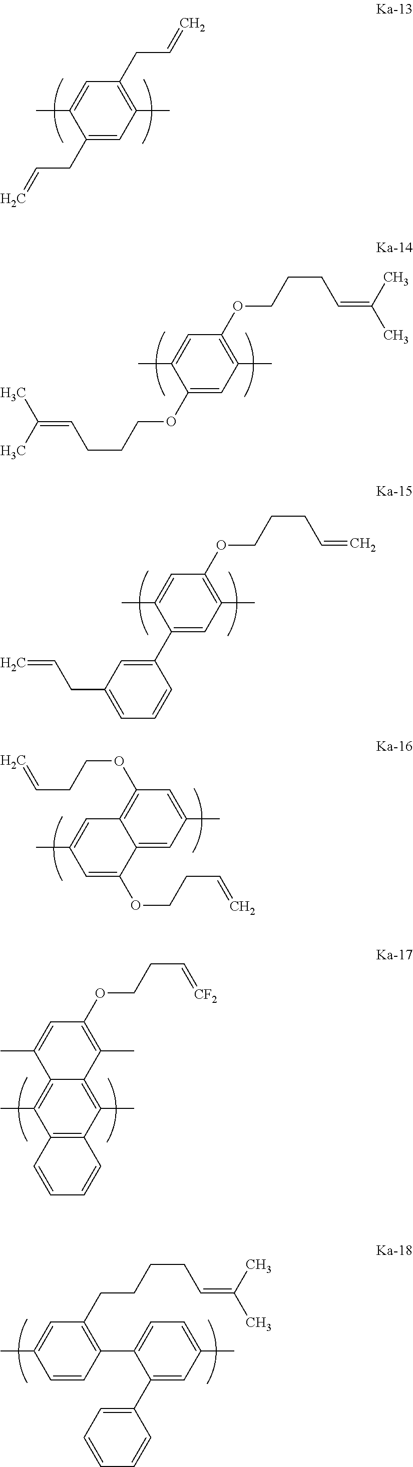

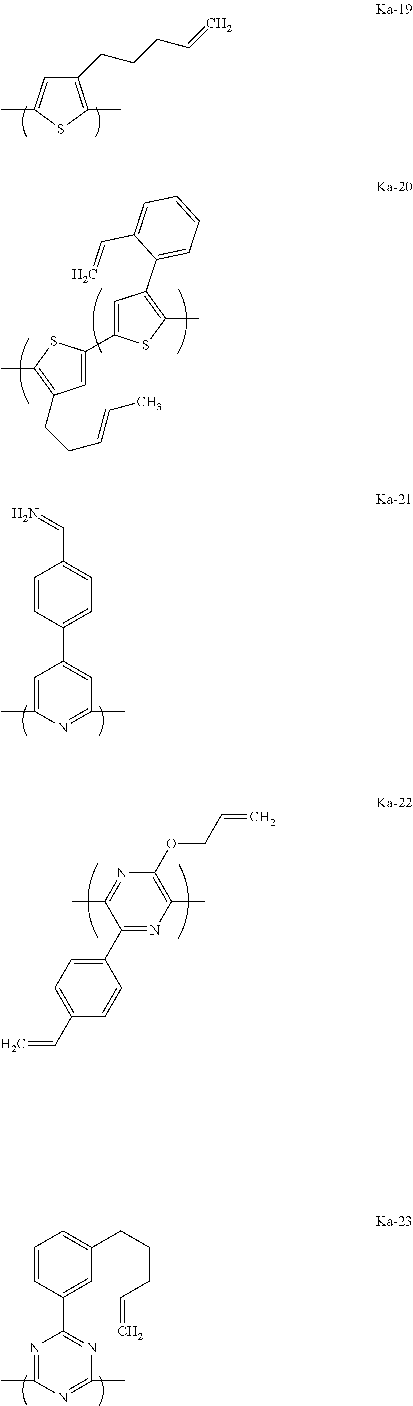

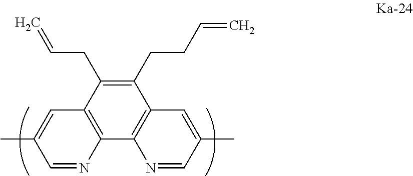

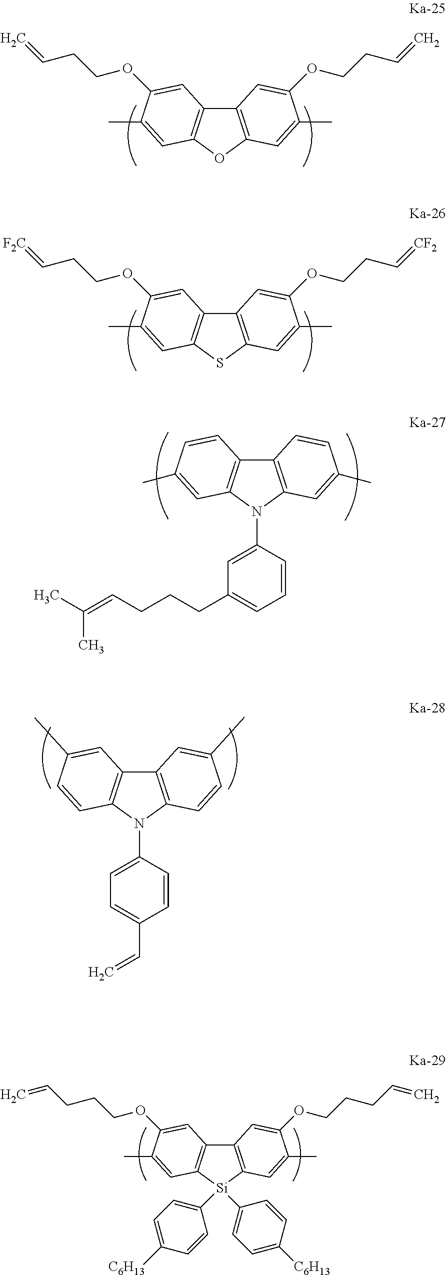

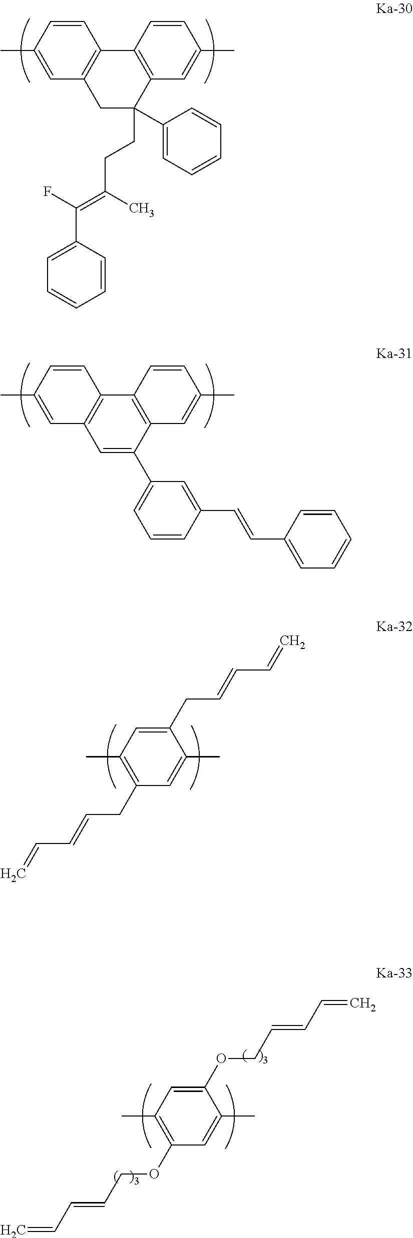

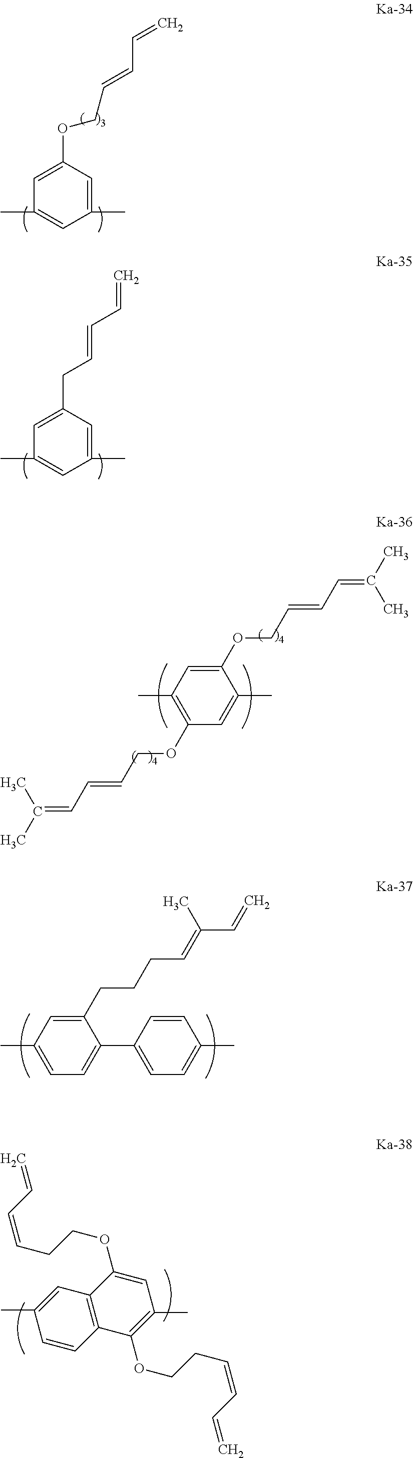

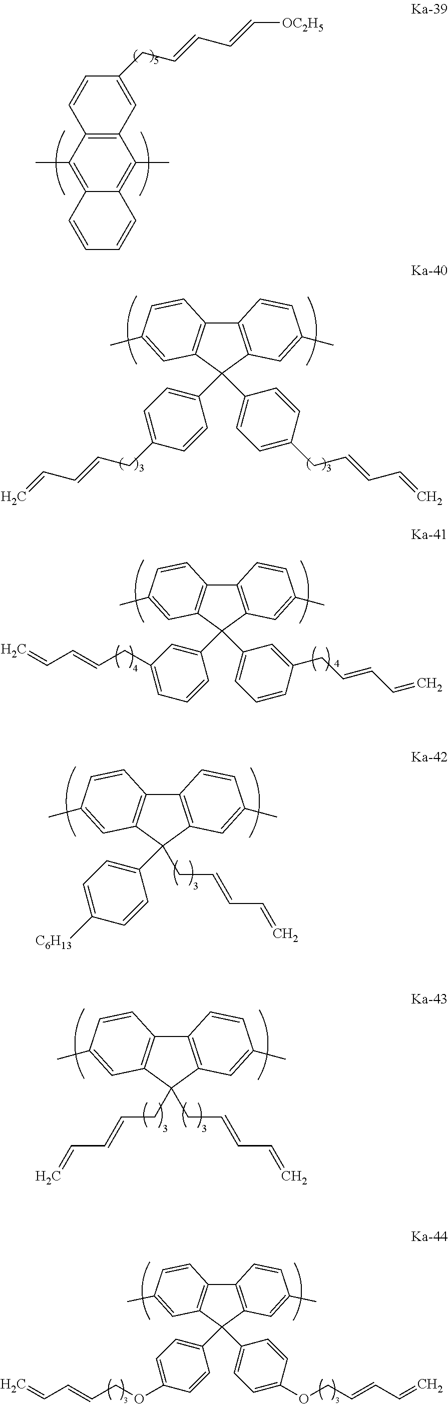

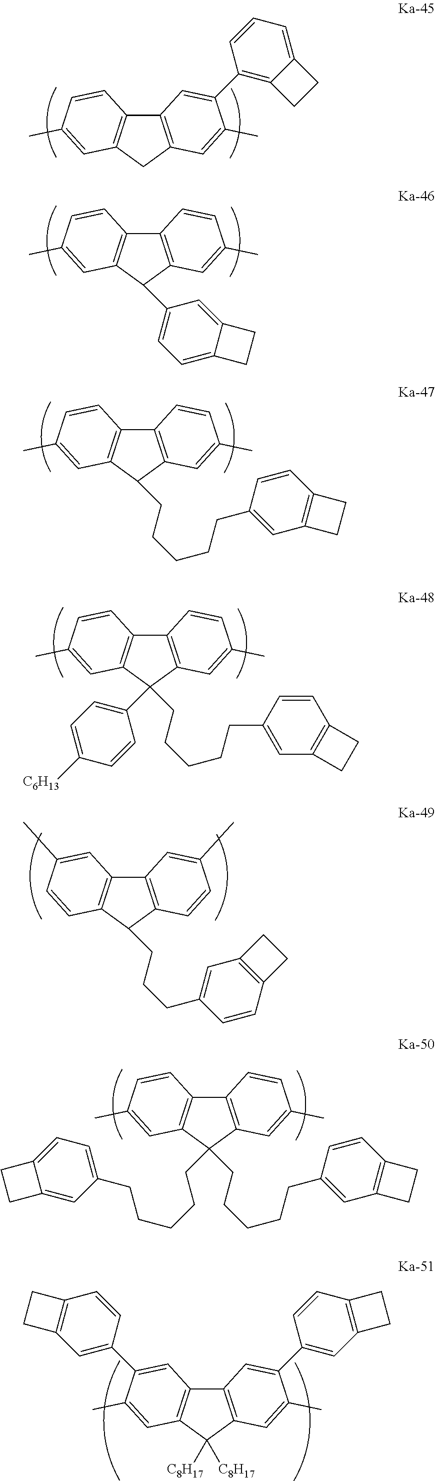

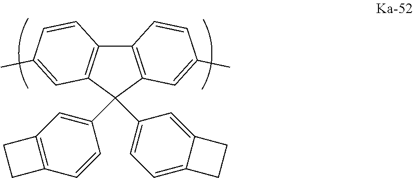

The aryl groups represented by Ar⁶, Ar⁷ and Ar⁸ in the above-described formula (5) are an atomic group obtained by removing one hydrogen atom from an aromatic hydrocarbon, and include groups having a condensed ring. The above-described aryl group has a carbon atom number of usually 6 to 60, preferably 6 to 48, more preferably 6 to 20. This carbon atom number does not include the carbon atom number of the substituent. Examples of the above-described aryl group are a phenyl group, a 1-naphthyl group, a 2-naphthyl group, a 1-anthryl group, a 2-anthryl group, a 9-anthryl group, a 1-pyrenyl group, a 2-pyrenyl group, a 4-pyrenyl group, a 1-phenanthryl group, a 2-phenanthryl group, a 3-phenanthryl group, a 4-phenanthryl group, a 9-phenanthryl group, a 2-fluorenyl group, a 3-fluorenyl group, a 9-fluorenyl group, a 2-perylenyl group, a 3-perylenyl group and a 4-biphenylyl group. The above-described aryl group may have a substituent.

As the above-described aryl group, a substituted or unsubstituted phenyl group and a substituted or unsubstituted 4-biphenylyl group are preferable. The substituent on the phenyl group and the 4-biphenylyl group includes preferably an alkyl group, a monovalent aromatic heterocyclic group, an alkoxy group and an aryloxy group, more preferably an alkyl group.

The monovalent aromatic heterocyclic groups represented by Ar⁶, Ar⁷ and Ar⁸ in the above-described formula (5) are an atomic group obtained by removing one hydrogen atom from an aromatic heterocyclic compound, and include groups having a condensed ring. The above-described monovalent aromatic heterocyclic group has a carbon atom number of usually 3 to 60, preferably 3 to 20. This carbon atom number does not include the carbon atom number of the substituent. The above-described monovalent aromatic heterocyclic group includes a 2-oxadiazole group, a 2-thiadiazole group, a 2-thiazole group, a 2-oxazole group, a 2-thienyl group, a 2-pyrrolyl group, a 2-furyl group, a 2-pyridyl group, a 3-pyridyl group, a 4-pyridyl group, a 2-pyrazyl group, a 2-pyrimidyl group, a 2-triazyl group, a 3-pyridazyl group, a 3-carbazolyl group, a 2-phenoxazinyl group, a 3-phenoxazinyl group, a 2-phenothiazinyl group, a 3-phenothiazinyl group and the like, preferably a 2-pyridyl group, a 3-pyridyl group, a 4-pyridyl group, a 2-pyrazyl group, a 2-pyrimidyl group, a 2-triazyl group and a 3-pyridazyl group. The above-described monovalent aromatic heterocyclic group may have a substituent. This substituent includes preferably an alkyl group, an aryl group and a monovalent aromatic heterocyclic group.

The divalent aromatic heterocyclic groups represented by Ar² to Ar⁵ in the above-described formula (5) have the same meaning as the divalent aromatic heterocyclic group represented by Ar¹ in the above-described formula (4).

It is preferable that at least one of p and q is 1 in the above-described formula (5).

The constitutional unit represented by the above-described formula (5) includes constitutional units represented by the following formulae Am1 to Am6 and Kb-1 to Kb-7, and from the viewpoint of the light emission property and the hole transportability when made into a device, preferably includes constitutional units represented by the formulae Am2 to Am5. These constitutional units may have a substituent.

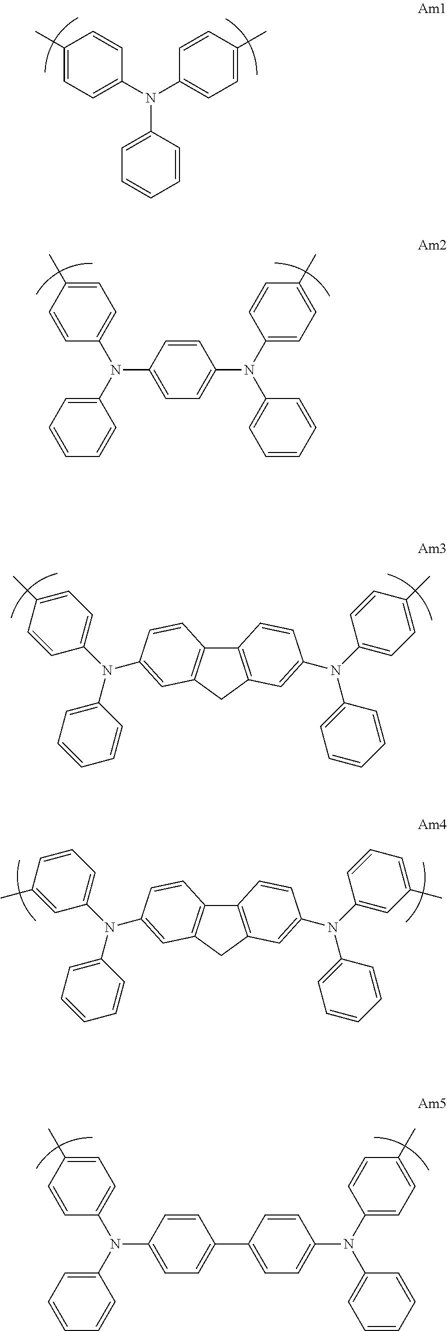

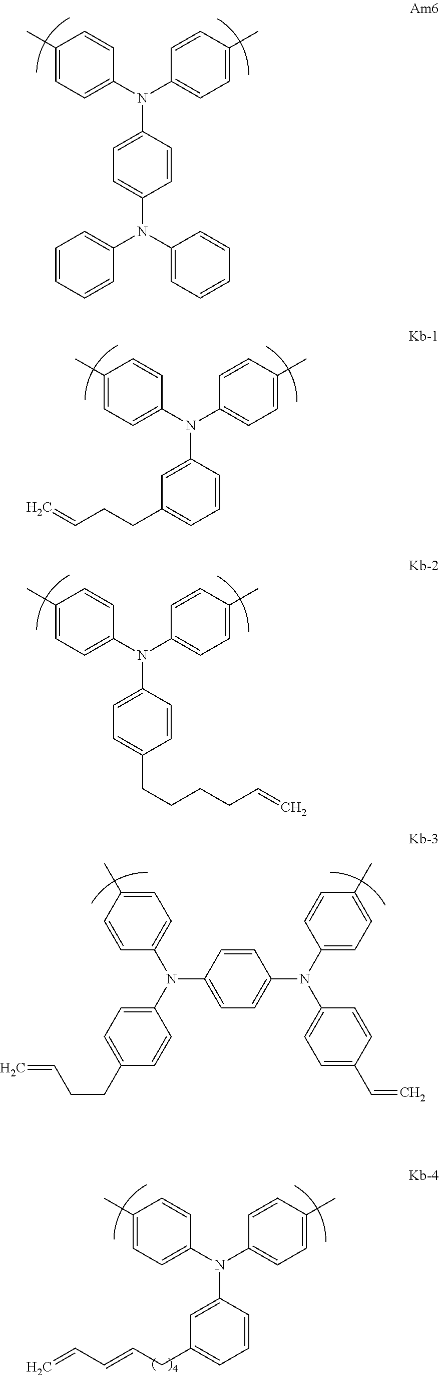

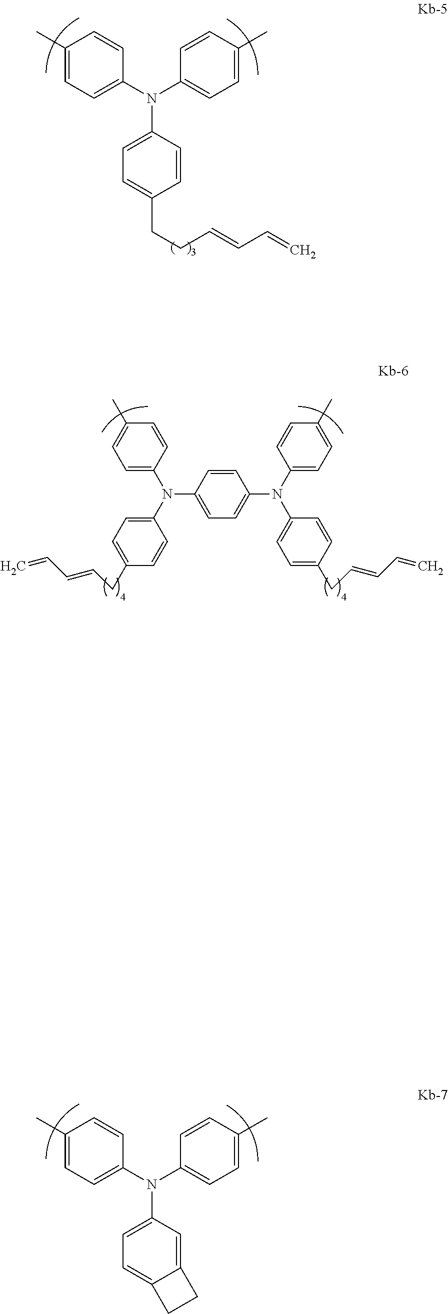

The above-described charge transporting polymer compound may also be a compound obtained by cross-linkage of the charge transporting polymer compound as described above.

The above-described charge transporting polymer compound has a polystyrene-equivalent weight-average molecular weight of usually 1×10³ to 1×10⁸, preferably 5×10⁴ to 5×10⁶. The above-described charge transporting polymer compound has a polystyrene-equivalent number-average molecular weight of usually 1×10³ to 1×10⁸, preferably 1×10⁴ to 1×10⁶.

The above-described charge transporting polymer compound includes the following compounds EP-1 to EP-4.

TABLE 1

| | constitutional units and molar ratio thereof | | | | |
|---|---|---|---|---|---|
| | formulae | formulae | formulae | formulae | |
| | Ar1 to | Ar36 to | B1 to | Am1 to | |
| | Ar35 | Ar67 | B42 | Am6 | others |
| compounds | v | w | x | y | z |
| EP-1 | 0.001 to | 0.001 to | 0 | 0 | 0 to |
| | 0.999 | 0.999 | | | 0.3 |
| EP-2 | 0.001 to | 0.001 to | 0.001 to | 0 | 0 to |
| | 0.998 | 0.998 | 0.998 | | 0.3 |
| EP-3 | 0.001 to | 0.001 to | 0 | 0.001 to | 0 to |
| | 0.998 | 0.998 | | 0.198 | 0.3 |
| EP-4 | 0.001 to | 0.001 to | 0.001 to | 0.001 to | 0 to |
| | 0.997 | 0.997 | 0.997 | 0.197 | 0.3 |

(in the table, v, w, x, y and z are numbers showing the molar ratios. Of them, the molar ratios of constitutional units represented by the above-described formula (4) are represented by v, w and x, the molar ratio of a constitutional unit represented by the above-described formula (5) is represented by y, and the molar ratio of other constitutional units is represented by z. v, w, x, y and z satisfy conditions: v+w+x+y+z=1 and 1≧v+w+x+y≧0.7).

Here, the above-described formulae Ar1 to Ar35, formulae Ar36 to Ar67, formulae B1 to B42 and formulae Am1 to Am6 have the same meaning as described above. “Others” mean constitutional units other than the above-described formulae Ar1 to Ar35, formulae Ar36 to Ar67, formulae B1 to B42 and formulae Am1 to Am6.

As the above-described charge transporting polymer compound, a single compound may be contained or two or more compounds may be contained. When two or more charge transporting polymer compounds are contained, the molar ratios of constitutional units represented by the above-described formulae (4) and (5) indicate an arithmetic average value, namely, the sum of products obtained by multiplying the molar ratios of respective charge transporting polymer compounds by the composition ratios by weight of respective charge transporting polymer compounds.

Other Materials

In the organic electroluminescent device of the present invention, the above-described light emitting layer may contain the first light emitting layer material and the second light emitting layer material, and other components.

### <Hole Transporting Layer>

Hole Transporting Polymer Compound

The above-described hole transporting polymer compound is a polymer compound containing a constitutional unit represented by the above-described formula (4) and a constitutional unit represented by the above-described formula (5), preferably a polymer compound containing a constitutional unit represented by the above-described formula (5) in a molar ratio of 20% or more, more preferably a polymer compound containing a constitutional unit represented by the above-described formula (5) in a molar ratio of 30% or more, from the viewpoint of the hole injectability and the hole transportability.

The constitutional unit represented by the above-described formula (4) is preferably a constitutional unit represented by the above-described formula (6) or a constitutional unit represented by the above-described formula (7), and from the viewpoint of the hole transportability, a constitutional unit represented by the above-described formula (6) is more preferable.

The above-described hole transporting polymer compound has a polystyrene-equivalent weight-average molecular weight of usually 1×10³ to 1×10⁸, preferably 5×10⁴ to 5×10⁶. The above-described hole transporting polymer compound has a polystyrene-equivalent number-average molecular weight of usually 1×10³ to 1×10⁸, preferably 1×10⁴ to 1×10⁶.

The above-described hole transporting polymer compound includes the following compounds EP-5 to EP-10.

TABLE 2

| | constitutional units and molar ratio thereof | | | | |
|---|---|---|---|---|---|
| | formulae | formulae | formulae | formulae | |
| | Ar1 to | Ar36 to | B1 to | Am1 to | |
| | Ar35 | Ar67 | B42 | Am6 | others |
| | v′ | w′ | x′ | Y′ | z′ |
| EP-5 | 0.001 to | 0 | 0 | 0.2 to | 0 to |
| | 0.8 | | | 0.999 | 0.3 |
| EP-6 | 0 | 0.001 to | 0 | 0.2 to | 0 to |
| | | 0.8 | | 0.999 | 0.3 |
| EP-7 | 0.001 to | 0.001 to | 0 | 0.2 to | 0 to |
| | 0.799 | 0.799 | | 0.998 | 0.3 |
| EP-8 | 0.001 to | 0 | 0.001 to | 0.2 to | 0 to |
| | 0.799 | | 0.799 | 0.998 | 0.3 |
| EP-9 | 0 | 0.001 to | 0.001 to | 0.2 to | 0 to |
| | | 0.799 | 0.799 | 0.998 | 0.3 |
| EP-10 | 0.001 to | 0.001 to | 0.001 to | 0.2 to | 0 to |
| | 0.798 | 0.798 | 0.798 | 0.997 | 0.3 |

(in the table, v′, w′, x′, y′ and z′ are numbers showing the molar ratios. Of them, the molar ratios of constitutional units represented by the above-described formula (4) are represented by v′, w′ and x′, the molar ratio of a constitutional unit represented by the above-described formula (5) is represented by y′, and the molar ratio of other constitutional units is represented by z′. v′, w′, x′, y′ and z′ satisfy conditions: v′+w′+x′+y′+z′=1 and 1≧v′+w′+x′+y′≧0.7).

Here, the above-described formulae Ar1 to Ar35, formulae Ar36 to Ar67, formulae B1 to B42 and formulae Am1 to Am6 have the same meaning as described above. “Others” mean constitutional units other than the above-described formulae Ar1 to Ar35, formulae Ar36 to Ar67, formulae B1 to B42 and formulae Am1 to Am6.

As the above-described hole transporting polymer compound, a single compound may be contained or two or more compounds may be contained. When two or more hole transporting polymer compounds are contained, the molar ratios of constitutional units represented by the above-described formulae (4) and (5) indicate an arithmetic average value, namely, the sum of products obtained by multiplying the molar ratios of respective hole transporting polymer compounds by the composition ratios by weight of respective hole transporting polymer compounds.

In the organic electroluminescent device of the present invention, a crosslinkable hole transporting polymer compound may be used as the above-described hole transporting polymer compound, and cross-linked in its molecule or between molecules thereof in a process of device production, to be contained under cross-linked condition in the hole transporting layer, from the viewpoint of insolubilization into a solvent in fabrication of the device.

Other Material

In the organic electroluminescent device of the present invention, the above-described hole transporting layer may be formed by using the above-described hole transporting polymer compound, and other components.

### <Device Constitution>

The layer structure of the organic electroluminescent device of the present invention includes the following structures a) to b).

a) anode/hole transporting layer/light emitting layer/cathode
b) anode/hole transporting layer/light emitting layer/electron transporting layer/cathode
(wherein “/” indicates adjacent lamination of layers. The same shall apply hereinafter.)

Of the hole transporting layer and the electron transporting layer disposed adjacent to an electrode, one having a function of improving the efficiency of injection of charges (holes, electrons) from the electrode and manifesting an effect of lowering the driving voltage of a device is called a charge injection layer.

In the organic electroluminescent device of the present invention, it is preferable that a hole injection layer is present between the above-described anode and the above-described hole transporting layer. In the organic electroluminescent device of the present invention, an insulation layer may be disposed adjacent to an electrode. For improvement of close adherence of an interface, prevention of mixing and the like, a thin buffer layer may be inserted between the above-described anode and the above-described hole transporting layer and a thin buffer layer may be inserted between the above-described light emitting layer and the above-described cathode. The order and the number of layers to be laminated and the thickness of each layer may advantageously be regulated in view of the light emission efficiency and the luminance life.

The layer structure of the organic electroluminescent device having a charge injection layer includes the following structures c) to h).

c) anode/hole injection layer/hole transporting layer/light emitting layer/cathode
d) anode/hole transporting layer/light emitting layer/electron injection layer/cathode
e) anode/hole injection layer/hole transporting layer/light emitting layer/electron injection layer/cathode
f) anode/hole injection layer/hole transporting layer/light emitting layer/electron transporting layer/cathode
g) anode/hole transporting layer/light emitting layer/electron transporting layer/electron injection layer/cathode
h) anode/hole injection layer/hole transporting layer/light emitting layer/electron transporting layer/electron injection layer/cathode

The anode is usually transparent or semitransparent and constituted of a film made of a metal oxide, a metal sulfide or a metal having high electric conductivity, and of them, materials of high transmission are preferably used for its constitution. As the material of the above-described anode, use is made of films (NESA and the like) fabricated using an electric conductive inorganic compound composed of indium oxide, zinc oxide, tin oxide, and composite thereof: indium•tin•oxide (ITO), indium•zinc•oxide and the like, and gold, platinum, silver, copper and the like, and preferable are ITO, indium•zinc•oxide and tin oxide. For fabrication of the above-described anode, methods such as a vacuum vapor-deposition method, a sputtering method, an ion plating method, a plating method and the like can be used. As the above-described anode, organic transparent electric conductive films made of polyaniline and derivatives thereof, polythiophene and derivatives thereof, and the like may be used.

The thickness of the anode may advantageously be selected in view of the light transmission and the electric conductivity, and it is usually 10 nm to 10 μm, preferably 20 nm to 1 μm, more preferably 50 nm to 500 nm.

The material used in the hole injection layer includes phenylamine compounds, starburst type amine compounds, phthalocyanine compounds, oxides such as vanadium oxide, molybdenum oxide, ruthenium oxide, aluminum oxide and the like, and electric conductive polymer compounds such as amorphous carbon, polyaniline and derivatives thereof, polythiophene and derivatives thereof, and the like.

When the material used in the hole injection layer is an electric conductive polymer compound, an anion such as a polystyrene sulfonate ion, an alkylbenzene sulfonate ion, a camphor sulfonate ion and the like may be doped for improving the electric conductivity of the electric conductive polymer compound.

As the method for forming a hole transporting layer, film formation from a solution containing the above-described hole transporting polymer compound is used. The solvent used for film formation from a solution may advantageously be a solvent which dissolves the above-described hole transporting polymer compound. This solvent includes chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethyl cellosolve acetate and the like.

For formation of the hole transporting layer, coating methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet print method and the like can be used.

The thickness of the hole transporting layer may advantageously be selected in view of the driving voltage and the light emission efficiency, and a thickness causing no generation of pin holes is necessary, and when it is too thick, the driving voltage of an organic electroluminescent device may increase in some cases. Therefore, the thickness of the hole transporting layer is usually 1 nm to 1 μm, preferably 2 nm to 500 nm, more preferably 5 nm to 200 nm.

The method for forming a light emitting layer includes a method for coating a solution containing the first light emitting layer material and the second light emitting layer material on or above the hole transporting layer, and the like. The solvent to be used in the above-described solution may advantageously be a solvent which dissolves the first light emitting layer material and the second light emitting layer material. This solvent includes chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethyl cellosolve acetate and the like. Here, the above-described solvent is preferably selected in view of dissolvability for a lower layer in addition to the viscosity of the solution and the film formability.

For formation of the light emitting layer, coating methods such as a spin coat method, a dip coat method, an inkjet print method, a flexo printing method, a gravure printing method, a slit coat method and the like can be used.

The thickness of the light emitting layer may advantageously be selected in view of the driving voltage and the light emission efficiency, and it is usually 2 to 200 nm.

In the case of formation of the light emitting layer subsequent to a hole transporting layer, particularly when both the layers are formed by a coating method, a layer formed previously is dissolved in a solvent contained in a coating solution to be used in subsequent formation of a layer, leading to impossibility of fabrication of a laminated structure in some cases. In this case, a method for insolubilizing the hole transporting layer in a solvent can be used. The method for insolubilization in a solvent includes (1) a method in which a hole transporting layer is formed by using a crosslinkable hole transporting polymer compound as the above-described hole transporting polymer compound, and polymer chains are cross-linked in a process of device production, (2) a method in which a low molecular weight compound having an aromatic ring and having a cross-linkage group typified by an aromatic bisazide is mixed as a cross-linking agent with the hole transporting polymer compound and a hole transporting layer is formed, and polymer chains are cross-linked via the low molecular weight compound in a process of device production, (3) a method in which a low molecular weight compound having no aromatic ring and having a cross-linkage group typified by an acrylate group is mixed as a cross-linking agent with the hole transporting polymer compound and a hole transporting layer is formed, and polymer chains are cross-linked via the low molecular weight compound in a process of device production and (4) a method in which a hole transporting layer as a lower layer is formed, then, heated to be insolubilized in an organic solvent to be used for formation of a light emitting layer as an upper layer, and the above-described method (1) is preferable. The heating temperature in heating a hole transporting layer in performing cross-linkage is usually 150 to 300° C., and the heating time is usually 1 minute to 1 hour. As other methods than cross-linkage for laminating a hole transporting layer without dissolution, there is a method for using a solution of difference polarity as a solution for forming an adjacent layer, and examples thereof include a method in which a hole transporting layer as a lower layer is formed by using a polymer compound which is not dissolved in a polar solvent, to cause no dissolution of the hole transporting layer even if a coating solution containing a light emitting layer material and a polar solvent is coated in formation of a light emitting layer as an upper layer; and other methods.

The material used in the electron transporting layer includes polymer compounds containing an electron transporting group (oxadiazole group, oxathiadiazole group, pyridyl group, pyrimidyl group, pyridazyl group, triazyl group and the like) as a constitutional unit and/or a substituent, and examples thereof include polyquinoline and derivatives thereof, polyquinoxaline and derivatives thereof, polyfluorene and derivatives thereof, and the like.

For formation of the electron transporting layer, methods of forming a film from a solution or melted condition are used. For film formation from a solution or melted condition, a polymer binder may be used together. The film formation method from a solution is the same as the above-described method for forming a hole transporting layer by film formation from a solution.

The thickness of the electron transporting layer may advantageously be regulated in view of the driving voltage and the light emission efficiency, and a thickness causing no formation of pin holes is necessary, and when the thickness is too large, the driving voltage of a device increases in some cases. Therefore, the thickness of the electron transporting layer is usually 1 nm to 1 μm, preferably 2 nm to 500 nm, further preferably 5 nm to 200 nm.

The electron injection layer includes, depending on the kind of a light emitting layer, an electron injection layer having a single layer structure composed of a Ca layer, or an electron injection layer having a lamination structure composed of a Ca layer and a layer formed of one or two or more materials selected from the group consisting of metals belonging to group IA and group IIA of the periodic table of elements and having a work function of 1.5 to 3.0 eV excluding Ca, and oxides, halides and carbonates of the metals. As the metals belonging to group IA of the periodic table of elements and having a work function of 1.5 to 3.0 eV and oxides, halides and carbonates thereof, listed are lithium, lithium fluoride, sodium oxide, lithium oxide, lithium carbonate and the like. As the metals belonging to group IIA of the periodic table of elements and having a work function of 1.5 to 3.0 eV excluding Ca, and oxides, halides and carbonates thereof, listed are strontium, magnesium oxide, magnesium fluoride, strontium fluoride, barium fluoride, strontium oxide, magnesium carbonate and the like.

For formation of the electron injection layer, a vapor-deposition method, a sputtering method, a printing method and the like are used. The thickness of the electron injection layer is preferably 1 nm to 1 μm.

As the material of a cathode, materials which have small work function and easily perform injection of electrons into a light emitting layer are preferable, and these materials include metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like; alloys composed of two or more of these metals; alloys composed of at least one of these metals and at least one of gold, silver, platinum, copper, manganese, titanium, cobalt, nickel, tungsten and tin; graphite, graphite intercalation compounds and the like.

The above-described alloy includes a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy and the like.

When the cathode has a lamination structure composed of two or more layers, it is preferable to combine a layer containing the above-described metal, metal oxide, metal fluoride or alloy thereof and a layer containing a metal such as aluminum, silver, chromium and the like.

The thickness of the cathode may advantageously be selected in view of the electric conductivity and the durability, and it is usually 10 nm to 10 μm, preferably 20 nm to 1 μm, more preferably 50 nm to 500 nm.

For fabrication of the cathode, a vacuum vapor-deposition method, a sputtering method, a laminate method for thermally compression-bonding a metal film, and the like are used. After cathode fabrication, it is preferable to install a protective layer and/or a protective cover for protecting an organic electroluminescent device.

As the protective layer, high molecular weight compounds, metal oxides, metal fluorides, metal borides and the like can be used. As the protective cover, a metal plate, a glass plate, and a plastic plate having a surface which has been subjected to a low water permeation treatment, and the like can be used. As the protective method, a method in which the protective cover is pasted to a device substrate with a thermosetting resin or a photo-curing resin to attain encapsulation is used. When a space is kept using a spacer, blemishing of a device can be prevented easily. If an inert gas such as nitrogen, argon and the like is filled in this space, oxidation of a cathode can be prevented, further, by placing a drying agent such as barium oxide and the like in this space, it becomes easy to suppress moisture adsorbed in a production process or a small amount of water invaded through a hardened resin from imparting a damage to the device. It is preferable to adopt at least one strategy among these methods.

The organic electroluminescent device of the present invention can be used as a planar light source, a display (segment display, dot matrix display), back light of a liquid crystal display, or the like. For obtaining light emission in the form of plane using the above-described organic electroluminescent device, a planar anode and a planar cathode may advantageously be placed so as to overlap. For obtaining light emission in the form of pattern, there are a method in which a mask having a window in the form of pattern is placed on the surface of the above-described planar organic electroluminescent device, a method in which an organic layer in non-light emitting parts is formed with extremely large thickness to give substantially no light emission, a method in which either an anode or a cathode, or both electrodes are formed in the form of pattern. By forming a pattern by any of these methods and placing several electrodes so that ON/OFF thereof is independently possible, a display of segment type is obtained which can display digits, letters, simple marks and the like. Further, for providing a dot matrix device, it may be advantageous that both an anode and a cathode are formed in the form of stripe, and placed so as to cross. By adopting a method in which several polymer compounds showing different emission colors are painted separately or a method in which a color filter or a fluorescence conversion filter is used, partial color display and multi-color display are made possible. In the case of a dot matrix device, passive driving is possible, and active driving may also be carried out in combination with TFT and the like. These display devices can be used as a display of a computer, a television, a portable terminal, a cellular telephone, a car navigation, a view finder of a video camera, and the like. Further, the above-described planar organic electroluminescent device is of self emitting and thin type, and can be suitably used as a planar light source for back light of a liquid crystal display, or as a planar light source for illumination, and the like. If a flexible substrate is used, it can also be used as a curved light source or display.

Next, the second group of inventions of the present invention will be illustrated in detail.

First, the terms commonly used in the present specification will be explained. In the present specification, the explanations are as described below unless otherwise stated.

As the halogen atom, a fluorine atom, a chlorine atom, a bromine atom and an iodine atom are shown.

The alkyl group may be linear or branched, and may also be a cycloalkyl group. The alkyl group may have a substituent. When the alkyl group has a substituent, one substituent may be present or two or more substituents may be present, and when two or more substituents are present, these may be the same or different. The carbon atom number of the alkyl group excluding the substituent is usually 1 to 20.

As the alkyl group, a methyl group, an ethyl group, a propyl group, an isopropyl group, a butyl group, an isobutyl group, a sec-butyl group, a tert-butyl group, a pentyl group, a hexyl group, a cyclohexyl group, a heptyl group, an octyl group, a 2-ethylhexyl group, a nonyl group, a decyl group, a 3,7-dimethyloctyl group and a dodecyl group are shown.

As the substituent which the alkyl group may have, an alkoxy group, an aryl group, an aryloxy group and a cyano group are preferable, from the viewpoint of the light emission property of a device.

The alkenyl group may be linear or branched, and may also be a cycloalkenyl group. The alkenyl group may have a substituent. When the alkenyl group has a substituent, one substituent may be present or two or more substituents may be present, and when two or more substituents are present, these may be the same or different. The carbon atom number of the alkenyl group excluding the substituent is usually 2 to 20.

As the alkenyl group, a vinyl group, a 1-propenyl group, a 2-propenyl group, a 1-butenyl group, a 2-butenyl group, a 3-butenyl group, a 1-pentenyl group, a 2-pentenyl group, a 3-pentenyl group, a 4-pentenyl group, a 1-hexenyl group, a 2-hexenyl group, a 3-hexenyl group, a 4-hexenyl group, a 5-hexenyl group, a 1-heptenyl group, a 2-heptenyl group, a 3-heptenyl group, a 4-heptenyl group, a 5-heptenyl group, a 6-heptenyl group, a 1-octenyl group, a 2-octenyl group, a 3-octenyl group, a 4-octenyl group, a 5-octenyl group, a 6-octenyl group, a 7-octenyl group, a 1-cyclohexenyl group, a 2-cyclohexenyl group and a 3-cyclohexenyl group are shown. The alkenyl group includes also alkadienyl groups such as a 1,3-butadienyl group and the like.

As the substituent which the alkenyl group may have, an alkoxy group, an aryl group, an aryloxy group and a cyano group are preferable, from the viewpoint of the light emission property of a device.

The alkynyl group may be linear or branched, and may also be a cycloalkynyl group. The alkynyl group may have a substituent. When the alkynyl group has a substituent, one substituent may be present or two or more substituents may be present, and when two or more substituents are present, these may be the same or different. The carbon atom number of the alkynyl group excluding the substituent is usually 2 to 20.

As the alkynyl group, an ethynyl group, a 1-propynyl group, a 2-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 1-heptynyl group, a 2-heptynyl group, a 3-heptynyl group, a 4-heptynyl group, a 5-heptynyl group, a 6-heptynyl group, a 1-octynyl group, a 2-octynyl group, a 3-octynyl group, a 4-octynyl group, a 5-octynyl group, a 6-octynyl group, a 7-octynyl group, a 2-cyclohexynyl group, a 3-cyclohexynyl group and a cyclohexylethynyl group are shown. The alkynyl group includes also alkydienyl groups such as a 1,3-butadiynyl group and the like, and groups having a double bond and a triple bond simultaneously such as a 2-penten-4-ynyl group and the like.

As the substituent which the alkynyl group may have, an alkoxy group, an aryl group, an aryloxy group and a cyano group are preferable from the viewpoint of the light emission property of a device.

The alkoxy group may be linear or branched, and may also be a cycloalkyloxy group. The alkoxy group may have a substituent. When the alkoxy group has a substituent, one substituent may be present or two or more substituents may be present, and when two or more substituents are present, these may be the same or different. The carbon atom number of the alkoxy group excluding the substituent is usually 1 to 20.

As the alkoxy group, a methoxy group, an ethoxy group, a propyloxy group, an isopropyloxy group, a butoxy group, an isobutoxy group, a sec-butoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a dodecyloxy group, a methoxymethyloxy group and a 2-methoxyethyloxy group are shown.

As the substituent which the alkoxy group may have, an alkenyl group, an alkynyl group, an alkoxy group, an aryl group, an aryloxy group and a cyano group are preferable, from the viewpoint of the light emission property of a device.

The alkylthio group may be linear or branched, and may also be a cycloalkylthio group. The alkylthio group may have a substituent. When the alkylthio group has a substituent, one substituent may be present or two or more substituents may be present, and when two or more substituents are present, these may be the same or different. The carbon atom number of the alkylthio group excluding the substituent is usually 1 to 20.

As the alkylthio group, a methylthio group, an ethylthio group, a propylthio group, an isopropylthio group, a butylthio group, an isobutylthio group, a sec-butylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group and a dodecylthio group are shown.

As the substituent which the alkylthio group may have, an alkenyl group, an alkynyl group, an alkoxy group, an aryl group, an aryloxy group and a cyano group are preferable, from the viewpoint of the light emission property of a device.

The alkylsilyl group may be linear or branched, and may also be a cycloalkylsilyl group. The alkylsilyl group may have a substituent. When the alkylsilyl group has a substituent, one substituent may be present or two or more substituents may be present, and when two or more substituents are present, these may be the same or different. The carbon atom number of the alkylsilyl group excluding the substituent is usually 1 to 20.

As the alkylsilyl group, a methylsilyl group, a dimethylsilyl group, a trimethylsilyl group, an ethylsilyl group, a diethylsilyl group, a triethylsilyl group, a butylsilyl group, an isobutylsilyl group, a sec-butylsilyl group, a tert-butylsilyl group, a dibutylsilyl group, a tributylsilyl group, a tert-butyldimethylsilyl group, a dimethyloctylsilyl group, a cyclohexyldimethylsilyl group and a tricyclohexylsilyl group are shown. The alkylsilyl group includes also silacycloalkan-1-yl groups such as a silacyclobutan-1-yl group, a 1-methylsilacyclohexan-1-yl group and the like.

As the substituent which the alkylsilyl group may have, an alkenyl group, an alkynyl group, an alkoxy group, an aryl group, an aryloxy group and a cyano group are preferable, from the viewpoint of the light emission property of a device.

The aryl group is an atomic group obtained by removing one hydrogen atom from an aromatic hydrocarbon, and also includes groups having a condensed ring, and groups having two or more independent benzene rings or condensed rings or both of them linked directly or via a vinylene group and the like. The aryl group may have a substituent. When the aryl group has a substituent, one substituent may be present or two or more substituents may be present, and when two or more substituents are present, these may be the same or different. The carbon atom number of a portion of the aryl group excluding the substituent is usually 6 to 60.

As the aryl group, a phenyl group, a 1-naphthyl group, a 2-naphthyl group, a 1-anthryl group, a 2-anthryl group, a 9-anthryl group, a 1-pyrenyl group, a 2-pyrenyl group, a 4-pyrenyl group, a 1-phenanthryl group, a 2-phenanthryl group, a 3-phenanthryl group, a 4-phenanthryl group, a 9-phenanthryl group, a 1-azulenyl group, a 2-azulenyl group, a 3-azulenyl group, a 4-azulenyl group, a 5-azulenyl group, a 6-azulenyl group, a 7-azulenyl group, a 8-azulenyl group, a 1-fluorenyl group, a 2-fluorenyl group, a 3-fluorenyl group, a 4-fluorenyl group, a 9-fluorenyl group, a 1-biphenylenyl group, a 2-biphenylenyl group, a 2-perylenyl group, a 3-perylenyl group, a 2-biphenylyl group, a 3-biphenylyl group, a 4-biphenylyl group and a 7-(2-anthryl)-2-naphthyl group are shown.

As the substituent which the aryl group may have, an alkyl group, an alkenyl group, an alkynyl group, an alkoxy group, an aryloxy group and a cyano group are preferable, from the viewpoint of the light emission property of a device.

The aryloxy group is a group represented by —OAr (wherein Ar represents an aryl group, the same shall apply hereinafter). The aryl group is as described above. The aryloxy group may have a substituent. When the aryloxy group has a substituent, one substituent may be present or two or more substituents may be present, and when two or more substituents are present, these may be the same or different. The carbon atom number of a portion of the aryl group excluding the substituent is usually 6 to 60.

As the aryloxy group, a phenyloxy group, a 1-naphthyloxy group, a 2-naphthyloxy group, a 1-anthryloxy group, a 2-anthryloxy group, a 9-anthryloxy group, a 1-pyrenyloxy group, a 2-pyrenyloxy group, a 4-pyrenyloxy group, a 1-phenanthryloxy group, a 2-phenanthryloxy group, a 3-phenanthryloxy group, a 4-phenanthryloxy group, a 9-phenanthryloxy group, a 1-azulenyloxy group, a 2-azulenyloxy group, a 3-azulenyloxy group, a 4-azulenyloxy group, a 5-azulenyloxy group, a 6-azulenyloxy group, a 7-azulenyloxy group, a 8-azulenyloxy group, a 1-fluorenyloxy group, a 2-fluorenyloxy group, a 3-fluorenyloxy group, a 4-fluorenyloxy group, a 9-fluorenyloxy group, a 1-biphenylenyloxy group, a 2-biphenylenyloxy group, a 2-perylenyloxy group, a 3-perylenyloxy group, a 2-biphenylyloxy group, a 3-biphenylyloxy group, a 4-biphenylyloxy group and a 7-(2-anthryl)-2-naphthyloxy group are shown.

As the substituent which the aryloxy group may have, an alkyl group, an alkenyl group, an alkynyl group, an alkoxy group, an aryloxy group and a cyano group are preferable, from the viewpoint of the light emission property of a device.

The arylsilyl group is a group represented by —SiH₂Ar, —SiHAr₂ or —SiAr₃. When a plurality of Ars are present, these may be the same or different. The arylsilyl group may have a substituent. When the arylsilyl group has a substituent, one substituent may be present or two or more substituents may be present, and when two or more substituents are present, these may be the same or different. The carbon atom number of a portion of the arylsilyl group excluding the substituent is usually 6 to 60.

As the arylsilyl group, a phenylsilyl group, a diphenylsilyl group, a triphenylsilyl group, a 1-naphthylsilyl group, a di(1-naphthyl)silyl group, a tris(1-naphthyl)silyl group, a di(1-naphthyl)phenylsilyl group, a 1-anthrylsilyl group, a 9-anthrylsilyl group, a 1-pyrenylsilyl group, a 2-pyrenylsilyl group, a 1-fluorenylsilyl group, a 1-biphenylenylsilyl group, a di(1-biphenylenyl)silyl group, a di(4-biphenylyl)silyl group and a 7-(2-anthryl)-2-naphthylsilyl group are shown.

As the substituent which the arylsilyl group may have, an alkyl group, an alkenyl group, an alkynyl group, an alkoxy group, an aryloxy group and a cyano group are preferable, from the viewpoint of the light emission property of a device.

The organic electroluminescent device of the present invention has an anode and a cathode, and a hole transporting layer and a light emitting layer disposed between the anode and the cathode. A hole injection layer may be present between the anode and the hole transporting layer, and an electron transporting layer and an electron injection layer may be present between the light emitting layer and the cathode. Each two or more layers of the hole injection layer, the hole transporting layer, the light emitting layer, the electron transporting layer and the electron injection layer may be present independently. Hereinafter, the hole injection layer and the electron injection layer are collectively called “charge injection layer”.

In the organic electroluminescent device of the present invention, when two or more hole transporting layers are present, at least one of them may contain

1) a mixture of 2,2′-bipyridine and/or 2,2′-bipyridine derivative and a non-2,2′-bipyridinediyl group-containing hole transporting polymer compound,

2) a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group,

or a combination thereof.

In the organic electroluminescent device of the present invention, it is preferable that the above-described hole transporting layer and the above-described light emitting layer are in contact with each other and a hole injection layer is disposed between the above-described hole transporting layer and the above-described anode, from the viewpoint of the driving voltage and the device life.

The light emitting layer means a layer contributing mainly to light emission as a device.

The hole transporting layer means a layer having mainly a function of transporting holes and manifesting substantially no light emission. It is preferable that the light emission energy generating from this hole transporting layer is 5% or less with respect to the whole light emission energy generated from the organic electroluminescent device.

The electron transporting layer means a layer having mainly a function of transporting electrons and manifesting substantially no light emission. It is preferable that the light emission energy generating from this electron transporting layer is 5% or less with respect to the whole light emission energy generated from the organic electroluminescent device.

The electron transporting layer and the hole transporting layer are collectively called a charge transporting layer.

The charge injection layer means a layer having a function of improving charge injection efficiency from an electrode.

As the structure of the organic electroluminescent device of the present invention, the following structures a′) to g′) are shown.

a′) anode/hole transporting layer/light emitting layer/cathode
b′) anode/hole transporting layer/hole transporting layer/light emitting layer/cathode
c′) anode/hole transporting layer/hole transporting layer/hole transporting layer/light emitting layer/cathode
d′) anode/hole transporting layer/light emitting layer/light emitting layer/cathode
e′) anode/hole transporting layer/hole transporting layer/light emitting layer/light emitting layer/cathode
f′) anode/hole transporting layer/light emitting layer/electron transporting layer/cathode
g′) anode/hole transporting layer/light emitting layer/electron transporting layer/electron transporting layer/cathode
(wherein “/” means adjacent lamination of layers. The same shall apply hereinafter.)

The order and the number of layers to be laminated and the thickness of each layer can be regulated in view of the light emission efficiency and the luminance life.

For improvement of charge injectability from an electrode, the above-described charge injection layer or an insulation layer having a thickness of 2 nm or less may be provided adjacent to an electrode, and for improvement of the close adherence of an interface, prevention of mixing and the like, a thin buffer layer may be inserted into the interface of the charge transporting layer and the light emitting layer.

As the material of the above-described insulation layer, metal fluorides, metal oxides, organic insulation materials and the like are mentioned.

As the organic electroluminescent device having the above-described insulation layer having a thickness of 2 nm or less, an organic electroluminescent device having an insulation layer having a thickness of 2 nm or less disposed adjacent to a cathode and an organic electroluminescent device having an insulation layer having a thickness of 2 nm or less disposed adjacent to an anode are mentioned.

In the organic electroluminescent device of the present invention, it is preferable that the hole transporting layer containing

1) a mixture of 2,2′-bipyridine and/or 2,2′-bipyridine derivative and a non-2,2′-bipyridinediyl group-containing hole transporting polymer compound (hereinafter, referred to also as “material 1”),

2) a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group (hereinafter, referred to also as “material 2”),

or a combination thereof.

is adjacent to the light emitting layer, it is more preferable that the hole transporting layer is adjacent to the light emitting layer and a hole injection layer is present between the above-described hole transporting layer and an anode, and it is further preferable that the hole transporting layer is adjacent to the light emitting layer and to the hole injection layer, from the viewpoint of the light emission property.

### <Hole Transporting Layer>

Next, the above-described hole transporting layer will be illustrated.

(Material 1: a mixture of 2,2′-bipyridine and/or 2,2′-bipyridine derivative and a non-2,2′-bipyridinediyl group-containing hole transporting polymer compound)

It is preferable that the above-described non-2,2′-bipyridinediyl group-containing hole transporting polymer compound is a polymer compound represented by the following formula α-(2).

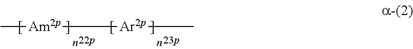

[in the formula α-(2), Am^{2p} represents a divalent aromatic amine residue, and Ar^{2p} represents an unsubstituted or substituted arylene group. n^{22p} and n^{23p} each independently represent numbers indicating the molar ratio of a divalent aromatic amine residue represented by Am^{2p} to an unsubstituted or substituted arylene group represented by Ar^{2p} in the polymer compound, satisfying n^{22p}+n^{23p}=1, 0.001≦n^{22p}≦1 and 0≦n^{23p}≦0.999. When a plurality of Am^{2p}s are present, these may be the same or different. When a plurality of Ar^{2p}s are present, these may be the same or different.].

In the formula α-(2), a plurality of Am^{2p}s may be present, and it is preferable from the viewpoint of synthesis of the polymer compound that all Am^{2p}s are identical, and it is preferable from the viewpoint of the light emission property that a plurality of Am^{2p}s are different (that is, several kinds of Am^{2p}s are present in the formula α-(2)).

The divalent aromatic amine residue represented by Am^{2p} means an atomic group obtained by removing two hydrogen atoms from an aromatic amine. The divalent aromatic amine residue may have a substituent, and the carbon atom number of a portion excluding the substituent is usually 12 to 100, preferably 18 to 60.

As the substituent which the above-described divalent aromatic amine residue may have, an alkyl group, an alkenyl group, an alkynyl group, an alkoxy group, an aryloxy group, a halogen atom and a cyano group are preferable and an alkyl group, an alkenyl group and an alkynyl group are more preferable, from the viewpoint of synthesis of the non-2,2′-bipyridinediyl group-containing polymer compound.

The above-described divalent aromatic amine residue includes groups represented by the following formulae α-Am1 to α-Am31, and groups represented by the formulae α-Am1 to α-Am5, the formulae α-Am10 to α-Am16, the formula α-Am19, the formula α-Am21, the formula α-Am23, the formula α-Am25, the formula α-Am27 and the formula α-Am30 are preferable and groups represented by the formulae α-Am12 to α-Am16, the formula α-Am19, the formula α-Am21, the formula α-Am23, the formula α-Am25, the formula α-Am27 and the formula α-Am30 are more preferable, from the viewpoint of the hole transportability and the light emission property of a device when used for fabrication of the device, and groups represented by the formulae α-Am1 to α-Am5, the formulae α-Am10 to α-Am12, the formula α-Am14, the formula α-Am15, the formula α-Am21 and the formula α-Am27 are preferable and groups represented by the formulae α-Am1 to α-Am5, the formulae α-Am10 to α-Am12, the formula α-Am14 and the formula α-Am15 are more preferable, from the viewpoint of synthesis of the non-2,2′-bipyridinediyl group-containing polymer compound. The divalent aromatic amine residue may have a substituent.

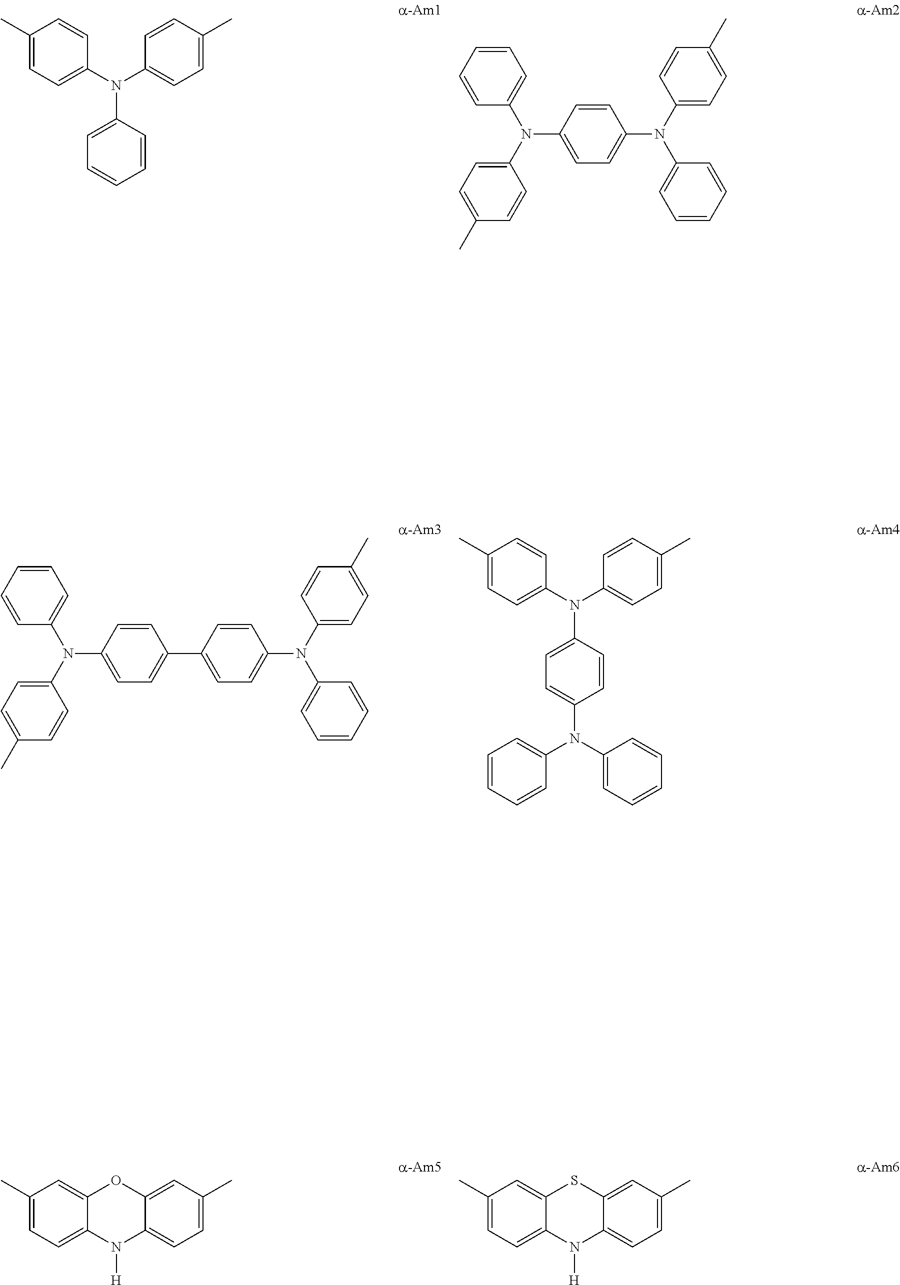

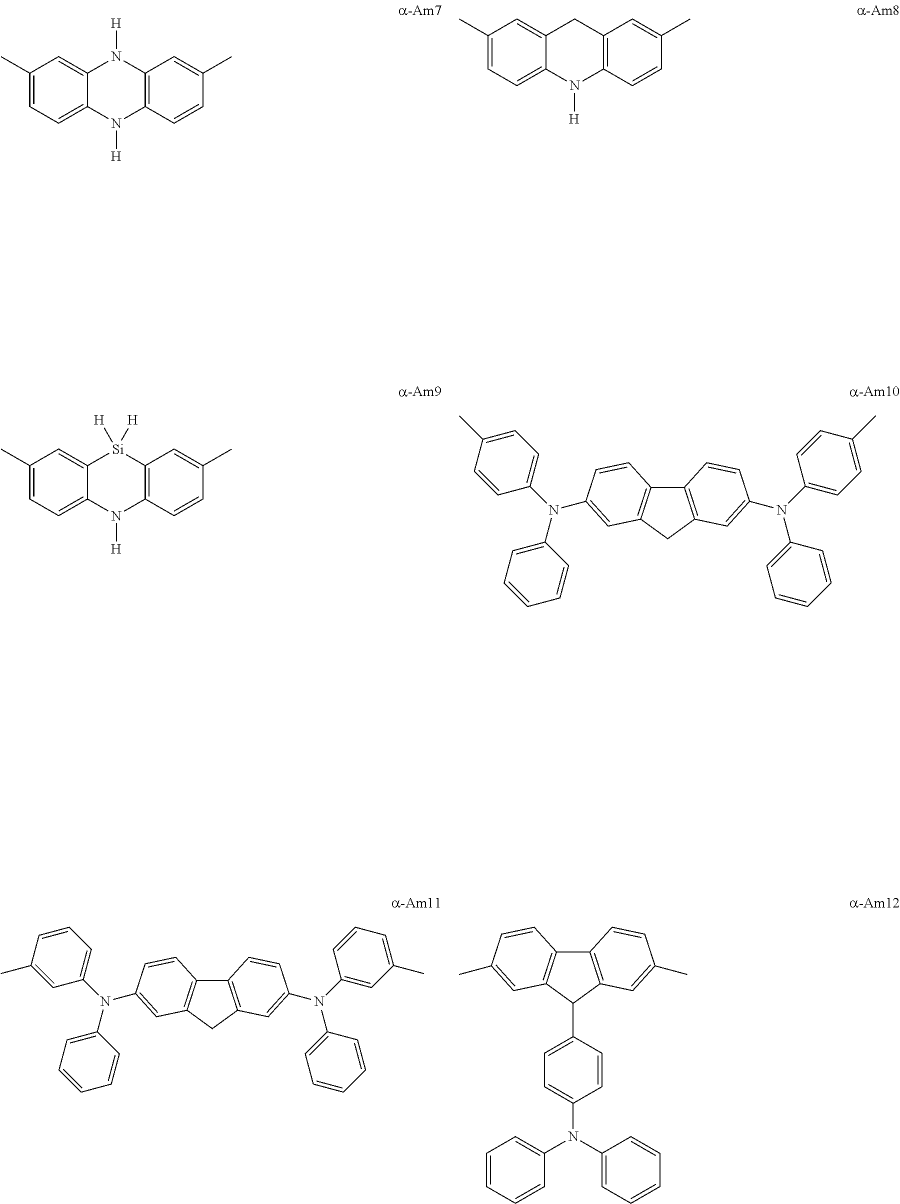

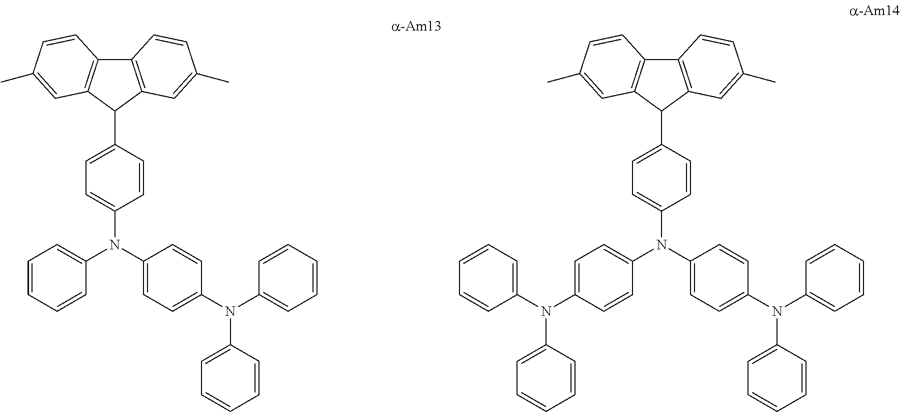

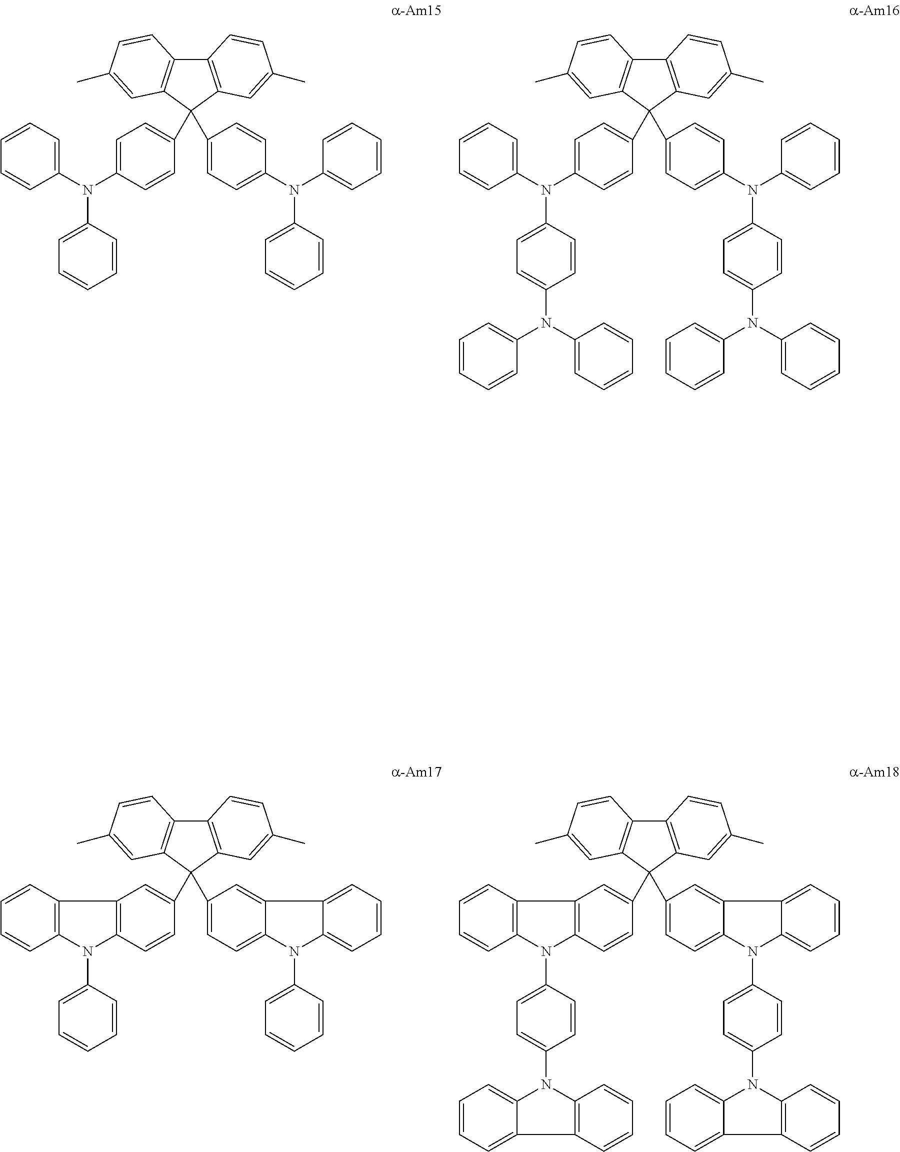

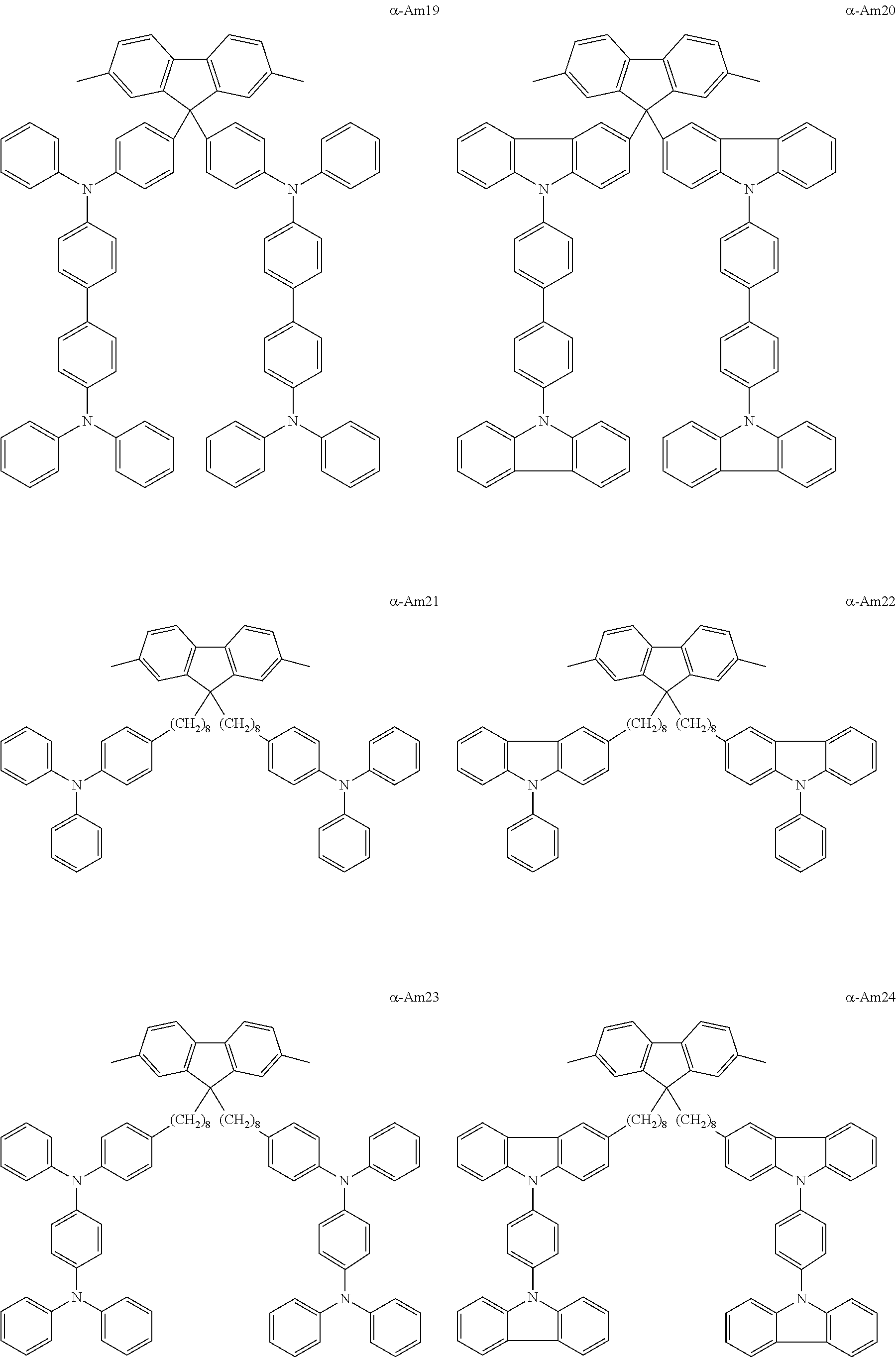

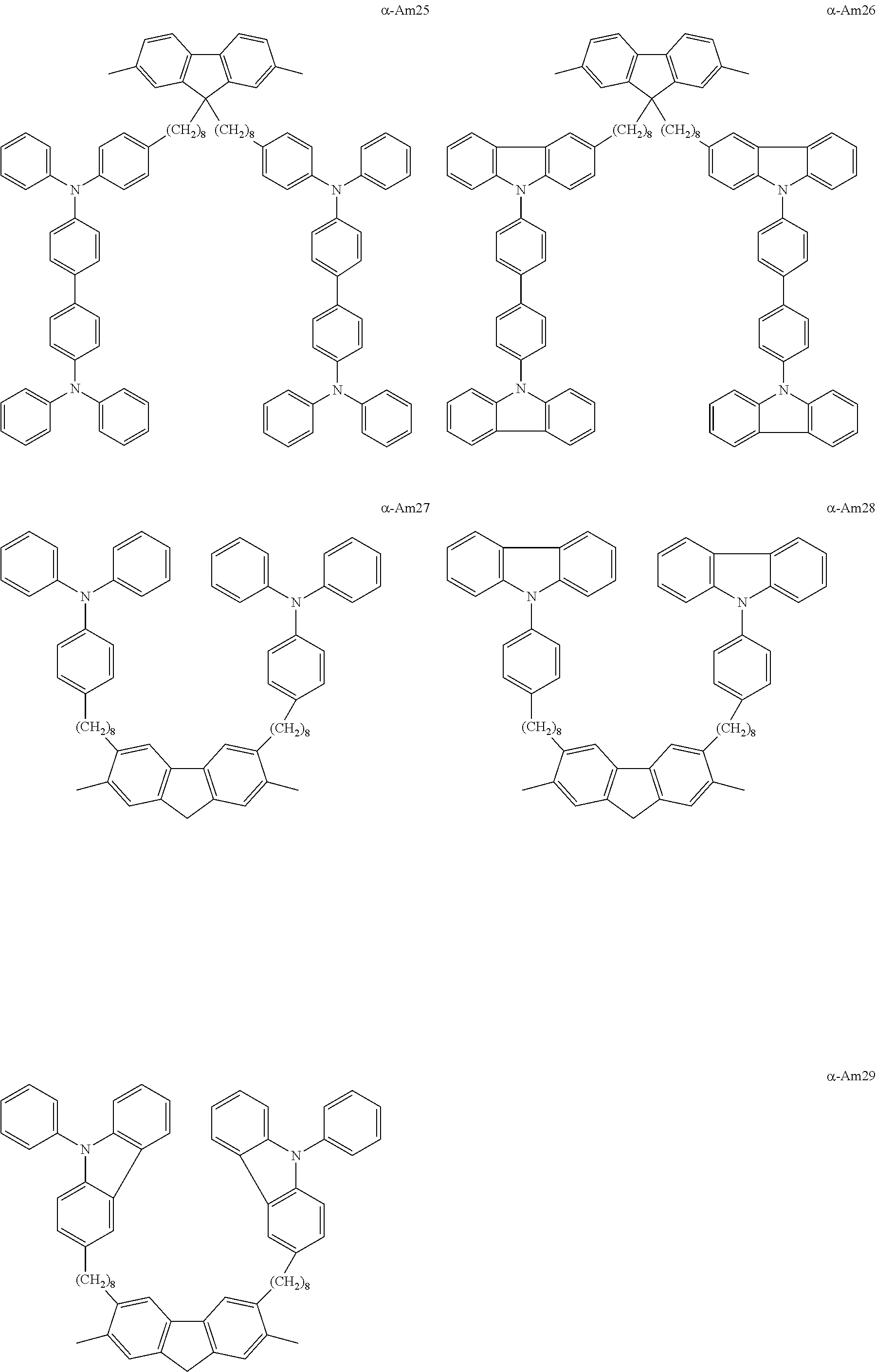

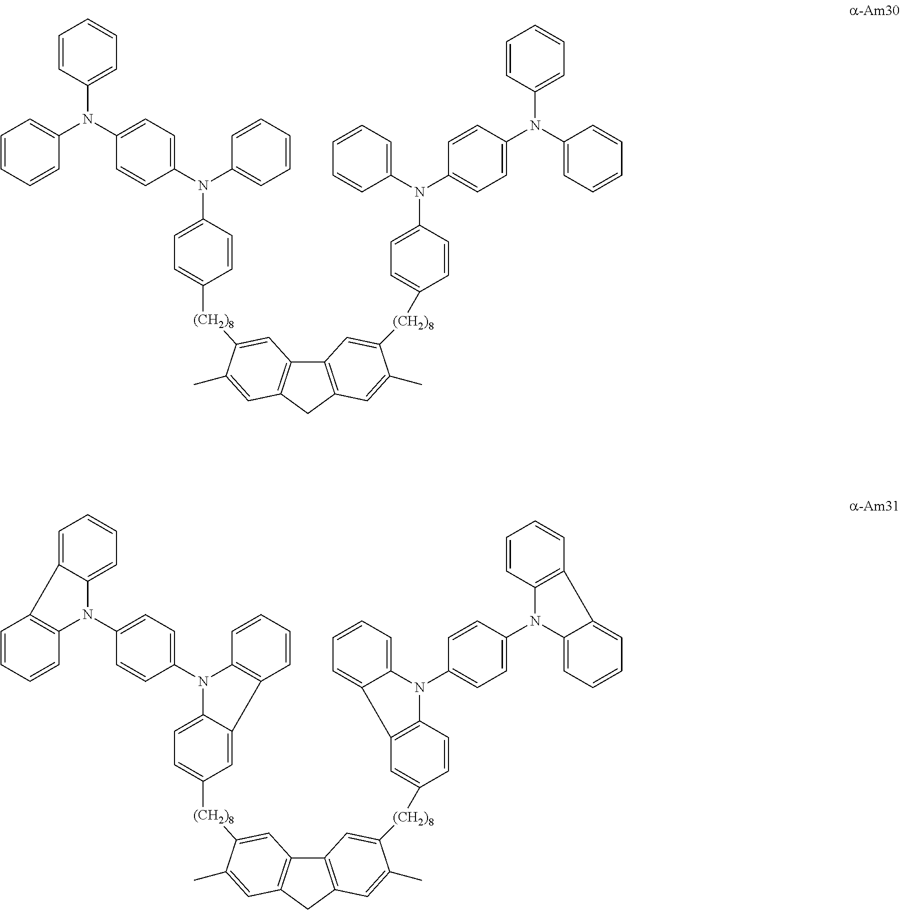

In the formula α-(2), a plurality of Ar^{2p}s may be present, and it is preferable from the viewpoint of synthesis of the polymer compound that all Ar^{2p}s are identical, and it is preferable from the viewpoint of the light emission property that a plurality of Ar^{2p}s are different (that is, several kinds of Ar^{2p}s are present in the formula α-(2)). It is particularly preferable from the viewpoint of the life property of a device and the charge transporting property that the above-described unsubstituted or substituted arylene group represented by Ar^{2p} includes at least one selected from the group consisting of unsubstituted or substituted fluorenediyl groups and unsubstituted or substituted phenylenediyl groups.

The unsubstituted or substituted arylene group represented by Ar^{2p} is an atomic group obtained by removing two hydrogen atoms from an aromatic hydrocarbon, and includes groups having a condensed ring, and groups having two or more independent benzene rings or condensed rings or both of them linked directly or via a vinylene group and the like. The arylene group may have a substituent.

As the substituent which the above-described arylene group may have, one substituent may be present or two or more substituents may be present, and when two or more substituents are present, these may be the same or different.

The carbon atom number of a portion of the above-described arylene group excluding the substituent is usually 6 to 60, and the carbon atom number including the substituent is usually 6 to 100.

As the substituent which the above-described arylene group may have, an alkyl group, an alkenyl group, an alkynyl group, an alkoxy group, an aryl group, an aryloxy group, a halogen atom and a cyano group are preferable and an alkyl group, an alkenyl group, an alkynyl group and an aryl group are more preferable, from the viewpoint of synthesis of the non-2,2′-bipyridinediyl group-containing polymer compound.

The above-described arylene group includes phenylene groups (the formulae α-Ar1 to α-Ar3), naphthalenediyl groups (the formulae α-Ar4 to α-Ar13), anthracenediyl groups (the formulae α-Ar14 to α-Ar19), biphenyldiyl groups (the formulae α-Ar20 to α-Ar25), terphenyldiyl groups (the formulae α-Ar26 to α-Ar28), condensed ring groups (the formulae α-Ar29 to α-Ar35), fluorenediyl groups (the formulae α-Ar36 to α-Ar48) and benzofluorenediyl groups (the formulae α-Ar49 to α-Ar67); and phenylene groups, biphenyldiyl groups, terphenyldiyl groups and fluorenediyl groups are preferable and phenylene groups and fluorenediyl groups are more preferable, from the viewpoint of the light emission property of a device when used for fabrication of the device, and groups represented by the formula α-Ar1, the formula α-Ar4, the formula α-Ar7, the formulae α-Ar12 to α-Ar14, the formula α-Ar16, the formula α-Ar17, the formulae α-Ar19 to α-Ar21, the formula α-Ar23, the formula α-Ar26, the formula α-Ar27, the formulae α-Ar29 to α-Ar33, the formulae α-Ar35 to α-Ar37, the formula α-Ar40, the formula α-Ar41, the formulae α-Ar43 to α-Ar46 and the formulae α-Ar49 to α-Ar67 are preferable, from the viewpoint of synthesis of the non-2,2′-bipyridinediyl group-containing polymer compound. These groups may have a substituent.

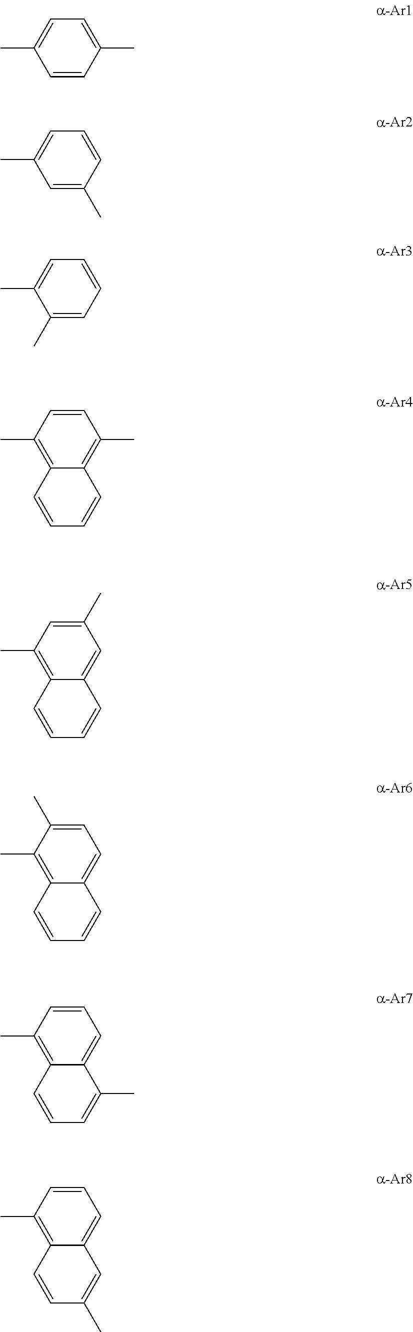

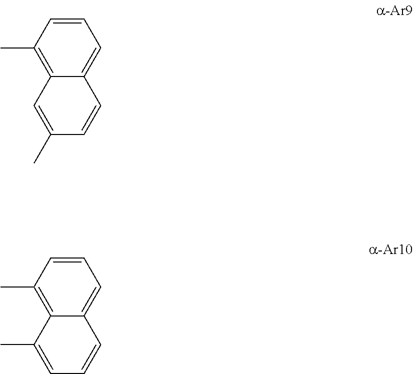

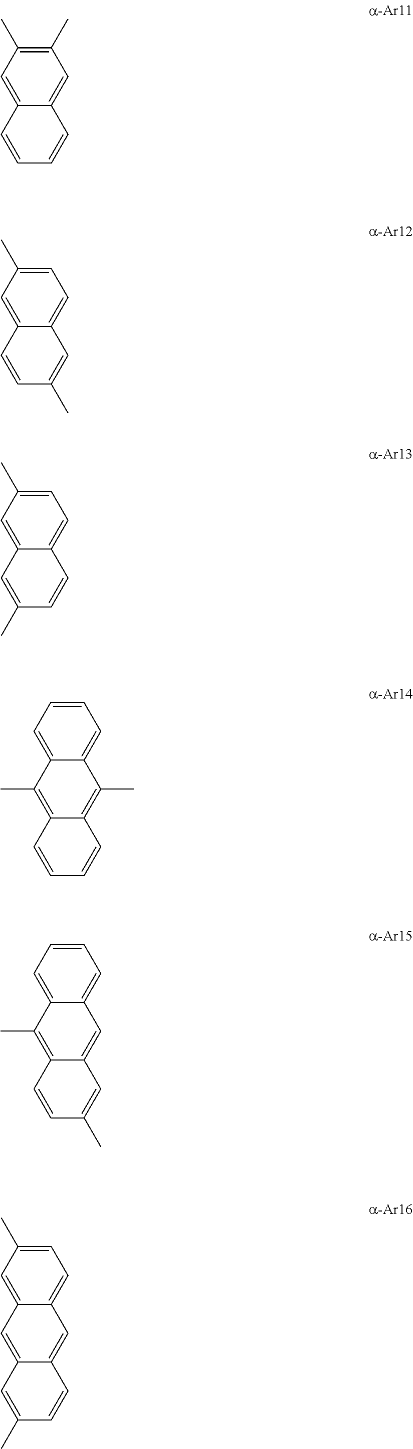

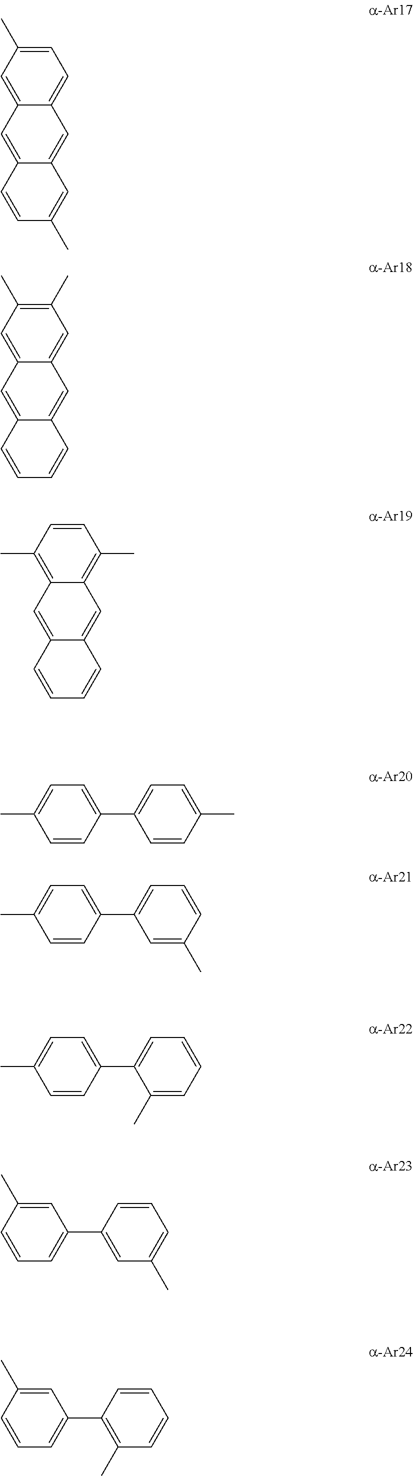

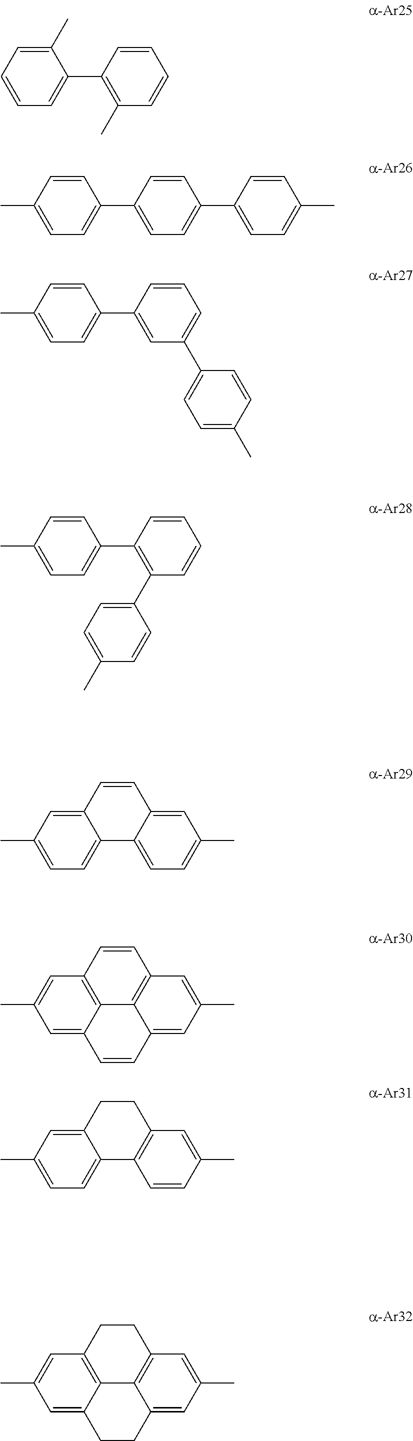

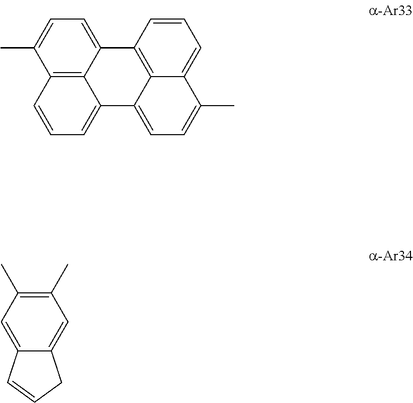

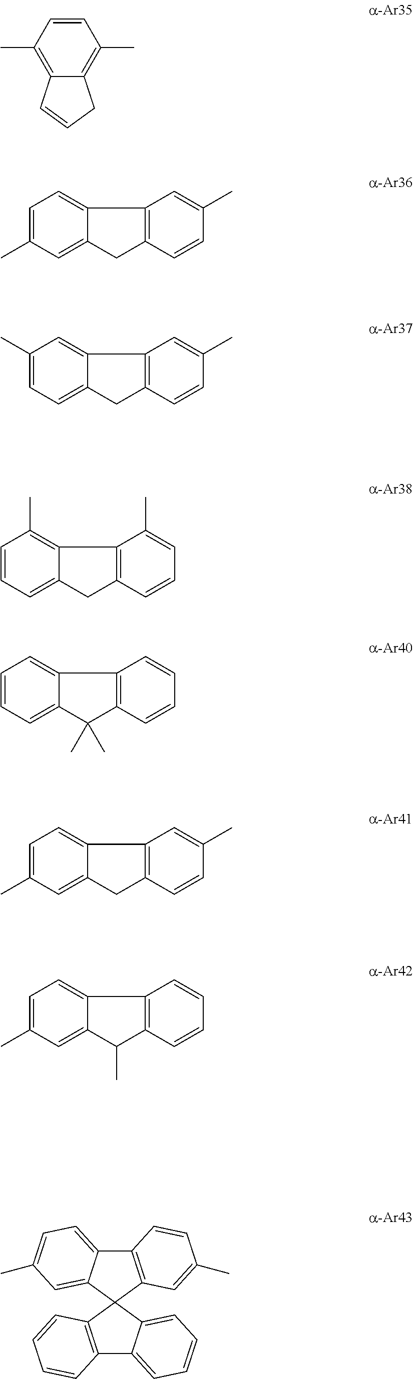

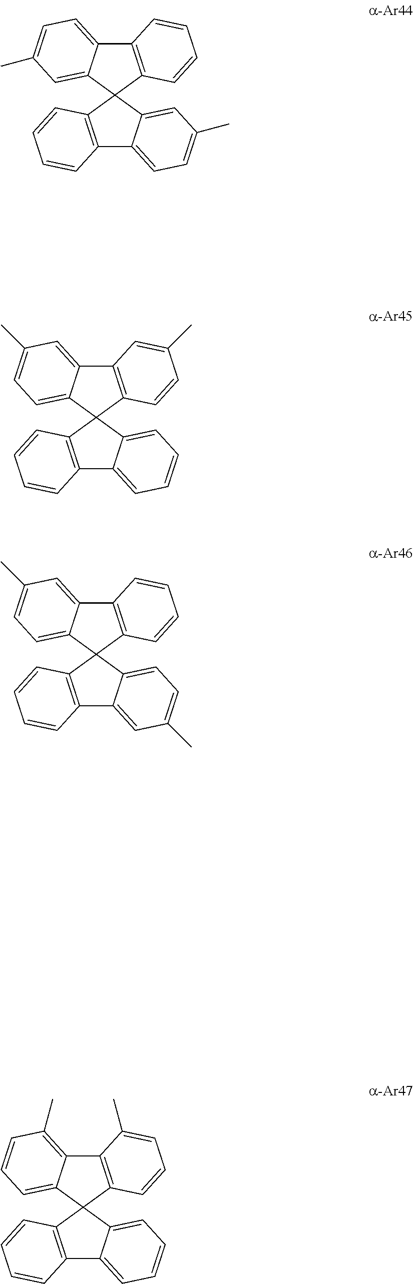

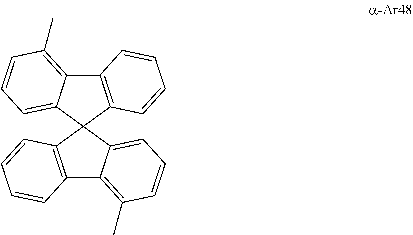

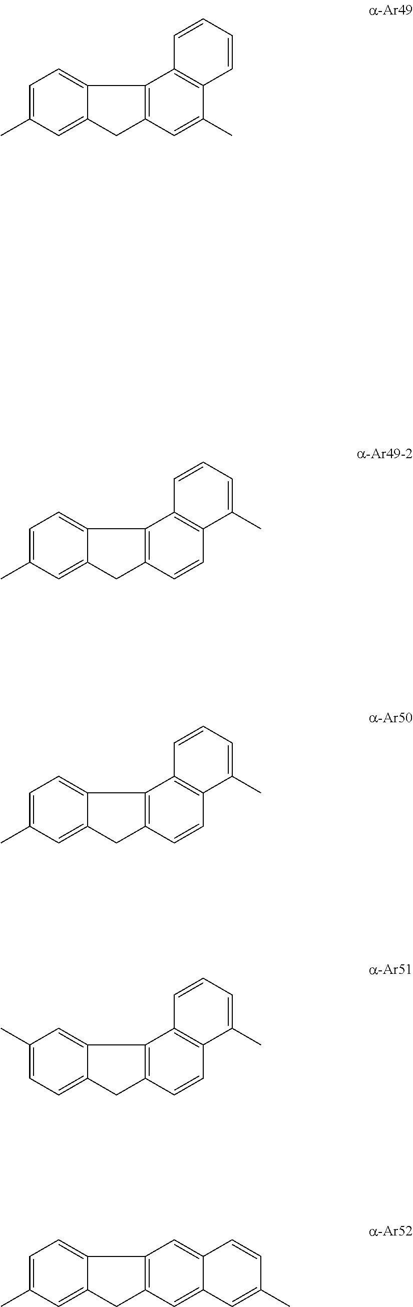

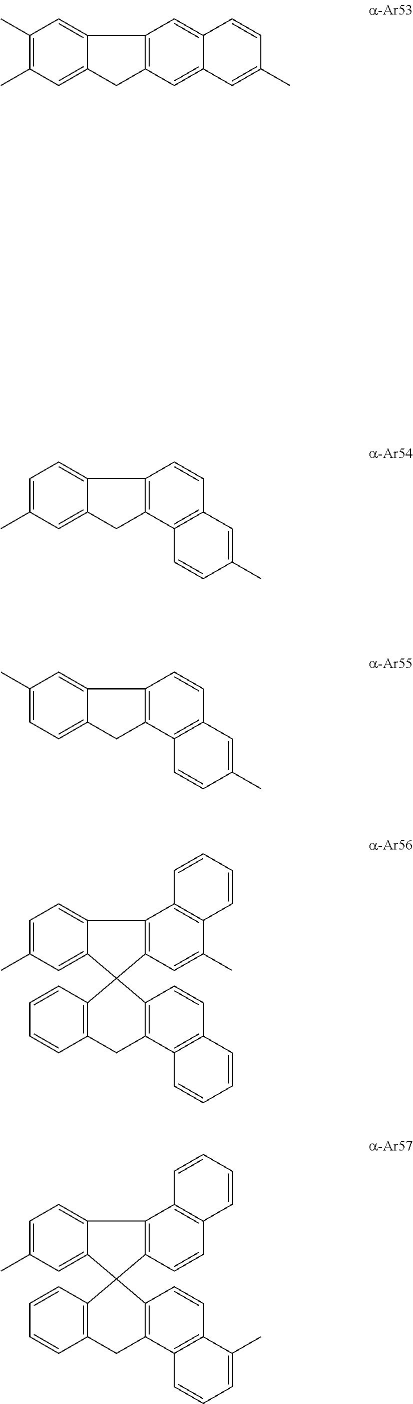

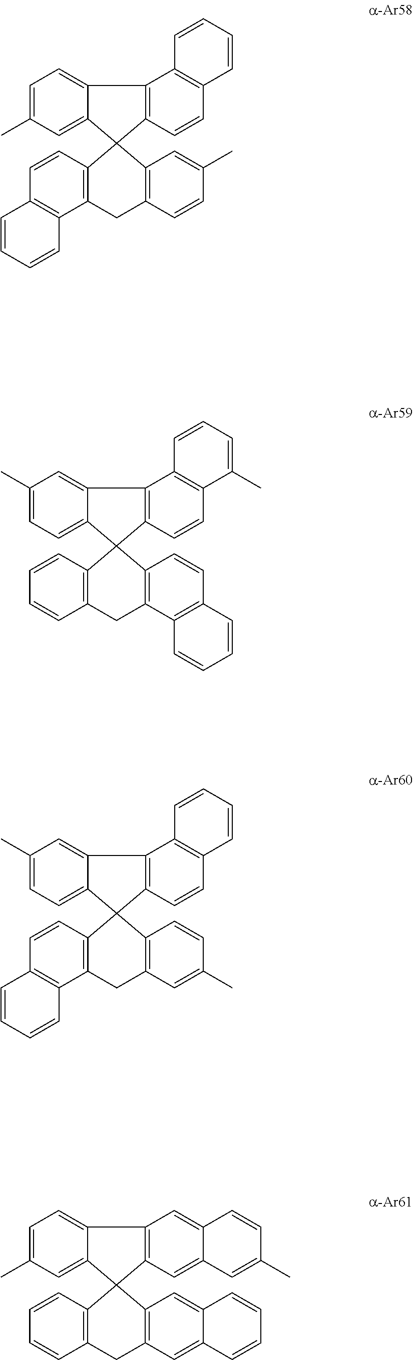

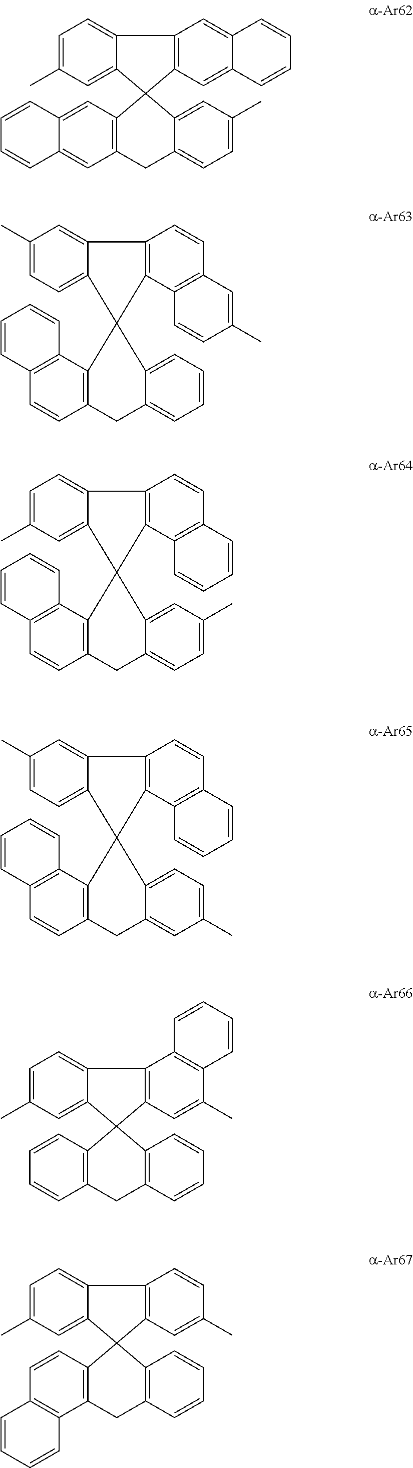

In the formula α-(2), n^{22p} represents preferably a number satisfying 0.001≦n^{22p}≦0.5, more preferably a number satisfying 0.001≦n^{22p}≦0.4, further preferably a number satisfying 0.001≦n^{22p}≦0.3, from the viewpoint of synthesis of the polymer compound, and represents preferably a number satisfying 0.1≦n^{22p}≦0.999, more preferably a number satisfying 0.2≦n^{22p}≦0.999, further preferably a number satisfying 0.4≦n^{22p}≦0.999, from the viewpoint of the light emission property and the hole transportability.

The polymer compound represented by the formula α-(2) has a polystyrene-equivalent number-average molecular weight of preferably 1×10³ to 1×10⁸, more preferably 1×10³ to 1×10⁷ and has a polystyrene-equivalent weight-average molecular weight of preferably 1×10³ to 1×10⁸, more preferably 1×10³ to 1×10⁷, from the viewpoint of the life property of the organic electroluminescent device. The number-average molecular weight and the weight-average molecular weight can be measured, for example, using size exclusion chromatography (SEC).

The polymer compound represented by the formula α-(2) may be any of an alternative copolymer, a random copolymer, a block copolymer and a graft copolymer, and may also be a polymer compound having an intermediate structure between them, for example, a random copolymer having a block property.

As the polymer compound represented by the formula α-(2), polymer compounds represented by the following formulae (EX2-1P) to (EX2-3P) are shown.

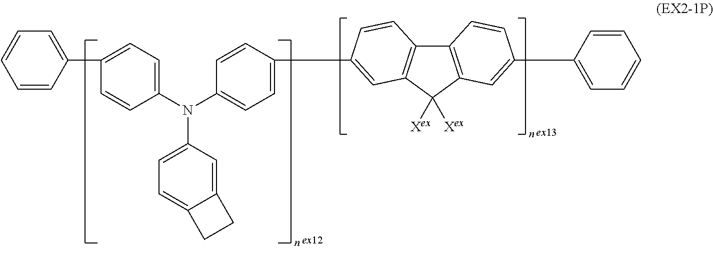

[in the formula (EX2-1P), X^{ex} represents a hydrogen atom, an alkyl group or an aryl group. n^{ex12} and n^{ex13} are numbers satisfying n^{ex12}+n^{ex13}=1, 0.01≦n^{ex12}≦0.9 and 0.1≦n^{ex13}≦0.99. Two or more X^{ex} moieties may be the same or different.]

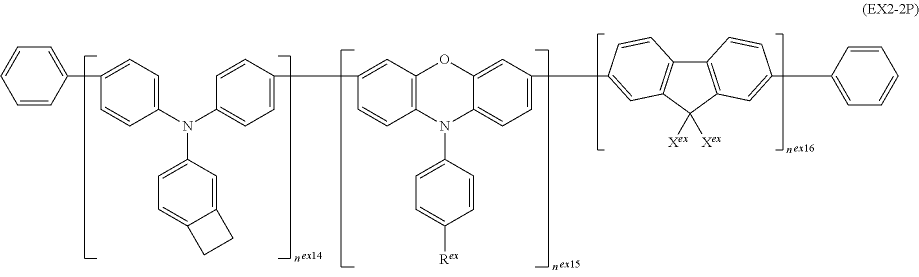

[in the formula (EX2-2P), X^{ex} is as described above, and R^{ex} represents an alkyl group or an alkenyl group. n^{ex14}, n^{ex15} and n^{ex16} are numbers satisfying n^{ex14}+n^{ex15}+n^{ex16}=1, 0.01≦n^{ex14}≦0.4, 0.01≦n^{ex15}≦0.6 and 0≦n^{ex16}≦0.98. Two or more X^{ex} moieties may be the same or different. When a plurality of R^{ex}s are present, these may be the same or different.]

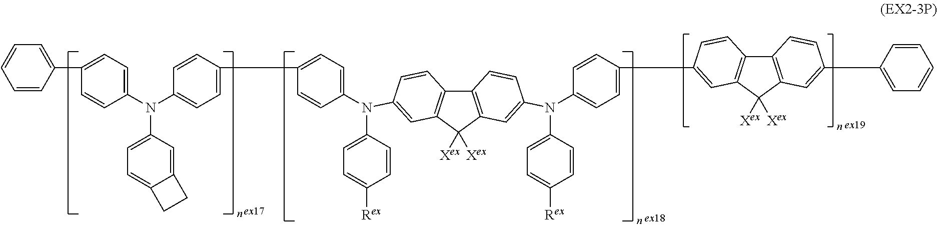

[in the formula (EX2-3P), X^{ex} and R^{ex} are as described above. n^{ex17}, n^{ex18} and n^{ex19} are numbers satisfying n^{ex17}+n^{ex18}+n^{ex19}=0.01≦n^{ex17}≦0.4, 0.01≦n^{ex18}≦0.6 and 0≦n^{ex19}≦0.98. Two or more X^{ex} moieties may be the same or different. Two or more R^{ex} moieties may be the same or different.]

The above-described non-2,2′-bipyridinediyl group-containing hole transporting polymer compound includes also polymer compounds obtained by intermolecular or intramolecular cross-linkage of a non-2,2′-bipyridinediyl group-containing hole transporting polymer compound such as polymer compounds represented by the above-described formula α-(2) explained above and the like.

The molecular weight of 2,2′-bipyridine and 2,2′-bipyridine derivative is usually 156 to 1500, preferably 184 to 800.

In the above-described formula, the alkyl group and the aryl group represented by X^{ex} are as described above.

In the above-described formula, the alkyl group and the alkenyl group represented by R^{ex} are as described above.

As the 2,2′-bipyridine or 2,2′-bipyridine derivative, compounds represented by the following formula α-(3) are preferable.

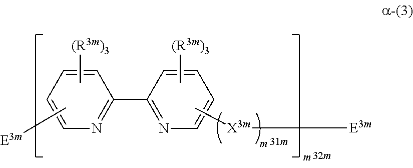

[in the formula α-(3), E^{3m} and R^{3m} each independently represent a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group. X^{3m} represents an unsubstituted or substituted arylene group, an unsubstituted or substituted alkanediyl group, an unsubstituted or substituted alkenediyl group or an unsubstituted or substituted alkynediyl group. Two or more E^{3m} moieties may be the same or different. Two or more R^{3m} moieties may be the same or different. m^{31m} represents an integer of 0 to 3. m^{32m} represents an integer of 1 to 3. When a plurality of m^{31m}s are present, these may be the same or different. When a plurality of X^{3m}s are present, these may be the same or different.].

In the formula α-(3), E^{3m} represents preferably a hydrogen atom, a halogen atom, a hydroxyl group, an unsubstituted or substituted alkyl group, an unsubstituted or substituted alkenyl group, an unsubstituted or substituted alkynyl group or an unsubstituted or substituted aryl group and more preferably a hydrogen atom, a halogen atom, a hydroxyl group, an unsubstituted or substituted alkyl group or an unsubstituted or substituted aryl group, from the viewpoint of synthesis of the compound represented by the formula α-(3), represents preferably a halogen atom, a hydroxyl group, an unsubstituted or substituted alkyl group, an unsubstituted or substituted alkenyl group, an unsubstituted or substituted alkynyl group or an unsubstituted or substituted aryl group and more preferably a hydroxyl group, an unsubstituted or substituted alkyl group, an unsubstituted or substituted alkenyl group or an unsubstituted or substituted alkynyl group, from the viewpoint of the solubility of the compound represented by formula α-(3) in an organic solvent, and represents preferably a hydrogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted aryl group or an unsubstituted or substituted aryloxy group and more preferably a hydrogen atom, a hydroxyl group, an unsubstituted or substituted alkyl group, an unsubstituted or substituted alkoxy group or an unsubstituted or substituted aryl group, from the viewpoint of the light emission property. It is preferable from the viewpoint of synthesis of the compound represented by the formula α-(3) that all E^{3m}s are identical.

In formula α-(3), R^{3m} represents preferably a hydrogen atom, a halogen atom, a hydroxyl group, an unsubstituted or substituted alkyl group, an unsubstituted or substituted alkenyl group, an unsubstituted or substituted alkynyl group or an unsubstituted or substituted aryl group, more preferably a hydrogen atom, an unsubstituted or substituted alkyl group or an unsubstituted or substituted aryl group and particularly preferably a hydrogen atom, from the viewpoint of synthesis of the compound represented by the formula α-(3), represents preferably a halogen atom, a hydroxyl group, an unsubstituted or substituted alkyl group, an unsubstituted or substituted alkenyl group, an unsubstituted or substituted alkynyl group or an unsubstituted or substituted aryl group and more preferably a hydroxyl group, an unsubstituted or substituted alkyl group, an unsubstituted or substituted alkenyl group or an unsubstituted or substituted alkynyl group, from the viewpoint of the solubility of the compound represented by the formula α-(3) in an organic solvent, and represents preferably a hydrogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted aryl group or an unsubstituted or substituted aryloxy group and more preferably a hydrogen atom, from the viewpoint of the light emission property.

In the formula α-(3), X^{3m} represents preferably an unsubstituted or substituted arylene group or an unsubstituted or substituted alkanediyl group. When a plurality of X^{3m}s are present, these may be the same or different. The unsubstituted or substituted arylene group represented by X^{3m} is as described above.

Examples of the alkanediyl group represented by X^{3m} include a methylene group, an ethylene group, a propylene group, a tetramethylene group, a pentaethylene group, a hexaethylene group and a heptaethylene group. This alkanediyl group may have a substituent.

Examples of the alkenediyl group represented by X^{3m} include a vinylene group, a propenylene group, a 1-butenylene group, a 2-butenylene group, a 1,2-butadienylene group, a 1,3-butadienylene group, a 1-pentenylene group, a 2-pentenylene group, a 1,2-pentadienylene group, a 1,3-pentadienylene group, a 1,4-pentadienylene group, a 2,3-pentadienylene group, a 2,4-pentadienylene group, a 1-hexenylene group, a 2-hexenylene group and a 3-hexenylene group. This alkenediyl group may have a substituent.

Examples of the alkynediyl group represented by X^{3m} include an ethynylene group, a propynylene group, a 1-butynylene group, a 2-butynylene group and a 1,3-butydinylene group. This alkynediyl group may have a substituent.

In the formula α-(3), m^{32m} represents preferably 1, from the viewpoint of the life property.

As the compound represented by the formula α-(3), compounds represented by the following formula α-(4) or α-(5) are preferable

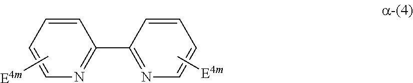

[in the formula α-(4), E^{4m} represents a hydrogen atom, a hydroxyl group, an unsubstituted or substituted alkyl group or an unsubstituted or substituted alkoxy group. Two or more E^{4m} moieties may be the same or different, providing that at least one of them represents a hydroxyl group, an unsubstituted or substituted alkyl group or an unsubstituted or substituted alkoxy group.]

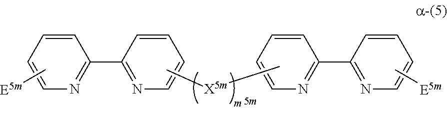

[in the formula α-(5), E^{5m} represents a hydrogen atom, hydroxyl group, an unsubstituted or substituted alkyl group or an unsubstituted or substituted alkoxy group. Two or more E^{5m} moieties may be the same or different. X^{5m} represents an unsubstituted or substituted arylene group or an unsubstituted or substituted alkanediyl group. m^{5m} represents an integer of 1 to 3. When a plurality of X^{5m}s are present, these may be the same or different.]

In the formula α-(4), E^{4m} represents preferably a hydroxyl group or an unsubstituted or substituted alkyl group, from the viewpoint of the light emission property. When E^{4m} represents a hydroxyl group or an unsubstituted or substituted alkyl group, the compound represented by the formula α-(4) includes compounds represented by the following formulae α-(4-1) to α-(4-10), and preferably, includes compounds represented by the formula α-(4-1), the formula α-(4-5), the formula α-(4-8) and the formula α-(4-10), from the viewpoint of synthesis. It is preferable that all E^{4m}s are identical.

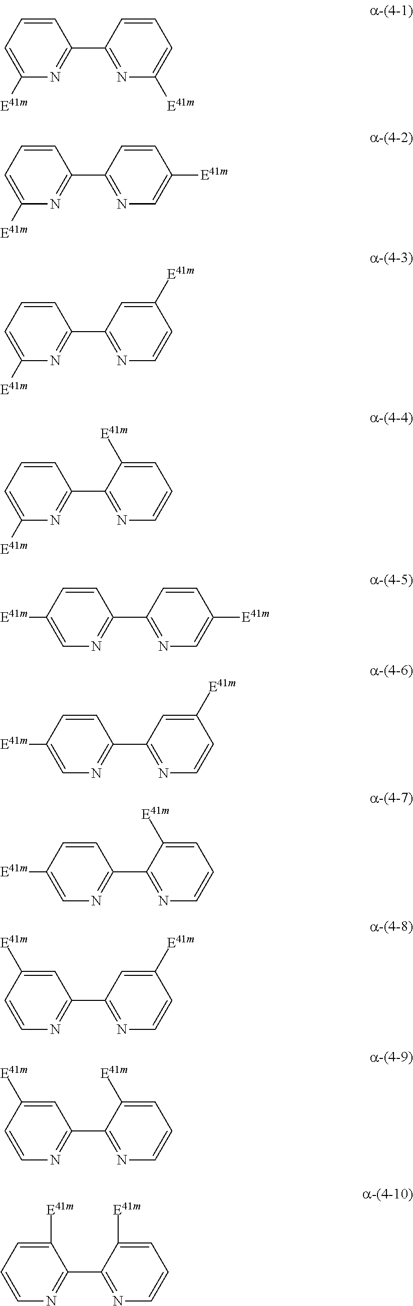

[in the formulae α-(4-1) to α-(4-10), E^{41m} represents a hydroxyl group or an unsubstituted or substituted alkyl group. Two or more E^{41m} moieties may be the same or different.]

In the formula α-(5), E^{5m} represents preferably a hydroxyl group or an unsubstituted or substituted alkyl group, from the viewpoint of the light emission property. It is preferable from the viewpoint of synthesis of the compound represented by the formula α-(5) that all E^{5m}s are identical.

In the formula α-(5), m^{5m} represents preferably 1 or 3, from the viewpoint of synthesis of the compound represented by the formula α-(5).

In the formula α-(5), when m^{5m} represents 1, X^{5m} represents preferably an unsubstituted or substituted alkanediyl group, from the viewpoint of the light emission property, and X^{5m} represents preferably an unsubstituted or substituted arylene group, from the viewpoint of synthesis of the compound represented by the formula α-(5). The alkanediyl group and the arylene group represented by X^{5m} are as described above.

In the formula α-(5), when m^{5m} represents 3, the compound represented by the formula α-(5) includes preferably compounds represented by the following formulae α-(5-1) to α-(5-8), more preferably compounds represented by the following formula α-(5-3) or α-(5-7).

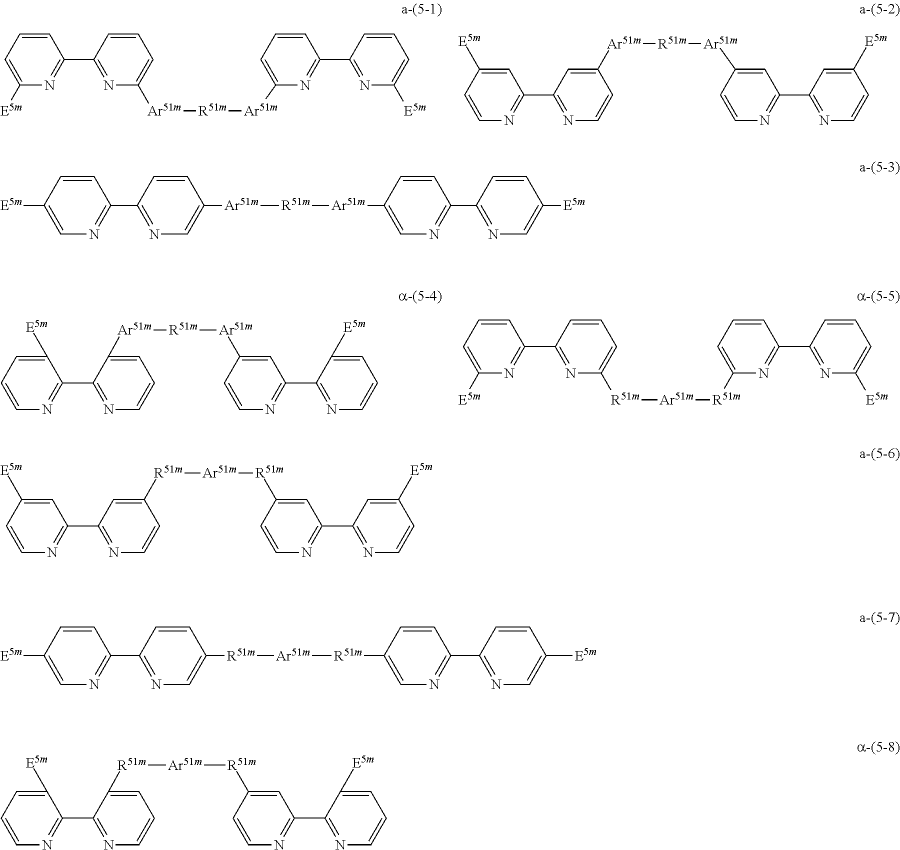

[in the formulae α-(5-1) to α-(5-8), E^{5m} is as described above. R^{51m} represents an unsubstituted or substituted alkanediyl group (this alkanediyl group is as described above). Ar^{51m} represents an unsubstituted or substituted arylene group (this arylene group is as described above). When a plurality of R^{51m}s are present, these may be the same or different. When a plurality of Ar^{51m}s are present, these may be the same or different.]

The melting point of the compounds represented by the formulae α-(3) to α-(5), the formulae α-(4-1) to α-(4-10) and the formulae α-(5-1) to α-(5-8) is preferably 10 to 500° C., more preferably 30 to 400° C., further preferably 40 to 300° C., from the viewpoint of the light emission property.

The saturated vapor pressure at 25° C. of the compounds represented by the formulae α-(3) to α-(5), the formulae α-(4-1) to α-(4-10) and the formulae α-(5-1) to α-(5-8) is preferably 1×10⁻³ Torr or less, more preferably 1×10⁻⁴ Torr or less, further preferably 1×10⁻⁵ Torr or less, from the viewpoint of the light emission property.

The compounds represented by the formulae α-(3) to α-(5), the formulae α-(4-1) to α-(4-10) and the formulae α-(5-1) to α-(5-8) are preferably a compound which can be dissolved at a concentration of 0.5 wt % or more, more preferably a compound which can be dissolved at a concentration of 1 wt % or more, further preferably a compound which can be dissolved at a concentration of 5 wt % or more and particularly preferably a compound which can be dissolved at a concentration of 10 wt % or more, at 25° C., in any of chlorine-based solvents such as chloroform, methylene chloride, 1,2-dichloroethane, 1,1,2-trichloroethane, chlorobenzene, o-dichlorobenzene and the like; ether solvents such as tetrahydrofuran, dioxane, anisole and the like; aromatic hydrocarbon solvents such as toluene, xylene and the like; aliphatic hydrocarbon solvents such as cyclohexane, methylcyclohexane, n-pentane, n-hexane, n-heptane, n-octane, n-nonane, n-decane and the like; ketone solvents such as acetone, methyl ethyl ketone, cyclohexanone, benzophenone, acetophenone and the like; ester solvents such as ethyl acetate, butyl acetate, ethyl cellosolve acetate, methyl benzoate, phenyl acetate and the like; polyhydric alcohols such as ethylene glycol, ethylene glycol monobutyl ether, ethylene glycol monoethyl ether, ethylene glycol monomethyl ether, dimethoxyethane, 1,2-propanediol, diethoxymethane, triethylene glycol monoethyl ether, glycerin, 1,2-hexanediol and the like, and derivatives thereof; alcohol solvents such as methanol, ethanol, propanol, isopropanol, cyclohexanol and the like; sulfoxide solvents such as dimethyl sulfoxide and the like; and amide solvents such as N-methyl-2-pyrrolidone, N,N-dimethylformamide and the like, or in several solvents among them.

The proportion of 2,2′-bipyridine and 2,2′-bipyridine derivative contained in the above-described hole transporting layer (total proportion) is preferably 0.01 to 50 wt %, more preferably 0.01 to 40 wt %, from the viewpoint of the driving voltage and the device life.

(Material 2: a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group)

The carbon atom number of the repeating unit composed of an unsubstituted or substituted 2,2′-bipyridinediyl group including the substituent contained in the above-described 2,2′-bipyridinediyl group-containing polymer compound is usually 10 to 100.

The divalent aromatic amine residue and the unsubstituted or substituted arylene group in the material 2 are the same as in the above-described non-2,2′-bipyridinediyl group-containing polymer compound.

As the substituent on the above-described repeating unit composed of a 2,2′-bipyridinediyl group, a halogen atom, a hydroxyl group, an alkyl group, an alkenyl group, an alkynyl group, an alkoxy group, an alkylthio group, an alkylsilyl group, an aryl group, an aryloxy group and an arylsilyl group are mentioned.

The above-described 2,2′-bipyridinediyl group includes groups represented by the following formulae Bpy1 to Bpy16. A part or all of hydrogen atoms contained in these groups may be substituted by a substituent.

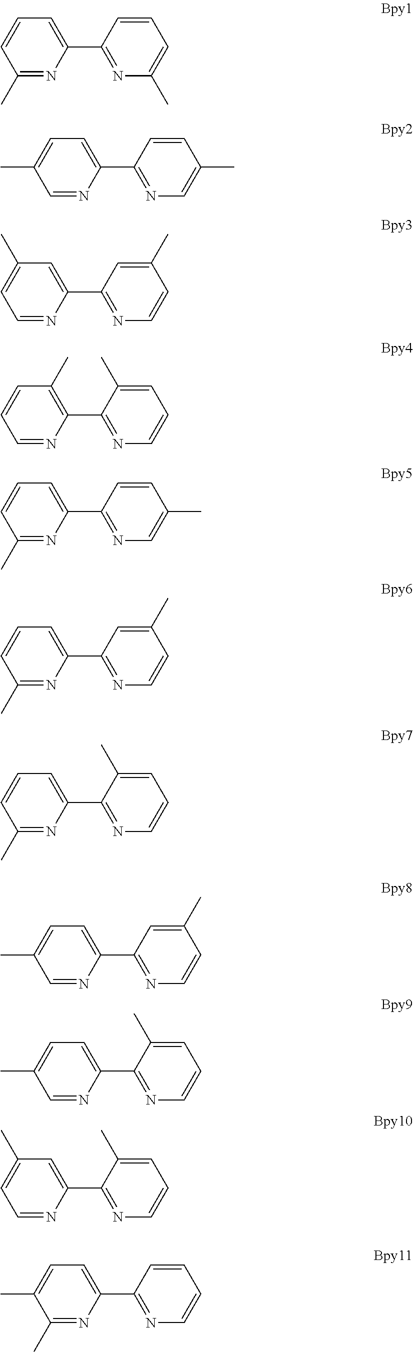

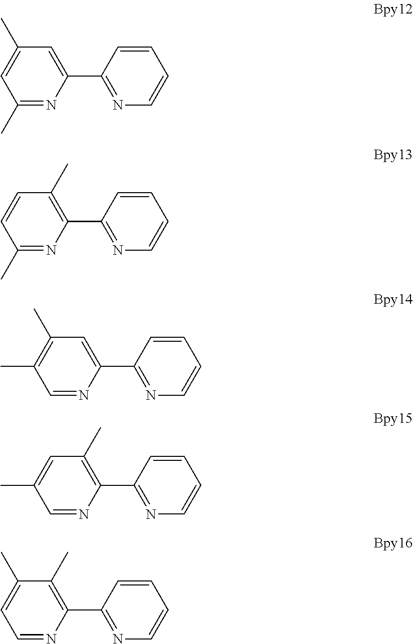

The above-described 2,2′-bipyridinediyl group-containing polymer compound is preferably a polymer compound represented by the following formula α-(1).

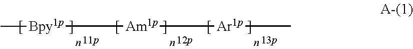

[in the formula α-(1), Bpy^{1p} represents an unsubstituted or substituted 2,2′-bipyridinediyl group. Ar^{1p} represents a divalent aromatic amine residue. Ar^{1p} represents an unsubstituted or substituted arylene group. n^{11p}, n^{12p} and n^{13p} each independently represent numbers indicating the molar ratio of the unsubstituted or substituted 2,2′-bipyridinediyl group represented by Bpy^{1p}, the divalent aromatic amine residue represented by Am^{1p} and the unsubstituted or substituted arylene group represented by Ar^{1p} in the polymer compound, satisfying n^{11p}+n^{12p}+n^{13p}=1, 0.001≦n^{11p}≦0.999, 0.001≦n^{12p}≦0.999 and 0≦n^{13p}≦0.998. When a plurality of Bpy^{1p}s are present, these may be the same or different. When a plurality of Am^{1p}s are present, these may be the same or different. When a plurality of Ar^{1p}s are present, these may be the same or different.].

The unsubstituted or substituted 2,2′-bipyridinediyl group represented by Bpy^{1p} in the formula α-(1) includes preferably groups represented by the above-described formulae Bpy1 to Bpy16, and the 2,2′-bipyridinediyl group is classified into groups represented by the following formula α-(1-2) or groups represented by the following formula α-(1-3) depending on the difference in the position of the connecting group. In the above-described formula α-(1), Bpy^{1p} is preferably a group represented by the following formula α-(1-2) from the viewpoint of more suppression of voltage increase in driving of a device, and is preferably a group represented by the formula α-(1-3) from the viewpoint of the light emission life when used for fabrication of a device.

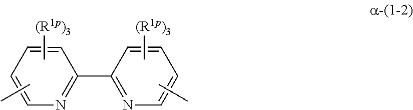

[in the formula α-(1-2), R^{1p} represents a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group. Two or more R^{1p} moieties may be the same or different.]

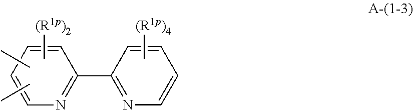

[in the formula α-(1-3), R^{1p} is as described above. Two or more R^{1p} moieties may be the same or different.]

In the above-described formulae α-(1-2) and α-(1-3), R^{1p} represents preferably a hydrogen atom, an unsubstituted or substituted alkyl group, an unsubstituted or substituted alkenyl group, an unsubstituted or substituted alkynyl group, an unsubstituted or substituted aryl group or a hydroxyl group, more preferably a hydrogen atom or an unsubstituted or substituted alkyl group and further preferably a hydrogen atom, from the viewpoint of the light emission property of a device when used for fabrication of the device, represents preferably an unsubstituted or substituted alkyl group, an unsubstituted or substituted alkenyl group, an unsubstituted or substituted alkynyl group, an unsubstituted or substituted alkoxy group, an unsubstituted or substituted aryl group, an unsubstituted or substituted aryloxy group, a halogen atom or a cyano group, from the viewpoint of synthesis of the 2,2′-bipyridinediyl group-containing polymer compound, and represents preferably a hydrogen atom, an unsubstituted or substituted alkyl group, an unsubstituted or substituted alkenyl group or an unsubstituted or substituted alkynyl group, more preferably a hydrogen atom, from the viewpoint of the driving voltage or the light emission life when fabricated into a device.

The group represented by the above-described formula α-(1-2) includes groups represented by the following formulae α-(1-2-1) to α-(1-2-10), and from the viewpoint of synthesis of the 2,2′-bipyridinediyl group-containing polymer compound, preferably includes groups represented by the formulae α-(1-2-1) to α-(1-2-4). R^{1q} in the formulae has the same meaning as the above-described R^{1p}. Two or more R^{1q} moieties may be the same or different.

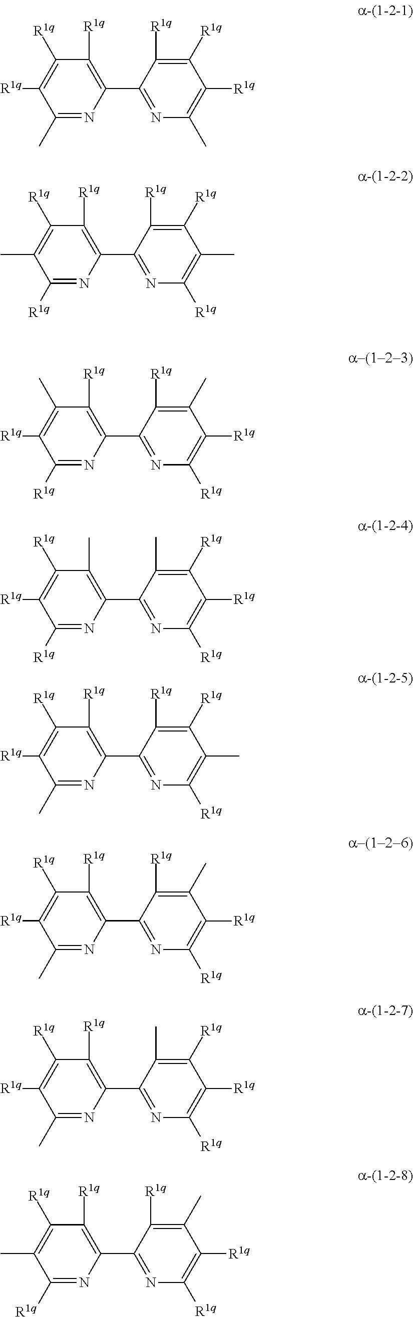

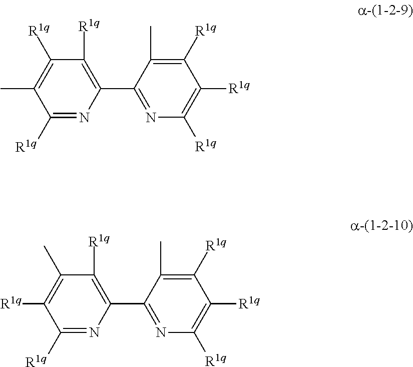

The group represented by the above-described formula α-(1-3) includes groups represented by the following formulae α-(1-3-1) to α-(1-3-6), and from the viewpoint of synthesis of the 2,2′-bipyridinediyl group-containing polymer compound, preferably includes compounds represented by the formula α-(1-3-2), the formula α-(1-3-3) and the formula α-(1-3-5). R^{1q} in the formulae has the same meaning as the above-described R¹. Two or more R^{1q} moieties may be the same or different.

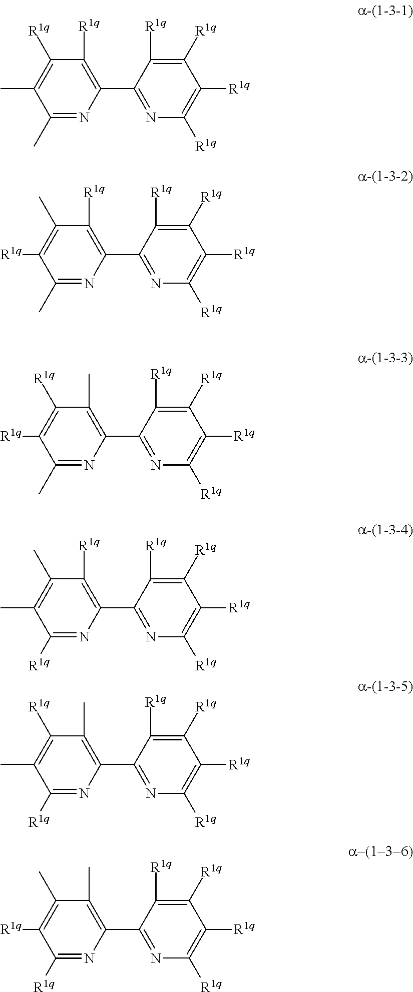

The divalent aromatic amine residue represented by Am^{1p} in the above-described formula α-(1) includes the same groups as for the above-described divalent aromatic amine residue. When a plurality of Am^{1p}s are present, these may be the same or different, and it is preferable from the viewpoint of synthesis of the 2,2′-bipyridinediyl group-containing polymer compound that a plurality of Am^{1p}s are identical and it is preferable from the viewpoint of the light emission property of a device when used for fabrication of the device that a plurality of Am^{1p}s are different (that is, several kinds of Am^{1p}s are present in the formula α-(1)).

The unsubstituted or substituted arylene group represented by Ar^{1p} in the above-described formula α-(1) includes the same groups as for the above-described arylene group. When a plurality of Ar^{1p}s are present, these may be the same or different, and it is preferable from the viewpoint of synthesis of the 2,2′-bipyridinediyl group-containing polymer compound that a plurality of Ar^{1p}s are identical and it is preferable from the viewpoint of the light emission life when fabricated into a device that a plurality of Ar^{1p}s are different (that is, several kinds of Ar^{1p}s are present in the formula α-(1)).

In the above-described formula α-(1), n^{11p} represents preferably a number satisfying 0.001≦n^{11p}≦0.5, more preferably a number satisfying 0.001≦n^{11p}≦0.2 and particularly preferably a number satisfying 0.001≦n^{11p}≦0.1, from the viewpoint of synthesis of the 2,2′-bipyridinediyl group-containing polymer compound, and represents preferably a number satisfying 0.001≦n^{11p}≦0.3, more preferably a number satisfying 0.005≦n^{11p}≦0.2 and particularly preferably a number satisfying 0.01≦n^{11p}≦0.1, from the viewpoint of the light emission property of a device when used for fabrication of the device.

In the above-described formula α-(1), n^{12p} represents preferably a number satisfying 0.001≦n^{12p}≦0.5, more preferably a number satisfying 0.001≦n^{12p}≦0.4 and particularly preferably a number satisfying 0.001≦n^{12p}≦0.3, from the viewpoint of synthesis of the 2,2′-bipyridinediyl group-containing polymer compound, and represents preferably a number satisfying 0.1≦n^{12p}≦0.999, more preferably a number satisfying 0.2≦n^{12p}≦0.999 and particularly preferably a number satisfying 0.4≦n^{12p}≦0.999, from the viewpoint of the light emission property of a device when used for fabrication of the device and from the viewpoint of the hole transportability.

The 2,2′-bipyridinediyl group-containing polymer compound represented by the above-described formula α-(1) has a polystyrene-equivalent number-average molecular weight of preferably 1×10³ to 1×10³, more preferably 1×10³ to 1×10⁷ and has a polystyrene-equivalent weight-average molecular weight of preferably 1×10³ to 1×10⁸, more preferably 1×10³ to 1×10⁷, from the viewpoint of the life property of a device when used for fabrication of the device. The number-average molecular weight and the weight-average molecular weight can be measured, for example, by using size exclusion chromatography.

The 2,2′-bipyridinediyl group-containing polymer compound represented by the above-described formula α-(1) may be any of an alternative copolymer, a random copolymer, a block copolymer and a graft copolymer.

The 2,2′-bipyridinediyl group-containing polymer compound represented by the formula α-(1) includes polymer compounds represented by the following formulae (EX1-1P) to (EX1-3P).

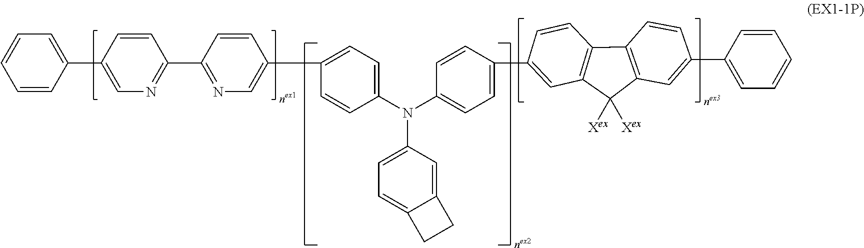

[in the formula (EX1-1P), X^{ex} is as described above. Two or more X^{ex} moieties may be the same or different. n^{ex1}, n^{ex2} and n^{ex3} each independently represent numbers satisfying 0.01≦n^{ex1}≦0.3, 0.01≦n^{ex2}≦0.89, 0.1≦n^{ex3}≦0.98 and n^{ex1}+n^{ex2}+n^{ex3}=1.]

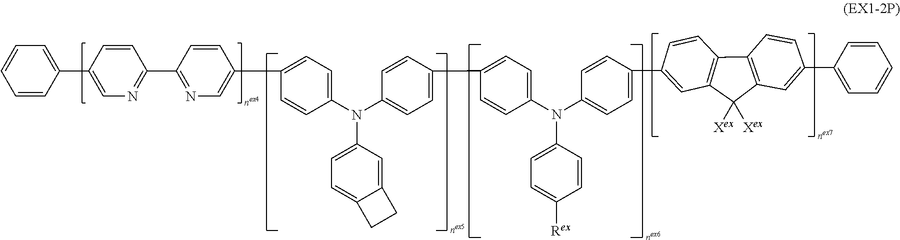

[in the formula (EX1-2P), X^{ex} and R^{ex} are as described above. n^{ex4}, n^{ex5}, n^{ex6} and n^{ex7} each independently represent numbers satisfying 0.01≦n^{ex4}≦0.3, 0.01≦n^{ex5}≦0.4, 0.01≦n^{ex6}≦0.6, 0≦n^{ex7}≦0.97 and n^{ex4}+n^{ex5}+n^{ex6}+n^{ex7}=1.]

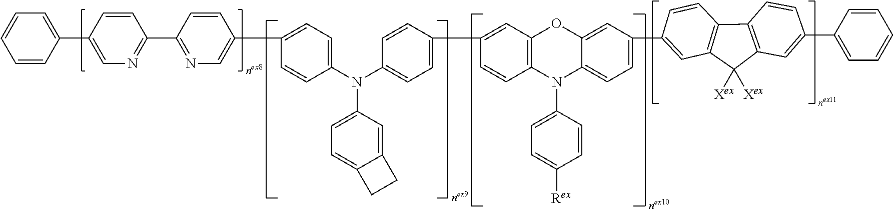

(EX1-3P)
   [in the formula (EX1-3P), X^{ex} and R^{ex} are as described above. n^{ex8}, n^{ex9}, n^{ex10} and n^{ex11} each independently represent numbers satisfying 0.01≦n^{ex8}≦0.3, 0.01≦n^{ex9}≦0.4, 0.01≦n^{ex10}≦0.6, 0≦n^{ex11}≦0.97 and n^{ex8}+n^{ex9}+n^{ex10}+n^{ex11}=1.]

When the above-described 2,2′-bipyridinediyl group-containing polymer compound and the above-described non-2,2′-bipyridinediyl group-containing hole transporting polymer compound are contained in the hole transporting layer, the preferable proportions of them are as described above.

The above-described 2,2′-bipyridinediyl group-containing polymer compound and the above-described non-2,2′-bipyridinediyl group-containing hole transporting polymer compound may be produced by any method, and can be produced by a method in which a compound having several polymerization reactive groups as a monomer is dissolved, if necessary, in an organic solvent, and reacted at a temperature of the melting point or higher and the boiling point or lower of the organic solvent using an alkali and a suitable catalyst. This is described in “Organic Reactions”, vol. 14, pp. 270-490, John Wiley & Sons, Inc., 1965, “Organic Syntheses”, Collective Volume VI, pp. 407-411, John Wiley & Sons, Inc., 1988, Chemical Reviews (Chem. Rev.), vol. 95, p. 2457 (1995), Journal of Organometallic Chemistry (J. Organomet. Chem.), vol. 576, p. 147 (1999), Macromolecular Chemistry Macromolecular Symposium (Macromol. Chem., Macromol. Symp.), vol. 12, p. 229 (1987) and JP-A No. 2009-108313, and the like.

The method for producing the above-described 2,2′-bipyridinediyl group-containing polymer compound is explained for the above-described 2,2′-bipyridinediyl group-containing polymer compound represented by the formula α-(1) as one example: it can be produced by condensation-polymerizing a compound represented by the formula: Y-Bpy^{1p}-Y, a compound represented by the formula: Y-Am^{1p}-Y and a compound represented by the formula: Y-Ar^{1p}-Y. In these formulae, Bpy^{1p}, Am^{1p} and Ar^{1p} are the same as Bpy^{1p}, Am^{1p} and Ar^{1p} in the above-described formula α-(1), and Y represents a polymerization reactive group. Two Y moieties in the formula may be the same or different.

Also the above-described non-2,2′-bipyridinediyl group-containing hole transporting polymer compound can be produced in the same manner as for the above-described 2,2′-bipyridinediyl group-containing polymer compound represented by the formula α-(1). Here, the non-2,2′-bipyridinediyl group-containing hole transporting polymer compound represented by the polymer compound represented by the formula α-(2) is explained as one example: it can produced by condensation-polymerizing a compound represented by the formula: Y-Am^{2p}-Y and a compound represented by the formula: Y-Ar^{2p}-Y. Am^{2p} and Ar^{2p} in these formulae are the same as Am^{2p} and Ar^{2p} in the above-described formula α-(2).

The above-described polymerization reactive group includes a halogen atom, an alkylsulfonyloxy group, an arylsulfonyloxy group, an arylalkylsulfonyloxy group, a borate residue, a sulfoniummethyl group, a phosphoniummethyl group, a phosphonatemethyl group, a methyl monohalide group, a boric acid residue (—B(OH)₂), a formyl group, a cyano group and a vinyl group.

The halogen atom as the above-described polymerization reactive group includes a fluorine atom, a chlorine atom, a bromine atom and an iodine atom.

The alkylsulfonyloxy group as the above-described polymerization reactive group includes a methanesulfonyloxy group, an ethanesulfonyloxy group and a trifluoromethanesulfonyloxy group.

The arylsulfonyloxy group as the above-described polymerization reactive group includes a benzenesulfonyloxy group and a p-toluenesulfonyloxy group.

The arylalkylsulfonyloxy group as the above-described polymerization reactive group includes a benzylsulfonyloxy group.

The borate residue as the above-described polymerization reactive group includes groups represented by the following formulae.

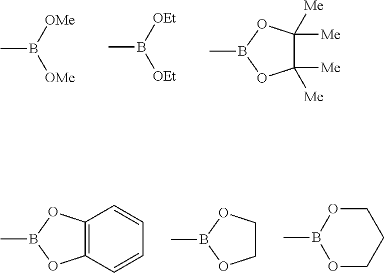

(wherein Me represents a methyl group and Et represents an ethyl group, the same shall apply hereinafter)

The sulfoniummethyl group as the above-described polymerization reactive group includes groups represented by the following formulae.

—CH₂S⁺Me₂X⁻, —CH₂S⁺Ph₂X⁻

(wherein X represents a halogen atom. Ph represents a phenyl group, the same shall apply hereinafter)

The phosphoniummethyl group as the above-described polymerization reactive group includes groups represented by the following formula.

—CH₂P⁺Ph₃X⁻

(wherein X is as described above.)

The phosphonatemethyl group as the above-described polymerization reactive group includes groups represented by the following formula.

—CH₂PO(OR′)₂

(wherein R′ represents an unsubstituted or substituted alkyl group or an unsubstituted or substituted aryl group. Two R′ moieties may be the same or different.)

The methyl monohalide group as the above-described polymerization reactive group includes a fluoromethyl group, a chloromethyl group, a bromomethyl group and an iodomethyl group.

The above-described polymerization reactive group is a halogen atom, an alkylsulfonyloxy group, an arylsulfonyloxy group, an arylalkylsulfonyloxy group or the like in the case of use of a nickel zerovalent complex such as in the Yamamoto coupling reaction and the like, and is an alkylsulfonyloxy group, a halogen atom, a borate residue, a boric acid residue or the like in the case of use of a nickel catalyst or a palladium catalyst such as in the Suzuki coupling reaction and the like.

Since the purity of the above-described 2,2′-bipyridinediyl group-containing polymer compound and the above-described non-2,2′-bipyridinediyl group-containing hole transporting polymer compound exerts an influence on device performances such as the light emission property and the like, it is preferable that a compound having several polymerization reactive groups as a monomer is purified by a method such as distillation, sublimation purification, recrystallization and the like before carrying out polymerization thereof. It is preferable that, after the polymerization, the resultant 2,2′-bipyridinediyl group-containing polymer compound and non-2,2′-bipyridinediyl group-containing hole transporting polymer compound are subjected to a purification treatment such as re-precipitation purification, chromatographic fractionation and the like.

Next, the method for forming a hole transporting layer will be explained.

The method for forming a hole transporting layer includes methods using, for example,

A) a first composition containing the above-described mixture of 2,2′-bipyridine and/or 2,2′-bipyridine derivative and a non-2,2′-bipyridinediyl group-containing hole transporting polymer compound; and an organic solvent,

B) a second composition containing the above-described 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group; and an organic solvent,

or a combination thereof [that is, a combination of A) and B)].

The method for forming a hole transporting layer as the first composition or the second composition containing an organic solvent (hereinafter, these are collectively called “solution”) as described above is advantageous for production since the solution may only be coated before removal of the organic solvent by drying.

As the above-described organic solvent, those capable of dissolving solid components contained in the solution may be permissible. Shown as this organic solvent are chlorine-based solvents such as chloroform, methylene chloride, dichloroethane and the like; ether solvents such as tetrahydrofuran and the like; aromatic hydrocarbon solvents such as toluene, xylene and the like; ketone solvents such as acetone, methyl ethyl ketone and the like; and ester solvents such as ethyl acetate, butyl acetate, ethyl cellosolve acetate and the like, and preferable are chloroform, methylene chloride, dichloroethane, tetrahydrofuran, toluene, xylene, mesitylene, tetralin, decalin and n-butylbenzene. As these solvents, those capable of dissolving solid components contained in the above-described solution, at a concentration of 0.1 wt % or more, are particularly preferable.

The number of the kinds of the solvent in the solution is preferably two or more, more preferably two to three, particularly preferably two, from the viewpoint of the film formability and from the viewpoint of device properties and the like.

When two solvents are contained in the solution, one of them may be in the solid state at 25° C. From the viewpoint of the film formability, one solvent has a boiling point of preferably 180° C. or higher, more preferably 200° C. or higher. From the viewpoint of viscosity, it is preferable that both two solvents are capable of dissolving the non-2,2′-bipyridinediyl group-containing hole transporting polymer compound or the 2,2′-bipyridinediyl group-containing polymer compound at a concentration of 1 wt % or more at 60° C., and it is more preferable that one of two solvents is capable of dissolving the non-2,2′-bipyridinediyl group-containing hole transporting polymer compound or the 2,2′-bipyridinediyl group-containing polymer compound at a concentration of 1 wt % or more at 25° C.

For formation of the above-described hole transporting layer, there can be adopted coating methods such as a spin coat method, a casting method, a micro gravure coat method, a gravure coat method, a bar coat method, a roll coat method, a wire bar coat method, a dip coat method, a slit coat method, a cap coat method, a spray coat method, and printing methods such as a screen printing method, a flexo printing method, an offset printing method, an inkjet print method, a nozzle coat method, and the like.

When the above-described printing method is adopted, if the amount of components other than the organic solvent in the first composition is 100 parts by weight, then, the proportion of the above-described mixture of 2,2′-bipyridine and/or 2,2′-bipyridine derivative and a non-2,2′-bipyridinediyl group-containing hole transporting polymer compound is usually 20 to 100 parts by weight, preferably 40 to 100 parts by weight.

When the above-described printing method is adopted, if the amount of components other than the organic solvent in the second composition is 100 parts by weight, then, the proportion of the above-described 2,2′-bipyridinediyl group-containing polymer compound having a constitutional unit composed of an unsubstituted or substituted 2,2′-bipyridinediyl group and at least one constitutional unit selected from the group consisting of constitutional units composed of a divalent aromatic amine residue and constitutional units composed of an unsubstituted or substituted arylene group is usually 20 to 100 parts by weight, preferably 40 to 100 parts by weight.

The proportion of the organic solvent contained in the solution is usually 1 to 99.9 parts by weight, preferably 60 to 99.5 parts by weight, further preferably 80 to 99.0 parts by weight, when the total weight of the solution is 100 parts by weight.

The viscosity of the above-described solution varies depending on the printing method, and in the case of a solution used in a method in which the solution passes through a discharge apparatus such as in an inkjet print method and the like, the viscosity is preferably 1 to 20 mPa·s at 25° C., for preventing clogging in discharging and preventing curved flying.

The above-described solution may contain a stabilizer, an additive for regulating viscosity and surface tension, and an antioxidant. The additive includes a compound of high molecular weight (thickening agent) and a poor solvent for enhancing viscosity, a compound of low molecular weight for lowering viscosity, a surfactant for lowering surface tension, and the like.

The above-described compound of high molecular weight may advantageously be a compound which is soluble in the above-described solvent and does not disturb light emission and charge transportation, and includes polystyrene, polymethylmethacrylate and the like. The above-described compound of high molecular weight has polystyrene-equivalent weight-average molecular weight of preferably 5×10⁵ or more, more preferably 1×10⁶ or more.

It is also possible to use a poor solvent as the thickening agent. When a poor solvent is used as the thickening agent, the kind and the addition amount of the organic solvent may be adjusted in a range not causing deposition of solid components in the solution. When also the stability of the solution in storage is taken into consideration, the amount of a poor solvent is preferably 50 parts by weight or less, further preferably 30 parts by weight or less, when the total weight of the solution is 100 parts by weight.

The above-described antioxidant may advantageously be a compound which is soluble in the above-described organic solvent and does not disturb light emission and charge transportation, and shown are phenol antioxidants and phosphorus-based antioxidants.

The above-described solution may contain water, silicon, phosphorus, fluorine, chlorine, bromine, metal or its salt in a range of 1 to 1000 ppm (by weight), however, it is preferable that its content is smaller, from the viewpoint of the light emission life when fabricated into a device.

The above-described metal includes lithium, sodium, calcium, potassium, iron, copper, nickel, aluminum, zinc, chromium, manganese, cobalt, platinum, iridium and the like.

The thickness of the hole transporting layer may advantageously be adjusted so as to give a suitable value of the driving voltage and a suitable value of the light emission efficiency, and a thickness causing no generation of pin holes is necessary. When the hole transporting layer is too thick, there is a tendency of increase in the driving voltage. Therefore, the thickness of the hole transporting layer is preferably 1 to 500 nm, more preferably 2 to 200 nm, further preferably 2 to 100 nm, particularly preferably 5 to 50 nm.

The hole transporting layer constituting the organic electroluminescent device of the present invention may contain other hole transporting materials, in addition to the above-described material 1 and the above-described material 2. Other hole transporting materials are classified into hole transporting materials of low molecular weight and hole transporting materials of high molecular weight.

As the above-described hole transporting material of high molecular weight, shown are polyvinylcarbazole and derivatives thereof, polysilane and derivatives thereof, polysiloxane derivatives having an aromatic amine in the side chain or the main chain, pyrazoline derivatives, arylamine derivatives, stilbene derivatives, triphenyldiamine derivatives, polyaniline and derivatives thereof, polythiophene and derivatives thereof, polypyrrole and derivatives thereof, poly(p-phenylenevinylene) and derivatives thereof and poly(2,5-thienylenevinylene) and derivatives thereof. As the hole transporting material of high molecular weight, also shown are materials described in JP-A No. 63-70257, JP-A No. 63-175860, JP-A No. 2-135359, JP-A No. 2-135361, JP-A No. 2-209988, JP-A No. 3-37992 and JP-A No. 3-152184. Of them, the hole transporting material of high molecular weight includes preferably polyvinylcarbazole and derivatives thereof, polysilane and derivatives thereof, polysiloxane derivatives having an aromatic amine compound group in the side chain or the main chain, polyaniline and derivatives thereof, polythiophene and derivatives thereof, poly(p-phenylenevinylene) and derivatives thereof and poly(2,5-thienylenevinylene) and derivatives thereof, more preferably polyvinylcarbazole and derivatives thereof, polysilane and derivatives thereof and polysiloxane derivatives having an aromatic amine in the side chain or the main chain.

As the above-described hole transporting material of low molecular weight, shown are pyrazoline derivatives, arylamine derivatives, stilbene derivatives and triphenyldiamine derivatives. When the above-described hole transporting layer contains the hole transporting material of low molecular weight, a polymer binder may be allowed to coexist.

This polymer binder is preferably a compound which does not extremely disturb hole transportation and shows no strong absorption for a visible light. Shown as this polymer binder are poly(N-vinylcarbazole), polyaniline and derivatives thereof, polythiophene and derivatives thereof, poly(p-phenylenevinylene) and derivatives thereof, poly(2,5-thienylenevinylene) and derivatives thereof, polycarbonate, polyacrylate, polymethyl acrylate, polymethyl methacrylate, polystyrene, polyvinyl chloride and polysiloxane.

As the above-described polyvinylcarbazole and derivatives thereof, compounds obtained by cation polymerization or radical polymerization from vinyl monomers are preferable.

As the above-described polysilane and derivatives thereof, compounds described in Chemical Reviews vol. 89, p. 1359 (1989) and GB 2300196 published specification are shown. Also as the method for synthesizing the polysilane and derivatives thereof, methods described in these documents can be used, and the Kipping method is suitably used.

Since the siloxane skeleton structure shows scarce hole transportability in the above-described polysiloxane and derivatives thereof, preferable are compounds having in its side chain or main chain the structure of the above-described hole transporting material of low molecular weight. As the polysiloxane and derivatives thereof, compounds having a hole transporting aromatic amine in the side chain or in the main chain are preferable.

### <Light Emitting Layer>

As the material for forming a light emitting layer (hereinafter, referred to as “light emitting material”), known compounds can be used. The light emitting material includes fluorescent materials and triplet light emitting materials (phosphorescent materials), and both of them are classified into light emitting materials of low molecular weight and light emitting materials of high molecular weight, and in the case of the fluorescent material, light emitting materials of high molecular weight are preferable, and in the case of the triplet light emitting material, both light emitting materials of low molecular weight and light emitting materials of high molecular weight are permissible.

When triplet light emitting material is a light emitting material of low molecular weight, the proportion of the triplet light emitting material contained in a light emitting layer is preferably 1 to 50 wt %, more preferably 2 to 45 wt %, further preferably 5 to 40 wt %, since the device life is good in this range.

When the triplet light emitting material is a light emitting material of high molecular weight, the proportion of the central metal atom of the triplet light emitting material contained in a light emitting layer is preferably 0.02 to 10 wt %, more preferably 0.05 to 9 wt %, further preferably 0.1 to 8 wt %, since the device life is good in this range.

The light emitting material is preferably a triplet light emitting material because of excellent light emission efficiency when fabricated into a device.

The above-described light emitting material of low molecular weight includes naphthalene derivatives, anthracene and derivatives thereof, perylene and derivatives thereof, dyes such as polymethine dyes, xanthene dyes, coumarin dyes, cyanine dyes and the like, metal complexes of 8-hydroxyquinoline and derivatives thereof, aromatic amines, tetraphenylcyclopentadiene and derivatives thereof and tetraphenylbutadiene and derivatives thereof, and additionally, compounds described in JP-A No. 57-51781 and JP-A No. 59-194393, triplet light emitting complexes and the like.

The triplet light emitting complex includes Ir(ppy)₃ (described, for example, in Appl. Phys. Lett., (1999), 75(1), 4 and Jpn. J. Appl. Phys., 34, 1883 (1995)), Btp₂Ir(acac) (described, for example, in Appl. Phys. Lett., (2001), 78(11), 1622), FIrpic (described, for example, in Inorg. Chem., 2007, 46, 11082), light emitting material A, light emitting material B, light emitting material C, light emitting material D, light emitting material E, and ADS066GE commercially marketed from American Dye Source, Inc., having iridium as a central metal; PtOEP (described, for example, in Nature, (1998), 395, 151) having platinum as a central metal; Eu(TTA)₃-phen having europium as a central metal, and the like, and additionally, complexes described in Proc. SPIE-Int. Soc. Opt. Eng. (2001), 4105 (Organic Light-Emitting Materials and Devices IV), 119, J. Am. Chem. Soc., (2001), 123, 4304, Appl. Phys. Lett., (1997), 71(18), 2596, Syn. Met., (1998), 97(2), 113, Syn. Met., (1999), 99(2), 127, Adv. Mater., (1999), 11(10), 852 and the like, and derivatives thereof.

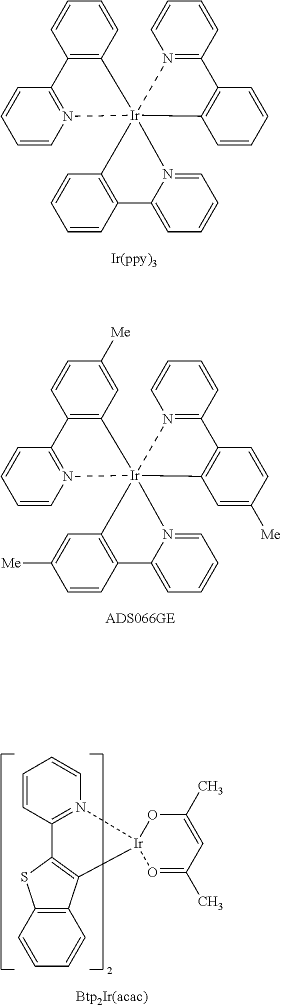

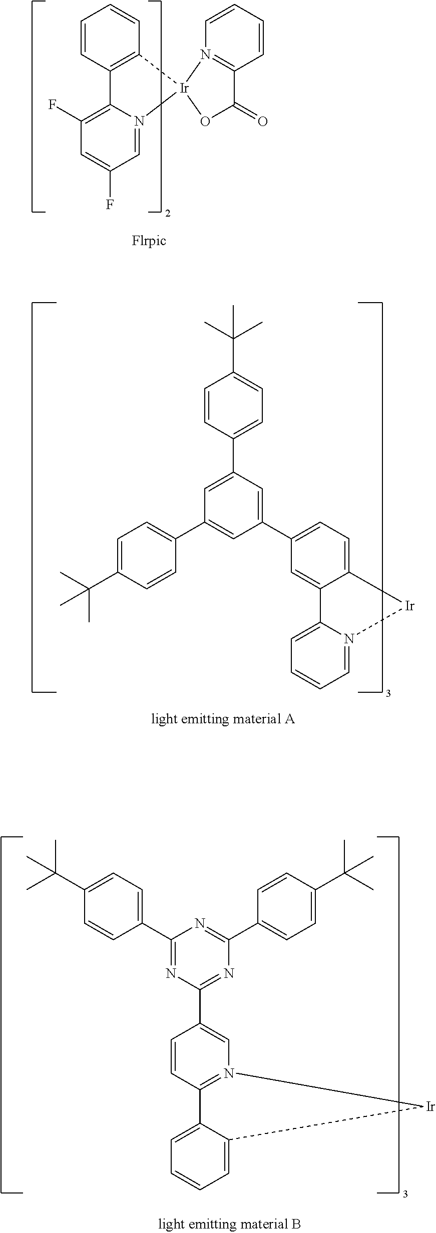

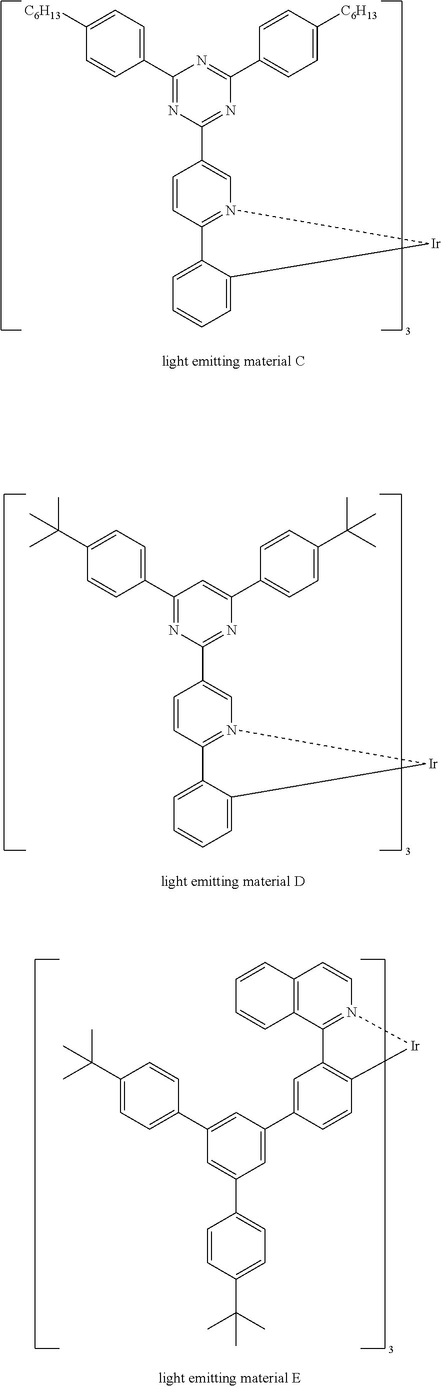

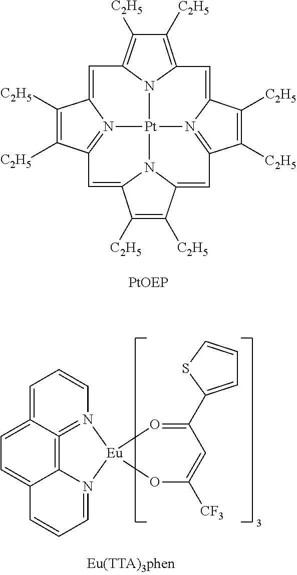

The above-described light emitting material of high molecular weight includes polyfluorenes, derivatives thereof and fluorene copolymers, polyarylenes, derivatives thereof and arylene copolymers, polyarylenevinylenes, derivatives thereof and arylenevinylene copolymers, and (co)polymers of aromatic amines and derivatives thereof disclosed in official gazettes such as WO 99/13692, WO 99/48160, GB 2340304A, WO 00/53656, WO 01/19834, WO 00/55927, GB 2348316, WO 00/46321, WO 00/06665, WO 99/54943, WO 99/54385, U.S. Pat. No. 5,777,070, WO 98/06773, WO 97/05184, WO 00/35987, WO 00/53655, WO 01/34722, WO 99/24526, WO 00/22027, WO 00/22026, WO 98/27136, U.S. Pat. No. 573,636, WO 98/21262, U.S. Pat. No. 5,741,921, WO 97/09394, WO 96/29356, WO 96/10617, EP 0707020, WO 95/07955, JP-A No. 2001-181618, JP-A No. 2001-123156, JP-A No. 2001-3045, JP-A No. 2000-351967, JP-A No. 2000-303066, JP-A No. 2000-299189, JP-A No. 2000-252065, JP-A No. 2000-136379, JP-A No. 2000-104057, JP-A No. 2000-80167, JP-A No. 10-324870, JP-A No. 10-114891, JP-A No. 9-111233, JP-A No. 9-45478 and the like.

The light emitting layer may further contain the above-described other hole transporting materials, and electron transporting materials described later.

The thickness of a light emitting layer may advantageously be adjusted so as to give a suitable value of the driving voltage and a suitable value of the light emission efficiency, and it is usually 1 nm to 1 μm, preferably 2 to 500 nm, further preferably 5 to 200 nm.

As the method for forming a light emitting layer, shown is a method for preparing a solution containing light emitting materials and the like and forming a film using the solution. As this film formation method, coating methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet print method and the like can be used, and because of easiness of pattern formation and multi-color separate painting, preferable are printing methods such as a screen printing method, a flexo printing method, an offset printing method, an inkjet print method and the like.

### <Anode, Cathode>

It is preferable that at least one of the above-described anode and the above-described cathode is transparent or semitransparent, and it is more preferable that the anode side is transparent or semitransparent.

The material of the above-described anode includes electric conductive metal oxide films, semitransparent metal films and the like, and preferable are films fabricated using an electric conductive inorganic compound composed of indium oxide, zinc oxide, tin oxide, and composites thereof: indium•tin•oxide (ITO), indium•zinc•oxide and the like, and NESA, gold, platinum, silver, copper, polyaniline and derivatives thereof, and polythiophene and derivatives thereof, more preferable are ITO, indium•zinc•oxide, and tin oxide.

The method for forming the anode includes a vacuum vapor-deposition method, a sputtering method, an ion plating method, a plating method and the like.

The thickness of the anode may advantageously be regulated in view of the light permeability and the electric conductivity, and it is preferably 10 nm to 10 μm, more preferably 20 nm to 1 μm, further preferably 50 to 500 nm, particularly preferably 50 to 200 nm.

On the anode, a layer composed of a phthalocyanine derivative, an electric conductive polymer, carbon or the like or a layer composed of a metal oxide, a metal fluoride, an organic insulation material or the like may be disposed, for rendering charge injection easy.

As the material of the above-described cathode, preferable are materials of small work function, more preferable are metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, and alloys composed of two or more of them, or alloys composed of at least one of them and at least one of gold, silver, platinum, copper, manganese, titanium, cobalt, nickel, tungsten and tin; and graphite or graphite interclation compounds.

The above-described alloy includes a magnesium-silver alloy, a magnesium-indium alloy, a magnesium-aluminum alloy, an indium-silver alloy, a lithium-aluminum alloy, a lithium-magnesium alloy, a lithium-indium alloy, a calcium-aluminum alloy and the like.

The cathode may take a lamination structure composed of two or more layers.

The thickness of the cathode may advantageously be regulated in view of the electric conductivity and the durability, and it is preferably 10 nm to 10 μm, more preferably 20 nm to 1 μm, further preferably 50 to 500 nm, particularly preferably 50 to 200 nm.

The method for forming the cathode includes a vacuum vapor-deposition method, a sputtering method, a laminate method for thermally compression-bonding a metal film, and the like.

### <Other Layers>

Between the cathode and the light emitting layer, a layer composed of an electric conductive polymer, or a layer composed of a metal oxide, a metal fluoride, an organic insulation material and the like, and an electron transporting layer may be provided.

As the electron transporting material used in the above-described electron transporting layer, known compounds can be used, and preferable are oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof and polyfluorene and derivatives thereof, and additionally, compounds described in JP-A No. 63-70257, JP-A No. 63-175860, JP-A No. 2-135359, JP-A No. 2-135361, JP-A No. 2-209988, JP-A No. 3-37992 and JP-A No. 3-152184, more preferable are oxadiazole derivatives, benzoquinone and derivatives thereof, anthraquinone and derivatives thereof, metal complexes of 8-hydroxyquinoline and derivatives thereof, polyquinoline and derivatives thereof, polyquinoxaline and derivatives thereof and polyfluorene and derivatives thereof, and particularly preferable are 2-(4-biphenylyl)-5-(4-t-butylphenyl)-1,3,4-oxadiazole, benzoquinone, anthraquinone, tris(8-quinolinol)aluminum and polyquinoline.

The method for forming the electron transporting layer includes a vacuum vapor-deposition method from a powder and a method of film formation from a solution or melted condition in the case of use of an electron transporting material of low molecular weight, and includes a method of film formation from a solution or melted condition in the case of use of an electron transporting material of high molecular weight. In film formation from a solution or melted condition, a polymer binder may be used together.

When formation of the electron transporting layer is carried out from a solution, organic solvents capable of dissolving the electron transporting material and/or the polymer binder, for example, chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethyl cellosolve acetate and the like can be used.

Examples of the method for forming the electron transporting layer include coating methods such as a spin coat method, a casting method, a micro gravure coat method, a gravure coat method, a bar coat method, a roll coat method, a wire bar coat method, a dip coat method, a slit coat method, a cap coat method, a spray coat method, a screen printing method, a flexo printing method, an offset printing method, an inkjet print method, a nozzle coat method and the like.

As the above-described polymer binder which can be used in forming the electron transporting layer, compounds which do not extremely disturb charge transportation and show no strong absorption for a visible light are preferable, and poly(N-vinylcarbazole), polyaniline and derivatives thereof, polythiophene and derivatives thereof, poly(p-phenylenevinylene) and derivatives thereof, poly(2,5-thienylenevinylene) and derivatives thereof, polycarbonate, polyacrylate, polymethyl acrylate, polymethyl methacrylate, polystyrene, polyvinyl chloride and polysiloxane are more preferable.

The thickness of the electron transporting layer may advantageously be regulated so as to give a suitable value of the driving voltage and a suitable value of the light emission efficiency, and a thickness causing no generation of pin holes is necessary. When the electron transporting layer is too thick, there is a tendency of increase in the driving voltage. Therefore, the thickness of the electron transporting layer is preferably 1 nm to 1 μm, more preferably 2 to 500 nm, further preferably 5 to 200 nm.

In the case of lamination of several organic layers in the organic electroluminescent device of the present invention, when, for example, a light emitting layer is formed adjacent to a hole transporting layer and particularly when both the layer are formed by a coating method, the materials of the two layers may be mixed to cause an undesirable influence on the device property in some cases. In the case of formation of a hole transporting layer by a coating method before forming a light emitting layer by a coating method, the method for suppressing mixing of the materials of the two layers includes methods in which a hole transporting layer is formed by a coating method, then, the hole transporting layer is heated to be insolubilized in an organic solvent to be used for fabrication of a light emitting layer, then, a light emitting layer is formed. The heating temperature is usually 150 to 300° C. and the heating time is usually one minute to one hour. In this case, for removal of components not insolubilized by heating, the hole transporting layer may advantageously be rinsed with an organic solvent to be used for formation of a light emitting layer, after heating and before formation of a light emitting layer. If the above-described insolubilization is carried out sufficiently, rinsing with a solvent can be omitted. For the above-described insolubilization to be carried out sufficiently, compounds containing at least one polymerization reactive group in its molecule, among them, compounds in which the number of the polymerization reactive group is 5% or more with respect to the number of repeating units in the molecule may advantageously be used, as the non-2,2′-bipyridinediyl group-containing hole transporting polymer compound or the 2,2′-bipyridinediyl group-containing polymer compound used in the hole transporting layer.

When the organic electroluminescent device of the present invention has a charge injection layer and when the charge injection layer is a layer containing the above-described electric conductive polymer, the electric conductivity of the electric conductive polymer is preferably 10⁻⁵ to 10³ S/cm, and for decreasing the leak current between emission picture elements, it is more preferably 10⁻⁵ to 10² S/cm, further preferably 10⁻⁵ to 10¹ S/cm. For the electric conductivity of the electric conductive polymer to be 10⁻⁵ to 10³ S/cm, the above-described electric conductive polymer is usually doped with a suitable amount of ions.

The above-described ion to be doped is an anion in the case of a hole injection layer, and a cation in the case of an electron injection layer.

The above-described anion includes a polystyrenesulfonate ion, an alkylbenzenesulfonate ion, a camphor sulfonate ion and the like.

The above-described cation includes a lithium ion, a sodium ion, a potassium ion, a tetrabutylammonium ion and the like.

The thickness of the charge injection layer is preferably 1 to 100 nm, more preferably 2 to 50 nm.

The material used in the charge injection layer may advantageously be selected according to the relation with the material of an electrode and an adjacent layer, and examples thereof include polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, electric conductive polymers such as a polymer containing an aromatic amine structure in its main chain or side chain and the like, metal phthalocyanines (copper phthalocyanine and the like), carbon and the like. For production of the charge injection layer, known production methods can be adopted.

The organic electroluminescent device of the present invention is usually formed on a substrate. This substrate may advantageously be a substrate which is not deformed in forming an electrode and forming an organic layer, and examples thereof include a glass substrate, a plastic substrate, a polymer film substrate and a silicon substrate. In the case of an opaque substrate, it is preferable that the opposite side electrode is transparent or semitransparent.

As the organic electroluminescent device of the present invention, preferable are organic electroluminescent devices produced by a production process including a step of forming a hole transporting layer by a coating method using a first composition, a second composition or a combination thereof, more preferable are organic electroluminescent devices produced by a production process including a step of forming the hole transporting layer by a coating method, then, heating the hole transporting layer, thereby insolubilizing the hole transporting layer in an organic solvent to be used for fabrication of a light emitting layer, further preferable are organic electroluminescent devices produced by a production process including a step of forming a light emitting layer using a solution containing the above-described light emitting material, so as to be adjacent to the hole transporting layer insolubilized in an organic solvent to be used for fabrication of the light emitting layer.

The organic electroluminescent device of the present invention can be used as a planar light source, a segment display, a dot matrix display, and back light of a liquid crystal display. For obtaining light emission in the form of plane using the organic electroluminescent device of the present invention, a planar anode and a planar cathode may advantageously be placed so as to overlap. For obtaining light emission in the form of pattern, there are a method in which a mask having a window in the form of pattern is placed on the surface of the above-described planar organic electroluminescent device, a method in which an organic layer in non-light emitting parts is formed with extremely large thickness to give substantially no light emission, a method in which either an anode or a cathode, or both electrodes are formed in the form of pattern. By forming a pattern by any of these methods and placing several electrodes so that ON/OFF thereof is independently possible, a display of segment type is obtained which can display digits, letters, simple marks and the like. Further, for providing a dot matrix device, it may be advantageous that both an anode and a cathode are formed in the form of stripe, and placed so as to cross. By adopting a method in which several polymer fluorescent substances showing different emission colors are painted separately or a method in which a color filter or a fluorescence conversion filter is used, partial color display and multi-color display are made possible. In the case of a dot matrix device, passive driving is possible, and active driving may also be carried out in combination with TFT and the like. These display devices can be used as a display of a computer, a television, a portable terminal, a cellular telephone, a car navigation, a view finder of a video camera, and the like. Further, the above-described planar organic electroluminescent device is of self emitting and thin type, and can be suitably used as a planar light source for back light of a liquid crystal display, or as a planar light source for illumination. If a flexible substrate is used, it can also be used as a curved light source or display.

### EXAMPLES

Examples will be shown below for illustrating the present invention further in detail, but the present invention is not limited to these examples.

First, examples of the first group of inventions will be illustrated.

For the number-average molecular weight and the weight-average molecular weight, the polystyrene-equivalent number-average molecular weight and weight-average molecular weight were measured by size exclusion chromatography (SEC). SEC using an organic solvent as the mobile phase is called gel permeation chromatography (GPC). A measurement sample was dissolved in tetrahydrofuran at a concentration of about 0.05 wt %, and 30 μL of the solution was injected into GPC (manufactured by Shimadzu Corp., trade name: LC-10Avp). Tetrahydrofuran was used as the mobile phase of GPC, and flowed at a flow rate of 0.6 mL/min. As the column, two columns of TSKgel SuperHM-H (manufactured by Tosoh Corp.) and one column of TSKgel SuperH2000 (manufactured by Tosoh Corp.) were serially connected. As the detector, a differential refractive index detector (manufactured by Shimadzu Corp., trade name: RID-10A) was used.

Measurement of LC-MS was carried out according to the following method. A measurement sample was dissolved in chloroform or tetrahydrofuran at a concentration of about 2 mg/mL, and 1 μL of the solution was injected into LC-MS (manufactured by Agilent Technologies, trade name: 1100LCMSD). Ion exchanged water, acetonitrile, tetrahydrofuran and a mixed solution thereof were used as the mobile phase of LC-MS, and acetic acid was added if necessary. As the column, L-column 2 ODS (3 μm) (manufactured by Chemicals Evaluation and Research Institute, Japan, internal diameter: 2.1 mm, length: 100 mm, particle size: 3 μm) was used.

Measurement of TLC-MS was carried out according to the following method. A measurement sample was dissolved in chloroform, toluene or tetrahydrofuran, and the resultant solution was coated in small amount on the surface of a previously cut TLC glass plate (manufactured by Merck, trade name: Silica gel 60 F₂₅₄). This was measured by TLC-MS (manufactured by JEOL Ltd., trade name: JMS-T100TD) using a helium gas heated at 240 to 350° C.

A measurement sample (5 to 20 mg) was dissolved in about 0.5 mL of deuterated chloroform and subjected to measurement of NMR using an NMR instrument (manufactured by Varian, Inc., trade name: MERCURY 300).

In examples, the lowest excitation triplet energy of a compound was determined by a scientific calculation method.

In examples, the ionization potential of a compound was measured according to the following method. First, a compound was dissolved in toluene, and the resultant solution was coated on the surface of a quartz substrate by a spin coat method, to form a film. Using this film on a quartz substrate, the ionization potential of the compound was measured by Photoelectron Spectrometer in Air “AC-2” (trade name) manufactured by RIKEN KEIKI Co., Ltd.

### Synthesis Example 1

### Synthesis of Compound M-1

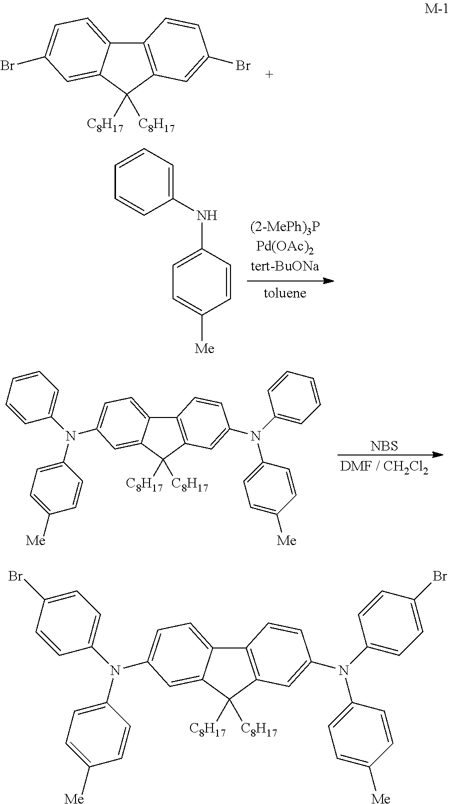

Into a nitrogen-purged reactor were charged 0.90 g of palladium(II) acetate, 2.435 g of tris(2-methylphenyl)phosphine and 125 mL of toluene, and the mixture was stirred at room temperature for 15 minutes. To this were added 27.4 g of 2,7-dibromo-9,9-dioctylfluorene, 22.91 g of (4-methylphenyl)phenylamine and 19.75 g of sodium-tert-butoxide, and the mixture was refluxed with heating overnight, then, cooled down to room temperature, 300 mL of water was added and washing thereof was performed. The organic layer was taken out and the solvent was distilled off under reduced pressure. The residue was dissolved in 100 mL of toluene, the resultant solution was passed through an alumina column. The eluate was concentrated under reduced pressure, to this was added methanol, to cause generation of a precipitate. The precipitate was filtrated, and recrystallized from p-xylene. This crystal was dissolved again in 100 mL of toluene, and the resultant solution was passed through an alumina column. The solution was concentrated to 50 to 100 mL, then, poured into 250 mL of methanol under stirring, to find generation of a precipitate. The precipitate was collected, and dried at room temperature under reduced pressure for 18 hours, to obtain white 2,7-bis[N-(4-methylphenyl)-N-phenyl]amino-9,9-dioctylfluorene (25.0 g).

Into a nitrogen-purged reactor were added 12.5 g of 2,7-bis[N-(4-methylphenyl)-N-phenyl]amino-9,9-dioctylfluorene and 95 mL of dichloromethane, and the reaction solution was cooled down to −10° C. while stirring. A solution of 5.91 g of N-bromosuccinimide (NBS) dissolved in 20 mL of dimethylformamide (DMF) was slowly dropped into this. The mixture was stirred for 3.5 hours, then, mixed with 450 mL of cold methanol, the generated precipitate was filtrated, and recrystallized from p-xylene. The resultant crystal was recrystallized again using toluene and methanol, to obtain 12.1 g of a compound M-1 as a white solid.

¹H-NMR (300 MHz, CDCl₃): δ 0.61-0.71 (m, 4H), 0.86 (t, J=6.8 Hz, 6H), 0.98-1.32 (m, 20H), 1.72-1.77 (m, 4H), 2.32 (br, 6H), 6.98-7.08 (m, 16H), 7.29 (d, J=8.3 Hz, 4H), 7.44 (br, 2H)

### Synthesis Example 2

### Synthesis of Compound M-2

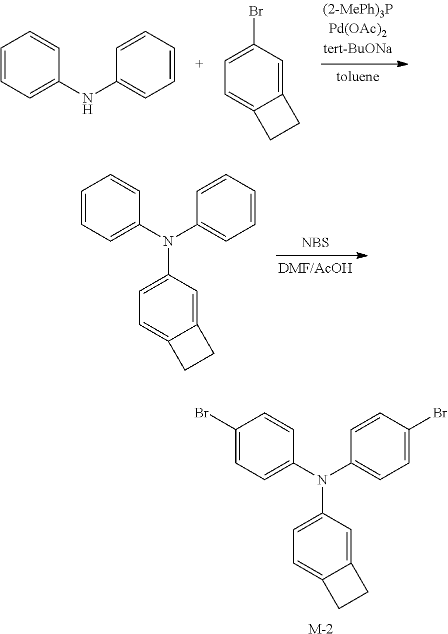

Into a nitrogen-purged 500 mL three-necked round bottom flask were charged 196 mg of palladium(II) acetate, 731 mg of tris(2-methylphenyl)phosphine and 100 mL of toluene, and the mixture was stirred at room temperature. To the reaction solution were added 20.0 g of diphenylamine, 23.8 g of 3-bromobicyclo[4.2.0]octa-1,3,5-triene and 400 mL of toluene, subsequently, 22.8 g of sodium-tert-butoxide, and the mixture was refluxed with heating for 22 hours. To this was added 30 mL of 1M hydrochloric acid, to stop the reaction. The resultant reaction mixture was washed with 100 mL of a 2M sodium carbonate aqueous solution, the organic layer was passed through alumina, the eluate was collected, and the solvent was distilled off from this under reduced pressure. To the resultant oily yellow residue was added isopropyl alcohol, then, the mixture was stirred, and the generated precipitate was filtrated. This precipitate was recrystallized from isopropyl alcohol, to obtain 3-N,N-diphenylaminobicyclo[4.2.0]octa-1,3,5-triene.

Into a 250 mL round bottom flask were charged 3-N,N-diphenylaminobicyclo[4.2.0]octa-1,3,5-triene (8.00 g) and 100 mL of dimethylformamide containing five drops of glacial acetic acid, and the mixture was stirred. To this was added N-bromosuccinimide (10.5 g), and the mixture was stirred for 5 hours. The resultant reaction mixture was poured into 600 mL of methanol/water (volume ratio 1/1), to stop the reaction, generating a precipitate. This precipitate was filtrated, and recrystallized from isopropyl alcohol, to obtain a compound M-2.

¹H NMR (300 MHz, CDCl₃): δ 3.11-3.15 (m, 4H), 6.80 (br, 1H), 6.87-6.92 (m, 5H), 6.96 (d, 1H), 7.27-7.33 (m, 4H)

### Synthesis Example 3

### Synthesis of Compound M-3

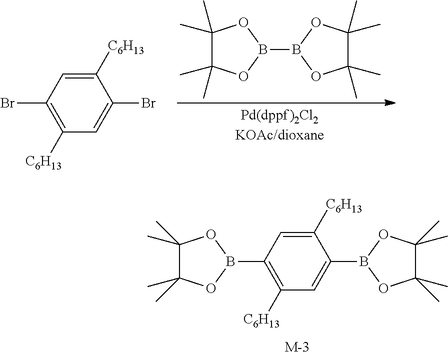

Into a 300 ml four-necked flask were charged 8.08 g of 1,4-dihexyl-2,5-dibromobenzene, 12.19 g of bis(pinacolate)diboron and 11.78 g of potassium acetate, and an atmosphere in the flask was purged with argon. Into this was charged 100 ml of dehydrated 1,4-dioxane, and the mixture was deaerated with argon. Into this was charged 0.98 g of [1,1′-bis(diphenylphosphino)ferrocene]dichloropalladium(II) (Pd(dppf)₂Cl₂), and the mixture was further deaerated with argon. The resultant mixed liquid was refluxed with heating for 6 hours. To the reaction solution was added toluene, and the mixture was washed with ion exchanged water. To the washed organic layer were added anhydrous sodium sulfate and activated carbon, and the mixture was filtrated through a funnel pre-coated with celite. The resultant filtrate was concentrated, to obtain 11.94 g of a dark brown crystal. This crystal was recrystallized from n-hexane, and the crystal was washed with methanol. The resultant crystal was dried under reduced pressure, to obtain 4.23 g of a white needle crystal of a compound M-3. The yield was 42%.

¹H-NMR (300 MHz, CDCl₃): δ 0.88 (t, 6H), 1.23-1.40 (m, 36H), 1.47-1.56 (m, 4H), 2.81 (t, 4H), 7.52 (s, 2H)

LC-MS (ESI, positive) m/z⁺=573 [M+K]⁺

### Synthesis Example 4

### Synthesis of Compound M-4

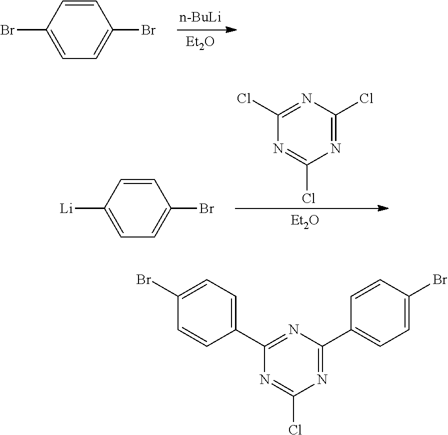

Under a nitrogen atmosphere, a solution of 27.1 g of 1,4-dibromobenzene in 217 ml of dehydrated diethyl ether was cooled by using a dry ice/methanol mixed bath. Into the resultant suspension, 37.2 ml of a 2.77 M solution of n-butyllithium in hexane was dropped slowly, then, the mixture was stirred for 1 hour, to prepare a lithium reagent.

Under a nitrogen atmosphere, a suspension of 10.0 g of cyanuric chloride in 68 ml of dehydrated diethyl ether was cooled by using a dry ice/methanol mixed bath, the above-described lithium reagent was added slowly, then, the mixture was warmed up to room temperature and reacted at room temperature. The resultant product was filtrated, and dried under reduced pressure. The resultant solid (16.5 g) was purified, to obtain 13.2 g of a needle crystal of 2,4-bis(4-bromophenyl)-6-chloro-1,3,5-triazine.

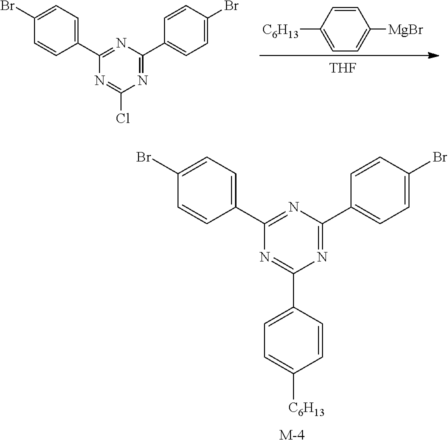

Under a nitrogen atmosphere, to a suspension obtained by adding 65 ml of dehydrated tetrahydrofuran to 1.37 g of magnesium was added portion-wise a solution of 14.2 g of 4-hexylbromobenzene in 15 ml of dehydrated tetrahydrofuran, and the mixture was heated, and stirred under reflux. To the resultant reaction liquid, after standing to cool, was added 0.39 g of magnesium additionally, and the mixture was heated again, and reacted under reflux, to prepare a Grignard reagent.

Under a nitrogen atmosphere, to a suspension of 12.0 g of the above-described needle crystal of 2,4-bis(4-bromophenyl)-6-chloro-1,3,5-triazine in 100 ml of dehydrated tetrahydrofuran was added the above-described Grignard reagent while stirring, and the mixture was refluxed with heating. The resultant reaction liquid was, after standing to cool, washed with a dilute hydrochloric acid aqueous solution. It was separated into an organic layer and an aqueous layer, and the aqueous layer was extracted with diethyl ether. The resultant organic layers were combined, washed with water again, the organic layer was dehydrated over anhydrous magnesium sulfate, and filtrated and concentrated. The resultant white solid was purified by a silica gel column, and further recrystallized, to obtain 6.5 g of a compound M-4 as a white solid.

¹H-NMR (300 MHz, CDCl₃): δ 0.90 (t, J=6.2 Hz, 3H), 1.25-1.42 (m, 6H), 1.63-1.73 (m, 2H), 2.71 (t, J=7.6 Hz, 2H), 7.34 (d, J=7.9 Hz, 2H), 7.65 (d, J=7.9 Hz, 4H), 8.53-8.58 (m, 6H)

### Synthesis Example 5

### Synthesis of Phosphorescent Compound A

A phosphorescent compound A was synthesized according to a synthesis method described in International Publication WO 2002/066552 pamphlet. Specifically, under a nitrogen atmosphere, 2-bromopyridine and 1.2 equivalent of 3-bromophenylboric acid were subjected to the Suzuki coupling (catalyst: tetrakis(triphenylphosphine)palladium(0), base: 2M sodium carbonate aqueous solution, solvent: ethanol, toluene), to obtain 2-(3′-bromophenyl)pyridine represented by the following formula:

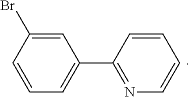

Next, under a nitrogen atmosphere, tribromobenzene and 2.2 equivalent of 4-tert-butylphenylboric acid were subjected to the Suzuki coupling (catalyst: tetrakis(triphenylphosphine)palladium(0), base: 2M sodium carbonate aqueous solution, solvent: ethanol, toluene), to obtain a bromo compound represented by the following formula:

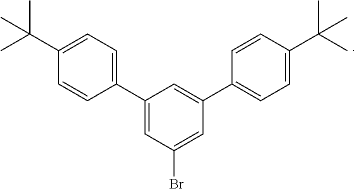

Under a nitrogen atmosphere, this bromo compound was dissolved in anhydrous THF, then, cooled down to −78° C., and a slight excess amount of tert-butyllithium was dropped. Under cooling, further, B(OC₄H₉)₃ was dropped, and reacted at room temperature. The resultant reaction liquid was post-treated with 3M hydrochloric acid water, to obtain a boric acid compound represented by the following formula:

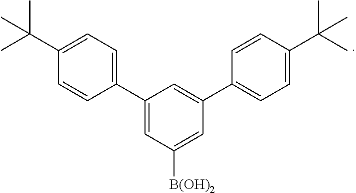

2-(3′-bromophenyl)pyridine and 1.2 equivalent of the above-described boric acid compound were subjected to the Suzuki coupling (catalyst: tetrakis(triphenylphosphine)palladium(0), base: 2M sodium carbonate aqueous solution, solvent: ethanol, toluene), to obtain a ligand (that is, a compound acting as a ligand) represented by the following formula:

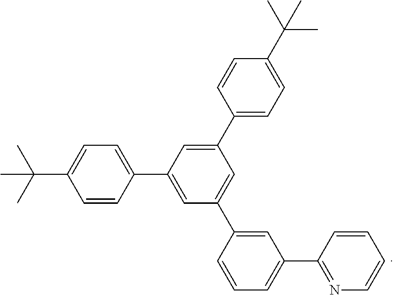

Under an argon atmosphere, IrCl₃.3H₂O and, 2.2 equivalent of the above-described ligand, 2-ethoxyethanol and ion exchanged water were charged, and refluxed. The deposited solid was filtrated under suction. The resultant solid was washed with ethanol and ion exchanged water in this order, then, dried, to obtain a compound represented by the following formula as a yellow powder:

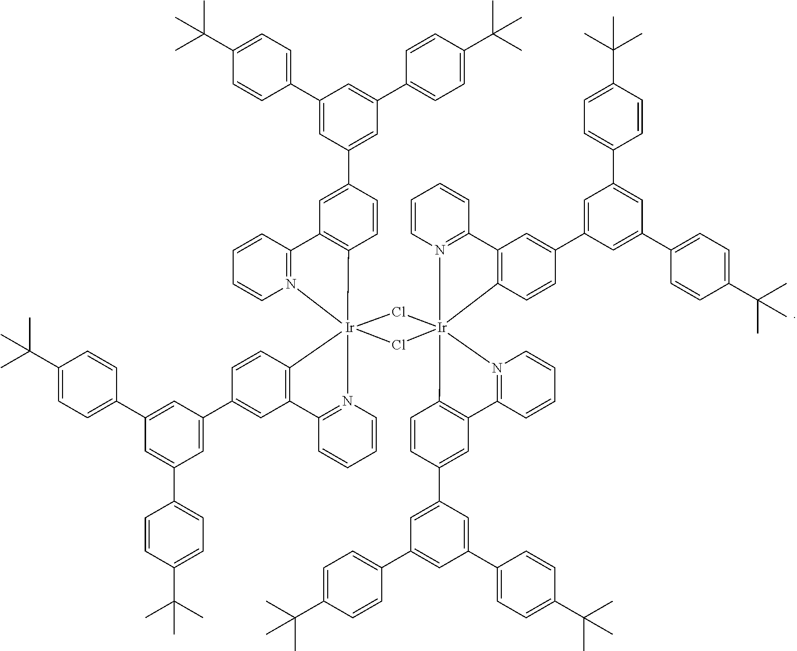

Under an argon atmosphere, to the above-described yellow powder were added 2 equivalent of the above-described ligand and 2 equivalent of silver trifluoromethanesulfonate, and the mixture was heated in diethylene glycol dimethyl ether, to obtain a phosphorescent compound A represented by the following formula:

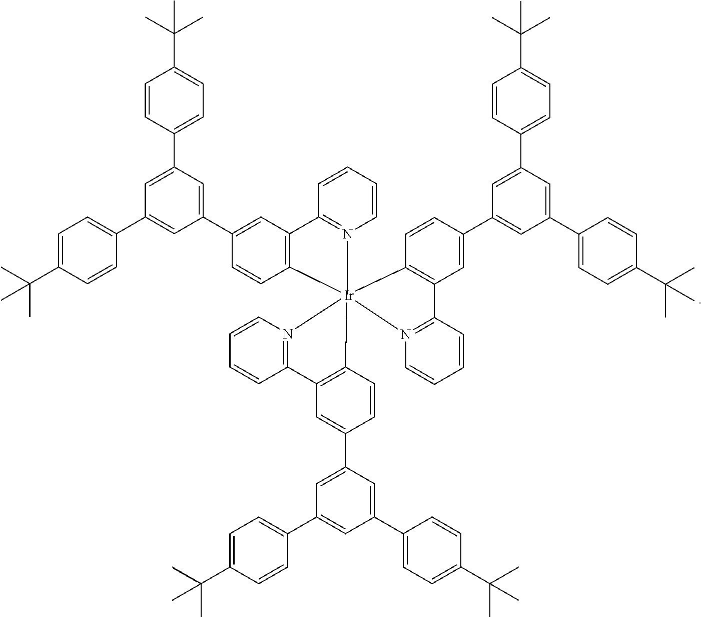

¹H-NMR (300 MHz, CDCl₃): δ 1.38 (s, 54H), 6.93 (dd, J=6.3 Hz and 6.6 Hz, 3H), 7.04 (br, 3H), 7.30 (d, J=7.9 Hz, 3H), 7.48 (d, J=7.3 Hz, 12H), 7.61-7.70 (m, 21H), 7.82 (s, 6H), 8.01 (s, 3H), 8.03 (d, J=7.9 Hz, 3H)

LC-MS (APCI, positive): m/z⁺=1677 [M+H]⁺

The phosphorescent compound A had a lowest excitation triplet energy of 2.60 eV and an ionization potential of 5.24 eV.

### Synthesis Example 6

### Synthesis of Polymer Compound P-1

Under an inert atmosphere, 5.20 g of 2,7-bis(1,3,2-dioxaborolan-2-yl)-9,9-dioctylfluorene, 5.42 g of bis(4-bromophenyl)-(4-sec-butylphenyl)-amine, 2.2 mg of palladium acetate, 15.1 mg of tris(2-methylphenyl)phosphine, 0.91 g of trioctylmethylammonium chloride (trade name: Aliquat336, manufactured by Aldrich) and 70 ml of toluene were mixed, and heated at 105° C. Into the reaction solution, 19 ml of a 2M sodium carbonate aqueous solution was dropped, and the mixture was refluxed for 4 hours. After the reaction, 121 mg of phenylboronic acid was added, and the mixture was further refluxed for 3 hours. Then, an aqueous solution of sodium N,N-diethyldithiocarbamate trihydrate was added, and the mixture was stirred at 80° C. for 2 hours. After cooling, the reaction solution was washed with water, 3 wt % acetic acid aqueous solution and water in this order, and the resultant toluene solution was purified by passing through an alumina column and a silica gel column. The resultant toluene solution was dropped into a large amount of methanol, stirred, then, the resultant precipitate was filtrated and dried, to obtain a polymer compound P-1. The polymer compound P-1 had a polystyrene-equivalent number-average molecular weight Mn of 1.2×10⁵ and a polystyrene-equivalent weight-average molecular weight Mw of 2.6×10⁵.

The polymer compound P-1 is a copolymer composed of a repeating unit represented by the following formula:

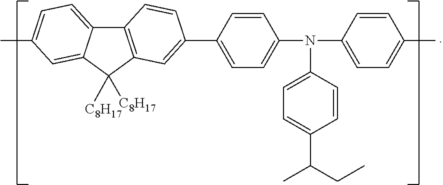

The polymer compound P-1 had a lowest excitation triplet energy of 2.76 eV and an ionization potential of 5.46 eV.

### Synthesis Example 7

### Synthesis of Polymer Compound P-2

Into an inert gas-purged reaction vessel, 17.57 g (33.13 mmol) of 2,7-bis(1,3,2-dioxaborolan-2-yl)-9,9-dioctylfluorene, 12.88 g (28.05 mmol) of bis(4-bromophenyl)-(4-sec-butylphenyl)-amine, 2.15 g (5.01 mmol) of the compound M-2, 3 g of methyltrioctylammonium chloride (trade name: Aliquat 336, manufactured by Aldrich) and 200 g of toluene were measured and charged. The reaction vessel was heated at 100° C., and 7.4 mg of palladium(II) acetate, 70 mg of tris(2-methylphenyl)phosphine and 64 g of an about 18 wt % sodium carbonate aqueous solution were added, and stirring thereof was continued with heating for 3 hours or more. Thereafter, 400 mg of phenylboronic acid was added, and stirring thereof was further continued with heating for 5 hours. The reaction liquid was diluted with toluene, washed with a 3 wt % acetic acid aqueous solution and ion exchanged water in this order, then, the organic layer was taken out and to this was added 1.5 g of sodium diethyldithiocarbamate trihydrate, and the mixture was stirred for 4 hours. The resultant solution was purified by column chromatography using an equal mixture of alumina and silica gel as the stationary phase. The resultant toluene solution was dropped into methanol, stirred, then, the resultant precipitate was filtrated and dried, to obtain a polymer compound P-2. The polymer compound P-2 had a polystyrene-equivalent number-average molecular weight Mn of 8.9×10⁴ and a polystyrene-equivalent weight-average molecular weight Mw of 4.2×10⁵.

The polymer compound P-2 is a copolymer containing a repeating unit represented by the following formula (hereinafter, referred to as “MN1”):

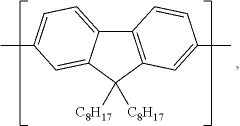

a repeating unit represented by the following formula (hereinafter, referred to as “MN2”):

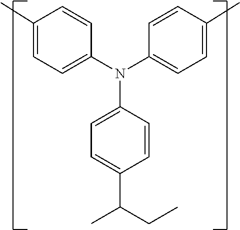

and a repeating unit represented by the following formula (hereinafter, referred to as “MN3”):

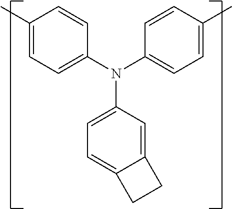

at a molar ratio of MN1:MN2:MN3=50:42:8, according to the theoretical value calculated from the charged raw materials.

The polymer compound P-2 had a lowest excitation triplet energy of 2.75 eV and an ionization potential of 5.45 eV.

### Synthesis Example 8

### Synthesis of Polymer Compound P-3

A polymer compound P-3 was obtained in the same manner as in Synthesis Example 7, excepting that bis(4-bromophenyl)-(4-sec-butylphenyl)-amine was replaced by the compound M-1, and 2,7-bis(1,3,2-dioxaborolan-2-yl)-9,9-dioctylfluorene, the compound M-1 and the compound M-2 were used at a molar ratio of 50:42:8 in Synthesis Example 7.

The polymer compound P-3 had a polystyrene-equivalent number-average molecular weight of 6.0×10⁴ and a polystyrene-equivalent weight-average molecular weight of 4.0×10⁵.

The polymer compound P-3 is a copolymer containing the repeating unit (MN1), a repeating unit represented by the following formula (hereinafter, referred to as “MN4”):

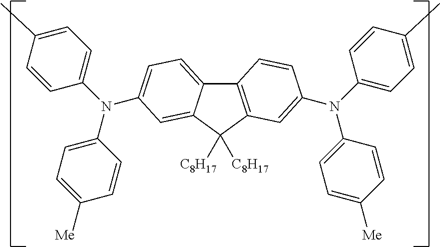

and the repeating unit (MN3) at a molar ratio of MN1:MN4:MN3=50:42:8, according to the theoretical value calculated from the charged raw materials.

The polymer compound P-3 had a lowest excitation triplet energy of 2.55 eV and an ionization potential of 5.29 eV.

### Synthesis Example 9

### Synthesis of Polymer Compound P-4

Under an inert gas atmosphere, the compound M-3 (3.13 g), the compound M-4 (0.70 g), 2,7-dibromo-9,9-dioctylfluorene (2.86 g), palladium(II) acetate (2.1 mg), tris(2-methoxyphenyl)phosphine (13.4 mg) and toluene (80 mL) were mixed, and the mixture was heated at 100° C. A 20 wt % tetraethylammonium hydroxide aqueous solution (21.5 ml) was dropped into the reaction solution, and the mixture was refluxed for 5 hours. After the reaction, phenylboric acid (78 mg), palladium(II) acetate (2.1 mg), tris(2-methoxyphenyl)phosphine (13.3 mg), toluene (6 mL) and a 20 wt % tetraethylammonium hydroxide aqueous solution (21.5 ml) were added, and the mixture was further refluxed for 17.5 hours. Then, to this was added a 0.2 M sodium diethyldithiocarbamate aqueous solution (70 ml), and the mixture was stirred at 85° C. for 2 hours. The solution was cooled down to room temperature, and washed with water, a 3 wt % acetic acid aqueous solution and water in this order. The organic layer was dropped into a large amount of methanol, the resultant precipitate was filtrated, then, dried, to obtain a solid. This solid was dissolved in toluene, and purified by passing through an alumina column and a silica gel column. The resultant toluene solution was dropped into methanol (1500 ml), and the resultant precipitate was filtrated and dried, to obtain 3.43 g of a polymer compound P-4.

The polymer compound P-4 had a polystyrene-equivalent number-average molecular weight Mn of 1.9×10⁵ and a polystyrene-equivalent weight-average molecular weight Mw of 5.7×10⁵.

The polymer compound P-4 is a copolymer containing a repeating unit represented by the following formula (hereinafter, referred to as “MN5”):

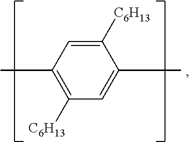

the repeating unit (MN1) and a repeating unit represented by the following formula (hereinafter, referred to as “MN6”):

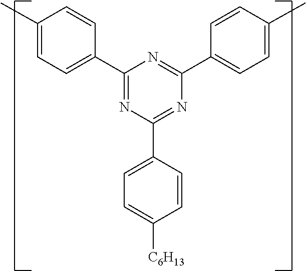

at a molar ratio of MN5:MN1:MN6=50:40:10, according to the theoretical value calculated from the charged raw materials.

The polymer compound P-4 had a lowest excitation triplet energy of 2.98 eV and an ionization potential of 6.10 eV.

### Example 1

### Fabrication of Organic Electroluminescent Device 1

On a glass substrate carrying thereon an ITO film having a thickness of 150 nm formed by a sputtering method, a suspension of poly(3,4)ethylenedioxythiophene/polystyrenesulfonic acid (Manufactured by H. C. Starck, trade name: CLEVIOS P AI4083) (hereinafter, referred to as “CLEVIOS P”) was placed, and spin-coated to form a film having a thickness of about 65 nm, and dried on a hot plate at 200° C. for 10 minutes. Next, the polymer compound P-3 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-4 and the phosphorescent compound A were dissolved at a concentration of 1.5 wt % (weight ratio: polymer compound P-4/phosphorescent compound A=70/30) in xylene (manufactured by Kanto Chemical Co., Inc.: for Electronics (EL grade)). The resultant xylene solution was placed on the thermally-treated film of the polymer compound P-3, and spin-coated to form a light emitting layer 1 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer 1, then, aluminum was vapor-deposited with a thickness of about 60 nm on the barium layer, as a cathode. After vapor deposition, encapsulation was performed using a glass substrate, to fabricate an organic electroluminescent device 1.

Voltage was applied on the organic electroluminescent device 1, to observe electroluminescence (EL) of green light emission. The light emission efficiency at a luminance of 1000 cd/m² was 25.9 cd/A, and the voltage under this condition was 5.8 V. The current density at a voltage of 6.0 V was 4.7 mA/cm². The luminance half life under an initial luminance of 4000 cd/m² was 52.8 hours.

### Comparative Example 1

### Fabrication of Organic Electroluminescent Device C1

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound P-1 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-4 and the phosphorescent compound A were dissolved at a concentration of 1.5 wt % (weight ratio: polymer compound P-4/phosphorescent compound A=70/30) in xylene (manufactured by Kanto Chemical Co., Inc.: for Electronics (EL grade)). The resultant xylene solution was placed on the thermally-treated film of the polymer compound P-1, and spin-coated to form a light emitting layer C1 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer C1, then, aluminum was vapor-deposited with a thickness of about 60 nm on the barium layer, as a cathode. After vapor deposition, encapsulation was performed using a glass substrate, to fabricate an organic electroluminescent device C1.

Voltage was applied on the organic electroluminescent device C1, to observe electroluminescence (EL) of green light emission. The light emission efficiency at a luminance of 1000 cd/m² was 27.5 cd/A, and the voltage under this condition was 6.6 V. The current density at a voltage of 6.0 V was 1.7 mA/cm². The luminance half life under an initial luminance of 4000 cd/m² was 27.8 hours.

### Comparative Example 2

### Fabrication of Organic Electroluminescent Device C2

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound P-2 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-4 and the phosphorescent compound A were dissolved at a concentration of 1.5 wt % (weight ratio: polymer compound P-4/phosphorescent compound A=70/30) in xylene (manufactured by Kanto Chemical Co., Inc.: for Electronics (EL grade)). The resultant xylene solution was placed on the thermally-treated film of the polymer compound P-2, and spin-coated to form a light emitting layer C2 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer C2, then, aluminum was vapor-deposited with a thickness of about 60 nm on the barium layer, as a cathode. After vapor deposition, encapsulation was performed using a glass substrate, to fabricate an organic electroluminescent device C2.

Voltage was applied on the organic electroluminescent device C2, to observe electroluminescence (EL) of green light emission. The light emission efficiency at a luminance of 1000 cd/m² was 30.8 cd/A, and the voltage under this condition was 6.4 V. The current density at a voltage of 6.0 V was 2.2 mA/cm². The luminance half life under an initial luminance of 4000 cd/m² was 39.6 hours.

### Synthesis Example 10

### Synthesis of Compound M-5

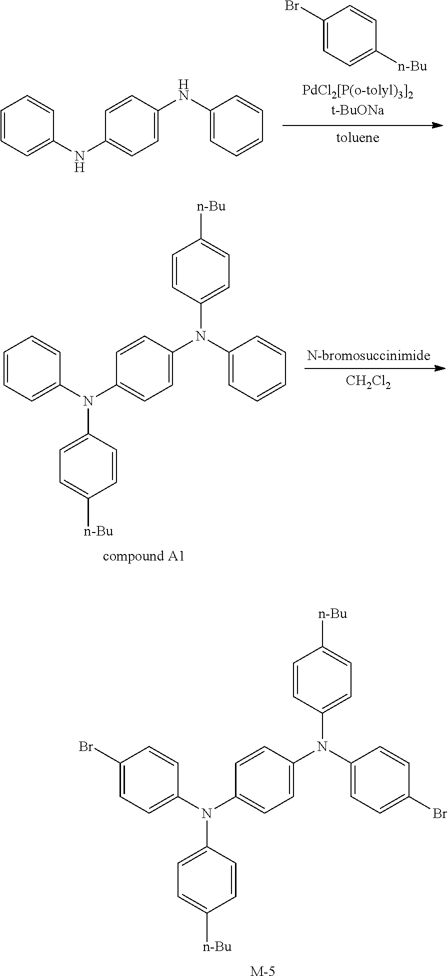

Under a nitrogen gas atmosphere, N,N′-diphenyl-1,4-phenylenediamine (61.17 g), 4-n-butylbromobenzene (100.12 g), sodium-tert-butoxide (63.2 g) and toluene (3180 ml) were mixed, to this was added bis(tri-o-tolylphosphine)palladium(II) dichloride (7.39 g), then, the mixture was stirred for about 5 hours under reflux with heating. After cooling down to room temperature, the solid was removed by filtration through celite, washing was performed with saturated brine (about 1.2 L), then, the resultant organic layer was concentrated under reduced pressure, to obtain a brown viscous oil. This was recrystallized from acetone, filtrated, washed with an acetone/methanol mixed solvent, and dried under reduced pressure, to obtain a compound A1 (106.4 g) as a white crystal. The yield was 89%. The area percentage value in HPLC analysis was about 98%.

Under a nitrogen gas atmosphere, the compound A1 (100.0 g) synthesized by the same procedure as described above, N,N-dimethylformamide (500 ml) and hexane (1000 ml) were mixed, and heated at 40° C. to obtain a uniform solution. This was cooled down to room temperature, then, a solution prepared by dissolving N-bromosuccinimide (72 g) in N,N-dimethylformamide (800 ml) was dropped over a period of 1 hour, and after completion of dropping, the mixture was stirred at room temperature for 1 hour, then, a 6 wt % sodium sulfite aqueous solution (200 ml) was added and the mixture was stirred thoroughly, liquid separation was carried out and the aqueous layer was removed. The resultant organic layer was concentrated under reduced pressure thereby distilling off hexane, to find deposition of a solid, this solid was filtrated, washed with a 6 wt % sodium sulfite aqueous solution (200 ml) and water (200 ml), and dried under reduced pressure, to obtain a white solid (88 g). The yield was 69%. The area percentage value in HPLC analysis was about 99.2%. An aliquot thereof (25.0 g) was dissolved in chloroform, activated carbon was added and the mixture was stirred and filtrated, then, recrystallized from toluene/hexane three times, to obtain the targeted compound M-5 (15.7 g) as a white solid. The area percentage value in HPLC analysis was about 99.9%. The yield after purification was 63%. The total yield was 43%.

### Synthesis Example 11

### Synthesis of Compound M-6

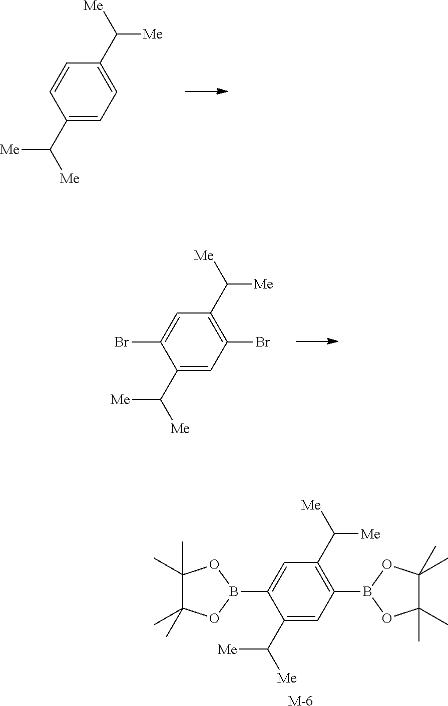

In a light-shielded 300 ml round bottom flask under an argon gas atmosphere, 1,4-diisopropylbenzene (24.34 g, 150 mmol), an iron powder (0.838 g, 15 mmol), dehydrated chloroform (40 ml) and trifluoroacetic acid (1.71 g, 15 mmol) were mixed and stirred, and cooled by an ice bath, and a dilute solution of bromine (55.1 g, 345 mmol) in dehydrated chloroform (92 ml) was dropped into the cooled solution over a period of 30 minutes, and the mixture was further stirred and reacted for 5 hours while cooling by an ice bath. After completion of the reaction, a 10 wt % sodium hydroxide aqueous solution was cooled by an ice bath and to this was added slowly the above-described reaction solution, and the mixture was further stirred for 15 minutes. It was separated into an organic layer and an aqueous layer, extraction with chloroform (100 ml) from the aqueous solution was carried out, the resultant organic layers were combined, then, a 10 wt % sodium sulfite aqueous solution (200 ml) was added, and the mixture was stirred at room temperature for 30 minutes (in this operation, the color of the organic layer changed from pale yellow to approximately colorless transparent). The aqueous layer was separated and removed, the resultant organic layer was washed with 15 wt % brine (200 ml), then, dried over anhydrous magnesium sulfate (30 g), the solvent was distilled off by concentration under reduced pressure, to obtain about 47 g of a pale yellow oil. Ethanol (15 g) was added, the mixture was shaken to uniform, then, allowed to stand still for 3 hours in a −10° C. freezer to cause deposition of a crystal which was then filtrated and washed with a small amount of methanol, and dried under reduced pressure overnight at room temperature, to obtain 1,4-dibromo-2,5-diisopropylbenzene (30.8 g, yield 64%) as a white crystal.

¹H-NMR (300 MHz, CDCl₃), δ=1.24 (d, 12H), 3.30 (m, 2H), 7.50 (s, 2H)

In a 1000 ml flask under an argon gas atmosphere, to magnesium small pieces (9.724 g, 400 mmol) were added a small amount of dehydrated tetrahydrofuran and 1,2-dibromoethane (0.75 g, 4 mmol) sequentially. Activation of magnesium was confirmed by heat generation and foaming, then, a solution prepared by dissolving 1,4-dibromo-2,5-diisopropylbenzene (32.0 g, 100 mmol) synthesized by the same manner as described above in dehydrated tetrahydrofuran (100 ml) was dropped over a period of about 1 hour. After completion of dropping, the mixture was heated by a 80° C. oil bath, and the mixture was stirred for 1 hour under reflux. The oil bath was removed, the solution was diluted with dehydrated tetrahydrofuran (200 ml), further cooled by an ice bath, then, 2-isopropoxy-4,4,5,5-tetramethyl-1,3,2-dioxaborolane (74.4 g, 400 mmol) was added. The ice bath was removed, the mixture was heated by a 80° C. oil bath, and stirred under reflux for 1.5 hours. The oil bath was removed, further cooling by an ice bath was carried out, then, a saturated ammonium chloride aqueous solution (25 ml) was added, and the mixture was stirred for 30 minutes. The ice bath was removed, hexane (2000 ml) was added, and the mixture was stirred vigorously for 30 minutes. Stirring was stopped, the mixture was allowed to stand still for 15 minutes without any procedure, then, filtrated through a glass filter paved with silica gel, the silica gel was washed with hexane (1000 ml), the combined filtrates were concentrated under reduced pressure, to obtain a coarse product (59.0 g). Further, the same operation was carried out again at a scale of 80% of the above-described operation, to obtain a coarse product (44.8 g).

The same synthesis was further carried out, and the coarse products were combined. To the whole coarse product (103.8 g) was added methanol (520 ml), and the mixture was stirred under reflux with heating for 1 hour using a 75° C. oil bath. The oil bath was removed, the mixture was cooled down to room temperature while stirring, then, the solid was filtrated, washed with methanol (100 ml), and dried under reduced pressure, to obtain a white crystal (48.8 g, HPLC area percentage (UV 254 nm): 93.3%). The dried crystal was dissolved with heating in isopropanol (690 ml), then, the solution was cooled slowly down to room temperature while allowing to stand still, to cause deposition of a crystal which was then filtrated and washed with methanol (50 ml), and dried under reduced pressure overnight at 50° C., to obtain the targeted compound M-6 as a white crystal (44.6 g, HPLC area percentage (UV 254 nm): 99.8%, yield 60%).

¹H-NMR (300 MHz, CDCl₃), δ=1.23 (d, 12H), 1.34 (s, 24H), 3.58 (m, 2H), 7.61 (s, 2H)

### Synthesis Example 12

### Synthesis of Compound M-7

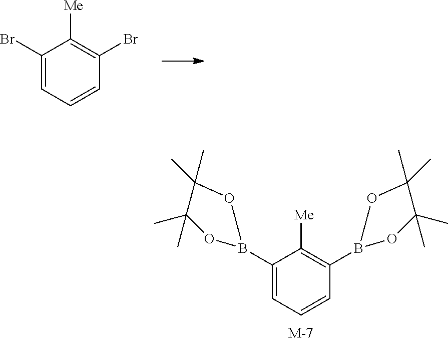

In a 1000 ml flask under an argon gas atmosphere, to magnesium small pieces (19.45 g, 800 mmol) were added a small amount of dehydrated tetrahydrofuran and 1,2-dibromoethane (1.50 g, 8 mmol) sequentially. Activation of magnesium was confirmed by heat generation and foaming, then, a solution prepared by dissolving 2,6-dibromotoluene (49.99 g, 200 mmol) in dehydrated tetrahydrofuran (200 ml) was dropped over a period of about 2 hours. After completion of dropping, heating by a 80° C. oil bath was carried out, and the mixture was stirred for 1 hour under reflux. The oil bath was removed, the mixture was diluted with dehydrated tetrahydrofuran (400 ml), further cooled by an ice bath, then, 2-isopropyloxy-4,4,5,5-tetramethyl-1,3,2-dioxaborolane (148.85 g, 800 mmol) was added. The ice bath was removed, and the mixture was stirred for 1.5 hours under reflux by heating by a 80° C. oil bath. The oil bath was removed, the mixture was further cooled by an ice bath, then, a saturated ammonium chloride aqueous solution (50 ml) was added, and the mixture was stirred for 30 minutes. The ice bath was removed, hexane (1500 ml) was added, and the mixture was stirred vigorously for 30 minutes. Stirring was stopped, the mixture was allowed to stand still for 15 minutes without any procedure, then, filtrated through a glass filter paved with silica gel, the silica gel was washed with hexane (1000 ml), and the combined filtrates were concentrated under reduced pressure, to obtain a coarse product (72.0 g). Further, the same operation was carried out again, to obtain a coarse product (75.4 g).

Next, methanol (740 ml) was added to the whole coarse product, and the mixture was stirred under reflux with heating for 1 hour using a 85° C. oil bath. The oil bath was removed, the mixture was cooled down to room temperature while stirring, then, the solid was filtrated, washed with methanol (100 ml), and dried under reduced pressure to obtain a white crystal (59.7 g). The dried crystal was dissolved with heating in isopropanol (780 ml), then, the solution was cooled slowly down to room temperature while allowing to stand still, to cause deposition of a crystal which was filtrated and washed with methanol (100 ml), and dried under reduced pressure overnight at 50° C., to obtain the targeted compound M-7 (50.8 g, HPLC area percentage (ultraviolet wavelength 254 nm): 99.8%, yield 37%) as a white crystal.

¹H-NMR (300 MHz, CDCl₃) δ (ppm)=1.34 (s, 24H), 2.74 (s, 3H), 7.14 (t, 1H), 7.79 (d, 2H)

### Synthesis Example 13

### Synthesis of Electron Transporting Material ET-A

According to the following reaction scheme, an electron transporting material ET-A was synthesized.

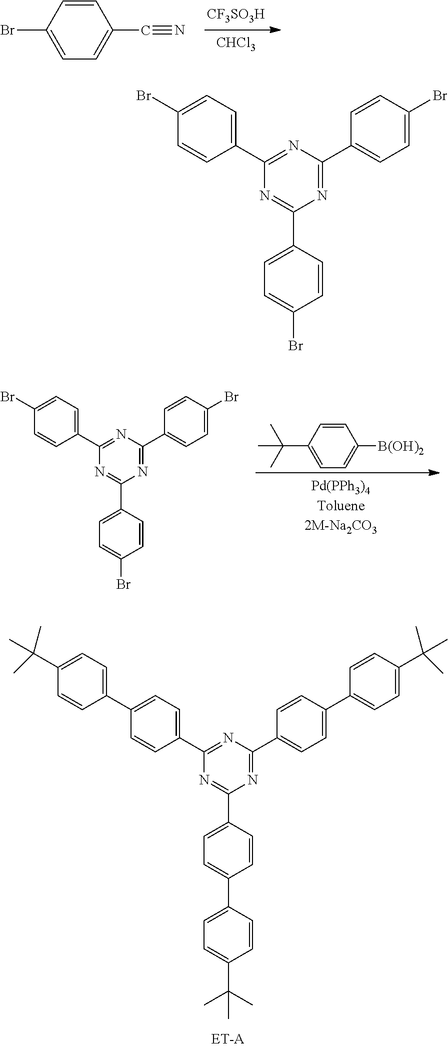

Specifically, under a nitrogen atmosphere, 100 g (0.653 mol) of trifluoromethanesulfonic acid was charged in a flask, and stirred at room temperature. To this was added dropwise a solution prepared by dissolving 61.93 g (0.327 mol) of 4-bromobenzonitrile in 851 ml of dehydrated chloroform. The resultant solution was heated up to 95° C., stirred while heating, then, cooled down to room temperature, to this was added a dilute ammonia aqueous solution under an ice bath, to find generation of a solid. This solid was separated by filtration, washed with water, then, washed with diethyl ether, and dried while reducing pressure, to obtain 47.8 g of a white crystal.

Next, under a nitrogen atmosphere, 8.06 g (14.65 mol) of this white crystal, 9.15 g (49.84 mol) of 4-t-butylphenylboronic acid, 1.54 g (1.32 mol) of Pd(PPh₃)₄, 500 ml of toluene through which nitrogen had been bubbled previously and 47.3 ml of ethanol through which nitrogen had been bubbled previously were mixed, stirred, and heated to reflux. Into the reaction solution, 47.3 ml of a 2M sodium carbonate aqueous solution through which nitrogen had been bubbled previously was dropped, and further heated to reflux. The reaction solution was left to cool, then, separated, the aqueous layer was removed, and the organic layer was washed with dilute hydrochloric acid and water in this order, and separated. The organic layer was dried over anhydrous magnesium sulfate, filtrated and concentrated. The resultant coarse product was passed through a silica gel column, and to the resultant filtrate was added acetonitrile, to obtain a crystal. This crystal was dried while reducing pressure, to obtain 8.23 g of an electron transporting material ET-A as a white crystal. The result of the ¹H-NMR analysis of the electron transporting material ET-A is shown below.

¹H-NMR (270 MHz/CDCl₃): δ 1.39 (s, 27H), 7.52 (d, 6H), 7.65 (d, 6H), 7.79 (d, 6H), 8.82 (d, 6H).

The electron transporting material ET-A had a lowest excitation triplet energy of 2.79 eV and an ionization potential of 6.13 eV.

### Synthesis Example 14

### Synthesis of Polymer Compound P-5

To an inert gas-purged reaction vessel were added 2,7-bis(4,4,5,5-tetramethyl-1,3,2-dioxaborolan-2-yl)-9,9-dioctylfluorene (1.62 g, 2.50 mmol), the compound M-1 (2.30 g, 2.50 mmol), palladium(II) acetate (0.56 mg), tris(2-methoxyphenyl)phosphine (3.53 mg) and toluene (67 mL), and the mixture was heated at 100° C. while stirring. Into the resultant solution, a 20 wt % tetraethylammonium hydroxide aqueous solution (8.5 mL) was dropped, and the mixture was refluxed for 7 hours. To this were added phenylboric acid (31 mg), palladium(II) acetate (0.56 mg), tris(2-methoxyphenyl)phosphine (3.53 mg) and a 20 wt % tetraethylammonium hydroxide aqueous solution (8.5 mL), and the mixture was further refluxed for 14 hours. Then, to this was added a solution prepared by dissolving sodium N,N-diethyldithiocarbamate trihydrate (1.39 g) in ion exchanged water (28 mL), and the mixture was stirred at 85° C. for 4 hours. The organic layer was separated from the aqueous layer, then, the organic layer was washed with ion exchanged water (33 mL) three times, with a 3 wt % acetic acid aqueous solution (33 mL) three times and with ion exchanged water (33 mL) three times. The organic layer was dropped into methanol (520 mL), and the resultant precipitate was filtrated, then, dried to obtain a solid. This solid was dissolved in toluene, and purified by passing through a silica gel/alumina column through which toluene had been passed previously. The resultant eluate was dropped into methanol (600 mL), the resultant precipitate was filtrated, then, dried to obtain 2.48 g of a polymer compound P-5. The polymer compound P-5 had a polystyrene-equivalent number-average molecular weight Mn of 2.3×10⁴ and a polystyrene-equivalent weight-average molecular weight Mw of 1.1×10⁵.

The polymer compound P-5 is a copolymer composed of a repeating unit represented by the following formula:

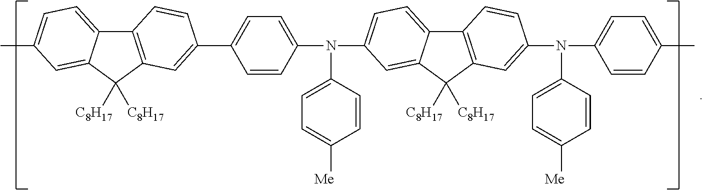

The polymer compound P-5 had lowest excitation triplet energy of 2.55 eV and an ionization potential of 5.28 eV.

### Synthesis Example 15

### Synthesis of Polymer Compound P-6

To an inert gas-purged reaction vessel were added 2,7-bis(4,4,5,5-tetramethyl-1,3,2-dioxaborolan-2-yl)-9,9-dioctylfluorene (2.65 g, 4.12 mmol), the compound M-5 (2.40 g, 3.52 mmol), the compound M-2 (0.267 g, 0.622 mmol), dichlorobis(triphenylphosphine)palladium(II) (2.9 mg) and toluene (81 mL), and the mixture was heated at 100° C. while stirring. Into the resultant solution, a 20 wt % tetraethylammonium hydroxide aqueous solution (14 mL) was dropped, and the mixture was refluxed for 4 hours. To this were added phenylboric acid (51 mg), dichlorobis(triphenylphosphine)palladium(II) (2.9 mg) and a 20 wt % tetraethylammonium hydroxide aqueous solution (14 mL), and the mixture was further refluxed for 19 hours. Then, to this was added a solution prepared by dissolving sodium N,N-diethyldithiocarbamate trihydrate (2.29 g) in ion exchanged water (46 mL), and the mixture was stirred at 85° C. for 6 hours. The organic layer was separated from the aqueous layer, then, the organic layer was washed with ion exchanged water (72 mL) twice, a 3 wt % acetic acid aqueous solution (72 mL) twice and ion exchanged water (72 mL) twice. The organic layer was dropped into methanol (660 mL), and the resultant precipitate was filtrated, then, dried to obtain a solid. This solid was dissolved in toluene, and purified by passing through a silica gel/alumina column through which toluene had been passed previously. The resultant eluate was dropped into methanol (1400 mL), the resultant precipitate was filtrated, then, dried to obtain 2.82 g of a polymer compound P-6. The polymer compound P-6 had a polystyrene-equivalent number-average molecular weight Mn of 3.0×10⁴ and a polystyrene-equivalent weight-average molecular weight Mw of 2.0×10⁵.

The polymer compound P-6 is a copolymer containing the repeating unit (MN1), a repeating unit represented by the following formula (hereinafter, referred to as “MN7”):

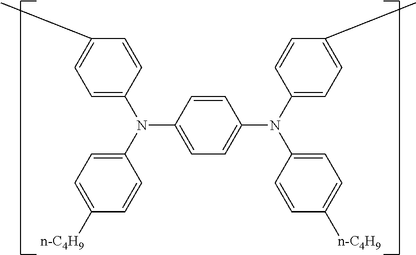

and the repeating unit (MN3) at a molar ratio of MN1:MN7:MN3=50:43:8, according to the theoretical value calculated from the charged raw materials.

The polymer compound P-6 had a lowest excitation triplet energy of 2.70 eV and an ionization potential of 5.29 eV.

### Synthesis Example 16

### Synthesis of Polymer Compound P-7

Into an inert gas-purged reaction vessel were added the compound M-6 (1.29 g, 3.11 mmol), the compound M-7 (0.261 g, 0.759 mmol), 2,7-dibromo-9,9-dioctylfluorene (2.01 g, 3.66 mmol), bis(4-bromophenyl)(4-sec-butylphenyl)amine (0.104 g, 0.226 mmol), palladium(II) acetate (0.85 mg), tris(2-methoxyphenyl)phosphine (5.3 mg) and toluene (38 ml), and the mixture was heated at 100° C. while stirring. Into the resultant solution, a 20 wt % tetraethylammonium hydroxide aqueous solution (13 ml) was dropped, and the mixture was refluxed for about 21 hours. To this were added phenylboric acid (47 mg), palladium(II) acetate (0.85 mg), tris(2-methoxyphenyl)phosphine (5.4 mg) and toluene (6 mL), and the mixture was further refluxed for 15 hours. Then, to this was added a solution prepared by dissolving sodium N,N-diethyldithiocarbamate trihydrate (2.10 g) in ion exchanged water (46 mL), and the mixture was stirred at 85° C. for 2 hours. The organic layer was separated from the aqueous layer, then, the organic layer was washed with ion exchanged water (50 mL) three times, with a 3 wt % acetic acid aqueous solution (50 mL) three times and with ion exchanged water (50 mL) three times. The organic layer was dropped into methanol (600 mL), and the resultant precipitate was filtrated, then, dried to obtain a solid. This solid was dissolved in toluene, and purified by passing through a silica gel/alumina column through which toluene had been passed previously. The resultant eluate was dropped into methanol (700 mL), the resultant precipitate was filtrated, then, dried to obtain 1.73 g of a polymer compound P-7. The polymer compound P-7 had a polystyrene-equivalent number-average molecular weight Mn of 5.1×10⁴ and a polystyrene-equivalent weight-average molecular weight Mw of 1.2×10⁵.

The polymer compound P-7 is copolymer containing a repeating unit represented by the following formula (hereinafter, referred to as “MN8”):

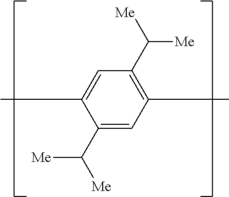

a repeating unit represented by the following formula (hereinafter, referred to as “MN9”):

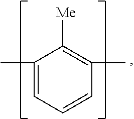

the repeating unit (MN1) and the repeating unit (MN2) at a molar ratio of MN8:MN9:MN1:MN2=40:10:47:3, according to the theoretical value calculated from the charged raw materials.

The polymer compound P-7 had a lowest excitation triplet energy of 3.08 V and an ionization potential of 5.83 eV.

### Example 2

### Fabrication of Organic Electroluminescent Device 2

On a glass substrate carrying thereon an ITO film having a thickness of 150 nm formed by a sputtering method, a suspension of poly(3,4)ethylenedioxythiophene/polystyrenesulfonic acid (CLEVIOS P) was placed, and spin-coated to form a film having a thickness of about 65 nm, and dried on a hot plate at 200° C. for 10 minutes. Next, the polymer compound P-5 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-4 and the phosphorescent compound A were dissolved at a concentration of 1.5 wt % (weight ratio: polymer compound P-4/phosphorescent compound A=70/30) in xylene (manufactured by Kanto Chemical Co., Inc.: for Electronics (EL grade)). The resultant xylene solution was placed on the thermally-treated film of the polymer compound P-5, and spin-coated to form a light emitting layer 2 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer 2, then, aluminum was vapor-deposited with a thickness of about 60 nm on the barium layer, as a cathode. After vapor deposition, encapsulation was performed using a glass substrate, to fabricate an organic electroluminescent device 2.

Voltage was applied on the organic electroluminescent device 2, to observe electroluminescence (EL) of green light emission. The light emission efficiency at a luminance of 1000 cd/m² was 24.3 cd/A, and the voltage under this condition was 5.9 V. The current density at a voltage of 6.0 V was 4.3 mA/cm². The luminance half life under an initial luminance of 4000 cd/m² was 54.0 hours.

### Example 3

### Fabrication of Organic Electroluminescent Device 3

On a glass substrate carrying thereon an ITO film having a thickness of 150 nm formed by a sputtering method, a suspension of poly(3,4)ethylenedioxythiophene/polystyrenesulfonic acid (CLEVIOS P) was placed, and spin-coated to form a film having a thickness of about 65 nm, and dried on a hot plate at 200° C. for 10 minutes. Next, the polymer compound P-5 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-7, the electron transporting material ET-A and the phosphorescent compound A were dissolved at a concentration of 2.1 wt % (weight ratio: polymer compound P-7/electron transporting material ET-A/phosphorescent compound A=42/28/30) in xylene (manufactured by Kanto Chemical Co., Inc.: for Electronics (EL grade)). The resultant xylene solution was placed on the thermally-treated film of the polymer compound P-5, and spin-coated to form a light emitting layer 3 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer 3, then, aluminum was vapor-deposited with a thickness of about 60 nm on the barium layer, as a cathode. After vapor deposition, encapsulation was performed using a glass substrate, to fabricate an organic electroluminescent device 3.

Voltage was applied on the organic electroluminescent device 3, to observe electroluminescence (EL) of green light emission. The light emission efficiency at a luminance of 1000 cd/m² was 27.3 cd/A, and the voltage under this condition was 5.9 V. The current density at a voltage of 6.0 V was 4.0 mA/cm². The luminance half life under an initial luminance of 4000 cd/m² was 150.0 hours.

### Example 4

### Fabrication of Organic Electroluminescent Device 4

On a glass substrate carrying thereon an ITO film having a thickness of 150 nm formed by a sputtering method, a suspension of poly(3,4)ethylenedioxythiophene/polystyrenesulfonic acid (CLEVIOS P) was placed, and spin-coated to form a film having a thickness of about 65 nm, and dried on a hot plate at 200° C. for 10 minutes. Next, the polymer compound P-3 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-7, the electron transporting material ET-A and the phosphorescent compound A were dissolved at a concentration of 2.1 wt % (weight ratio: polymer compound P-7/electron transporting material ET-A/phosphorescent compound A=42/28/30) in xylene (manufactured by Kanto Chemical Co., Inc.: for Electronics (EL grade)). The resultant xylene solution was placed on the thermally-treated film of the polymer compound P-3, and spin-coated to form a light emitting layer 4 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer 4, then, aluminum was vapor-deposited with a thickness of about 60 nm on the barium layer, as a cathode. After vapor deposition, encapsulation was performed using a glass substrate, to fabricate an organic electroluminescent device 4.

Voltage was applied on the organic electroluminescent device 4, to observe electroluminescence (EL) of green light emission. The light emission efficiency at a luminance of 1000 cd/m² was 32.5 cd/A, and the voltage under this condition was 5.7 V. The current density at a voltage of 6.0 V was 4.0 mA/cm². The luminance half life under an initial luminance of 4000 cd/m² was 177.0 hours.

### Example 5

### Fabrication of Organic Electroluminescent Device 5

On a glass substrate carrying thereon an ITO film having a thickness of 150 nm formed by a sputtering method, a suspension of poly(3,4)ethylenedioxythiophene/polystyrenesulfonic acid (CLEVIOS P) was placed, and spin-coated to form a film having a thickness of about 65 nm, and dried on a hot plate at 200° C. for 10 minutes. Next, the polymer compound P-6 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-7, the electron transporting material ET-A and the phosphorescent compound A were dissolved at a concentration of 2.1 wt % (weight ratio: polymer compound P-7/electron transporting material ET-A/phosphorescent compound A=42/28/30) in xylene (manufactured by Kanto Chemical Co., Inc.: for Electronics (EL grade)). The resultant xylene solution was placed on the thermally-treated film of the polymer compound P-6, and spin-coated to form a light emitting layer 5 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer 5, then, aluminum was vapor-deposited with a thickness of about 60 nm on the barium layer, as a cathode. After vapor deposition, encapsulation was performed using a glass substrate, to fabricate an organic electroluminescent device 5.

Voltage was applied on the organic electroluminescent device 5, to observe electroluminescence (EL) of green light emission. The light emission efficiency at a luminance of 1000 cd/m² was 22.0 cd/A, and the voltage under this condition was 6.2 V. The current density at a voltage of 6.0 V was 3.9 mA/cm². The luminance half life under an initial luminance of 4000 cd/m² was 147.0 hours.

### Comparative Example 3

### Fabrication of Organic Electroluminescent Device C3

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound P-1 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-7, the electron transporting material ET-A and the phosphorescent compound A were dissolved at a concentration of 2.1 wt % (weight ratio: polymer compound P-7/electron transporting material ET-A/phosphorescent compound A=42/28/30) in xylene (manufactured by Kanto Chemical Co., Inc.: for Electronics (EL grade)). The resultant xylene solution was placed on the thermally-treated film of the polymer compound P-1, and spin-coated to form a light emitting layer C3 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer C3, then, aluminum was vapor-deposited with a thickness of about 60 nm on the barium layer, as a cathode. After vapor deposition, encapsulation was performed using a glass substrate, to fabricate an organic electroluminescent device C3.

Voltage was applied on the organic electroluminescent device C3, to observe electroluminescence (EL) of green light emission. The light emission efficiency at a luminance of 1000 cd/m² was 34.5 cd/A, and the voltage under this condition was 5.9 V. The current density at a voltage of 6.0 V was 3.3 mA/cm². The luminance half life under an initial luminance of 4000 cd/m² was 48.7 hours.

### Comparative Example 4

### Fabrication of Organic Electroluminescent Device C4

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound P-2 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), the film was dried at 180° C. for 60 minutes to obtain a thermally-treated film. Next, the polymer compound P-7, the electron transporting material ET-A and the phosphorescent compound A were dissolved at a concentration of 2.1 wt % (weight ratio: polymer compound P-7/electron transporting material ET-A/phosphorescent compound A=42/28/30) in xylene (manufactured by Kanto Chemical Co., Inc.: for Electronics (EL grade)). The resultant xylene solution was placed on the thermally-treated film of the polymer compound P-2, and spin-coated to form a light emitting layer C4 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer C4, then, aluminum was vapor-deposited with a thickness of about 60 nm on the barium layer, as a cathode. After vapor deposition, encapsulation was performed using a glass substrate, to fabricate an organic electroluminescent device C4.

Voltage was applied on the organic electroluminescent device C4, to observe electroluminescence (EL) of green light emission. The light emission efficiency at a luminance of 1000 cd/m² was 30.9 cd/A, and the voltage under this condition was 6.1 V. The current density at a voltage of 6.0 V was 2.9 mA/cm². The luminance half life under an initial luminance of 4000 cd/m² was 108.0 hours.

TABLE 3

| | hole | | | | |
|---|---|---|---|---|---|
| | transporting | light emitting layer | | | 4000 |
| | layer | | second | | cd/m² |
| | hole | | light | | lumi- |
| | transporting | first | emitting | T1ₜ- | nance |
| | polymer | light emitting | layer | T1ₑ | half life |
| | compound | layer material | material | (eV) | (hr) |
| Example | P-3 | phosphorescent | P-4 | −0.05 | 52.8 |
| 1 | | compound A | | | |
| Example | P-5 | phosphorescent | P-4 | −0.05 | 54.0 |
| 2 | | compound A | | | |
| Example | P-5 | phosphorescent | P-7 | −0.05 | 150.0 |
| 3 | | compound A | | | |
| Example | P-3 | phosphorescent | P-7 | −0.05 | 177.0 |
| 4 | | compound A | | | |
| Example | P-6 | phosphorescent | P-7 | 0.10 | 147.0 |
| 5 | | compound A | | | |
| Comparative | P-1 | phosphorescent | P-4 | 0.16 | 27.8 |
| Example | | compound A | | | |
| 1 | | | | | |
| Comparative | P-2 | phosphorescent | P-4 | 0.15 | 39.6 |
| Example | | compound A | | | |
| 2 | | | | | |
| Comparative | P-1 | phosphorescent | P-7 | 0.16 | 48.7 |
| Example | | compound A | | | |
| 3 | | | | | |
| Comparative | P-2 | phosphorescent | P-7 | 0.15 | 108.0 |
| Example | | compound A | | | |
| 4 | | | | | |

TABLE 4

| | hole | | | | | | |
|---|---|---|---|---|---|---|---|
| | transporting | | | | | | |
| | layer | light emitting layer | | | | | |
| | Hole | first light | second light | | 1000 cd/m² | 1000 | 6.0 V |
| | transporting | emitting | emitting | IPₑₕ- | light emission | cd/m² | current |
| | polymer | layer | layer | IPₜ | efficiency | voltage | density |
| | compound | material | material | (eV) | (cd/A) | (V) | (mA/cm²) |
| Example 1 | P-3 | phosphorescent | P-4 | −0.05 | 25.9 | 5.8 | 4.7 |
| | | compound A | | | | | |
| Example 2 | P-5 | phosphorescent | P-4 | −0.05 | 24.3 | 5.9 | 4.3 |
| | | compound A | | | | | |
| Example 3 | P-5 | phosphorescent | P-7 | −0.04 | 27.3 | 5.9 | 4.0 |
| | | compound A | | | | | |
| Example 4 | P-3 | phosphorescent | P-7 | −0.05 | 32.5 | 5.7 | 4.0 |
| | | compound A | | | | | |
| Example 5 | P-6 | phosphorescent | P-7 | −0.05 | 22.0 | 6.2 | 3.9 |
| | | compound A | | | | | |
| Comparative | P-1 | phosphorescent | P-4 | −0.22 | 27.5 | 6.6 | 1.7 |
| Example 1 | | compound A | | | | | |
| Comparative | P-2 | phosphorescent | P-4 | −0.21 | 30.8 | 6.4 | 2.2 |
| Example 2 | | compound A | | | | | |
| Comparative | P-1 | phosphorescent | P-7 | −0.22 | 34.5 | 5.9 | 3.3 |
| Example 3 | | compound A | | | | | |
| Comparative | P-2 | phosphorescent | P-7 | −0.21 | 30.9 | 6.1 | 2.9 |
| Example 4 | | compound A | | | | | |

Next, examples of the second group of inventions will be illustrated.

The number-average molecular weight and the weight-average molecular weight, the polystyrene-equivalent number-average molecular weight and weight-average molecular weight were measured by size exclusion chromatography (SEC). SEC using an organic solvent as the mobile phase is called gel permeation chromatography (GPC). Molecular weight measurement by GPC was carried out according to the following (GPC-condition 1) or (GPC-condition 2).

### (GPC-Condition 1)

The polymer to be measured was dissolved at a concentration of about 0.05 wt % in tetrahydrofuran, and 30 μL of the solution was injected into GPC (manufactured by Shimadzu Corp., trade name: LC-10Avp). Tetrahydrofuran was used as the mobile phase of GPC, and flowed at a flow rate of 0.6 mL/min. As the column, two columns of TSKgel SuperHM-H (manufactured by Tosoh Corp.) and one column of TSKgel SuperH2000 (manufactured by Tosoh Corp.) were serially connected. As the detector, a differential refractive index detector (manufactured by Shimadzu Corp., trade name: RID-10A) was used.

### (GPC-Condition 2)

The polymer to be measured was dissolved at a concentration of about 0.05 wt % in tetrahydrofuran, and 10 μL of the solution was injected into GPC (manufactured by Shimadzu Corp., trade name: LC-10Avp). Tetrahydrofuran was used as the mobile phase of GPC, and flowed at a flow rate of 2.0 mL/min. As the column, PLgel MIXED-B (manufactured by Polymer Laboratories) was used. As the detector, a UV-VIS detector (manufactured by Shimadzu Corp., trade name: SPD-10Avp) was used.

LC-MS measurement was carried out according to the following method. A measurement sample was dissolved at a concentration of about 2 mg/mL in chloroform or tetrahydrofuran, an 1 μL of the solution was injected into LC-MS (manufactured by Agilent Technologies, trade name: 1100LCMSD). Ion exchanged water, acetonitrile, tetrahydrofuran and a mixture solution thereof were used as the mobile phase of LC-MS, and if necessary, acetic acid was added. As the column, L-column 2 ODS (3 μm) (manufactured by Chemicals Evaluation and Research Institute, Japan, internal diameter: 2.1 mm, length: 100 mm, particle size 3 μm) was used.

TLC-MS measurement was carried out according to the following method. A measurement sample was dissolved in chloroform, toluene or tetrahydrofuran, and the resultant solution was coated in small amount on the surface of a previously cut TLC glass plate (manufactured by Merck, trade name: Silica gel 60 F₂₅₄). This was measured by TLC-MS (manufactured by JEOL Ltd., trade name: JMS-T100TD) using a helium gas heated at 240 to 350° C.

A measurement sample (5 to 20 mg) was dissolved in about 0.5 mL of deuterated chloroform and subjected to measurement of NMR using an NMR instrument (manufactured by Varian, Inc., trade name: MERCURY 300).

### Synthesis Example α-1

### Synthesis of Compound α-M-1

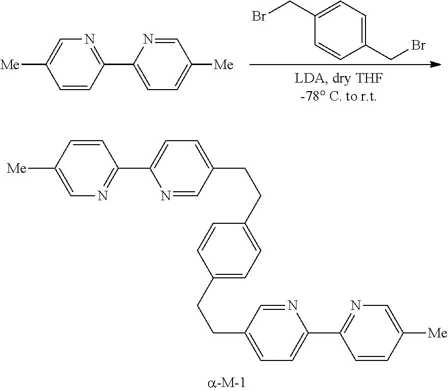

To an argon-purged 2 L four-necked flask were added 20 g (109 mmol) of 5,5′-dimethyl-2,2′-bipyridine and 400 mL of dehydrated THF, and the mixture was cooled down to −78° C. while stirring. Into this, a solution prepared by diluting 105 mL (113 mmol) of a 1.08M hexane/THF mixed solution of lithiumdiisopropylamide (LDA) with 100 mL of dehydrated THF was dropped. After completion of dropping, the mixture was stirred at 0° C. for 1.5 hours. The reaction solution was cooled again down to −78° C., then, a solution prepared by dissolving 11.9 g (45.2 mmol) of 1,4-bis(bromomethyl)benzene in 100 mL dehydrated THF was dropped, and after completion of dropping, the mixture was stirred at −78° C. for 2 hours. Thereafter, the mixture was stirred at room temperature for 1 hour, and about 20 mL of ion exchanged water was added, to stop the reaction. From the reaction solution, the solvent was distilled off under reduced pressure, the resultant residue was dispersed in ion exchanged water, and an insoluble red solid was filtrated. This red solid was washed with methanol, further, only an insoluble component was taken out. This was purified by middle pressure preparative chromatography (eluate CHCl₃:hexane:Et₃N=90:9:1 (volume ratio), stationary phase: silica gel), and further, a liquid separation operation was carried out using ion exchanged water and toluene containing 5% by volume of ethylenediamine. The organic layer was dehydrated over anhydrous sodium sulfate, then, filtrated. To the filtrate was added activated carbon, and the mixture was stirred at 80° C. for 30 minutes while heating, and filtrated under suction with heating. The resultant filtrate was distilled off under reduced pressure, to obtain 4 g of a white powder. This white powder was dispersed in 100 mL of acetonitrile, and an insoluble component was filtrated, dried at 60° C. under reduced pressure, to obtain 3 g of a compound α-M-1.

¹H-NMR (300 MHz, CDCl₃): δ 2.38 (s, 6H), 2.94 (br, 8H), 7.07 (s, 4H), 7.54 (d, J=8.1 Hz, 2H), 7.60 (d, J=8.1 Hz, 2H), 8.25 (d, J=8.1 Hz, 4H), 8.45 (s, 2H), 8.49 (s, 2H)

¹³C-NMR (75.5 MHz, CDCl₃): δ 18.47, 34.89, 37.14, 120.46, 120.49, 128.71, 133.19, 136.84, 137.04, 137.53, 138.75, 149.42, 149.69, 153.85, 154.34

TLC-MS (DART, positive): m/z⁺=471 [M+H]⁺

### Synthesis Example α-2

### Synthesis of Compound α-M-2

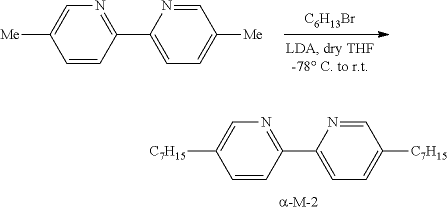

To an argon-purged 2 L four-necked flask were added 9.0 g (49 mmol) of 5,5′-dimethyl-2,2′-bipyridine and 430 mL of dehydrated THF, and the mixture was cooled down to −78° C. while stirring. Into this, a solution prepared by diluting 100 mL (107 mmol) of a 1.08M hexane/THF mixed solution of lithiumdiisopropylamide with 100 mL of dehydrated THF was dropped. After completion of dropping, the mixture was stirred at 0° C. for 1.5 hours. The reaction solution was cooled again down to −78° C., then, a solution prepared by diluting 11.9 g (107 mmol) of 1-bromohexane with 100 mL dehydrated THF was dropped, and after completion of dropping, the mixture was stirred at −78° C. for 2 hours. Thereafter, the mixture was stirred at room temperature for 1 hour, and about 20 mL of ion exchanged water was added, to stop the reaction. From the reaction solution, the solvent was distilled off under reduced pressure, the resultant residue was dispersed in 50 mL of diethyl ether, and washed with a sodium chloride aqueous solution three times. The organic layer was dehydrated over anhydrous sodium sulfate, and the solvent was distilled off under reduced pressure, to obtain a pale yellow viscous liquid. This viscous liquid was purified by middle pressure preparative chromatography (eluate CHCl₃, stationary phase: silica gel), to obtain about 6.3 g of a yellowish viscous solid. This viscous solid was dissolved in 10 mL of ethanol, and the solution was cooled down to about −30° C., and the deposited crystal was filtrated, and dried at room temperature under reduced pressure, to obtain 6 g (yield 35%) of a compound α-M-2 (melting point 47° C.) as a colorless plate-like crystal.

¹H-NMR (300 MHz, CDCl₃): δ 0.88 (t, J=6.5 Hz, 6H), 1.26-1.37 (m, 16H), 1.60-1.70 (m, 4H), 2.65 (t, J=7.5 Hz, 4H), 7.60 (d, J=8.1 Hz, 2H), 8.26 (d, J=8.1 Hz, 2H), 8.48 (s, 2H)

¹³C-NMR (75.5 MHz, CDCl₃): δ 14.07, 22.62, 29.08, 31.09, 31.76, 32.83, 120.35, 136.70, 137.85, 149.25, 153.99

TLC-MS (DART, positive): m/z⁺=353 [M+H]⁺

### Synthesis Example α-3

### Synthesis of Compound α-M-3

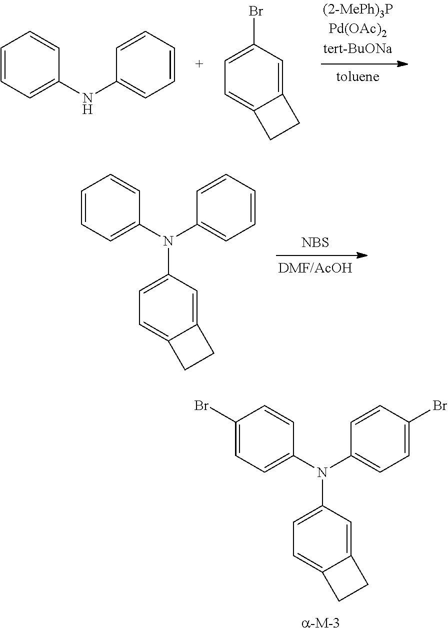

Into a nitrogen-purged 500 mL three-necked round bottom flask, 196 mg of palladium(II) acetate, 731 mg of tris(2-methylphenyl)phosphine and 100 mL of toluene were charged, and the mixture was stirred at room temperature. To the reaction solution were added 20.0 g of diphenylamine, 23.8 g of 3-bromobicyclo[4.2.0]octa-1,3,5-triene and 400 mL of toluene, subsequently, 22.8 g of sodium-tert-butoxide, and the mixture was refluxed with heating for 22 hours. To this was added 30 mL of 1M hydrochloric acid, to stop the reaction. The resultant reaction mixture was washed with 100 mL of a 2M sodium carbonate aqueous solution, the organic layer was passed through alumina, the eluate was collected, and from this, the solvent was distilled off under reduced pressure. To the resultant yellow oily residue was added isopropyl alcohol, then, the mixture was stirred, and the generated precipitate was filtrated. This precipitate was recrystallized from isopropyl alcohol, to obtain 3-N,N-diphenylaminobicyclo[4.2.0]octa-1,3,5-triene. Into a 250 mL round bottom flask, 3-N,N-diphenylaminobicyclo[4.2.0]octa-1,3,5-triene (8.00 g) and 100 mL of dimethylformamide (DMF) containing five drops of glacial acetic acid were charged and stirred. To this was added N-bromosuccinimide (NBS) (10.5 g), and the mixture was stirred for 5 hours. The resultant reaction mixture was poured into 600 mL of methanol/water (volume ratio 1/1), to stop the reaction, generating a precipitate. This precipitate was filtrated, and recrystallized from isopropyl alcohol, to obtain a compound α-M-3.

¹H NMR (300 MHz, CDCl₃): δ 3.11-3.15 (m, 4H), 6.80 (br, 1H), 6.87-6.92 (m, 5H), 6.96 (d, 1H), 7.27-7.33 (m, 4H)

### Synthesis Example α-4

### Synthesis of Compound α-M-4

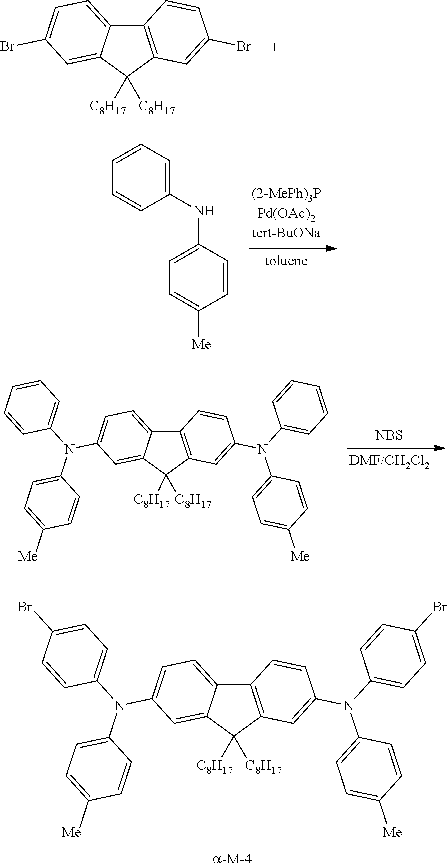

Into a nitrogen-purged reactor, 0.90 g of palladium(II) acetate, 2.435 g of tris(2-methylphenyl)phosphine and 125 mL of toluene were charged, and the mixture was stirred at room temperature for 15 minutes. To this were added 27.4 g of 2,7-dibromo-9,9-dioctylfluorene, 22.91 g of (4-methylphenyl)phenylamine and 19.75 g of sodium-tert-butoxide, and the mixture was refluxed with heating overnight, then, cooled down to room temperature, and 300 mL of water was added and washing thereof was performed. The organic layer was taken out and the solvent was distilled off under reduced pressure. The residue was dissolved in 100 mL of toluene, and the resultant solution was passed through an alumina column. The eluate was concentrated under reduced pressure, and to this was added methanol, to cause generation of a precipitate. The precipitate was filtrated, and recrystallized from p-xylene. This crystal was re-dissolved in 100 mL of toluene, and the resultant solution was passed through an alumina column. The eluate was concentrated to 50 to 100 mL, then, poured into 250 mL of methanol under stirring, to find generation of a precipitate. The precipitate was collected, dried at room temperature under reduced pressure for 18 hours, to obtain white 2,7-bis[N-(4-methylphenyl)-N-phenyl]amino-9,9-dioctylfluorene (25.0 g).

Into a nitrogen-purged reactor were added 12.5 g of 2,7-bis[N-(4-methylphenyl)-N-phenyl]amino-9,9-dioctylfluorene and 95 mL of dichloromethane, and the reaction solution was cooled down to −10° C. while stirring. Into this, a solution of 5.91 g of N-bromosuccinimide dissolved in 20 mL of DMF was dropped slowly. The mixture was stirred for 3.5 hours, then, mixed with 450 mL of cold methanol, the generated precipitate was filtrated, and recrystallized from p-xylene. The resultant crystal was recrystallized again using toluene and methanol, to obtain 12.1 g of a compound α-M-4 as a white solid.

¹H-NMR (300 MHz, CDCl₃): δ 0.61-0.71 (m, 4H), 0.86 (t, J=6.8 Hz, 6H), 0.98-1.32 (m, 20H), 1.72-1.77 (m, 4H), 2.32 (br, 6H), 6.98-7.08 (m, 16H), 7.29 (d, J=8.3 Hz, 4H), 7.44 (br, 2H)

### Synthesis Example α-5

### Synthesis of Compound α-M-5

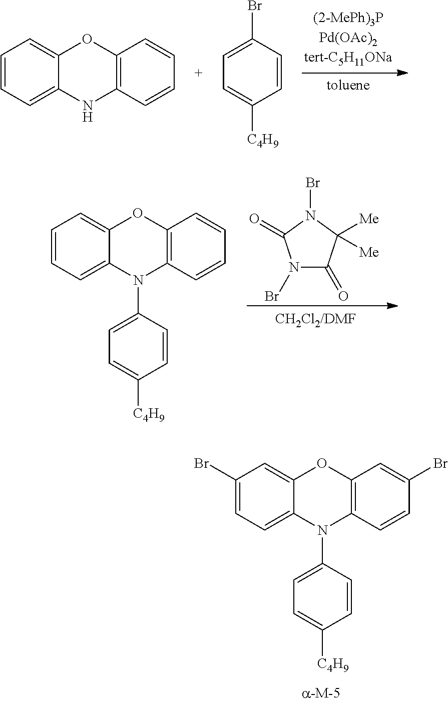

Into a nitrogen-purged 3 L four-necked flask were added 1.10 g of palladium(II) acetate, 1.51 g of tris(2-methylphenyl)phosphine and 370 mL of toluene, and the mixture was stirred at room temperature for 30 minutes. To this were added 143 g of phenoxazine, 97.1 g of sodium tert-pentoxide and 800 mL of toluene and the mixture was stirred, then, a solution prepared by dissolving 133 mL of 1-bromo-4-butylbenzene in 60 mL of toluene was dropped into the reaction vessel. The reaction solution was stirred at 105° C. for 5 hours, then, cooled down to room temperature, and filtrated through a glass filter covered with alumina. The resultant filtrate was washed with 3.5 wt % hydrochloric acid, then, the solvent was distilled off under reduced pressure. The resultant residue was recrystallized using 30 mL of toluene and 700 mL of isopropyl alcohol, to obtain 209 g of N-(4-butylphenyl)phenoxazine.

Into a nitrogen-purged 3 L four-necked flask were added 209 g of N-(4-butylphenyl)phenoxazine and 700 mL of dichloromethane, and the mixture was stirred at room temperature. Into this, 340 mL a solution prepared by dissolving 190 g of 1,3-dibromo-5,5-dimethylhydantoin in 200 mL of DMF was dropped. To the resultant reaction mixture was added methanol, the mixture was stirred for 1 hour while slowly cooling down to 10° C., and the deposited precipitate was filtrated and washed with methanol, to obtain 284 g of a compound α-M-5 as a pale white green solid.

¹H-NMR (300 MHz, CDCl₃): δ 0.97 (t, J=7.3 Hz, 3H), 1.35-1.47 (m, 2H), 1.61-1.72 (m, 2H), 2.69 (t, J=7.8 Hz, 2H), 5.76 (d, J=8.6 Hz, 2H), 6.68 (dd, J=2.2 Hz and 8.6 Hz, 2H), 6.79 (d, J=2.2 Hz, 2H), 7.16 (d, J=8.1 Hz, 2H), 7.38 (d, J=8.1 Hz, 2H)

### Synthesis Example α-6

### Synthesis of Compound α-M-6

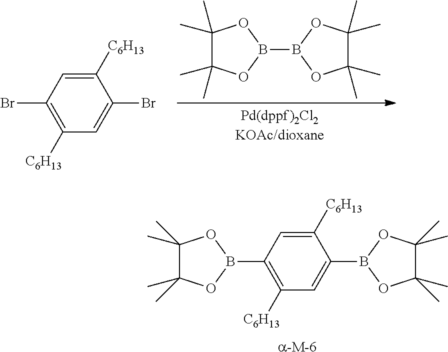

Into a 300 ml four-necked flask, 8.08 g of 1,4-dihexyl-2,5-dibromobenzene, 12.19 g of bis(pinacolate)diboron and 11.78 g of potassium acetate were charged, and an atmosphere in the flask was purged with argon. To this was charged 100 ml of dehydrated 1,4-dioxane, and the mixture was deaerated with argon. [1,1′-bis(diphenylphosphino)ferrocene]dichloropalladium(II) (Pd(dppf)₂Cl₂) (0.98 g) was charged, and the mixture was further deaerated with argon, and refluxed for 6 hours while heating. To this was added toluene, and the mixture was washed with ion exchanged water. To the organic layer after washing was added anhydrous sodium sulfate and activated carbon, and the mixture was filtrated through a funnel pre-coated with celite. The resultant filtrate was concentrated, to obtain 11.94 g of a dark brown crystal. This crystal was recrystallized from n-hexane, and the crystal was washed with methanol. The resultant crystal was dried under reduced pressure, to obtain 4.23 g of a white needle crystal of a compound α-M-6 (yield 42%).

¹H-NMR (300 MHz, CDCl₃): δ 0.88 (t, 6H), 1.23-1.40 (m, 36H), 1.47-1.56 (m, 4H), 2.81 (t, 4H), 7.52 (s, 2H)

LC-MS (ESI, positive): m/z⁺=573 [M+K]⁺

### Synthesis Example α-7

### Synthesis of Compound α-M-7

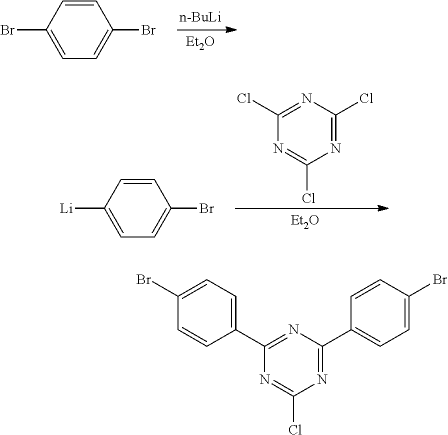

Under a nitrogen atmosphere, a solution of 27.1 g of 1,4-dibromobenzene in 217 ml of dehydrated diethyl ether was cooled by using a dry ice/methanol mixed bath. Into the resultant suspension, 37.2 ml of a 2.77M hexane solution of n-butyllithium was slowly dropped, then, the mixture was stirred for 1 hour, to prepare a lithium reagent.

Under a nitrogen atmosphere, a suspension of 10.0 g of cyanuric chloride in 68 ml of dehydrated diethyl ether was cooled by using a dry ice/methanol mixed bath, the above-described lithium reagent was added slowly, then, the mixture was warmed up to room temperature and reacted at room temperature. The resultant product was filtrated, and dried under reduced pressure. The resultant solid (16.5 g) was purified, to obtain 13.2 g of a needle crystal.

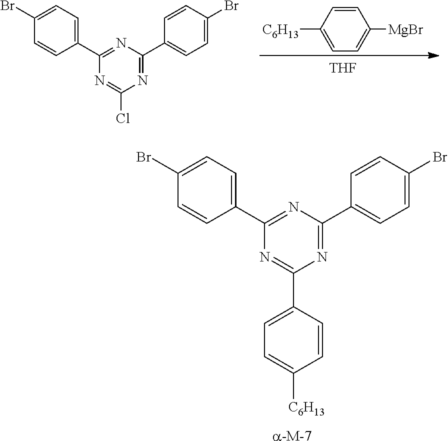

Under a nitrogen atmosphere, to a suspension prepared by adding 65 ml of dehydrated tetrahydrofuran to 1.37 g of magnesium was added bit by bit a solution of 14.2 g of 4-hexylbromobenzene in 15 ml of dehydrated tetrahydrofuran, and the mixture was heated, and stirred under reflux. After standing to cool, to the reaction solution was added 0.39 g of magnesium additionally, and the mixture was heated again, and reacted under reflux, to prepare a Grignard reagent.

Under a nitrogen atmosphere, to a suspension of 12.0 g of the above-described needle crystal in 100 ml of dehydrated tetrahydrofuran was added the above-described Grignard reagent while stirring, and the mixture was refluxed with heating. After standing to cool, the reaction liquid was washed with a dilute hydrochloric acid aqueous solution. It was separated into an organic layer and an aqueous layer, and the aqueous layer was extracted with diethyl ether. The resultant organic layers were combined, washed with water again, the organic layer was dehydrated over anhydrous magnesium sulfate, then, filtrated and concentrated. The resultant white solid was purified by a silica gel column, and further recrystallized, to obtain 6.5 g of a compound α-M-7 as a white solid.

¹H-NMR (300 MHz, CDCl₃): δ 0.90 (t, J=6.2 Hz, 3H), 1.25-1.42 (m, 6H), 1.63-1.73 (m, 2H), 2.71 (t, J=7.6 Hz, 2H), 7.34 (d, J=7.9 Hz, 2H), 7.65 (d, J=7.9 Hz, 4H), 8.53-8.58 (m, 6H)

LC-MS (APCI, positive): m/z⁺=566 [M+H]⁺

### Synthesis Example α-8

### Synthesis of Light Emitting Material A: Synthesis of Iridium Complex

An iridium complex was synthesized according to a synthesis method described in WO02/066552. That is, under a nitrogen atmosphere, 2-bromopyridine and 1.2 equivalent of 3-bromophenylboric acid were subjected to the Suzuki coupling (catalyst: tetrakis(triphenylphosphine)palladium(0), base: 2M sodium carbonate aqueous solution, solvent: ethanol, toluene), to obtain 2-(3′-bromophenyl)pyridine represented by the following formula:

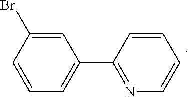

Next, under a nitrogen atmosphere, tribromobenzene and 2.2 equivalent of 4-tert-butylphenylboric acid were subjected to the Suzuki coupling (catalyst: tetrakis(triphenylphosphine)palladium(0), base: 2M sodium carbonate aqueous solution, solvent: ethanol, toluene), to obtain a bromo compound represented by the following formula:

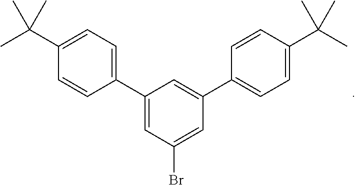

Under a nitrogen atmosphere, this bromo compound was dissolved in dehydrated THF, then, the resultant solution was cooled down to −78° C., and a small excess amount of tert-butyllithium was dropped. Under cooling, B(OC₄H₉)₃ was further dropped, and reacted at room temperature. The reaction solution was post-treated with 3M hydrochloric acid, to obtain a boric acid compound represented by the following formula:

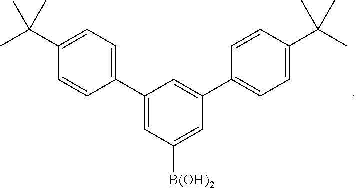

2-(3′-bromophenyl)pyridine and 1.2 equivalent of the above-described boric acid compound were subjected to the Suzuki coupling (catalyst: tetrakis(triphenylphosphine)palladium(0), base: 2M sodium carbonate aqueous solution, solvent: ethanol, toluene), to obtain ligand (that is, a compound acting as a ligand) represented by the following formula:

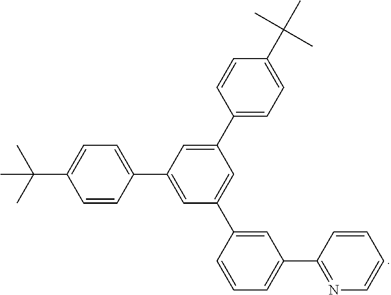

Under an argon atmosphere, IrCl₃.3H₂O, 2.2 equivalent of the above-described ligand, 2-ethoxyethanol and ion exchanged water were charged, and refluxed. The deposited solid was filtrated under suction. The resultant solid was washed with ethanol and ion exchanged water in this order, then, dried to obtain a yellow powder represented by the following formula:

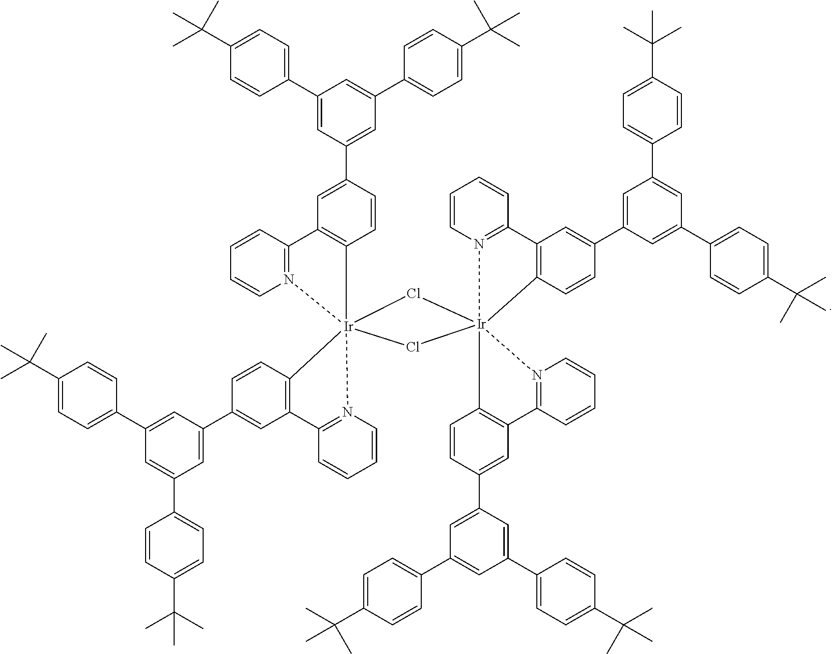

Under an argon atmosphere, to the above-described yellow powder were added 2 equivalent of the above-described ligand and 2 equivalent of silver trifluoromethanesulfonate, and the mixture was heated in diethylene glycol dimethyl ether, to obtain an iridium complex (hereinafter, referred to as “light emitting material A”) represented by the following formula:

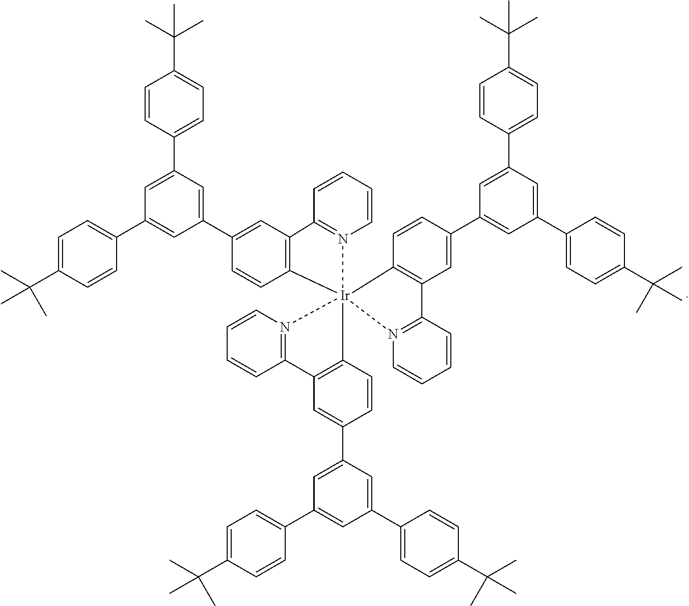

¹H-NMR (300 MHz, CDCl₃): δ 1.38 (s, 54H), 6.93 (dd, J=6.3 Hz/6.6 Hz, 3H), 7.04 (br, 3H), 7.30 (d, J=7.9 Hz, 3H), 7.48 (d, J=7.3 Hz, 12H), 7.61-7.70 (m, 21H), 7.82 (s, 6H), 8.01 (s, 3H), 8.03 (d, J=7.9 Hz, 3H)

LC-MS (APCI, positive): m/z⁺=1677 [M+H]⁺

### Synthesis Example α-9

### Synthesis of Polymer Compound α-P-1

Into a nitrogen-purged reaction vessel, 17.57 g (33.13 mmol) of 2,7-bis(1,3,2-dioxaborolan-2-yl)-9,9-dioctylfluorene, 12.88 g (28.05 mmol) of bis(4-bromophenyl)(4-sec-butylphenyl)amine, 2.15 g (5.01 mmol) of the compound α-M-3, 3 g of methyltrioctylammonium chloride (trade name: Aliquat336, manufactured by Aldrich) and 200 g of toluene were measured and charged. The reaction vessel was heated at 100° C., and 7.4 mg of palladium(II) acetate, 70 mg of tris(2-methylphenyl)phosphine and 64 g of an about 18 wt % sodium carbonate aqueous solution were added, and the mixture was stirred while heating for 3 hours or more. Thereafter, 400 mg of phenylboronic acid was added, and further, the mixture was stirred while heating for 5 hours. The reaction solution was diluted with 1900 g of toluene, and washed with 60 g of a 3 wt % acetic acid aqueous solution twice and with 60 g of ion exchanged water once, then, the organic layer was taken out and to this was added 1.5 g of sodium diethyldithiocarbamate trihydrate, and the mixture was stirred for 4 hours. The resultant solution was purified by column chromatography using an equal mixture of alumina and silica gel as the stationary phase. The resultant eluate was dropped into methanol, stirred, then, the resultant precipitate was filtrated and dried, to obtain a polymer compound α-P-1. The polymer compound α-P-1 had a polystyrene-equivalent number-average molecular weight of 8.9×10⁴ and a polystyrene-equivalent weight-average molecular weight of 4.2×10⁵ (GPC-condition 1).

The polymer compound α-P-1 is a copolymer containing a repeating unit represented by the following formula:

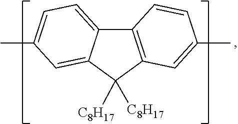

a repeating unit represented by the following formula:

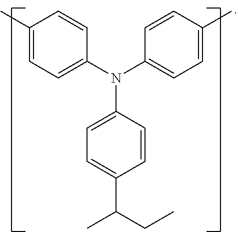

and a repeating unit represented by the following formula:

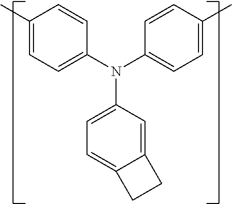

at a molar ratio of 50:42:8, according to the theoretical value calculated from the charged raw materials.

### Synthesis Example α-10

### Synthesis of Polymer Compound α-P-2

A polymer compound α-P-2 was synthesized in the same manner as in Synthesis Example α-9 excepting that the compound α-M-4 was used instead of bis(4-bromophenyl)(4-sec-butylphenyl)amine, and 2,7-bis(1,3,2-dioxaborolan-2-yl)-9,9-dioctylfluorene, the compound α-M-4 and the compound α-M-3 were used at a molar ratio of 50:42:8, in Synthesis Example α-9. The polymer compound α-P-2 had a polystyrene-equivalent number-average molecular weight of 6.0×10⁴ and a polystyrene-equivalent weight-average molecular weight of 4.0×10⁵(GPC-condition 1).

The polymer compound α-P-2 is a copolymer containing a repeating unit represented by the following formula:

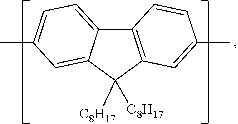

a repeating unit represented by the following formula:

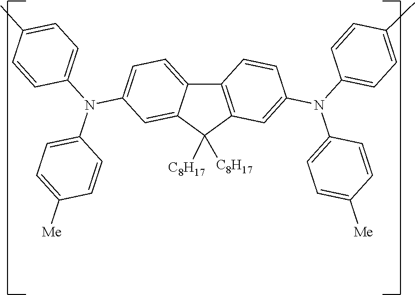

and a repeating unit represented by the following formula:

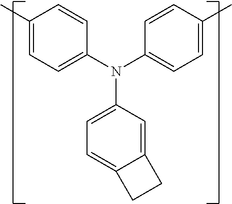

at a molar ratio of 50:42:8, according to the theoretical value calculated from the charged raw materials.

### Synthesis Example α-11

### Synthesis of Polymer Compound α-P-3

A polymer compound α-P-3 was synthesized in the same manner as in Synthesis Example α-9 excepting that the compound α-M-5 was used instead of bis(4-bromophenyl)-(4-sec-butylphenyl)-amine, and 2,7-bis(1,3,2-dioxaborolan-2-yl)-9,9-dioctylfluorene, the compound α-M-5 and the compound α-M-3 were used at a molar ratio of 50:42:8 in Synthesis Example α-9. The polymer compound α-P-3 had polystyrene-equivalent number-average molecular weight of 6.0×10⁴ and a polystyrene-equivalent weight-average molecular weight of 2.3×10⁵(GPC-condition 1).

The polymer compound α-P-3 is a copolymer containing a repeating unit represented by the following formula:

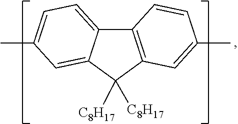

a repeating unit represented by the following formula:

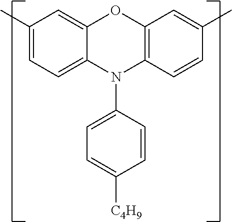

and a repeating unit represented by the following formula:

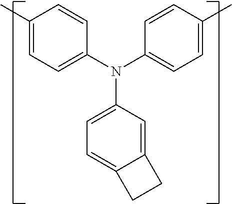

at a molar ratio of 50:42:8, according to the theoretical value calculated from the charged raw materials.

### Synthesis Example α-12

### Synthesis of Polymer Compound α-P-4

Under a nitrogen atmosphere, 3.13 g of the compound α-M-6, 0.70 g of the compound α-M-7, 2.86 g of 2,7-dibromo-9,9-dioctylfluorene, 2.1 mg of palladium(II) acetate, 13.4 mg of tris(2-methoxyphenyl)phosphine and 80 mL of toluene were mixed, and the mixture was heated at 100° C. while stirring. Into the reaction solution, 21.5 ml of a 20 wt % tetraethylammonium hydroxide aqueous solution was dropped, and the mixture was refluxed for 5 hours. To reaction solution were added 78 mg of phenylboric acid, 2.1 mg of palladium(II) acetate, 13.3 mg of tris(2-methoxyphenyl)phosphine, 6 mL of toluene and 21.5 ml of a 20 wt % tetraethylammonium hydroxide aqueous solution, and further, the mixture was refluxed for 17.5 hours. Then, to this was added 70 ml of a 0.2M sodium diethyldithiocarbamate aqueous solution, and the mixture was stirred at 85° C. for 2 hours. The reaction solution was cooled down to room temperature, and washed with 82 ml of water three times, with 82 ml of a 3 wt % acetic acid aqueous solution three times and with 82 ml of water three times. The organic layer was dropped into 1000 ml methanol, to find generation of a precipitate, and this precipitate was filtrated, then, dried, to obtain a solid. This solid was dissolved in toluene, and purified by passing through an alumina column and a silica gel column. The resultant eluate was dropped into 1500 ml of methanol, and the resultant precipitate was filtrated and dried, to obtain 3.43 g of a polymer compound α-P-4. The polymer compound α-P-4 had a polystyrene-equivalent number-average molecular weight of 1.9×10⁵ and a polystyrene-equivalent weight-average molecular weight of 5.7×10⁵(GPC-condition

The polymer compound α-P-4 is a copolymer containing a repeating unit represented by the following formula:

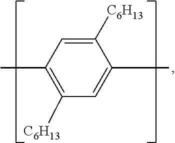

a repeating unit represented by the following formula:

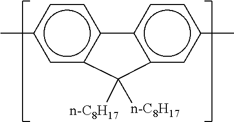

and a repeating unit represented by the following formula:

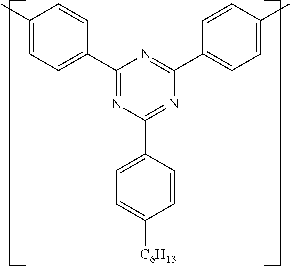

at a molar ratio of 50:40:10, according to the theoretical value calculated from the charged raw materials.

### Synthesis Example α-13

### Synthesis of Polymer Compound α-P-5

Under a nitrogen atmosphere, 3.13 g of the compound α-M-6, 3.58 g of 2,7-dibromo-9,9-dioctylfluorene, 2.2 mg of palladium(II) acetate, 13.4 mg of tris(2-methoxyphenyl)phosphine and 80 mL of toluene were mixed, and heated at 100° C. Into the reaction solution, 21.5 ml of a 20 wt % tetraethylammonium hydroxide aqueous solution was dropped, and the mixture was refluxed for 4.5 hours. After the reaction, to this were added 78 mg of phenylboric acid, 2.2 mg of palladium(II) acetate, 13.4 mg of tris(2-methoxyphenyl)phosphine, 20 mL of toluene and 21.5 ml of a 20 wt % tetraethylammonium hydroxide aqueous solution, and further, the mixture was refluxed for 15 hours. Then, to this was added 70 ml of a 0.2M sodium diethyldithiocarbamate aqueous solution, and the mixture was stirred at 85° C. for 2 hours. The reaction solution was cooled down to room temperature, and washed with 82 ml of water three times, with 82 ml of a 3 wt % acetic acid aqueous solution three times and with 82 ml of water three times. The organic layer was dropped into 1200 ml of methanol to find generation of a precipitate, and this precipitate was filtrated, then, dried, to obtain a solid. This solid was dissolved in toluene, and purified by passing through an alumina column and a silica gel column. The resultant eluate was dropped into 1500 ml of methanol, to obtain 3.52 g of a polymer compound α-P-5. The polymer compound α-P-5 had a polystyrene-equivalent number-average molecular weight of 3.0×10⁵ and a polystyrene-equivalent weight-average molecular weight of 8.4×10⁵(GPC-condition 1).

The polymer compound α-P-5 is a copolymer composed of a repeating unit represented by the following formula:

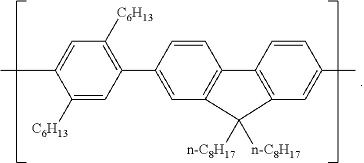

### Synthesis Example α-14

### Synthesis of Compound α-M-8

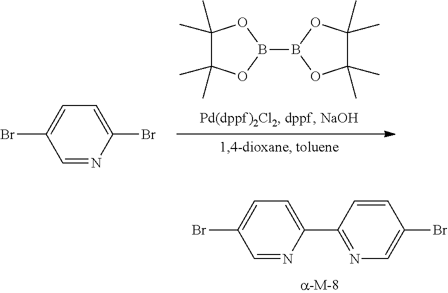

Under an inert gas atmosphere, 37.0 g of bis(pinacolate)diboron, 103.5 g of 2,5-dibromopyridine, 7.14 g of [1,1′-bis(diphenylphosphino)ferrocene]dichloropalladium(II) (Pd(dppf)₂Cl₂), 4.85 g of 1,1′-bis(diphenylphosphino)ferrocene (dppf), 35.0 g of sodium hydroxide and 568 mL of 1,4-dioxane were stirred at 100 to 105° C. for 95 hours. The reaction solution was cooled down to room temperature, then, 460 mL of toluene was added, and the mixture was stirred at room temperature for 20 minutes. The resultant solution was filtrated through a filtration apparatus paved with silica gel, and the filtrate was concentrated to dryness, obtaining a solid. Recrystallization of the solid was repeated, then, the resultant solid was filtrated with heating using acetonitrile (650 mL), and the resultant filtrate was concentrated to dryness. The resultant solid was recrystallized from chloroform, to obtain 1.17 g of a compound α-M-8 (yield 3%, HPLC area percentage 99.5%, GC area percentage 99.2%).

¹H-NMR (299.4 MHz, CDCl₃): 7.94 (d, 2H), 8.29 (d, 2H), 8.71 (s, 2H)

LC-MS (APPI (positive)): m/z⁺=313[M+H]⁺

### Synthesis Example α-15

### Synthesis of Polymer Compound P-6

In a nitrogen-purged reaction vessel, 1.04 g (1.62 mmol) of 2,7-bis(1,3,2-dioxaborolan-2-yl)-9,9-dioctylfluorene, 0.48 g (1.05 mmol) of bis(4-bromophenyl)(4-sec-butylphenyl)amine, 0.10 g (0.23 mmol) of the compound α-M-3, 0.10 g (0.32 mmol) of the compound α-M-8, 0.5 mg of palladium(II) acetate, 3.6 mg of tris(2-methoxyphenyl)phosphine and 32 mL of toluene were mixed, and heated at 100° C. Into the reaction solution, 5.5 ml of a 20 wt % tetraethylammonium hydroxide aqueous solution was dropped, and the mixture was refluxed for 5 hours. After the reaction, to this were added 20 mg of phenylboric acid, 0.5 mg of palladium(II) acetate, 3.4 mg of tris(2-methoxyphenyl)phosphine, 3 mL of toluene and 5.6 ml of a 20 wt % tetraethylammonium hydroxide aqueous solution, and further, the mixture was refluxed for 17 hours. Then, to this was added 18 ml of a 0.2M sodium diethyldithiocarbamate aqueous solution, and the mixture was stirred at 85° C. for 2 hours. The reaction solution was cooled down to room temperature, and washed with 25 ml of water twice, with 25 ml of a 3 wt % acetic acid aqueous solution twice and with 25 ml of water three times. The organic layer was dropped into 200 ml methanol to find generation of a precipitate. This precipitate was filtrated, then, dried, to obtain a solid. This solid was dissolved in toluene, and purified by passing through an alumina column and a silica gel column. The resultant eluate was dropped into 300 ml of methanol, to obtain 0.77 g of a polymer compound α-P-6. The polymer compound α-P-6 had a polystyrene-equivalent number-average molecular weight of 1.8×10⁴ and a polystyrene-equivalent weight-average molecular weight of 6.6×10⁴(GPC-condition 2).

The polymer compound α-P-6 is a copolymer containing a repeating unit represented by the following formula:

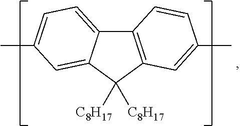

a repeating unit represented by the following formula:

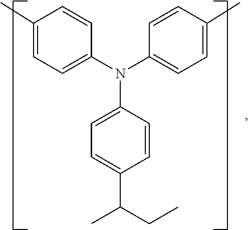

a repeating unit represented by the following formula:

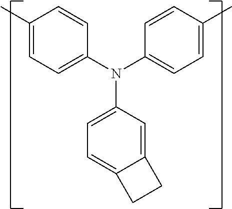

and a repeating unit represented by the following formula:

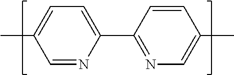

at a molar ratio of 50:32:7:10, according to the theoretical value calculated from the charged raw materials.

### Example α-1

### Fabrication of Organic Electroluminescent Device α-1

On a glass substrate carrying thereon an ITO film having a thickness of 150 nm formed by a sputtering method, a suspension of poly(3,4)ethylenedioxythiophene/polystyrenesulfonic acid (Manufactured by H. C. Starck, trade name: CLEVIOS P AI4083) (hereinafter, referred to as, “CLEVIOS P”) was placed, and spin-coated to form a film having a thickness of about 65 nm, and dried on a hot plate at 200° C. for 10 minutes. Next, the polymer compound α-P-1 and the compound α-M-1 were dissolved at a concentration of 0.7 wt % (weight ratio: polymer compound α-P-1/compound α-M-1=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), and the film was dried at 180° C. for 60 minutes. Next, the polymer compound α-P-5 and the light emitting material A were dissolved at a concentration of 1.1 wt % (weight ratio: polymer compound α-P—S/light emitting material A=70/30) in xylene (manufactured by Kanto Chemical Co., Inc.: for Electronics (EL grade)). The resultant xylene solution was placed on the film of the polymer compound α-P-1/compound α-M-1, and spin-coated to form a light emitting layer α-1 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-1, then, aluminum was vapor-deposited with a thickness of about 60 nm on the barium layer, as a cathode. After vapor deposition, encapsulation was performed using a glass substrate, to fabricate an organic electroluminescent device α-1.

Voltage was applied to the organic electroluminescent device α-1, to observe electroluminescence of green light emission. The light emission efficiency at a luminance of 1000 cd/m² was 26.8 cd/A, and the voltage under this condition was 9.3 V. When voltage was applied after half life of luminance, the voltage at a luminance of 1000 cd/m² was 12.0 V. The increase in voltage at 1000 cd/m² was 2.7 V.

### Example α-2

### Fabrication of Organic Electroluminescent Device α-2

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-1 and the compound α-M-1 were dissolved at a concentration of 0.7 wt % (weight ratio: polymer compound α-P-1/compound α-M-1=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-1/compound α-M-1, and spin-coated to form a light emitting layer α-2 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about nm on the film of the light emitting layer α-2, then, aluminum was vapor-deposited with a thickness of about 60 nm on the barium layer, as a cathode. After vapor deposition, encapsulation was performed using a glass substrate, to fabricate an organic electroluminescent device α-2.

Voltage was applied to the organic electroluminescent device α-2, to observe electroluminescence of green light emission. The light emission efficiency at a luminance of 1000 cd/m² was 26.0 cd/A, and the voltage under this condition was 6.6 V. When voltage was applied after half life of luminance, the voltage at a luminance of 1000 cd/m² was 8.1 V. The increase in voltage at 1000 cd/m² was 1.5 V.

### Example α-3

### Fabrication of Organic Electroluminescent Device α-3

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-1 and the compound α-M-2 were dissolved at a concentration of 0.7 wt % (weight ratio: polymer compound α-P-1/compound α-M-2=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-1/compound α-M-2, and spin-coated to form a light emitting layer α-3 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-3, then, aluminum was vapor-deposited with a thickness of about 60 nm on the barium layer, as a cathode. After vapor deposition, encapsulation was performed using a glass substrate, to fabricate an organic electroluminescent device α-3.

Voltage was applied to the organic electroluminescent device α-3, to observe electroluminescence of green light emission. The light emission efficiency at a luminance of 1000 cd/m² was 32.2 cd/A, and the voltage under this condition was 6.5 V. When voltage was applied after half life of luminance, the voltage at a luminance of 1000 cd/m² was 9.0 V. The increase in voltage at 1000 cd/m² was 2.5 V.

### Example α-4

### Fabrication of Organic Electroluminescent Device α-4

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-1 and the 3,3′-dihydroxy-2,2′-bipyridine were dissolved at a concentration of 0.7 wt % (weight ratio: polymer compound α-P-1/3,3′-dihydroxy-2,2′-bipyridine=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-1/3,3′-dihydroxy-2,2′-bipyridine, and spin-coated to form a light emitting layer α-4 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-4, then, aluminum was vapor-deposited with a thickness of about 60 nm on the barium layer, as a cathode. After vapor deposition, encapsulation was performed using a glass substrate, to fabricate an organic electroluminescent device α-4.

Voltage was applied to the organic electroluminescent device α-4, to observe electroluminescence of green light emission. The light emission efficiency at a luminance of 1000 cd/m² was 30.8 cd/A, and the voltage under this condition was 6.1 V. When voltage was applied after half life of luminance, the voltage at a luminance of 1000 cd/m² was 8.3 V. The increase in voltage at 1000 cd/m² was 2.2 V.

### Example α-5

### Fabrication of Organic Electroluminescent Device α-5

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-2 and the compound α-M-1 were dissolved at a concentration of 0.7 wt % (weight ratio: polymer compound α-P-2/compound α-M-1=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-2/compound α-M-1, and spin-coated to form a light emitting layer α-5 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-5, then, aluminum was vapor-deposited with a thickness of about 60 nm on the barium layer, as a cathode. After vapor deposition, encapsulation was performed using a glass substrate, to fabricate an organic electroluminescent device α-5.

Voltage was applied to the organic electroluminescent device α-5, to observe electroluminescence of green light emission. The light emission efficiency at a luminance of 1000 cd/m² was 20.1 cd/A, and the voltage under this condition was 6.3 V. When voltage was applied after half life of luminance, the voltage at a luminance of 1000 cd/m² was 8.7 V. The increase in voltage at 1000 cd/m² was 2.4 V.

### Example α-6

### Fabrication of Organic Electroluminescent Device α-6)

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-2 and the compound α-M-2 were dissolved at a concentration of 0.7 wt % (weight ratio: polymer compound α-P-2/compound α-M-2=90/10) in xylene (manufactured by Kanto Chemical Co Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-2/compound α-M-2, and spin-coated to form a light emitting layer α-6 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-6, then, aluminum was vapor-deposited with a thickness of about 60 nm on the barium layer, as a cathode. After vapor deposition, encapsulation was performed using a glass substrate, to fabricate an organic electroluminescent device α-6.

Voltage was applied to the organic electroluminescent device α-6, to observe electroluminescence of green light emission. The light emission efficiency at a luminance of 1000 cd/m² was 27.4 cd/A, and the voltage under this condition was 6.2 V. When voltage was applied after half life of luminance, the voltage at a luminance of 1000 cd/m² was 8.8 V. The increase in voltage at 1000 cd/m² was 2.6 V.

### Example α-7

### Fabrication of Organic Electroluminescent Device α-7

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-2 and 3,3′-dihydroxy-2,2′-bipyridine were dissolved at a concentration of 0.7 wt % (weight ratio: polymer compound α-P-2/3,3′-dihydroxy-2,2′-bipyridine=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-2/3,3′-dihydroxy-2,2′-bipyridine, and spin-coated to form a light emitting layer α-7 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-7, then, aluminum was vapor-deposited with a thickness of about 60 nm on the barium layer, as a cathode. After vapor deposition, encapsulation was performed using a glass substrate, to fabricate an organic electroluminescent device α-7.

Voltage was applied to the organic electroluminescent device α-7, to observe electroluminescence of green light emission. The light emission efficiency at a luminance of 1000 cd/m² was 26.3 cd/A, and the voltage under this condition was 6.1 V. When voltage was applied after half life of luminance, the voltage at a luminance of 1000 cd/m² was 8.5 V. The increase in voltage at 1000 cd/m² was 2.4 V.

### Example α-8

### Fabrication of Organic Electroluminescent Device α-8

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-3 and the compound α-M-1 were dissolved at a concentration of 0.7 wt % (weight ratio: polymer compound α-P-3/compound α-M-1=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-3/compound α-M-1, and spin-coated to form a light emitting layer α-8 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-8, then, aluminum was vapor-deposited with a thickness of about 60 nm on the barium layer, as a cathode. After vapor deposition, encapsulation was performed using a glass substrate, to fabricate an organic electroluminescent device α-8.

Voltage was applied to the organic electroluminescent device α-8, to observe electroluminescence of green light emission. The light emission efficiency at a luminance of 1000 cd/m² was 14.5 cd/A, and the voltage under this condition was 7.2 V. When voltage was applied after half life of luminance, the voltage at a luminance of 1000 cd/m² was 9.1 V. The increase in voltage at 1000 cd/m² was 1.9 V.

### Example α-9

### Fabrication of Organic Electroluminescent Device α-9

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-3 and the compound α-M-2 were dissolved at a concentration of 0.7 wt % (weight ratio: polymer compound α-P-3/compound α-M-2=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-3/compound α-M-2, and spin-coated to form a light emitting layer α-9 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-9, then, aluminum was vapor-deposited with a thickness of about 60 nm on the barium layer, as a cathode. After vapor deposition, encapsulation was performed using a glass substrate, to fabricate an organic electroluminescent device α-9.

Voltage was applied to the organic electroluminescent device α-9, to observe electroluminescence of green light emission. The light emission efficiency at a luminance of 1000 cd/m² was 18.9 cd/A, and the voltage under this condition was 6.6 V. When voltage was applied after half life of luminance, the voltage at a luminance of 1000 cd/m² was 9.0 V. The increase in voltage at 1000 cd/m² was 2.4 V.

### Example α-10

### Fabrication of Organic Electroluminescent Device α-10

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-3 and 3,3′-dihydroxy-2,2′-bipyridine were dissolved at a concentration of 0.7 wt % (weight ratio: polymer compound α-P-3/3,3′-dihydroxy-2,2′-bipyridine=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-3/3,3′-dihydroxy-2,2′-bipyridine, and spin-coated to form a light emitting layer α-10 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-10, then, aluminum was vapor-deposited with a thickness of about 60 nm on the barium layer, as a cathode. After vapor deposition, encapsulation was performed using a glass substrate, to fabricate an organic electroluminescent device α-10.

Voltage was applied to the organic electroluminescent device α-10, to observe electroluminescence of green light emission. The light emission efficiency at a luminance of 1000 cd/m² was 19.3 cd/A, and the voltage under this condition was 5.9 V. When voltage was applied after half life of luminance, the voltage at a luminance of 1000 cd/m² was 8.5 V. The increase in voltage at 1000 cd/m² was 2.6 V.

### Example α-11

### Fabrication of Organic Electroluminescent Device α-11

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-6 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-6, and spin-coated to form a light emitting layer α-11 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-11, then, aluminum was vapor-deposited with a thickness of about 60 nm on the barium layer, as a cathode. After vapor deposition, encapsulation was performed using a glass substrate, to fabricate an organic electroluminescent device α-11. Voltage was applied to the organic electroluminescent device α-11, to observe electroluminescence of green light emission. The light emission efficiency at a luminance of 1000 cd/m² was 28.3 cd/A, and the voltage under this condition was 7.2 V. When voltage was applied after half life of luminance, the voltage at a luminance of 1000 cd/m² was 9.3 V. The increase in voltage at 1000 cd/m² was 2.1 V.

### Example α-12

### Fabrication of Organic Electroluminescent Device α-12

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-6 and the compound α-M-1 were dissolved at a concentration of 0.7 wt % (weight ratio: polymer compound α-P-6/compound α-M-1=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-6/compound α-M-1, and spin-coated to form a light emitting layer α-12 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-12, then, aluminum was vapor-deposited with a thickness of about 60 nm on the barium layer, as a cathode. After vapor deposition, encapsulation was performed using a glass substrate, to fabricate an organic electroluminescent device α-12.

Voltage was applied to the organic electroluminescent device α-12, to observe electroluminescence of green light emission. The light emission efficiency at a luminance of 1000 cd/m² was 21.7 cd/A, and the voltage under this condition was 6.9 V. When voltage was applied after half life of luminance, the voltage at a luminance of 1000 cd/m² was 9.2 V. The increase in voltage at 1000 cd/m² was 2.3 V.

### Example α-13

### Fabrication of Organic Electroluminescent Device α-13

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-6 and the compound α-M-2 were dissolved at a concentration of 0.7 wt % (weight ratio: polymer compound α-P-6/compound α-M-2=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-6/compound α-M-2, and spin-coated to form a light emitting layer α-13 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-13, then, aluminum was vapor-deposited with a thickness of about 60 nm on the barium layer, as a cathode. After vapor deposition, encapsulation was performed using a glass substrate, to fabricate an organic electroluminescent device α-13.

Voltage was applied to the organic electroluminescent device α-13, to observe electroluminescence of green light emission. The light emission efficiency at a luminance of 1000 cd/m² was 22.8 cd/A, and the voltage under this condition was 7.0 V. When voltage was applied after half life of luminance, the voltage at a luminance of 1000 cd/m² was 9.3 V. The increase in voltage at 1000 cd/m² was 2.3 V.

### Example α-14

### Fabrication of Organic Electroluminescent Device α-14

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-6 and 3,3′-dihydroxy-2,2′-bipyridine were dissolved at a concentration of 0.7 wt % (weight ratio: polymer compound α-P-6/3,3′-dihydroxy-2,2′-bipyridine=90/10) in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-6/3,3′-dihydroxy-2,2′-bipyridine, and spin-coated to form a light emitting layer α-14 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-14, then, aluminum was vapor-deposited with a thickness of about 60 nm on the barium layer, as a cathode. After vapor deposition, encapsulation was performed using a glass substrate, to fabricate an organic electroluminescent device α-14.

Voltage was applied to the organic electroluminescent device α-14, to observe electroluminescence of green light emission. The light emission efficiency at a luminance of 1000 cd/m² was 22.0 cd/A, and the voltage under this condition was 7.0 V. When voltage was applied after half life of luminance, the voltage at a luminance of 1000 cd/m² was 9.2 V. The increase in voltage at 1000 cd/m² was 2.2 V.

### Comparative Example α-1

### Fabrication of Organic Electroluminescent Device α-C1

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound P-1 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-5 and the light emitting material A were dissolved at a concentration of 1.1 wt % (weight ratio: polymer compound α-P-5/light emitting material A=70/30) in xylene (manufactured by Kanto Chemical Co., Inc.: for Electronics (EL grade)). The resultant xylene solution was placed on the film of the polymer compound α-P-1, and spin-coated to form a light emitting layer α-C1 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-C1, then, aluminum was vapor-deposited with a thickness of about 60 nm on the barium layer, as a cathode. After vapor deposition, encapsulation was performed using a glass substrate, to fabricate an organic electroluminescent device α-C1.

Voltage was applied to the organic electroluminescent device α-C1, to observe electroluminescence of green light emission. The light emission efficiency at a luminance of 1000 cd/m² was 29.8 cd/A, and the voltage under this condition was 8.8 V. When voltage was applied after half life of luminance, the voltage at a luminance of 1000 cd/m² was 12.1 V. The increase in voltage at 1000 cd/m² was 3.3 V.

### Comparative Example α-2

### Fabrication of Organic Electroluminescent Device α-C2

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-1 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound α-P-4/light emitting material A=70/30) in xylene (manufactured by Kanto Chemical Co., Inc.: for Electronics (EL grade)). The resultant xylene solution was placed on the film of the polymer compound α-P-1, and spin-coated to form a light emitting layer α-C2 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-C2, then, aluminum was vapor-deposited with a thickness of about 60 nm on the barium layer, as a cathode. After vapor deposition, encapsulation was performed using a glass substrate, to fabricate an organic electroluminescent device α-C2.

Voltage was applied to the organic electroluminescent device α-C2, to observe electroluminescence of green light emission. The light emission efficiency at a luminance of 1000 cd/m² was 30.8 cd/A, and the voltage under this condition was 6.4 V. When voltage was applied after half life of luminance, the voltage at a luminance of 1000 cd/m² was 9.7 V. The increase in voltage at 1000 cd/m² was 3.3 V.

### Comparative Example α-3

### Fabrication of Organic Electroluminescent Device α-C3

On a glass substrate carrying thereon an ITO film having a thickness of 150 nm formed by a sputtering method, a suspension of CLEVIOS P was placed, and spin-coated to form a film having a thickness of about 65 nm, and dried on a hot plate at 200° C. for 10 minutes. Next, the polymer compound α-P-2 was dissolved at a concentration of 0.7 wt % in xylene (manufactured by Kanto Chemical Co., Inc.: for Electronics (EL grade)), the resultant xylene solution was placed on the film of CLEVIOS P, and spin-coated to form a film having a thickness of about 20 nm, and under a nitrogen atmosphere having an oxygen concentration and a moisture concentration of each 10 ppm or less (based on weight), dried at 180° C. for 60 minutes. Next, the polymer compound α-P-4 and the light emitting material A were dissolved at a concentration of 1.5 wt % (weight ratio: polymer compound P-4/light emitting material A=70/30) in xylene (manufactured by Kanto Chemical Co., Inc.: for Electronics (EL grade)). The resultant xylene solution was placed on the film of the polymer compound α-P-2, and spin-coated to form a light emitting layer α-C3 having a thickness of about 80 nm. Then, under a nitrogen atmosphere having an oxygen concentration and a moisture concentration of each 10 ppm or less (based on weight), the film was dried at 130° C. for 10 minutes. After pressure reduction to 1.0×10⁻⁴ Pa or lower, barium was vapor-deposited with a thickness of about 5 nm on the film of the light emitting layer α-C3, then, aluminum was vapor-deposited with a thickness of about 60 nm on the barium layer, as a cathode. After vapor deposition, encapsulation was performed using a glass substrate, to fabricate an organic electroluminescent device α-C3.

Voltage was applied to the organic electroluminescent device α-C3, to observe electroluminescence of green light emission. The light emission efficiency at a luminance of 1000 cd/m² was 24.7 cd/A, and the voltage under this condition was 6.1 V. When voltage was applied after half life of luminance, the voltage at a luminance of 1000 cd/m² was 9.2 V. The increase in voltage at 1000 cd/m² was 3.1 V.

TABLE 5

| | | | voltage |
|---|---|---|---|
| | hole transporting | light emitting | increase |
| | layer | layer | (V) |
| Example α-1 | polymer compound | polymer | 2.7 |
| | α-P-1/ | compound α-P-5-/ | |
| | compound α-M-1 | light emitting | |
| | | material A | |
| Example α-2 | polymer compound | polymer | 1.5 |
| | α-P-1/ | compound α-P-4/ | |
| | compound α-M-1 | light | |
| | | emitting | |
| | | material A | |
| Example α-3 | polymer compound | polymer | 2.5 |
| | α-P-1/ | compound α-P-4/ | |
| | compound α-M-2 | light | |
| | | emitting | |
| | | material A | |
| Example α-4 | polymer compound | polymer | 2.2 |
| | α-P-1/ | compound α-P-4/ | |
| | 3,3′-dihydroxy- | light | |
| | 2,2′-bipyridine | emitting | |
| | | material A | |
| Example α-5 | polymer compound | polymer compound | 2.4 |
| | α-P-2/ | α-P-4/ | |
| | compound α-M-1 | light | |
| | | emitting | |
| | | material A | |
| Example α-6 | polymer compound | polymer | 2.6 |
| | α-P-2/ | compound α-P-4/ | |
| | compound α-M-2 | light | |
| | | emitting | |
| | | material A | |
| Example α-7 | polymer compound | polymer | 2.4 |
| | α-P-2/ | compound α-P-4/ | |
| | 3,3′-dihydroxy- | light | |
| | 2,2′-bipyridine | emitting | |
| | | material A | |
| Example α-8 | polymer compound | polymer | 1.9 |
| | α-P-3/ | compound α-P-4/ | |
| | compound α-M-1 | light | |
| | | emitting | |
| | | material A | |
| Example α-9 | polymer compound | polymer | 2.4 |
| | α-P-3/ | compound α-P-4/ | |
| | compound α-M-2 | light | |
| | | emitting | |
| | | material A | |
| Example α-10 | polymer compound | polymer | 2.6 |
| | α-P-3/ | compound α-P-4/ | |
| | 3,3′-dihydroxy- | light | |
| | 2,2′-bipyridine | emitting | |
| | | material A | |
| Example α-11 | polymer compound | polymer | 2.1 |
| | α-P-6 | compound α-P-4/ | |
| | | light | |
| | | emitting | |
| | | material A | |
| Example α-12 | polymer compound | polymer | 2.3 |
| | α-P-6/ | compound α-P-4/ | |
| | compound α-M-1 | light | |
| | | emitting | |
| | | material A | |
| Example α-13 | polymer compound | polymer | 2.3 |
| | α-P-6/ | compound α-P-4/ | |
| | compound α-M-2 | light | |
| | | emitting | |
| | | material A | |
| Example α-14 | polymer compound | polymer | 2.2 |
| | α-P-6/ | compound α-P-4/ | |
| | 3,3′-dihydroxy- | light | |
| | 2,2′-bipyridine | emitting | |
| | | material A | |
| Comparative | polymer compound | polymer | 3.3 |
| Example | α-P-1 | compound α-P-5/ | |
| α-1 | | light | |
| | | emitting | |
| | | material A | |
| Comparative | polymer compound | polymer | 3.3 |
| Example | α-P-1 | compound α-P-4/ | |
| α-2 | | light | |
| | | emitting | |
| | | material A | |
| Comparative | polymer compound | polymer | 3.1 |
| Example | α-P-2 | compound α-P-4/ | |
| α-3 | | light | |
| | | emitting | |
| | | material A | |

### INDUSTRIAL APPLICABILITY

According to the first group of inventions, an organic electroluminescent device having a long luminance life can be provided.

The organic electroluminescent device according to the second group of inventions is an organic electroluminescent device showing a suppressed increase in the driving voltage at half life of luminance when driven at a constant current value.

1. An organic electroluminescent device comprising
an anode,
a cathode,
a light emitting layer that is disposed between the anode and the cathode and contains a first light emitting layer material containing a phosphorescent compound and a second light emitting layer material containing a charge transporting polymer compound, and
a hole transporting layer that is disposed between the anode and the light emitting layer so as to be adjacent to the light emitting layer and is composed of a hole transporting polymer compound,
wherein the lowest excitation triplet energy T1ₑ (eV) of the first light emitting layer material, the lowest excitation triplet energy T1ₕ (eV) of the second light emitting layer material and the lowest excitation triplet energy T1ₜ (eV) of the hole transporting polymer compound satisfy the following formulae (A) and (B):
T1ₑ≦T1ₕ (A)
T1ₜ−T1ₑ≦0.10 (B).

2. The organic electroluminescent device according to claim 1, wherein, T1ₜ and T1ₑ further satisfy the following formula (B′):
T1ₜ−T1ₑ≦−0.30 (B′).

3. The organic electroluminescent device according to claim 1, wherein the minimum value IPₑₕ (eV) of the ionization potential of said first light emitting layer material and the ionization potential of said second light emitting layer material, and the ionization potential IPₜ (eV) of said hole transporting polymer compound satisfy the following formula (C):
IPₑₕ−IPₜ≧−0.20 (C).

4. The organic electroluminescent device according to claim 1, wherein said hole transporting polymer compound is a polymer compound containing a constitutional unit represented by the following formula (4):
Ar¹ (4)
in the formula (4), Ar¹ represents an arylene group, a divalent aromatic heterocyclic group, or a divalent group composed of two or more directly linked identical or different groups selected from the group consisting of the arylene group and the divalent aromatic heterocyclic group, wherein the group represented by Ar¹ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent;
and a constitutional unit represented by the following formula (5): 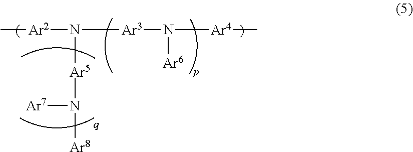
in the formula (5), Ar², Ar³, Ar⁴ and Ar⁵ each independently represent an arylene group, a divalent aromatic heterocyclic group, or a divalent group composed of two or more directly linked identical or different groups selected from the group consisting of the arylene group and the divalent aromatic heterocyclic group; Ar⁶, Ar⁷ and Ar⁸ each independently represent an aryl group or a monovalent aromatic heterocyclic group; p and q each independently represent 0 or 1, wherein the groups represented by Ar², Ar³, Ar⁴, Ar⁵, Ar⁶, Ar⁷ and Ar⁸ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent, and the groups represented by Ar⁵, Ar⁶, Ar⁷ and Ar⁸ may each be linked directly or via —O—, —S—, —C(═O)—,
—C(═O)—O—, —N(R^{A})—, —C(═O)—N(R^{A})— or —C(R^{A})₂— to the group represented by Ar², Ar³, Ar⁴, Ar⁵, Ar⁶, Ar⁷ or Ar⁸ linked to the nitrogen atom to which the groups are attached, thereby forming a 5 to 7-membered ring; R^{A} represents an alkyl group, an aryl group, a monovalent aromatic heterocyclic group or an aralkyl group.

5. The organic electroluminescent device according to claim 1, wherein said hole transporting polymer compound is a crosslinkable hole transporting polymer compound.

6. The organic electroluminescent device according to claim 1, wherein said charge transporting polymer compound is a polymer compound containing at least one constitutional unit selected from the group consisting of constitutional units represented by the following formula (4):
Ar¹ (4)
in the formula (4), Ar¹ represents an arylene group, a divalent aromatic heterocyclic group, or a divalent group composed of two or more directly linked identical or different groups selected from the group consisting of the arylene group and the divalent aromatic heterocyclic group, wherein the group represented by Ar¹ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent.]
and constitutional units represented by the following formula (5): 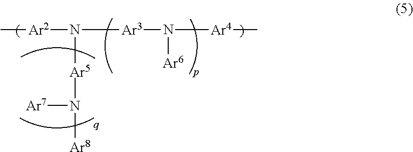
in the formula (5), Ar², Ar³, Ar⁴ and Ar⁵ each independently represent an arylene group, a divalent aromatic heterocyclic group, or a divalent group composed of two or more directly linked identical or different groups selected from the group consisting of the arylene group and the divalent aromatic heterocyclic group; Ar⁶, Ar⁷ and Ar⁸ each independently represent an aryl group or a monovalent aromatic heterocyclic group; p and q each independently represent 0 or 1, wherein the groups represented by Ar², Ar³, Ar⁴, Ar⁵, Ar⁶, Ar⁷ and Ar⁸ may have an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group as a substituent, and the groups represented by Ar⁵, Ar⁶, Ar⁷ and Ar⁸ may each be linked directly or via —O—, —S—, —C(═O)—,
—C(═O)—O—, —N(R^{A})—, —C(═O)—N(R^{A})— or —C(R^{A})₂— to the group represented by Ar², Ar³, Ar⁴, Ar⁵, Ar⁶, Ar⁷ or Ar⁸ linked to the nitrogen atom to which the groups are attached, thereby forming a 5 to 7-membered ring; R^{A} represents an alkyl group, an aryl group, a monovalent aromatic heterocyclic group or an aralkyl group.

7. The organic electroluminescent device according to claim 4, containing a constitutional unit represented by the following formula (6) and/or a constitutional unit represented by the following formula (7), as the constitutional unit represented by said formula (4): 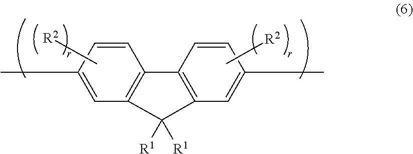
in the formula (6), each R¹ represents an alkyl group, an aryl group, a monovalent aromatic heterocyclic group or an aralkyl group; each R² represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group; each r represents an integer of 0 to 3, wherein two R′ moieties may be the same or different, and two R¹ moieties may be linked to form a ring; when a plurality of R² moieties are present, these may be the same or different; two characters of r may be the same or different, 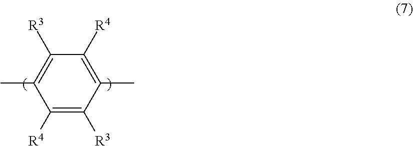
in the formula (7), each R³ represents an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group or a cyano group; each R⁴ represents a hydrogen atom, an alkyl group, an aryl group, a monovalent aromatic heterocyclic group, an alkoxy group, an aryloxy group, an aralkyl group, an arylalkoxy group, a substituted amino group, a substituted carbonyl group, a substituted carboxyl group, a fluorine atom or a cyano group, wherein two R³ moieties may be the same or different, and two R⁴ moieties may be the same or different.

8. The organic electroluminescent device according to claim 7, wherein the constitutional unit represented by said formula (4) is a constitutional unit represented by said formula (6).

9. The organic electroluminescent device according to claim 7, wherein the constitutional unit represented by said formula (4) is a constitutional unit represented by said formula (7).

10. The organic electroluminescent device according to claim 4, wherein at least one of p and q is 1 in said formula (5).

11. The organic electroluminescent device according to claim 1, wherein said phosphorescent compound is an iridium complex.

12. The organic electroluminescent device according to claim 1, having a hole injection layer between said anode and said hole transporting layer.

13. An organic electroluminescent device comprising an anode, a cathode, and a hole transporting layer and a light emitting layer disposed between the anode and the cathode,
wherein the hole transporting layer contains
1) a mixture of 2,2′-bipyridine and/or 2,2′-bipyridine derivative and a non-2,2′-bipyridinediyl group-containing hole transporting polymer compound,
2) a 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group,
or a combination thereof.

14. The organic electroluminescent device according to claim 13, wherein said non-2,2′-bipyridinediyl group-containing hole transporting polymer compound is a polymer compound represented by the following formula α-(2): 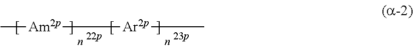
in the formula α-(2), Am^{2p} represents a divalent aromatic amine residue, and Ar^{2p} represents an unsubstituted or substituted arylene group; n^{22p} and n^{23p} each independently represent the number indicating the molar ratio of a divalent aromatic amine residue represented by Am^{2p} to an unsubstituted or substituted arylene group represented by Ar^{2p} in the polymer compound, satisfying n^{22p}+n^{23p}=1, 0.001≦n^{22p}≦1 and 0≦n^{23p}≦0.999; when a plurality of Am^{2p}s are present, these may be the same or different, and when a plurality of Ar^{2p}s are present, these may be the same or different.

15. The organic electroluminescent device according to claim 14, wherein the arylene group represented by said Ar^{2p} includes at least one member selected from the group consisting of an unsubstituted or substituted fluorenediyl group and an unsubstituted or substituted phenylene group.

16. The organic electroluminescent device according to claim 13, wherein said 2,2′-bipyridine or 2,2′-bipyridine derivative is a compound represented by the following formula α-(3): 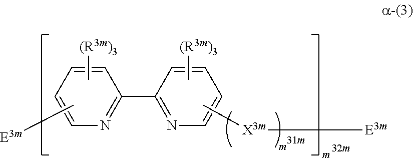
in the formula α-(3), each E^{3m} and each R^{3m} independently represent a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group; X^{3m} represents an unsubstituted or substituted arylene group, an unsubstituted or substituted alkanediyl group, an unsubstituted or substituted alkenediyl group or an unsubstituted or substituted alkynediyl group, wherein the plurality of E^{3m} moieties may be the same or different and the plurality of R^{3m} moieties may be the same or different; m^{31m} represents an integer of 0 to 3; m^{32m} represents an integer of 1 to 3, wherein when a plurality of m^{31m} moieties are present, these may be the same or different and when a plurality of X^{3m} moieties are present, these may be the same or different.

17. The organic electroluminescent device according to claim 16, wherein E^{3m} represents a hydrogen atom, a hydroxyl group, an unsubstituted or substituted alkyl group, an unsubstituted or substituted alkoxy group or an unsubstituted or substituted aryl group in said formula α-(3).

18. The organic electroluminescent device according to claim 16, wherein R^{3m} represents a hydrogen atom in said formula α-(3).

19. The organic electroluminescent device according to claim 16, wherein X^{3m} represents an unsubstituted or substituted arylene group or an unsubstituted or substituted alkanediyl group in said formula α-(3).

20. The organic electroluminescent device according to claim 16, wherein the compound represented by said formula α-(3) is a compound represented by the following formula α-(4): 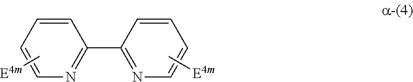
in the formula α-(4), each E^{4m} represents a hydrogen atom, a hydroxyl group, an unsubstituted or substituted alkyl group or an unsubstituted or substituted alkoxy group, wherein the plurality of E^{4m} moieties may be the same or different, and at least one of them represents a hydroxyl group, an unsubstituted or substituted alkyl group or an unsubstituted or substituted alkoxy group.

21. The organic electroluminescent device according to claim 16, wherein the compound represented by said formula α-(3) is a compound represented by the following formula α-(5): 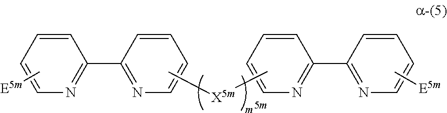
in the formula α-(5), each E^{5m} represents a hydrogen atom, a hydroxyl group, an unsubstituted or substituted alkyl group or an unsubstituted or substituted alkoxy group, wherein the plurality of E^{5m} moieties may be the same or different; X^{5m} represents an unsubstituted or substituted arylene group or an unsubstituted or substituted alkanediyl group; m^{5m} represents an integer of 1 to 3, wherein when a plurality of X^{5m}s are present, these may be the same or different.

22. The organic electroluminescent device according to claim 13, wherein said hole transporting layer contains a mixture of 2,2′-bipyridine and/or 2,2′-bipyridine derivative and a non-2,2′-bipyridinediyl group-containing hole transporting polymer compound, and the proportion of the 2,2′-bipyridine and 2,2′-bipyridine derivative contained in the hole transporting layer is 0.01 to 50 wt %.

23. The organic electroluminescent device according to claim 13, wherein said 2,2′-bipyridinediyl group-containing polymer compound is a polymer compound represented by the following formula α-(1): 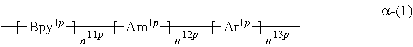
in the formula α-(1), Bpy^{1p} represents an unsubstituted or substituted 2,2′-bipyridinediyl group; Am^{1p} represents a divalent aromatic amine residue; Ar^{1p} represents an unsubstituted or substituted arylene group; n^{11p}, n^{12p} and n^{13p} each independently represent the number indicating the molar ratio of the unsubstituted or substituted 2,2′-bipyridinediyl group represented by Bpy^{1p}, the divalent aromatic amine residue represented by Am^{1p} and the unsubstituted or substituted arylene group represented by Ar^{1p} in the polymer compound, satisfying n^{11p}+n^{12p}+n^{13p}=1, 0.001≦n^{11p}≦0.999, 0.001≦n^{12p}≦0.999 and 0≦n^{13p}≦0.998; when a plurality of Bpy^{1p} moieties are present, these may be the same or different; when a plurality of Am^{1p} moieties are present, these may be the same or different, when a plurality of Ar^{1p} moieties are present, these may be the same or different.

24. The organic electroluminescent device according to claim 23, wherein Bpy^{1p} in said formula α-(1) is a divalent group represented by the following formula α-(1-2): 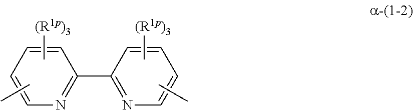
in the formula α-(1-2), each R^{1p} represents a hydrogen atom, a halogen atom, a hydroxyl group, an unsubstituted or substituted alkyl group, an unsubstituted or substituted alkenyl group, an unsubstituted or substituted alkynyl group, an unsubstituted or substituted alkoxy group, an unsubstituted or substituted alkylthio group, an unsubstituted or substituted alkylsilyl group, an unsubstituted or substituted aryl group, an unsubstituted or substituted aryloxy group or an unsubstituted or substituted arylsilyl group, wherein a plurality of R^{1p} moieties may be the same or different.

25. The organic electroluminescent device according to claim 24, wherein R^{1p} in said formula α-(1-2) is a hydrogen atom.

26. The organic electroluminescent device according to claim 13, wherein said hole transporting layer is fabricated by using
A) a first composition containing said mixture of 2,2′-bipyridine and/or 2,2′-bipyridine derivative and a non-2,2′-bipyridinediyl group-containing hole transporting polymer compound; and an organic solvent,
B) a second composition containing said 2,2′-bipyridinediyl group-containing polymer compound having a constitutional unit composed of an unsubstituted or substituted 2,2′-bipyridinediyl group, and at least one constitutional unit selected from the group consisting of constitutional units composed of a divalent aromatic amine residue and constitutional units composed of an unsubstituted or substituted arylene group; and an organic solvent,
or a combination thereof.

27. The organic electroluminescent device according to claim 13, wherein said hole transporting layer and said light emitting layer are in contact with each other, and a hole injection layer is disposed between said hole transporting layer and said anode.
